(19) United States
(12) Patent Application Publication
(10) Pub. No.: US 2026/0028266 A1
(43) Pub. Date: Jan. 29, 2026

(54) GLASS

(71) Applicant: AGC Inc., Tokyo (JP)

(72) Inventors: Rikiya KADO, Tokyo (JP); Hirofumi TOKUNAGA, Tokyo (JP)

(73) Assignee: AGC Inc., Tokyo (JP)

(21) Appl. No.: 19/348,011

(22) Filed: Oct. 2, 2025

Related U.S. Application Data
(63) Continuation of application No. PCT/JP2024/015074, filed on Apr. 16, 2024.

(30) Foreign Application Priority Data
Apr. 17, 2023 (JP) 2023-067480

(51) Int. Cl. C03C 3/095; C03C 4/00; H01L 23/15

(52) U.S. Cl. CPC C03C 3/095; C03C 4/0085; H01L 23/15

(57) ABSTRACT

Manufacturing is facilitated while deflection is suppressed, and transmission ability is increased. A glass (10) contains SiO₂: 40% to 60%, B₂O₃: 0.01% to 15%, and Al₂O₃+rare earth oxide: 0% to 20% as expressed in mol % on an oxide basis, and the ratio of the total content of Al₂O₃ and ΣRO to the total content of SiO₂, Al₂O₃, and ΣRO (that is, (Al₂O₃+ΣRO)/(SiO₂+Al₂O₃+ΣRO)) is 0.38 or more.

### CROSS-REFERENCE TO RELATED APPLICATION(S)

This application is a continuation of International Application No. PCT/JP2024/015074, filed on Apr. 16, 2024 which claims the benefit of priority of the prior Japanese Patent Application No. 2023-067480, filed on Apr. 17, 2023, the entire contents of which are incorporated herein by reference.

### BACKGROUND OF THE INVENTION

### 1. Field of the Invention

The present invention relates to glass.

### 2. Description of the Related Art

During manufacturing process of a semiconductor device, a glass may be used as a member for supporting the semiconductor device. For example, JP 2021-20840 A describes a supporting glass substrate having a high Young's modulus for suppressing deflection. In addition, the rate of thermal expansion may be lowered in order to suppress deflection due to the temperature change.

However, a glass having a low rate of thermal expansion and a high Young's modulus for suppressing deflection may be difficult to manufacture. In addition, the transmittance may deteriorate. Thus, there is a demand for a glass that is easy to manufacture while deflection is suppressed, and is excellent in the transmission ability.

### SUMMARY OF THE INVENTION

It is an object of the present invention to at least partially solve the problems in the conventional technology.

A glass of the present disclosure comprises:
SiO₂: 40% to 60%,
B₂O₃: 0.01% to 15%, and
Al₂O₃+rare earth oxide: 0% to 20%, as expressed in mol % on an oxide basis,
wherein a ratio of a total content of Al₂O₃ and ΣRO to a total content of SiO₂, Al₂O₃, and ΣRO, which is a total content of divalent oxides, (that is, (Al₂O₃+ΣRO)/(SiO₂+Al₂O₃+ΣRO)) is 0.38 or more.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a glass according to the present embodiment; and

FIG. 2 is a schematic diagram for explaining a deflection evaluation.

### DETAILED DESCRIPTION OF THE PREFERRED EMBODIMENTS

Hereinafter, preferred embodiments of the present invention will be described in detail with reference to the accompanying drawings. Note that the present invention is not limited by the embodiments, and in a case where there are a plurality of embodiments, the present invention includes a combination of the embodiments. In addition, the numerical value includes the range of rounding. Also, the numerical range represented by “to” means a numerical range including numerical values before and after “to” as a lower limit value and an upper limit value, and when “to” is used in the following description, the same meaning is given.

### Glass

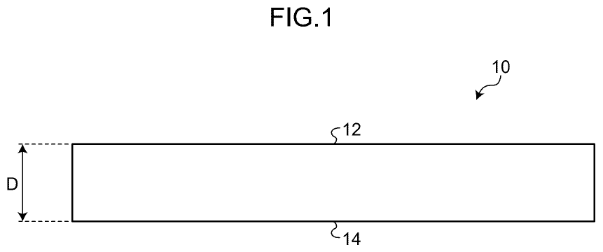

FIG. 1 is a schematic diagram of a glass according to the present embodiment. As illustrated in FIG. 1, the glass 10 according to the present embodiment is used as a glass substrate for manufacturing a semiconductor package, and more specifically, is a supporting glass substrate for manufacturing FOWLP or the like. However, the application of the glass 10 is not limited to the manufacture of FOWLP and the like and may be any application, and the glass 10 may be a glass substrate used for supporting a member or may be used for an application other than the support of a member. Note that FOWLP and the like encompass a fan out wafer level package (FOWLP) and a fan out panel level package (FOPLP).

### (Composition of Glass)

Next, a preferred composition of the glass 10 will be described.

### SiO₂

The glass 10 preferably contains SiO₂ (the content of SiO₂ is higher than 0 mol %). SiO₂ is a component for decreasing the coefficient of linear thermal expansion and is a component for controlling the Young's modulus. In addition, in order to appropriately suppress increases in the melting temperature and the liquidus temperature, the content of SiO₂ is preferably 60% or less. Further, SiO₂ has an effect of improving the acid resistance and the sulfuric acid resistance of glass. In the glass 10, the content of SiO₂ is preferably 40% or more and 60% or less, preferably 41% or more and 59% or less, preferably 42% or more and 58% or less, preferably 43% or more and 57% or less, preferably 43.5% or more and 56% or less, preferably 44% or more and 55% or less, preferably 44.5% or more and 54% or less, preferably 45% or more and 53% or less, preferably 45.5% or more and 52% or less, preferably 46% or more and 51.5% or less, preferably 46.5% or more and 51% or less, preferably 47% or more and 50.5% or less, preferably 47.5% or more and 50% or less, and more preferably 48% or more and 49.5% or less as expressed in mol % on an oxide basis. When the content of SiO₂ falls within this range, manufacturing can be facilitated while deflection is suppressed. Note that the content herein refers to a ratio of the content to the entire glass 10 in terms of mol % on an oxide basis. That is, for example, the content of SiO₂ of 40% or more and 60% or less means that the ratio of the content of SiO₂ to the entire glass 10 in terms of mol % on an oxide basis is 40% or more and 60% or less.

B₂O₃

B₂O₃ has effects of suppressing devitrification due to crystallization of glass to facilitate manufacturing and controlling the Young's modulus. Thus, the glass 10 need not contain B₂O₃ (the content of B₂O₃ is 0 mol %), but may contain B₂₀₃. In the glass 10, the content of B₂O₃ is preferably 0.01% or more and 15% or less, preferably 1% or more and 12% or less, preferably 2% or more and 10% or less, preferably 3% or more and 9% or less, preferably 4% or more and 8% or less, preferably 5% or more and 7% or less, and more preferably 5.5% or more and 6.5% or less as expressed in molo on an oxide basis. When the content of B₂O₃ falls within this range, manufacturing can be facilitated while deflection is suppressed.

Al₂O₃+Rare Earth Oxide

The glass 10 preferably contains at least one of Al₂O₃ or a rare earth oxide. The rare earth oxide herein may be one kind of rare earth oxide or a plurality of kinds of rare earth oxides. Containing Al₂O₃ and the rare earth oxide increases the Young's modulus. By not excessively reducing the total content of Al₂O₃ and the rare earth oxide, a decrease in the Young's modulus can be appropriately suppressed. In the glass 10, the total content of Al₂O₃ and the rare earth oxide (Al₂O₃+rare earth oxide) is preferably 0% or more and 20% or less, preferably 1% or more and 17% or less, preferably 3% or more and 16% or less, preferably 6% or more and 15% or less, preferably 7% or more and 14% or less, preferably 8% or more and 13% or less, preferably 9% or more and 12.5% or less, and more preferably 10% or more and 12% or less as expressed in mol % on an oxide basis. When the total content of Al₂O₃ and the rare earth oxide falls within this range, the liquidus temperature can be lowered, and thus manufacturing can be facilitated.

Note that the total content of Al₂O₃ and the rare earth oxide refers to the ratio of the total value of the content of Al₂O₃ and the content of the rare earth oxide to the entire glass 10. In addition, the glass 10 does not necessarily contain both Al₂O₃ and the rare earth oxide. For example, when the rare earth oxide is not contained, the total content of Al₂O₃ and the rare earth oxide refers to the content of Al₂O₃, and when the Al₂O₃ is not contained, it refers to the content of the rare earth oxide. When a plurality of kinds of rare earth oxides are contained, the content of the rare earth oxide refers to the total content of these rare earth oxides.

### Parameter A

The ratio of the total content of Al₂O₃ and ΣRO in the glass 10 to the total content of SiO₂, Al₂O₃, and ΣRO in the glass 10 (that is, (Al₂O₃+ΣRO)/(SiO₂+Al₂O₃+ΣRO)) as expressed in mol % on an oxide basis is defined as the parameter A. The ΣRO herein is the total content of divalent oxides. When a plurality of kinds of divalent oxides are contained, the total content of divalent oxides refers to the total content of these divalent oxides and when one kind of divalent oxide is contained, it refers to the content of the divalent oxide. The parameter A of the glass 10 is preferably 0.38 or more, preferably 0.39 or more and 0.5 or less, preferably 0.395 or more and 0.495 or less, preferably 0.4 or more and 0.49 or less, preferably 0.405 or more and 0.485 or less, preferably 0.41 or more and 0.48 or less, preferably 0.415 or more and 0.475 or less, preferably 0.42 or more and 0.47 or less, preferably 0.425 or more and 0.465 or less, preferably 0.43 or more and 0.46 or less, preferably 0.435 or more and 0.455 or less, and more preferably 0.44 or more and 0.45 or less. When the parameter A falls within this range, the melting temperature of the glass 10 can be lowered, and thus manufacturing can be facilitated.

Note that the glass 10 does not necessarily contain all of SiO₂, Al₂O₃, and a divalent oxide. For example, when SiO₂ is not contained, SiO₂ in (SiO₂+Al₂O₃+ΣRO) is treated as zero. Similarly, when Al₂O₃ is not contained, Al₂O₃ in (Al₂O₃+ΣRO) and (SiO₂+Al₂O₃+ΣRO) is treated as zero. Similarly, when no divalent oxide is contained, ΣRO in (Al₂O₃+ΣRO) and (SiO₂+Al₂O₃+ΣRO) is treated as zero.

Al₂O₃

Al₂O₃ has effects of increasing the Young's modulus to suppress deflection and suppressing phase separation of glass. Thus, the glass 10 need not contain Al₂O₃ (the content of Al₂O₃ is 0 mol %), but may contain Al₂O₃. In addition, by adjusting the content of Al₂O₃ to 20% or less, an increase in the liquidus temperature can be suppressed. In the glass 10, the content of Al₂O₃ is preferably 5% or more and 20% or less, preferably 6% or more and 18% or less, preferably 7% or more and 17% or less, preferably 8% or more and 16% or less, preferably 8.5% or more and 15% or less, preferably 9% or more and 14% or less, preferably 9.5% or more and 13% or less, preferably 10% or more and 12% or less, and more preferably 10.5% or more and 11% or less as expressed in mol % on an oxide basis. When the content of Al₂O₃ falls within this range, manufacturing can be facilitated while deflection is suppressed.

### MgO

Since MgO increases the Young's modulus without increasing the density, deflection can be suppressed by increasing the specific modulus. In addition, there is also an effect of reducing the coefficient of linear thermal expansion. On the other hand, by adjusting the content of MgO to 30% or less, the liquidus temperature can be controlled to be low. Thus, the glass 10 need not contain MgO (the content of MgO is 0 mol %), but may contain MgO. In the glass 10, the content of MgO is preferably 1% or more and 30% or less, more preferably 5% or more and 29.5% or less, more preferably 9% or more and 29% or less, more preferably 10% or more and 28.5% or less, more preferably 11% or more and 28% or less, more preferably 12% or more and 27.5% or less, more preferably 13% or more and 27% or less, more preferably 14% or more and 26.5% or less, more preferably 15% or more and 26% or less, more preferably 16% or more and 25.5% or less, more preferably 17% or more and 25% or less, more preferably 18% or more and 24.5% or less, more preferably 19% or more and 24% or less, more preferably 19.5% or more and 23.5% or less, and more preferably 20% or more and 23% or less as expressed in mol % on an oxide basis. When the content of MgO falls within this range, manufacturing can be facilitated while deflection is suppressed.

### Cao

CaO has characteristics of increasing the specific modulus next to MgO in the oxides of the group 2 elements, and not excessively decreasing the coefficient of linear thermal expansion, and further has a characteristic of being less likely to increase the liquidus temperature as compared with MgO. Thus, the glass 10 need not contain Cao (the content of Cao is 0 mol %), but may contain Cao. By adjusting the content of Cao to 10% or less, an increase in the coefficient of linear thermal expansion can be suppressed, and the liquidus temperature can be controlled to be low. In the glass 10, the content of Cao is preferably 0.01% or more and 10% or less, preferably 0.5% or more and 9% or less, preferably 1% or more and 8% or less, preferably 1.5% or more and 7% or less, preferably 1.65% or more and 6% or less, preferably 1.8% or more and 5% or less, and more preferably 2% or more and 4% or less as expressed in mol % on an oxide basis. In addition, the content of CaO may be 0.5% or more and 2% or less, or 1% or more and 1.5% or less. When the content of Cao falls within this range, manufacturing can be facilitated while deflection is suppressed.

### SrO

SrO has effects of improving the meltability of glass and lowering the liquidus temperature. Thus, the glass 10 need not contain SrO (the content of SrO is 0 mol %), but may contain SrO. By adjusting the content of SrO to 10% or less, an increase in the coefficient of linear thermal expansion can be suppressed, and the liquidus temperature can be controlled to be low. In the glass 10, the content of SrO is preferably 0.01% or more and 10% or less, preferably 0.5% or more and 9% or less, preferably 1% or more and 8% or less, preferably 1.5% or more and 7% or less, preferably 1.65% or more and 6% or less, preferably 1.8% or more and 5% or less, and more preferably 2% or more and 4% or less as expressed in mol % on an oxide basis. In addition, the content of SrO may be 0.5% or more and 2% or less, or 1% or more and 1.5% or less. When the content of SrO falls within this range, manufacturing can be facilitated while deflection is suppressed.

### BaO

BaO has effects of improving the meltability of glass and lowering the liquidus temperature. Thus, the glass 10 need not contain Bao (the content of Bao is 0 mol %), but may contain Bao. By adjusting the content of Bao to 10% or less, an increase in the coefficient of linear thermal expansion can be suppressed, and the liquidus temperature can be controlled to be low. In the glass 10, the content of BaO is preferably 0.01% or more and 10% or less, preferably 0.5% or more and 9% or less, preferably 1% or more and 8% or less, preferably 1.5% or more and 7% or less, preferably 1.65% or more and 6% or less, preferably 1.8% or more and 5% or less, and more preferably 2% or more and 4% or less as expressed in mol % on an oxide basis. In addition, the content of BaO may be 0.5% or more and 2% or less, or 1% or more and 1.5% or less. When the content of BaO falls within this range, manufacturing can be facilitated while deflection is suppressed.

In addition, by lowering the content of Bao, it is possible to suppress occurrence of cloudy defects on the surface caused when the glass is immersed in an acid. Thus, the glass 10 may contain BaO or need not contain BaO. In the glass 10, the content of Bao is preferably 10% or less, preferably 5% or less, preferably 3% or less, preferably 1% or less, preferably 0.8% or less, preferably 0.5% or less, more preferably 0.3% or less, and more preferably 0.1% or less as expressed in mol % on an oxide basis. When the content of BaO falls within this range, cloudy defects can be suppressed, and the sulfuric acid resistance of the glass can be improved.

### Li₂O

Among alkali metal oxides, Li₂O has an effect of improving the meltability without decreasing the coefficient of linear thermal expansion. Thus, the glass 10 need not contain Li₂O (the content of Li₂O is 0 mol %), but may contain Li₂O. By adjusting the content of Li₂O to 5% or less, the Young's modulus can be increased, and an increase in the coefficient of linear thermal expansion can be suppressed. In the glass 10, the content of Li₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less as expressed in mol % on an oxide basis. When the content of Li₂O falls within this range, manufacturing can be facilitated while deflection is suppressed.

### Na₂O

Among alkali metal oxides, Na₂O especially has effects of improving the meltability of glass and lowering the liquidus temperature. Thus, the glass 10 need not contain Na₂O (the content of Na₂O is 0 mol %), but may contain Na₂O. By adjusting the content of Na₂O to 5% or less, the Young's modulus can be increased, and an increase in the coefficient of linear thermal expansion can be suppressed. In the glass 10, the content of Na₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less as expressed in mol % on an oxide basis. When the content of Na₂O falls within this range, manufacturing can be facilitated while deflection is suppressed.

### K₂O

K₂O has effects of improving the meltability of glass and lowering the liquidus temperature. Thus, the glass 10 need not contain K₂O (the content of K₂O is 0 mol %), but may contain K₂O. By adjusting the content of K₂O to 5% or less, the Young's modulus can be increased, and an increase in the coefficient of linear thermal expansion can be suppressed. In the glass 10, the content of K₂O is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less as expressed in mol % on an oxide basis. When the content of K₂O falls within this range, manufacturing can be facilitated while deflection is suppressed.

The glass 10 may contain an alkali metal component, but preferably does not contain an alkali metal component. In the glass 10, the total content of alkali metal components is preferably 1% or less, more preferably 0.001% or more and 0.1% or less, more preferably 0.003% or more and 0.05% or less, and still more preferably 0.005% or more and 0.01% or less as expressed in mol % on an oxide basis. When the total content of the alkali metal components is small as described above, it is possible to suppress deterioration of properties of a metal or an oxide film provided on a glass surface in a manufacturing process of FOWLP or the like.

Note that the alkali metal component herein refers to a Group 1 metal such as Li, Na, K, or Rb or an oxide thereof contained in the glass 10.

### ZnO

ZnO has effects of improving the meltability of glass and increasing the Young's modulus. Thus, the glass 10 need not contain ZnO (the content of ZnO is 0 mol %), but may contain ZnO. By adjusting the content of ZnO to 10% or less, an increase in the coefficient of linear thermal expansion can be suppressed, and the liquidus temperature can be controlled. In the glass 10, the content of ZnO is preferably 0.01% or more and 10% or less, more preferably 0.1% or more and 9% or less, more preferably 0.2% or more and 8% or less, more preferably 0.4% or more and 7% or less, more preferably 0.6% or more and 6% or less, more preferably 0.8% or more and 5% or less, and more preferably 1% or more and 4% or less as expressed in mol % on an oxide basis. When the content of ZnO falls within this range, manufacturing can be facilitated while deflection is suppressed.

P₂O₅

P₂O₅ has effects of improving the meltability of glass and lowering the coefficient of linear thermal expansion. Thus, the glass 10 need not contain P₂O₅ (the content of P₂O₅ is 0 mol %), but may contain P₂O₅. By adjusting the content of P₂O₅ to 5% or less, the Young's modulus can be increased without deteriorating the chemical resistance, and an increase in the coefficient of linear thermal expansion can be suppressed. In the glass 10, the content of P₂O₅ is preferably 0.01% or more and 5% or less, more preferably 0.1% or more and 4% or less, more preferably 0.15% or more and 3% or less, more preferably 0.2% or more and 2% or less, more preferably 0.25% or more and 1.5% or less, and more preferably 0.3% or more and 1% or less as expressed in molo on an oxide basis. When the content of P₂O₅ falls within this range, manufacturing can be facilitated while deflection is suppressed.

### ZrO₂

ZrO₂ can increase the Young's modulus without relatively decreasing the coefficient of linear thermal expansion. In addition, ZrO₂ has an effect of improving the acid resistance and the sulfuric acid resistance of glass. Thus, the glass 10 need not contain ZrO₂ (the content of ZrO₂ is 0 mol %), but may contain ZrO₂. By adjusting the content of ZrO₂ to 10% or less, the liquidus temperature can be controlled. In the glass 10, the content of ZrO₂ is preferably 0.01% or more and 10% or less, more preferably 0.2% or more and 7% or less, more preferably 0.5% or more and 4% or less, more preferably 0.7% or more and 4% or less, and more preferably 1% or more and 2% or less as expressed in mol % on an oxide basis. When the content of ZrO₂ falls within this range, manufacturing can be facilitated while deflection is suppressed.

### TiO₂

TiO₂ can increase the Young's modulus without relatively decreasing the coefficient of linear thermal expansion. In addition, TiO₂ has an effect of improving the acid resistance and the sulfuric acid resistance of glass. Thus, the glass 10 need not contain TiO₂ (the content of TiO₂ is 0 mol %), but may contain TiO₂. By adjusting the content of TiO₂ to 10% or less, the liquidus temperature can be controlled. In the glass 10, the content of TiO₂ is preferably 0.01% or more and 10% or less, more preferably 0.2% or more and 7% or less, more preferably 0.5% or more and 4% or less, more preferably 0.7% or more and 4% or less, and more preferably 1% or more and 2% or less as expressed in mol % on an oxide basis. When the content of TiO₂ falls within this range, manufacturing can be facilitated while deflection is suppressed.

Y₂O₃

Y₂O₃ has effects of improving the meltability of glass and increasing the Young's modulus. Thus, the glass 10 need not contain Y₂O₃ (the content of Y₂O₃ is 0 mol %), but may contain Y₂O₃. By adjusting the content of Y₂O₃ to 7% or less, the coefficient of linear thermal expansion can be controlled. In the glass 10, the content of Y₂O₃ is preferably 0.1% or more and 7% or less, more preferably 0.7% or more and 6% or less, more preferably 1% or more and 5% or less, more preferably 1.5% or more and 4% or less, and more preferably 2% or more and 3% or less as expressed in mol % on an oxide basis. When the content of Y₂O₃ falls within this range, manufacturing can be facilitated while deflection is suppressed.

Gd₂O₃

Gd₂O₃ has effects of improving the meltability of glass and increasing the Young's modulus. Thus, the glass 10 need not contain Gd₂O₃ (the content of Gd₂O₃ is 0 mol %), but may contain Gd₂O₃. By adjusting the content of Gd₂O₃ to 7% or less, the coefficient of linear thermal expansion can be controlled. In the glass 10, the content of Gd₂O₃ is preferably 0.1% or more and 7% or less, more preferably 0.7% or more and 6% or less, more preferably 1% or more and 5% or less, more preferably 1.5% or more and 4% or less, and more preferably 2% or more and 3% or less as expressed in molo on an oxide basis. When the content of Gd₂O₃ falls within this range, manufacturing can be facilitated while deflection is suppressed.

La₂O₃

La₂O₃ has effects of improving the meltability of glass and increasing the Young's modulus. Thus, the glass 10 need not contain La₂O₃ (the content of La₂O₃ is 0 mol %), but may contain La₂O₃. By adjusting the content of La₂O₃ to 7% or less, the coefficient of linear thermal expansion can be controlled. In the glass 10, the content of La₂O₃ is preferably 0.1% or more and 7% or less, more preferably 0.7% or more and 6% or less, more preferably 1% or more and 5% or less, more preferably 1.5% or more and 4% or less, and more preferably 2% or more and 3% or less as expressed in mol % on an oxide basis. When the content of La₂O₃ falls within this range, manufacturing can be facilitated while deflection is suppressed.

### WO₃

WO₃ has effects of improving the meltability of glass and increasing the Young's modulus. Thus, the glass 10 need not contain WO₃ (the content of WO₃ is 0 mol %), but may contain WO₃. By adjusting the content of WO₃ to 7% or less, an increase in the coefficient of linear thermal expansion can be suppressed, and the liquidus temperature can be controlled. In the glass 10, the content of WO₃ is preferably 0.1% or more and 7% or less, more preferably 0.3% or more and 5% or less, more preferably 0.5% or more and 3% or less, more preferably 0.8% or more and 2.5% or less, and more preferably 1% or more and 2% or less as expressed in mol % on an oxide basis. When the content of WO₃ falls within this range, manufacturing can be facilitated while deflection is suppressed.

Ta₂O₅

Ta₂O₅ has effects of decreasing the coefficient of linear thermal expansion and increasing the Young's modulus. In addition, Ta₂O₅ has an effect of improving the acid resistance and the sulfuric acid resistance of glass. Thus, the glass 10 need not contain Ta₂O₅ (the content of Ta₂O₅ is 0 mol %), but may contain Ta₂O₅. By adjusting the content of Ta₂O₅ to 10% or less, the liquidus temperature can be controlled. In the glass 10, the content of Ta₂O₅ is preferably 0.1% or more and 10% or less, more preferably 0.5% or more and 5% or less, more preferably 1% or more and 4% or less, more preferably 1.5% or more and 3.5% or less, and more preferably 2% or more and 3% or less as expressed in mol % on an oxide basis. When the content of Ta₂O₅ falls within this range, manufacturing can be facilitated while deflection is suppressed.

### MnO

MnO has an effect of increasing the Young's modulus. However, MnO may increase the liquidus temperature, and even a small amount of MnO causes the glass to be colored from dark brown to black. Thus, it is preferable that the glass 10 does not contain MnO. In the glass 10, the content of MnO is preferably 5% or less, preferably 3% or less, preferably 0.1% or less, more preferably 0.001% or more and 0.05% or less, and still more preferably 0.005% or more and 0.01% or less as expressed in mol % on an oxide basis. When the content of MnO falls within this range, a decrease in the light transmittance can be suppressed.

### PbO

PbO has an effect of increasing the Young's modulus, but is an oxide having a high environmental load. Thus, it is preferable that the glass 10 does not contain PbO. In the glass 10, the content of PbO is preferably 0.1% or less, more preferably 0.05% or less, and still more preferably 0.01% or less as expressed in mol % on an oxide basis. When the content of PbO falls within this range, the environmental load can be suppressed.

Fe₂O₃

The glass 10 preferably does not contain Fe₂O₃. In the glass 10, the content of Fe₂O₃ in outer percentage is preferably 0.1% or less, more preferably 0.001% or more and 0.05% or less, and still more preferably 0.005% or more and 0.01% or less as expressed in mass % on an oxide basis. When the content of Fe₂O₃ is low as described above, a decrease in the light transmittance can be suppressed.

Note that the content of Fe₂O₃ in outer percentage refers to the ratio of the mass of Fe₂O₃ contained in the glass 10 to the total value of the mass of all the components of the glass 10 excluding Fe₂O₃ on an oxide basis.

Y₂O₃+Gd₂O₃+La₂O₃+Nd₂O₃+Ta₂O₅+Nb₂O₅

In the glass 10, the total content of Y₂O₃, Gd₂O₃, La₂O₃, Nd₂O₃, Ta₂O₅, and Nb₂O₅ (Y₂O₃+Gd₂₀₃+Ta₂O₅+La₂O₃+Nd₂O₃+Nb₂O₅) is preferably 0.5% or more, more preferably 1% or more and 10% or less, more preferably 2% or more and 8% or less, more preferably 3% or more and 7% or less, and more preferably 4% or more and 6% or less as expressed in mol % on an oxide basis. The total content of these components may be 1% or more and 4% or less, or 1.5% or more and 2% or less. When the total content of these components falls within this range, manufacturing can be facilitated while deflection is suppressed.

Note that the glass 10 need not contain all of the above components, and may include only some of the components. In addition, the glass 10 may contain none of the above components. That is, for example, when Y₂O₃ is not contained, (Y₂O₃) in (Y₂O₃+Gd₂O₃+Ta₂O₅+La₂O₃+Nd₂O₃+Nb₂O₅) is treated as zero, and the same applies to a case where other components are not contained.

(Al₂O₃+MgO)/(SiO₂+Al₂O₃+B₂O₃+MgO)

In the glass 10, the ratio of the total content of Al₂O₃ and MgO to the total content of SiO₂, Al₂O₃, B₂O₃, and MgO (that is, (Al₂O₃+MgO)/(SiO₂+Al₂O₃+B₂O₃+MgO)) as expressed in mol % on an oxide basis is preferably 0.1 or more and 1 or less, more preferably 0.26 or more and 0.48 or less, more preferably 0.28 or more and 0.46 or less, more preferably 0.3 or more and 0.44 or less, more preferably 0.32 or more and 0.42 or less, and more preferably 0.34 or more and 0.4 or less. When the total content of these components falls within this range, the Young's modulus can be increased to suppress deflection.

Note that the glass 10 does not necessarily contain all of SiO₂, Al₂O₃, B₂O₃, and MgO. That is, for example, when Al₂O₃ is not contained, (Al₂O₃) in (Al₂O₃+MgO) and (SiO₂+Al₂O₃+B₂O₃+MgO) is treated as zero, and the same applies to a case where other components are not contained.

### MgO/ΣRO

In the glass 10, the ratio of the content of MgO to the total content of divalent oxides (ΣRO), (MgO/ΣRO) as expressed in mol % on an oxide basis is preferably 0.3 or more and 1 or less, more preferably 0.4 or more and 0.9 or less, more preferably 0.45 or more and 0.875 or less, more preferably 0.5 or more and 0.85 or less, more preferably 0.55 or more and 0.825 or less, and more preferably 0.6 or more and 0.8 or less. In addition, the ratio may be 0.75% or more and 0.95% or less, or 0.8% or more and 0.9% or less. When the total content of these components falls within this range, the coefficient of linear thermal expansion can be lowered to suppress deflection.

Note that the glass 10 does not necessarily contain divalent oxides such as MgO. For example, when MgO is not contained, MgO in (MgO/ΣRO) is treated as zero, and when divalent oxides other than MgO are not contained, the content of the divalent oxides other than MgO in (MgO/ΣRO) is treated as zero.

### Value of N

In the glass 10, the number of oxides present in a content of 0.5% or more, among oxides contained in the glass 10, represented by N, is preferably 5 or more, more preferably 7 or more, more preferably 8 or more, more preferably 9 or more, and more preferably 10 or more. When the number of N is high as described above, the liquidus temperature can be lowered, and thus manufacturing can be facilitated.

Note that the glass 10 preferably does not contain a sintered body. That is, the glass 10 is preferably a glass that is not a sintered body. Here, the sintered body refers to a member in which a plurality of particles are heated at a temperature lower than the melting point to bond the particles. The porosity of the sintered body is high to some extent because the sintered body includes voids, but the porosity of the glass 10 is low, and is usually 0% because the glass is not a sintered body. However, it is allowable to include an inevitable very small amount of pores. The porosity herein is a so-called true porosity, and refers to a value obtained by dividing a sum of volumes of pores (voids) communicating with the outside and pores (voids) not communicating with the outside by a total volume (apparent volume). The porosity can be measured according to, for example, JIS R 1634:1998 “Test methods for density and apparent porosity of fine ceramics”.

In addition, it is preferable that a glass used for the glass 10 is usually an amorphous glass, that is, an amorphous solid. Also, this glass may be a crystallized glass containing crystals on the surface or inside, but an amorphous glass is preferable from the viewpoint of density. Among ceramics, those produced by a sintering method are preferably not used because they have a low transmittance and a high density.

### Shape of Glass

Next, the shape of the glass 10 will be described. As illustrated in FIG. 1, the glass 10 is a plate-like glass substrate including a surface 12 which is a principal surface on one side and a surface 14 which is a principal surface opposite to the surface 12. The surface 14 may be, for example, parallel to the surface 12. The glass 10 may have a disk shape that is circular in plan view, that is, when viewed from a direction orthogonal to the surface 12, but the glass is not limited to the disk shape and may have any shape, and may be a plate of a polygonal shape such as a rectangle. Note that examples of the shape also include shapes in which a cut-out such as a notch or an orientation flat is provided on the outer periphery.

In addition, the thickness D of the glass 10, that is, the length between the surface 12 and the surface 14 is preferably 0.1 mm or more and 5.0 mm or less, more preferably 0.1 mm or more and 2.0 mm or less, and still more preferably 0.1 mm or more and 0.5 mm or more. By adjusting the thickness D to 0.1 mm or more, it is possible to prevent the glass 10 from becoming too thin and to suppress breakage due to deflection or impact. By adjusting the thickness D to 2.0 mm or less, it is possible to suppress the weight, and by adjusting the thickness D to 0.5 mm or less, it is possible to more suitably suppress the weight.

### Properties of Glass

Next, properties of the glass 10 will be described.

### Young's Modulus

The Young's modulus E of the glass 10 is preferably 80 GPa or more, more preferably 85 GPa or more and 180 GPa or less, more preferably 88 GPa or more and 170 GPa or less, more preferably 90 GPa or more and 160 GPa or less, more preferably 93 GPa or more and 150 GPa or less, more preferably 95 GPa or more and 145 GPa or less, more preferably 97 GPa or more and 140 GPa or less, more preferably 98 GPa or more and 135 GPa or less, and still more preferably 99 GPa or more and 130 GPa or less. By setting the Young's modulus E within this range, deflection can be appropriately suppressed. When the Young's modulus is too high, cutting, grinding, and polishing processing become difficult.

### Young's Modulus Parameter

The Young's modulus parameter Y of the glass 10 calculated from the composition is preferably 0.8 or more, more preferably 0.85 or more and 1.8 or less, more preferably 0.88 or more and 1.7 or less, more preferably 0.9 or more and 1.6 or less, more preferably 0.93 or more and 1.5 or less, more preferably 0.95 or more and 1.45 or less, more preferably 0.97 or more and 1.4 or less, more preferably 0.98 or more and 1.35 or less, and still more preferably 0.99 or more and 1.3 or less. By setting the Young's modulus parameter within this range, deflection can be appropriately suppressed.

The Young's modulus parameter Y is calculated from Formula (1).

$$Y = ( 123 - 0.54 [ {SiO}_{2} ] + 0.3 [ {Al}_{2} {O}_{3} ] - 1.15 [ {B}_{2} {O}_{3} ] + 0.21 [ MgO ] - 0.2 [ CaO ] - 0.1 [ SrO ] - 1.2 [ BaO ] + [ {Li}_{2} O ] - 2.8 [ {K}_{2} O ] + 0.05 [ ZnO ] + 1.46 [ {ZrO}_{2} ] - 0.05 [ {TiO}_{2} ] + 1.6 [ {Y}_{2} {O}_{3} ] + 1.35 [ {Gd}_{2} {O}_{3} ] + 1.37 [ {La}_{2} {O}_{3} ] + [ {Ta}_{2} {O}_{5} ] ) / 100 \qquad ( 1 )$$

Note that the content of the oxide RₓO_{y} (R is an element constituting the oxide, and x and y are any suitable integers) contained in the glass 10 in terms of mol % on an oxide basis is represented by [RₓO_{y}]. The content herein refers to the ratio of the content of the oxide RₓO_{y} to the entire glass 10 in terms of mol % on an oxide basis. That is, for example, [SiO₂] in Formula (1) refers to the ratio of the content of SiO₂ to the entire glass 10 in terms of mol % on an oxide basis.

The glass 10 need not contain all the oxides shown in Formula (1). In Formula (1), the content of the oxide not contained in the glass 10 is treated as zero. In addition, the glass 10 may contain a component other than the oxides shown in Formula (1).

### Coefficient of Linear Thermal Expansion

The coefficient of linear thermal expansion α of the glass 10 is preferably 6 ppm/° C. or less, more preferably 3 ppm/° C. or more and 5.9 ppm/° C. or less, more preferably 3.5 ppm/° C. or more and 5.8 ppm/° C. or less, more preferably 4 ppm/° C. or more and 5.7 ppm/° C. or less, more preferably 4.2 ppm/° C. or more and 5.6 ppm/° C. or less, more preferably 4.4 ppm/° C. or more and 5.5 ppm/° C. or less, more preferably 4.6 ppm/° C. or more and 5.4 ppm/° C. or less, and still more preferably 4.8 ppm/° C. or more and 5.3 ppm/° C. or less.

The coefficient of linear thermal expansion α of the glass 10 may also be in the following range. The coefficient of linear thermal expansion α of the glass 10 is preferably 6.5 ppm/° C. or less, more preferably 3 ppm/° C. or more and 6.4 ppm/° C. or less, more preferably 3.5 ppm/° C. or more and 6.3 ppm/° C. or less, more preferably 4 ppm/° C. or more and 6.2 ppm/° C. or less, more preferably 4.5 ppm/° C. or more and 6.1 ppm/° C. or less, more preferably 5 ppm/° C. or more and 6 ppm/° C. or less, more preferably 5.5 ppm/° C. or more and 5.9 ppm/° C. or less, more preferably 5.6 ppm/° C. or more and 5.85 ppm/° C. or less, and still more preferably 5.7 ppm/° C. or more and 5.8 ppm/° C. or less.

In addition, the coefficient of linear thermal expansion α of the glass 10 may be in the following range. The coefficient of linear thermal expansion α of the glass 10 is preferably 5.0 ppm/° C. or less, more preferably 3.6 ppm/° C. or more and 4.9 ppm/° C. or less, more preferably 3.7 ppm/° C. or more and 4.8 ppm/° C. or less, more preferably 3.8 ppm/° C. or more and 4.7 ppm/° C. or less, more preferably 3.85 ppm/° C. or more and 4.65 ppm/° C. or less, more preferably 3.9 ppm/° C. or more and 4.6 ppm/° C. or less, more preferably 3.95 ppm/° C. or more and 4.55 ppm/° C. or less, more preferably 4 ppm/° C. or more and 4.5 ppm/° C. or less, more preferably 4.1 ppm/° C. or more and 4.45 ppm/° C. or less, and still more preferably 4.2 ppm/° C. or more and 4.4 ppm/° C. or less.

By setting the coefficient of linear thermal expansion within this range, deflection can be appropriately suppressed. The coefficient of linear thermal expansion α is an average coefficient of thermal expansion in the range of 50° C. to 200° C., and is a value measured in accordance with DIN-51045-1 as a standard for thermal expansion measurement. For example, measurement is performed in the range of 30° C. to 300° C. using a dilatometer DIL 402 Expedis Supreme) manufactured by NETZSCH as a measuring apparatus, and an average coefficient of thermal expansion in the range of 50° C. to 200° C. may be employed as the coefficient of linear thermal expansion.

### Thermal Expansion Parameter

The thermal expansion parameter C of the glass 10 calculated from the composition is preferably 1.2 or less, more preferably 0.6 or more and 1.18 or less, more preferably 0.7 or more and 1.16 or less, more preferably 0.8 or more and 1.14 or less, more preferably 0.84 or more and 1.12 or less, more preferably 0.88 or more and 1.1 or less, more preferably 0.92 or more and 1.08 or less, and still more preferably 0.96 or more and 1.06 or less.

The thermal expansion parameter C of the glass 10 may also be in the following range. The thermal expansion parameter C is preferably 1.3 or less, more preferably 0.6 or more and 1.28 or less, more preferably 0.7 or more and 1.26 or less, more preferably 0.8 or more and 1.24 or less, more preferably 0.9 or more and 1.22 or less, more preferably 1 or more and 1.2 or less, more preferably 1.1 or more and 1.18 or less, more preferably 1.12 or more and 1.17 or less, and still more preferably 1.14 or more and 1.16 or less.

In addition, the thermal expansion parameter C of the glass 10 may be in the following range. The thermal expansion parameter C is preferably 1.0 or less, more preferably 0.72 or more and 0.98 or less, more preferably 0.74 or more and 0.96 or less, more preferably 0.76 or more and 0.94 or less, more preferably 0.77 or more and 0.93 or less, more preferably 0.78 or more and 0.92 or less, more preferably 0.79 or more and 0.91 or less, more preferably 0.8 or more and 0.9 or less, more preferably 0.82 or more and 0.89 or less, and still more preferably 0.84 or more and 0.88 or less.

By setting the thermal expansion parameter C within this range, the coefficient of linear thermal expansion can be kept low, and deflection can be appropriately suppressed.

The thermal expansion parameter C is calculated from Formula (2).

$$C = ( 14.098 - 0.1245 [ {SiO}_{2} ] - 0.131 [ {Al}_{2} {O}_{3} ] - 0.101 [ {B}_{2} {O}_{3} ] - 0.051 [ MgO ] + 0.013 [ CaO ] + 0.53 [ SrO ] + 0.018 [ BaO ] + 0.041 [ {Li}_{2} O ] + 0.395 [ {Na}_{2} O ] - 0.066 [ ZnO ] - 0.033 [ {ZrO}_{2} ] - 0.072 [ {TiO}_{2} ] + 0.035 [ {Y}_{2} {O}_{3} ] + 0.074 [ {Gd}_{2} {O}_{3} ] + 0.074 [ {La}_{2} {O}_{3} ] - 0.091 [ {Ta}_{2} {O}_{5} ] ) / 5 \qquad ( 2 )$$

The glass 10 need not contain all the oxides shown in Formula (2). In Formula (2), the content of the oxide not contained in the glass 10 is treated as zero. In addition, the glass 10 may contain a component other than the oxides shown in Formula (2).

### Liquidus Temperature

The liquidus temperature T_{L} of the glass 10 is preferably 1300° C. or lower, more preferably 800° C. or higher and 1290° C. or lower, more preferably 825° C. or higher and 1280° C. or lower, more preferably 850° C. or higher and 1270° C. or lower, more preferably 875° C. or higher and 1260° C. or lower, more preferably 900° C. or higher and 1250° C. or lower, more preferably 925° C. or higher and 1240° C. or lower, more preferably 950° C. or higher and 1230° C. or lower, more preferably 975° C. or higher and 1220° C. or lower, more preferably 1000° C. or higher and 1210° C. or lower, and still more preferably 1200° C. or lower. By setting the liquidus temperature within this range, manufacturing can be facilitated. The liquidus temperature can be evaluated by placing glass particles, which pass through a sieve with a mesh width of 4.0 mm and do not pass through a sieve with a mesh width of 2.3 mm, on a platinum dish, then holding the glass particles for 1 hour in an electric furnace set at a predetermined temperature, and measuring the temperature at which crystals are precipitated.

### Liquidus Parameter

The liquidus parameter L of the glass 10 calculated from the composition is preferably 10.5 or less, more preferably 6.4 or more and 10.4 or less, more preferably 7.2 or more and 10.3 or less, more preferably 7.6 or more and 10.2 or less, more preferably 7.7 or more and 10.1 or less, more preferably 7.8 or more and 10 or less, more preferably 7.9 or more and 9.9 or less, and still more preferably 8 or more and 9.8 or less. is still more preferred. By setting the liquidus parameter L within this range, the liquidus temperature can be kept low, and thus manufacturing can be facilitated.

The liquidus parameter L is calculated from Formula (3).

$$L = ( - 642.5 + 20.6 [ {SiO}_{2} ] + 31.9 [ {Al}_{2} {O}_{3} ] + 2.85 [ {B}_{2} {O}_{3} ] + 11.24 [ MgO ] + 17.3 [ CaO ] + 1.75 [ SrO ] + 31.41 [ BaO ] - 6.86 [ {Li}_{2} O ] + 37.96 [ {K}_{2} O ] + 11.47 [ ZnO ] + 25.83 [ {ZrO}_{2} ] + 41. [ {TiO}_{2} ] + 12.32 [ {Y}_{2} {O}_{3} ] - 1.18 [ {Gd}_{2} {O}_{3} ] - 1.18 [ {La}_{2} {O}_{3} ] + 24.46 [ {Ta}_{2} {O}_{5} ] ) / 125 \qquad ( 3 )$$

The glass 10 need not contain all the oxides shown in Formula (3). In Formula (3), the content of the oxide not contained in the glass 10 is treated as zero. In addition, the glass 10 may contain a component other than the oxides shown in Formula (3).

Melting Temperature T₂, Working Temperature T₃, Molding Temperature T₄

The melting temperature T₂ of the glass 10 is preferably 1000° C. or higher and 1550° C. or lower, more preferably 1100° C. or higher and 1500° C. or lower, more preferably 1150° C. or higher and 1450° C. or lower, more preferably 1200° C. or higher and 1400° C. or lower, and more preferably 1250° C. or higher and 1350° C. or lower. The melting temperature T₂ refers to a temperature at which the viscosity n is 102 dPa·s. When the melting temperature T₂ is relatively low as described above, melting can be facilitated.

The working temperature T₃ of the glass 10 is preferably 1000° C. or higher and 1400° C. or lower, more preferably 1050° C. or higher and 1350° C. or lower, more preferably 1080° C. or higher and 1300° C. or lower, more preferably 1100° C. or higher and 1250° C. or lower, and more preferably 1130° C. or higher and 1200° C. or lower. The working temperature T₃ refers to a temperature at which the viscosity n is 103 dPa·s. When the working temperature T₃ is relatively low as described above, molding can be easily performed.

The molding temperature T₄ of the glass 10 is preferably 900° C. or higher and 1250° C. or lower, more preferably 950° C. or higher and 1200° C. or lower, more preferably 1000° C. or higher and 1150° C. or lower, and more preferably 1030° C. or higher and 1100° C. or lower. The molding temperature T₄ refers to a temperature at which the viscosity η is 104 dPa·s. When the molding temperature T₄ is relatively low as described above, molding can be easily performed.

Note that the melting temperature T₂, the working temperature T₃, and the molding temperature T₄ can be measured by an inner cylinder rotation method or the like.

### Glass Transition Temperature

The glass transition temperature of the glass 10 is preferably 600° C. or higher and 850° C. or lower, more preferably 620° C. or higher and 800° C. or lower, more preferably 640° C. or higher and 780° C. or lower, more preferably 660° C. or higher and 760° C. or lower, more preferably 680° C. or higher and 740° C. or lower, more preferably 690° C. or higher and 730° C. or lower, and still more preferably 695° C. or higher and 720° C. or lower. The glass transition temperature can be measured in accordance with the method defined in JIS R3103-3:2001 “Viscosity and viscometric fixed temperature of glass-Part 3: Determination of dilatometric transformation temperature”.

### Density

The density of the glass 10 is preferably 2.6 g/cm³ or more and 3.6 g/cm³ or less, more preferably 2.7 g/cm³ or more and 3.4 g/cm³ or less, more preferably 2.75 g/cm³ or more and 3.35 g/cm³ or less, more preferably 2.8 g/cm³ or more and 3.3 g/cm³ or less, more preferably 2.85 g/cm³ or more and 3.25 g/cm³ or less, and still more preferably 2.9 g/cm³ or more and 3.2 g/cm³ or less.

### Liquidus Viscosity

The liquidus viscosity log η_{L} (dPa·s) of the glass 10 is preferably 2 or more and 7 or less, more preferably 2.2 or more and 6.5 or less, more preferably 2.4 or more and 6 or less, more preferably 2.6 or more and 5.5 or less, more preferably 2.8 or more and 5 or less, more preferably 2.9 or more and 4.5 or less, and more preferably 3 or more and 4.2 or less. The liquidus viscosity refers to the viscosity of the glass 10 at the liquidus temperature. When the liquidus viscosity is relatively high as described above, manufacturing can be facilitated. Note that the liquidus viscosity can be determined by measuring a temperature-viscosity curve according to an inner cylinder rotation method or the like and calculating the viscosity at the liquidus temperature.

### Fracture Toughness Value

The fracture toughness value K_{IC} of the glass 10 is preferably 0.5 MPa·m^{0.5} or more and 2 MPa·m^{0.5} or less, more preferably 0.7 MPa·m^{0.5} or more and 1.5 MPa·m^{0.5} or less, more preferably 0.8 MPa·m^{0.5} or more and 1.4 MPa·m^{0.5} or less, and still more preferably 0.9 MPa·m^{0.5} or more and 1.3 MPa·m^{0.5} or less. When the fracture toughness value K_{IC} falls within this range, breakage of the glass 10 can be suppressed. Note that the fracture toughness value K_{IC} can be measured using a single-edge-precracked-beam method (SEPB method) as defined in, for example, JIS R1607:2015 “Testing methods for fracture toughness of fine ceramics at room temperature”.

### Transmittance of Light

The internal transmittance for light with a wavelength of 308 nm (ultraviolet ray) through the glass 10 having a thickness D of 0.7 mm is preferably 30% or more, more preferably 35% or more, still more preferably 40% or more, still more preferably 45% or more, still more preferably 50% or more, still more preferably 55% or more, and still more preferably 60% or more. When the transmittance for light with a wavelength of 308 nm falls within this range, ultraviolet rays can be appropriately transmitted.

The internal transmittance for light with a wavelength of 350 nm (ultraviolet ray) through the glass 10 having a thickness D of 0.7 mm is preferably 30% or more, more preferably 40% or more, still more preferably 50% or more, still more preferably 60% or more, still more preferably 70% or more, still more preferably 75% or more, and still more preferably 77% or more. When the transmittance for light with a wavelength of 350 nm falls within this range, ultraviolet rays can be appropriately transmitted.

The internal transmittance for light with a wavelength of 550 nm (visible light) through the glass 10 having a thickness D of 0.7 mm is preferably 70% or more, more preferably 75% or more, still more preferably 80% or more, still more preferably 85% or more, still more preferably 86% or more, still more preferably 87% or more, and still more preferably 88% or more. When the transmittance for light with a wavelength of 550 nm falls within this range, visible light can be appropriately transmitted.

The internal transmittance for light with a wavelength of 1064 nm (infrared ray) through the glass 10 having a thickness D of 0.7 mm is preferably 80% or more, more preferably 85% or more, and more preferably 90% or more. When the transmittance for light with a wavelength of 1064 nm falls within this range, infrared rays can be appropriately transmitted.

Note that the transmittance can be measured by measuring a spectral transmittance curve with a spectrophotometer or the like.

### Sulfuric Acid Resistance

The amount of weight change (amount of weight loss) at the time of exposure of the glass 10 to acid (sulfuric acid) is preferably 0.20 mg/cm² or less, preferably 0.10 mg/cm² or less, preferably 0.050 mg/cm² or less, preferably 0.030 mg/cm² or less, preferably 0.020 mg/cm² or less, preferably 0.015 mg/cm² or less, preferably 0.010 mg/cm² or less, preferably 0.008 mg/cm² or less, preferably 0.005 mg/cm² or less, and more preferably 0.003 mg/cm² or less. When the amount of weight change at the time of exposure of the glass 10 to acid is small as described above, the glass 10 can be used in an acid environment. In addition, it can be repeatedly used in the acid treatment step. The amount of weight change at the time of exposure to acid refers to a value obtained by dividing the absolute value of the difference between the weight of the glass 10 after exposure to acid and the weight of the glass 10 before exposure to acid by the surface area of the glass 10 before exposure to acid. The conditions for exposure to acid may be any conditions, but in this case, the glass 10 is immersed in sulfuric acid (H₂SO₄) having a pH of 2 and a temperature of 40° C. for 2 hours.

In addition, it is preferable that the glass 10 has no change in the light transmission ability of the glass 10 before exposure to acid and after exposure to acid. In the determination of a change in the transmission ability after exposure to acid, at the time of visual observation, a case where no cloudy portion was observed on the surface was evaluated as “∘” (no change in the transmission ability), and a case where a cloudy portion was observed was evaluated as “×” (change in the transmission ability). When the change in the transmission ability at the time of exposure of the glass 10 to acid is small as described above, the glass 10 can be used in an acid environment. In addition, it can be repeatedly used in the acid treatment step.

The state before exposure to acid refers to a state after the glass 10 is weighed and before it is exposed to acid. Then, the state after exposure to acid refers to a state after the glass 10 is weighed and exposed to acid. The conditions for exposure to acid may be any conditions, but in this case, the glass 10 is immersed in sulfuric acid (H₂SO₄) having a pH of 2 and a temperature of 40° C. for 2 hours.

As described above, the glass 10 according to the present embodiment preferably has high sulfuric acid resistance. When the sulfuric acid resistance of the glass 10 is high, there is an effect that makes the light transmission ability less likely to be impaired even after the glass 10 is exposed to sulfuric acid. In addition, when the sulfuric acid resistance of the glass is high, it is possible to suppress surface deposits at the time of exposure to sulfuric acid. When the glass subjected to the process including sulfuric acid immersion is introduced into the subsequent process, the surface deposits may contaminate the process. By suppressing the surface deposits, it is possible to suppress process contamination.

### Sulfuric Acid Resistance Parameter

The sulfuric acid resistance parameter S of the glass 10 calculated from the BaO content and the amount of weight change at the time of exposure to acid is preferably −3 or less, more preferably −3.5 or less, more preferably −4.0 or less, more preferably −4.5 or less, more preferably −4.7 or less, more preferably −5.0 or less, more preferably −5.3 or less, and still more preferably −5.5 or less.

By setting the sulfuric acid resistance parameter S within this range, it is possible to suppress occurrence of cloudy defects (cloudy portions) at the time of exposure to acid.

The sulfuric acid resistance parameter S is calculated from Formula (4).

$$S = [ BaO ] = 3.75 \times {log}_{10} ( amount of weight change at the time of exposure to acid ) \qquad ( 4 )$$

Note that the BaO content and the amount of weight change at the time of exposure to acid shown in Formula (4) may be 0.

### (Acid Resistance Parameter)

The acid resistance parameter T of the glass 10 calculated from the composition is preferably −1.0 or more, more preferably −0.5 or more, more preferably 0.0 or more, more preferably 0.15 or more, more preferably 0.3 or more, more preferably 0.5 or more, more preferably 0.65 or more, more preferably 0.8 or more, more preferably 0.9 or more, more preferably 1.0 or more, and still more preferably 1.05 or more. By setting the acid resistance parameter T within this range, it is possible to suppress a weight change at the time of exposure to acid (for example, sulfuric acid).

The acid resistance parameter T is calculated from Formula (5).

$$A = 0.1 [ {SiO}_{2} ] + 0.017 [ {Al}_{2} {O}_{3} ] + 0.025 [ {B}_{2} {O}_{3} ] + 0.044 [ MgO ] + 0.003 [ CaO ] - 0.001 [ SrO ] - 0.001 [ BaO ] + 0.036 [ {Li}_{2} O ] + 0.002 [ ZnO ] + 0.183 [ {ZrO}_{2} ] + 0.114 [ {TiO}_{2} ] + 0.012 [ {Y}_{2} {O}_{3} ] - 0.06 [ {Gd}_{2} {O}_{3} ] - 0.001 [ {La}_{2} {O}_{3} ] + 0.329 [ {Ta}_{2} {O}_{5} ] - 5.97 \qquad ( 5 )$$

Note that the content of the oxide RₓO_{y} (R is an element constituting the oxide, and x and y are any suitable integers) contained in the glass 10 in terms of mol % on an oxide basis is represented by [RₓO_{y}]. The content herein refers to the ratio of the content of the oxide RₓO_{y} to the entire glass 10 in terms of mol % on an oxide basis. That is, for example, [SiO₂] in Formula (5) refers to the ratio of the content of SiO₂ to the entire glass 10 in terms of mol % on an oxide basis.

The glass 10 need not contain all the oxides shown in Formula (5). In Formula (5), the content of the oxide not contained in the glass 10 is treated as zero. In addition, the glass 10 may contain a component other than the oxides shown in Formula (5).

### Method for Manufacturing Glass

The glass 10 may be manufactured by any method, but is manufactured, for example, by the following method. First, raw materials such as silica sand and soda ash, which are raw materials of the compounds contained in the glass 10, are melted by heating at a predetermined temperature (for example, 1500° C. to 1600° C.). Then, after the melted raw materials (glass) are clarified, a molding step of molding the glass into a plate shape is performed. The molded glass has the composition range of the glass 10 described above on an oxide basis. Then, a slow cooling step is performed on the glass molded in the molding step to manufacture glass 10.

Note that the method for manufacturing the glass 10 is not limited to the above, and may be any method. For example, the slow cooling step is not essential. In addition, various methods can be adopted as the molding step in manufacturing the glass 10, and examples thereof include a melt casting method, down-draw methods (for example, an overflow down-draw method, a slot down method, a redraw method, and the like), a float method, a roll-out method, and a press method.

Next, an example of a manufacturing step performed when the glass 10 is used for FOWLP manufacturing will be described. In the FOWLP manufacturing, a plurality of semiconductor chips are bonded onto the glass 10, and the semiconductor chips are covered with an encapsulant to form an element substrate. Then, the glass 10 and the element substrate are separated, and the opposite side of the element substrate from the semiconductor chips is bonded onto, for example, another glass 10. Then, wiring, solder bumps, and the like are formed on the semiconductor chips, and the element substrate and the glass 10 are separated again. Then, the element substrate is cut into pieces for each semiconductor chip, thereby obtaining a semiconductor device.

### Effects

As described above, a glass 10 according to a first aspect of the present disclosure contains,
SiO₂: 40% to 60%,

B₂₀₃: 0.01% to 15%, and
Al₂O₃+rare earth oxide: 0% to 20%,
as expressed in mol % on an oxide basis
a parameter A, which is a ratio of the total content of Al₂O₃ and ΣRO to the total content of SiO₂, Al₂O₃, and ΣRO, being 0.38 or more.

According to the present disclosure, when the parameter A falls within the above range, the melting temperature of the glass 10 can be lowered, and thus manufacturing can be facilitated. When the contents of other components fall within the above ranges, deflection can be suppressed. Thus, according to the present disclosure, manufacturing can be facilitated while deflection is suppressed.

In addition, for example, a glass having a high Young's modulus and a low coefficient of thermal expansion for suppressing deflection has a high melting temperature and thus may be difficult to manufacture. On this matter, in the present disclosure, by adopting the above-described composition, an increase in the melting temperature can be suppressed, and thus manufacturing can be facilitated.

A glass 10 according to a second aspect of the present disclosure is the glass 10 according to the first aspect, and preferably contains
SiO₂: 41% to 59%,
B₂O₃: 1% to 12%,
Al₂O₃: 5% to 20%, and
(Y₂O₃+Gd₂O₃+Ta₂O₅+La₂O₃+Nd₂O₃+Nb₂O₅): 0.5% or more,
as expressed in mol % on an oxide basis. By adjusting the content of each component within this range, manufacturing can be facilitated while deflection is suppressed.

A glass 10 according to a third aspect of the present disclosure is the glass 10 according to the first aspect or the second aspect, preferably has a transmittance of light with a wavelength of 308 nm at a thickness of 0.7 mm of 30% or more. When the transmittance falls within this range, ultraviolet rays can be appropriately transmitted.

A glass 10 according to a fourth aspect of the present disclosure is the glass 10 according to any one of the first to third aspects, and preferably satisfies

$$0.1 \leq \{ ( {Al}_{2} {O}_{3} + MgO ) / ( {SiO}_{2} + {Al}_{2} {O}_{3} + {B}_{2} {O}_{3} + MgO ) \} \leq 1. ,$$

$$0.3 \leq ( MgO / {Σ}_{RO} ) \leq 1 , and$$

$$0 \% \leq {Al}_{2} {O}_{3} + rare earth oxide \leq 20 \% ,$$

as expressed in mol % on an oxide basis. As a result, since the Young's modulus can be increased, the coefficient of linear thermal expansion can be decreased, and the liquidus temperature can be decreased, manufacturing can be facilitated while deflection is suppressed.

A glass 10 according to a fifth aspect of the present disclosure is the glass 10 according to any one of the first to fourth aspects, and preferably has a Young's modulus parameter Y calculated by Formula (1) of 0.8 or more, a thermal expansion parameter C calculated by Formula (2) of 1.2 or less, and a liquidus parameter L calculated by Formula (3) of 10.5 or less. As a result, since the Young's modulus can be increased, the coefficient of linear thermal expansion can be decreased, and the liquidus temperature can be decreased, manufacturing can be facilitated while deflection is suppressed.

A glass 10 according to a sixth aspect of the present disclosure is the glass 10 according to any one of the first to fifth aspects, and is preferably used as a substrate. The glass 10 of the present disclosure is suitably used for a substrate.

A glass 10 according to a seventh aspect of the present disclosure is the glass 10 according to the sixth aspect, and is preferably used in manufacture of at least one of a fan out wafer level package or a fan out panel level package. The glass 10 is suitably used for these applications.

### EXAMPLES

Next, examples will be described. Tables 1 to 117 are tables showing properties of the glass of each example. Note that the embodiment may be changed as long as the effects of the invention are obtained.

TABLE 1

| (mol %) | Example 1 | Example 2 | Example 3 | Example 4 |
|---|---|---|---|---|
| SiO₂ | 48 | 49 | 50 | 49 |
| Al₂O₃ | 12 | 12 | 12 | 13 |
| B₂O₃ | 7 | 7 | 7 | 7 |
| MgO | 22 | 22 | 22 | 23 |
| CaO | 2 | 2 | 2 | 2 |
| SrO | 2 | 2 | 2 | 2 |
| BaO | 2 | 2 | 2 | 2 |
| Li₂O | 1 | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 1 | 1 | 1 | |
| Gd₂O₃ | 1 | 1 | | |
| La₂O₃ | | | | |
| WO₃ | | | | |
| Ta₂O₅ | | | | |
| Al₂O₃ + rare earth oxide | 14 | 14 | 13 | 13 |
| Y₂O₃ + Gd₂O₃ + La₂O₃ + Nd₂O₃ + Ta₂O₅ + Nb₂O₅ | 2 | 2 | 1 | 0 |
| Parameter A = (Al₂O₃ + RO)/(SiO₂ + Al₂O₃ + RO) | 0.45 | 0.45 | 0.44 | 0.46 |
| (Al₂O₃ + MgO)/(SiO₂ + Al₂O₃ + B₂O₃ + MgO) | 0.38 | 0.38 | 0.37 | 0.39 |
| MgO/ΣRO | 0.79 | 0.79 | 0.79 | 0.79 |
| N | 12 | 11 | 10 | 9 |
| Young's modulus E (GPa) | 101 | 98 | 96 | 95 |
| Coefficient of thermal expansion α (ppm/° C.) | 4.95 | 4.76 | 4.52 | 4.41 |
| Liquidus temperature TL (° C.) | 1155 | 1150 | 1185 | 1215 |
| Young's modulus parameter Y | 1.00 | 0.98 | 0.96 | 0.96 |
| Liquidus parameter L | 9.3 | 9.6 | 9.7 | 9.8 |
| Thermal expansion parameter C | 0.99 | 0.95 | 0.91 | 0.90 |
| Glass transition point (° C.) | 697 | 725 | 724 | 722 |
| Density (g/cm³) | 2.90 | 2.89 | 2.78 | 2.72 |
| Liquidus viscosity log η_{L} (dPa · s) | 3.17 | 3.32 | 3.15 | 2.9 |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 85≤ | 85≤ | 85≤ | 85≤ |
| Transmittance (%) @550 nm, 0.7 mmt | 90≤ | 90≤ | 90≤ | 90≤ |
| Transmittance (%) @1064 nm, 0.7 mmt | 85≤ | 85≤ | 85≤ | 85≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | 0.095 | | | |
| Sulfuric acid resistance (transmission ability) | x | | | |
| Sulfuric acid resistance parameter S | −1.83 | | | |
| Acid resistance parameter T | 0.51 | 0.58 | 0.74 | 0.68 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |
| (mol %) | Example 5 | Example 6 | Example 7 | Example 8 |
| SiO₂ | 48 | 48 | 48 | 48 |
| Al₂O₃ | 12 | 11 | 10 | 12 |
| B₂O₃ | 7 | 7 | 7 | 7 |
| MgO | 22 | 22 | 22 | 20 |
| CaO | 2 | 3 | 3 | 3 |
| SrO | 3 | 3 | 3 | 3 |
| BaO | 2 | 3 | 3 | 3 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 1 | 1 | 2 |
| Gd₂O₃ | | | | |
| La₂O₃ | | | | |
| WO₃ | | | | |
| Ta₂O₅ | | | 1 | |
| Al₂O₃ + rare earth oxide | 14 | 12 | 11 | 14 |
| Y₂O₃ + Gd₂O₃ + La₂O₃ + Nd₂O₃ + Ta₂O₅ + Nb₂O₅ | 2 | 1 | 2 | 2 |
| Parameter A = (Al₂O₃ + RO)/(SiO₂ + Al₂O₃ + RO) | 0.46 | 0.47 | 0.46 | 0.46 |
| (Al₂O₃ + MgO)/(SiO₂ + Al₂O₃ + B₂O₃ + MgO) | 0.38 | 0.38 | 0.37 | 0.37 |
| MgO/ΣRO | 0.76 | 0.71 | 0.71 | 0.69 |
| N | 10 | 10 | 11 | 10 |
| Young's modulus E (GPa) | 99 | 96 | 97 | 98 |
| Coefficient of thermal expansion α (ppm/° C.) | 4.9 | 5.01 | 4.96 | 5 |
| Liquidus temperature TL (° C.) | 1155 | 1175 | 1165 | 1155 |
| Young's modulus parameter Y | 0.99 | 0.95 | 0.96 | 0.97 |
| Liquidus parameter L | 9.5 | 9.6 | 9.5 | 9.7 |
| Thermal expansion parameter C | 0.98 | 1.01 | 1.01 | 1.01 |
| Glass transition point (° C.) | 718 | 710 | 708 | 718 |
| Density (g/cm³) | 2.87 | 2.85 | 2.97 | 2.90 |
| Liquidus viscosity log η_{L} (dPa · s) | 3.27 | 3.08 | 3.17 | 3.14 |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 85≤ | 85≤ | 85≤ | 85≤ |
| Transmittance (%) @550 nm, 0.7 mmt | 90≤ | 90≤ | 90≤ | 90≤ |
| Transmittance (%) @1064 nm, 0.7 mmt | 85≤ | 85≤ | 85≤ | 85≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | 0.091 | | | 0.095 |
| Sulfuric acid resistance (transmission ability) | x | | | x |
| Sulfuric acid resistance parameter S | −1.90 | | | −0.83 |
| Acid resistance parameter T | 0.55 | 0.52 | 0.83 | 0.46 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

TABLE 2

| (mol %) | Example 9 | Example 10 | Example 11 | Example 12 |
|---|---|---|---|---|
| SiO₂ | 47 | 48 | 48 | 48 |
| Al₂O₃ | 12 | 11 | 11 | 12 |
| B₂O₃ | 9 | 7 | 7 | 7 |
| MgO | 22 | 22 | 22 | 22 |
| CaO | 2 | 3 | 3 | 3 |
| SrO | 2 | 3 | 3 | 3 |
| BaO | 2 | 3 | 3 | 3 |
| Li₂O | | | | |
| Na₂O | | | | |
| K₂O | | | | |
| ZnO | | | | |
| P₂O₅ | | | | |
| ZrO₂ | 1 | 1 | | |
| TiO₂ | 1 | | 1 | |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 14 | 13 | 13 | 14 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.46 | 0.47 | 0.47 | 0.47 |
| (Al₂O₃ + MgO)/(SiO₂ + Al₂O₃ + B₂O₃ + MgO) | 0.38 | 0.38 | 0.38 | 0.38 |
| MgO/ΣRO | 0.79 | 0.71 | 0.71 | 0.71 |
| N | 10 | 9 | 9 | 8 |
| Young's modulus E (GPa) | 98 | 98 | 96.6 | 96.6 |
| Coefficient of thermal expansion α (ppm/° C.) | 4.68 | 5.14 | 5.22 | 5.08 |
| Liquidus temperature TL (° C.) | 1130 | 1155 | 1170 | 1175 |
| Young's modulus parameter Y | 0.97 | 0.97 | 0.96 | 0.96 |
| Liquidus parameter L | 9.4 | 9.3 | 9.4 | 9.4 |
| Thermal expansion parameter C | 0.96 | 1.03 | 1.02 | 1.01 |
| Glass transition point (° C.) | 717 | 709 | 710 | 709 |
| Density (g/cm³) | 2.82 | 2.91 | 2.89 | 2.88 |
| Liquidus viscosity log η_{L} (dPa · s) | 3.23 | 3.08 | 2.5< | 2.5< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 85≤ | 85≤ | 85≤ | 85≤ |
| Transmittance (%) @550 nm, 0.7 mmt | 90≤ | 90≤ | 90≤ | 90≤ |
| Transmittance (%) @1064 nm, 0.7 mmt | 85≤ | 85≤ | 85≤ | 85≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | | 0.181 | 0.171 | 0.281 |
| Sulfuric acid resistance (transmission ability) | | x | x | x |
| Sulfuric acid resistance parameter S | | 0.22 | 0.12 | 0.93 |
| Acid resistance parameter T | 0.50 | 0.42 | 0.35 | 0.25 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |
| (mol %) | Example 13 | Example 14 | Example 15 | Example 16 |
| SiO₂ | 51 | 52 | 50 | 48 |
| Al₂O₃ | 12 | 11 | 10 | 11 |
| B₂O₃ | 5 | 3 | 6 | 7 |
| MgO | 20 | 22 | 22 | 22 |
| CaO | 3 | 3 | 2 | 2 |
| SrO | 3 | 3 | 2 | 2 |
| BaO | 3 | 2 | 4 | 4 |
| Li₂O | | | | |
| Na₂O | | | | |
| K₂O | | | | |
| ZnO | | | | |
| P₂O₅ | | | | |
| ZrO₂ | | 1 | 1 | 1 |
| TiO₂ | | 1 | 1 | 1 |
| Y₂O₃ | 3 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 15 | 13 | 12 | 13 |
| Y₂O₃ + Gd₂O₃ + La₂O₃ + Nd₂O₃ + Ta₂O₅ + Nb₂O₅ | 3 | 2 | 2 | 2 |
| Parameter A = (Al₂O₃ + RO)/(SiO₂ + Al₂O₃ + RO) | 0.45 | 0.44 | 0.44 | 0.46 |
| (Al₂O₃ + MgO)/(SiO₂ + Al₂O₃ + B₂O₃ + MgO) | 0.36 | 0.38 | 0.36 | 0.38 |
| MgO/ΣRO | 0.69 | 0.73 | 0.73 | 0.73 |
| N | 8 | 10 | 10 | 10 |
| Young's modulus E (GPa) | 98.9 | 100.5 | 97 | 96.4 |
| Coefficient of thermal expansion α (ppm/° C.) | 5.04 | 4.97 | 5.06 | 5.21 |
| Liquidus temperature TL (° C.) | 1185 | 1210 | 1190 | 1150 |
| Young's modulus parameter Y | 0.98 | 1.01 | 0.96 | 0.96 |
| Liquidus parameter L | 9.7 | 10.0 | 9.8 | 9.8 |
| Thermal expansion parameter C | 1.00 | 0.99 | 1.00 | 1.00 |
| Glass transition point (° C.) | 724 | 731 | 722 | 722 |
| Density (g/cm³) | 2.94 | 2.91 | 2.91 | 2.92 |
| Liquidus viscosity log η_{L} (dPa · s) | 2.5< | 2.94 | 2.84 | 3.09 |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 85≤ | 85≤ | 85≤ | 85≤ |
| Transmittance (%) @550 nm, 0.7 mmt | 90≤ | 90≤ | 90≤ | 90≤ |
| Transmittance (%) @1064 nm, 0.7 mmt | 85≤ | 85≤ | 85≤ | 85≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | 0.224 | | 0.047 | 0.096 |
| Sulfuric acid resistance (transmission ability) | x | | x | x |
| Sulfuric acid resistance parameter S | 0.56 | | −0.98 | 0.18 |
| Acid resistance parameter T | 0.43 | 0.83 | 0.69 | 0.53 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

TABLE 3

| (mol %) | Example 17 | Example 18 | Example 19 | Example 20 |
|---|---|---|---|---|
| SiO₂ | 49 | 52 | 52 | 52 |
| Al₂O₃ | 11 | 11 | 11 | 11 |
| B₂O₃ | 7 | 5 | 5 | 5 |
| MgO | 19 | 18 | 19 | 18 |
| CaO | 3 | 2 | 2 | 3 |
| SrO | 3 | 3 | 3 | 3 |
| BaO | 3 | 4 | 3 | 3 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 3 | 3 | 3 | 3 |
| Gd₂O₃ | | | | |
| La₂O₃ | | | | |
| WO₃ | | | | |
| Ta₂O₅ | | | | |
| Al₂O₃ + rare earth oxide | 14 | 14 | 14 | 14 |
| Y₂O₃ + Gd₂O₃ + La₂O₃ + Nd₂O₃ + Ta₂O₅ + Nb₂O₅ | 3 | 3 | 3 | 3 |
| Parameter A = (Al₂O₃ + RO)/(SiO₂ + Al₂O₃ + RO) | 0.44 | 0.42 | 0.42 | 0.42 |
| (Al₂O₃ + MgO)/(SiO₂ + Al₂O₃ + B₂O₃ + MgO) | 0.35 | 0.34 | 0.34 | 0.34 |
| MgO/ΣRO | 0.68 | 0.67 | 0.70 | 0.67 |
| N | 10 | 10 | 10 | 10 |
| Young's modulus E (GPa) | 98 | 97 | 98 | 97 |
| Coefficient of thermal expansion α (ppm/° C.) | 5.4 | 5.16 | 4.87 | 4.96 |
| Liquidus temperature TL (° C.) | 1110 | 1230 | 1155 | 1165 |
| Young's modulus parameter Y | 0.97 | 0.97 | 0.98 | 0.98 |
| Liquidus parameter L | 9.6 | 10.1 | 10.0 | 10.0 |
| Thermal expansion parameter C | 1.03 | 1.00 | 0.99 | 1.00 |
| Glass transition point (° C.) | 720 | 732 | 732 | 731 |
| Density (g/cm³) | 2.98 | 2.99 | 2.94 | 2.93 |
| Liquidus viscosity log η_{L} (dPa · s) | 2.5< | 2.3< | 2.5< | 2.5< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 85≤ | 85≤ | 85≤ | 85≤ |
| Transmittance (%) @550 nm, 0.7 mmt | 90≤ | 90≤ | 90≤ | 90≤ |
| Transmittance (%) @1064 nm, 0.7 mmt | 85≤ | 85≤ | 85≤ | 85≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | 0.082 | 0.056 | | |
| Sulfuric acid resistance (transmission ability) | x | x | | |
| Sulfuric acid resistance parameter S | −1.07 | −0.69 | | |
| Acid resistance parameter T | 0.51 | 0.71 | 0.76 | 0.72 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |
| (mol %) | Example 21 | Example 22 | Example 23 | Example 24 |
| SiO₂ | 50 | 50 | 48 | 48 |
| Al₂O₃ | 11 | 11 | 11 | 11 |
| B₂O₃ | 5 | 5 | 5 | 5 |
| MgO | 17 | 15 | 17 | 17 |
| CaO | 3 | 4 | 4 | 4 |
| SrO | 4 | 4 | 4 | 4 |
| BaO | 4 | 5 | 5 | 5 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 4 | 4 | 4 | 2 |
| Gd₂O₃ | | | | |
| La₂O₃ | | | | 2 |
| WO₃ | | | | |
| Ta₂O₅ | | | | |
| Al₂O₃ + rare earth oxide | 15 | 15 | 15 | 15 |
| Y₂O₃ + Gd₂O₃ + La₂O₃ + Nd₂O₃ + Ta₂O₅ + Nb₂O₅ | 4 | 4 | 4 | 4 |
| Parameter A = (Al₂O₃ + RO)/(SiO₂ + Al₂O₃ + RO) | 0.44 | 0.44 | 0.46 | 0.46 |
| (Al₂O₃ + MgO)/(SiO₂ + Al₂O₃ + B₂O₃ + MgO) | 0.34 | 0.32 | 0.35 | 0.35 |
| MgO/ΣRO | 0.61 | 0.54 | 0.57 | 0.57 |
| N | 10 | 10 | 10 | 11 |
| Young's modulus E (GPa) | 98 | 98 | 100 | 98 |
| Coefficient of thermal expansion α (ppm/° C.) | 5.11 | 5.48 | 5.79 | 5.73 |
| Liquidus temperature TL (° C.) | 1235 | 1275 | 1295 | 1295 |
| Young's modulus parameter Y | 0.99 | 0.97 | 0.99 | 0.98 |
| Liquidus parameter L | 10.0 | 10.2 | 10.0 | 9.8 |
| Thermal expansion parameter C | 1.08 | 1.11 | 1.14 | 1.16 |
| Glass transition point (° C.) | 725 | 725 | 721 | 720 |
| Density (g/cm³) | 3.06 | 3.11 | 3.13 | 3.19 |
| Liquidus viscosity log η_{L} (dPa · s) | 2.3< | 1.8< | 1.7< | 1.7< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Transmittance (%) @1064 nm, 0.7 mmt | 85≤ | 85≤ | 85≤ | 85≤ |
| T₂ (° C.) | <1300 | <1300 | <1300 | <1300 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | | | | |
| Sulfuric acid resistance (transmission ability) | | | | |
| Sulfuric acid resistance parameter S | | | | |
| Acid resistance parameter T | 0.48 | 0.40 | 0.28 | 0.26 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

TABLE 4

| (mol %) | Example 25 | Example 26 | Example 27 | Example 28 |
|---|---|---|---|---|
| SiO₂ | 50 | 50 | 50.6 | 47.9 |
| Al₂O₃ | 7 | 11 | 8 | 8 |
| B₂O₃ | 3 | 5 | 3 | 3 |
| MgO | 16 | 12 | 16.4 | 19.1 |
| CaO | 5 | 4 | 4 | 5 |
| SrO | 4 | 4 | 4 | 4 |
| BaO | 4 | 5 | 3 | 4 |
| Li₂O | | | | |
| Na₂O | | | | |
| K₂O | | | | |
| ZnO | 8 | | 5 | 5 |
| P₂O₅ | | | | |
| ZrO₂ | 1.2 | 1 | 1 | 1 |
| TiO₂ | 1 | 1 | 1 | 1 |
| Y₂O₃ | 0.8 | 7 | | 2 |
| Gd₂O₃ | | | | |
| La₂O₃ | | | 4 | |
| WO₃ | | | | |
| Ta₂O₅ | | | | |
| Al₂O₃ + rare earth oxide | 7.8 | 18 | 12.0 | 10.0 |
| Y₂O₃ + Gd₂O₃ + La₂O₃ + Nd₂O₃ + Ta₂O₅ + Nb₂O₅ | 0.8 | 7 | 4 | 2 |
| Parameter A = (Al₂O₃ + RO)/(SiO₂ + Al₂O₃ + RO) | 0.47 | 0.42 | 0.44 | 0.48 |
| (Al₂O₃ + MgO)/(SiO₂ + Al₂O₃ + B₂O₃ + MgO) | 0.30 | 0.29 | 0.31 | 0.35 |
| MgO/ΣRO | 0.43 | 0.48 | 0.51 | 0.51 |
| N | 11 | 10 | 11 | 11 |
| Young's modulus E (GPa) | 96 | 100 | 99 | 99 |
| Coefficient of thermal expansion α (ppm/° C.) | 5.50 | 5.69 | 5.81 | 5.78 |
| Liquidus temperature TL (° C.) | 1185 | 1295 | 1185 | 1225 |
| Young's modulus parameter Y | 0.95 | 1.01 | 1.00 | 0.99 |
| Liquidus parameter L | 9.5 | 10.2 | 9.1 | 9.5 |
| Thermal expansion parameter C | 1.11 | 1.16 | 1.16 | 1.16 |
| Glass transition point (° C.) | 675 | 736 | 698 | 688 |
| Density (g/cm³) | 3.12 | 3.25 | 3.32 | 3.22 |
| Liquidus viscosity log η_{L} (dPa · s) | 2.5< | 1.7< | 2.64 | 2.2< |
| K_{IC} (MPa · m^{0.5}) | 0.8< | 0.8< | 0.89 | 0.8< |
| Transmittance (%) @308 nm, 0.7 mmt | 30≤ | 30≤ | 34.5 | 30≤ |
| Transmittance (%) @350 nm, 0.7 mmt | 75≤ | 75≤ | 84.2 | 75≤ |
| Transmittance (%) @550 nm, 0.7 mmt | 88≤ | 88≤ | 89.3 | 88≤ |
| Transmittance (%) @1064 nm, 0.7 mmt | 85≤ | 85≤ | 89.5 | 85≤ |
| T₂ (° C.) | <1300 | <1300 | <1300 | <1300 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | | | 0.165 | |
| Sulfuric acid resistance (transmission ability) | | | x | |
| Sulfuric acid resistance parameter S | | | 0.07 | |
| Acid resistance parameter T | 0.34 | 0.30 | 0.38 | 0.26 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

| (mol %) | Example 29 | Example 30 | Example 31 | Example 32 |
|---|---|---|---|---|
| SiO₂ | 48.2 | 49.1 | 49.3 | 48 |
| Al₂O₃ | 8 | 8 | 8 | 11 |
| B₂O₃ | 3 | 3 | 3.1 | 5 |
| MgO | 19.8 | 23.9 | 24.7 | 17 |
| CaO | 4 | 4 | 3 | 2 |
| SrO | 4 | 4 | 3 | 6 |
| BaO | 4 | 4 | 3 | 2 |
| Li₂O | | | | 3 |
| Na₂O | | | | |
| K₂O | | | | |
| ZnO | 5 | | | |
| P₂O₅ | | | | |
| ZrO₂ | 1 | 1 | 1 | 1 |
| TiO₂ | 1 | 1 | 1 | 1 |
| Y₂O₃ | | | | 4 |
| Gd₂O₃ | | | | |
| La₂O₃ | 2 | 2 | 4 | |
| WO₃ | | | | |
| Ta₂O₅ | | | | |
| Al₂O₃ + rare earth oxide | 10.0 | 10.0 | 12.0 | 15 |
| Y₂O₃ + Gd₂O₃ + La₂O₃ + Nd₂O₃ + Ta₂O₅ + Nb₂O₅ | 2 | 2 | 4 | 4 |
| Parameter A = (Al₂O₃ + RO)/(SiO₂ + Al₂O₃ + RO) | 0.48 | 0.47 | 0.46 | 0.44 |
| (Al₂O₃ + MgO)/(SiO₂ + Al₂O₃ + B₂O₃ + MgO) | 0.35 | 0.38 | 0.38 | 0.35 |
| MgO/ΣRO | 0.54 | 0.67 | 0.73 | 0.63 |
| N | 11 | 10 | 10 | 11 |
| Young's modulus E (GPa) | 99 | 99 | 102 | 104 |
| Coefficient of thermal expansion α (ppm/° C.) | 5.85 | 5.93 | 6.00 | 5.82 |
| Liquidus temperature TL (° C.) | 1225 | 1290 | 1290 | 1225 |
| Young's modulus parameter Y | 0.98 | 0.99 | 1.03 | 1.06 |
| Liquidus parameter L | 9.3 | 9.3 | 9.0 | 8.8 |
| Thermal expansion parameter C | 1.16 | 1.16 | 1.16 | 1.17 |
| Glass transition point (° C.) | 688 | 707 | 720 | 644 |
| Density (g/cm³) | 3.22 | 3.13 | 3.25 | 3.06 |
| Liquidus viscosity log η_{L} (dPa · s) | 2.2< | 1.7< | 1.7< | 2.28 |
| K_{IC} (MPa · m^{0.5}) | 0.8< | 0.8< | 0.8< | 0.94 |
| Transmittance (%) @308 nm, 0.7 mmt | 30≤ | 30≤ | 30≤ | 39.4 |
| Transmittance (%) @350 nm, 0.7 mmt | 75≤ | 75≤ | 75≤ | 87.9 |
| Transmittance (%) @550 nm, 0.7 mmt | 88≤ | 88≤ | 88≤ | 89.8 |
| Transmittance (%) @1064 nm, 0.7 mmt | 85≤ | 85≤ | 85≤ | 90.1 |
| T₂ (° C.) | <1300 | 1279 | <1300 | <1300 |
| T₃ (° C.) | <1200 | 1152 | <1200 | <1200 |
| T₄ (° C.) | <1100 | 1063 | <1100 | <1100 |
| Sulfuric acid resistance (amount of weight loss (mg/cm²)) | | | | 0.169 |
| Sulfuric acid resistance (transmission ability) | | | | x |
| Sulfuric acid resistance parameter S | | | | −0.90 |
| Acid resistance parameter T | 0.29 | 0.55 | 0.60 | 0.39 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

TABLE 5

| (mol %) | Example 33 | Example 34 | Example 35 | Example 36 | Example 37 |
|---|---|---|---|---|---|
| SiO₂ | 48 | 51 | 51 | 52.5 | 51.4 |
| Al₂O₃ | 12 | 13 | 12 | 12.5 | 12.3 |
| B₂O₃ | 7 | 7 | 7 | 7.5 | 8 |
| MgO | 20 | 21 | 21 | 21.5 | 21 |
| CaO | 3 | 1 | 2 | 1 | 1.3 |
| SrO | 2 | 1 | 1 | 1 | 1.3 |
| BaO | 2 | 1 | 1 | 0.5 | 0.3 |
| Li₂O | | | | | |
| Na₂O | | | | | |
| K₂O | | | | | |
| ZnO | | | | | |
| P₂O₅ | | | | | |
| ZrO₂ | 1 | 1 | 1 | 1 | 1 |
| TiO₂ | 1 | 1 | 1 | 1 | 1 |
| Y₂O₃ | 2 | 3 | 3 | 1.5 | 2.4 |
| Gd₂O₃ | | | | | |
| La₂O₃ | 2 | | | | |
| WO₃ | | | | | |
| Ta₂O₅ | | | | | |
| Al₂O₃ + rare earth oxide | 16 | 16 | 15 | 14 | 14.7 |
| Y₂O₃ + Gd₂O₃ + La₂O₃ + Nd₂O₃ + Ta₂O₅ + Nb₂O₅ | 4 | 3 | 3 | 1.5 | 2.4 |
| Parameter A = (Al₂O₃ + RO)/(SiO₂ + Al₂O₃ + RO) | 0.45 | 0.42 | 0.42 | 0.41 | 0.41 |
| (Al₂O₃ + MgO)/(SiO₂ + Al₂O₃ + B₂O₃ + MgO) | 0.37 | 0.37 | 0.36 | 0.36 | 0.36 |
| MgO/ΣRO | 0.74 | 0.88 | 0.84 | 0.90 | 0.88 |
| N | 11 | 10 | 10 | 10 | 9 |
| Young's modulus E (GPa) | 100 | 100 | 100 | 101 | 99 |
| Coefficient of thermal expansion α (ppm/° C.) | 5.25 | 4.36 | 4.47 | 4.30 | 4.22 |
| Liquidus temperature TL (° C.) | 1120 | 1195 | 1175 | 1235 | 1175 |
| Young's modulus parameter Y | 1.01 | 1.00 | 1.00 | 0.97 | 0.99 |
| Liquidus parameter L | 9.4 | 9.9 | 9.7 | 9.8 | 9.6 |
| Thermal expansion parameter C | 1.02 | 0.87 | 0.90 | 0.82 | 0.86 |
| Glass transition point (° C.) | 729 | 744 | 739 | 737 | 734 |
| Density (g/cm³) | 3.03 | 2.82 | 2.82 | 2.84 | 2.76 |
| Liquidus viscosity log η_{L} (dPa · s) | 3.6 | 3.15 | 2.5< | 2.5< | 2.5< |
| K_{IC} (MPa · m^{0.5}) | 0.93 | 0.95 | 0.8< | 0.8< | 0.8< |
| Transmittance (%) @308 nm, 0.7 mmt | 34.2 | 33.8 | 30≤ | 30≤ | 30≤ |
| Transmittance (%) @350 nm, 0.7 mmt | 88.8 | 85.3 | 80≤ | 80≤ | 80≤ |
| Transmittance (%) @550 nm, 0.7 mmt | 90.0 | 90.3 | 88≤ | 88≤ | 88≤ |
| Transmittance (%) @1064 nm, 0.7 mmt | 90.2 | 90.6 | 90≤ | 90≤ | 90≤ |
| T₂ (° C.) | 1296 | 1359 | <1400 | <1400 | <1400 |
| T₃ (° C.) | 1168 | 1213 | <1250 | <1250 | <1250 |
| T₄ (° C.) | 1079 | 1113 | <1150 | <1150 | <1150 |
| Sulfuric acid resistance (amount of weight loss (mg/cm²)) | 0.098 | 0.019 | | | |
| Sulfuric acid resistance (transmission ability) | x | x | | | |
| Sulfuric acid resistance parameter S | −1.78 | −5.45 | | | |
| Acid resistance parameter T | 0.46 | 0.83 | 0.82 | 0.99 | 0.88 |
| Deflection determination | ∘ | ∘ | ∘ | ∘ | ∘ |
| Manufacturability determination | ∘ | ∘ | ∘ | ∘ | ∘ |
| Transmission ability determination | ∘ | ∘ | ∘ | ∘ | ∘ |

| (mol %) | Example 38 | Example 39 | Example 40 |
|---|---|---|---|
| SiO₂ | 51.2 | 49 | 50.8 |
| Al₂O₃ | 12.1 | 14 | 12.9 |
| B₂O₃ | 8 | 8 | 7 |
| MgO | 21.4 | 21.4 | 22.4 |
| CaO | 1.3 | 1.3 | 1 |
| SrO | 1.3 | 1.3 | 1 |
| BaO | 0.6 | 0.6 | 1 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 14.1 | 16.0 | 14.9 |
| Y₂O₃ + Gd₂O₃ + La₂O₃ + Nd₂O₃ + Ta₂O₅ + Nb₂O₅ | 2.0 | 2.0 | 2.0 |
| Parameter A = (Al₂O₃ + RO)/(SiO₂ + Al₂O₃ + RO) | 0.42 | 0.44 | 0.43 |
| (Al₂O₃ + MgO)/(SiO₂ + Al₂O₃ + B₂O₃ + MgO) | 0.36 | 0.38 | 0.38 |
| MgO/ΣRO | 0.87 | 0.87 | 0.88 |
| N | 10 | 10 | 10 |
| Young's modulus E (GPa) | 97 | 100 | 98 |
| Coefficient of thermal expansion α (ppm/° C.) | 4.21 | 4.25 | 4.27 |
| Liquidus temperature TL (° C.) | 1185 | 1205 | 1205 |
| Young's modulus parameter Y | 0.98 | 1.00 | 0.99 |
| Liquidus parameter L | 9.6 | 9.7 | 9.8 |
| Thermal expansion parameter C | 0.86 | 0.86 | 0.86 |
| Glass transition point (° C.) | 732 | 733 | 739 |
| Density (g/cm³) | 2.74 | 2.76 | 2.75 |
| Liquidus viscosity log η_{L} (dPa · s) | 2.5< | 2.99 | 2.5< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 80≤ | 80≤ | 80≤ |
| Transmittance (%) @550 nm, 0.7 mmt | 88≤ | 88≤ | 88≤ |
| Transmittance (%) @1064 nm, 0.7 mmt | 90≤ | 90≤ | 90≤ |
| T₂ (° C.) | <1400 | 1351 | <1400 |
| T₃ (° C.) | <1250 | 1204 | <1250 |
| T₄ (° C.) | <1150 | 1104 | <1150 |
| Sulfuric acid resistance (amount of weight loss (mg/cm²)) | | | |
| Sulfuric acid resistance (transmission ability) | | | |
| Sulfuric acid resistance parameter S | | | |
| Acid resistance parameter T | 0.87 | 0.68 | 0.85 |
| Deflection determination | ∘ | ∘ | ∘ |
| Manufacturability determination | ∘ | ∘ | ∘ |
| Transmission ability determination | ∘ | ∘ | ∘ |

TABLE 6

| (mol %) | Example 41 | Example 42 | Example 43 | Example 44 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | | | | |
| Gd₂O₃ | | 0.5 | 1 | 1.5 |
| La₂O₃ | 2 | 1.5 | 1 | 0.5 |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.73 | 0.73 | 0.73 | 0.73 |
| N | 10 | 11 | 11 | 11 |
| Young's modulus E (GPa) | 97 | 97 | 97 | 97 |
| Coefficient of thermal expansion α (ppm/° C.) | 5.23 | 5.25 | 5.26 | 5.28 |
| Liquidus temperature TL (° C.) | 1218 | 1217 | 1212 | 1212 |
| Young's modulus parameter Y | 0.95 | 0.95 | 0.95 | 0.95 |
| Liquidus parameter L | 9.6 | 9.6 | 9.6 | 9.6 |
| Thermal expansion parameter C | 1.02 | 1.02 | 1.02 | 1.02 |
| Glass transition point (° C.) | 705 | 704 | 703 | 703 |
| Density (g/cm³) | 2.99 | 2.99 | 3.00 | 3.00 |
| Liquidus viscosity log η_{L} (dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.66 | 0.83 | 0.60 | 0.57 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

| (mol %) | Example 45 | Example 46 | Example 47 |
|---|---|---|---|
| SiO₂ | 50 | 50 | 50 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | 0.5 | 0.5 |
| Gd₂O₃ | 2 | | 0.5 |
| La₂O₃ | | 1.5 | 1 |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.73 | 0.73 | 0.73 |
| N | 10 | 11 | 12 |
| Young's modulus E (GPa) | 97 | 97 | 97 |
| Coefficient of thermal expansion α (ppm/° C.) | 5.30 | 5.19 | 5.21 |
| Liquidus temperature TL (° C.) | 1209 | 1205 | 1203 |
| Young's modulus parameter Y | 0.95 | 0.96 | 0.96 |
| Liquidus parameter L | 9.6 | 9.6 | 9.6 |
| Thermal expansion parameter C | 1.02 | 1.01 | 1.01 |
| Glass transition point (° C.) | 704 | 705 | 704 |
| Density (g/cm³) | 3.01 | 2.97 | 2.97 |
| Liquidus viscosity log η_{L} (dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.54 | 0.67 | 0.64 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ∘ | ∘ | ∘ |
| Manufacturability determination | ∘ | ∘ | ∘ |
| Transmission ability determination | ∘ | ∘ | ∘ |

TABLE 7

| (mol %) | Example 48 | Example 49 | Example 50 | Example 51 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 0.5 | 0.5 | 1 | 1 |
| Gd₂O₃ | 1 | 1.5 | | 0.5 |
| La₂O₃ | 0.5 | | 1 | 0.5 |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.73 | 0.73 | 0.73 | 0.73 |
| N | 12 | 11 | 11 | 12 |
| Young's modulus E (GPa) | 97 | 97 | 97 | 97 |
| Coefficient of thermal expansion α (ppm/° C.) | 5.23 | 5.24 | 5.15 | 5.17 |
| Liquidus temperature TL (° C.) | 1201 | 1198 | 1194 | 1192 |
| Young's modulus parameter Y | 0.96 | 0.96 | 0.96 | 0.96 |
| Liquidus parameter L | 9.6 | 9.6 | 9.7 | 9.7 |
| Thermal expansion parameter C | 1.01 | 1.01 | 1.01 | 1.01 |
| Glass transition point (° C.) | 703 | 703 | 705 | 704 |
| Density (g/cm³) | 2.98 | 2.98 | 2.95 | 2.95 |
| Liquidus viscosity log η_{L} (dPa · s) | 2< | 2< | 2< | 2< |
| K_{IC} (MPa · m^{0.5}) | 0.8< | 0.8< | 0.84 | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.61 | 0.58 | 0.67 | 0.64 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

| (mol %) | Example 52 | Example 53 | Example 54 |
|---|---|---|---|
| SiO₂ | 50 | 50 | 50 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 1 | 1.5 | 1.5 |
| Gd₂O₃ | 1 | | 0.5 |
| La₂O₃ | | 0.5 | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.73 | 0.73 | 0.73 |
| N | 11 | 11 | 11 |
| Young's modulus E (GPa) | 97 | 97 | 97 |
| Coefficient of thermal expansion α (ppm/° C.) | 5.19 | 5.11 | 5.13 |
| Liquidus temperature TL (° C.) | 1187 | 1192 | 1190 |
| Young's modulus parameter Y | 0.96 | 0.96 | 0.96 |
| Liquidus parameter L | 9.7 | 9.8 | 9.8 |
| Thermal expansion parameter C | 1.01 | 1.00 | 1.00 |
| Glass transition point (° C.) | 703 | 705 | 704 |
| Density (g/cm³) | 2.96 | 2.93 | 2.94 |
| Liquidus viscosity log η_{L} (dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.61 | 0.68 | 0.65 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ∘ | ∘ | ∘ |
| Manufacturability determination | ∘ | ∘ | ∘ |
| Transmission ability determination | ∘ | ∘ | ∘ |

TABLE 8

| (mol %) | Example 55 | Example 56 | Example 57 | Example 58 |
|---|---|---|---|---|
| SiO₂ | 48 | 48 | 48.0 | 48 |
| Al₂O₃ | 9 | 9 | 9 | 9 |
| B₂O₃ | 5 | 7 | 7 | 7 |
| MgO | 22 | 22 | 22.0 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1.0 | 1.0 | 1 |
| TiO₂ | 1 | 1.0 | 1.0 | 1 |
| Y₂O₃ | 2 | | 2.0 | 2 |
| Gd₂O₃ | 2 | 2 | | 2 |
| La₂O₃ | 2 | 2 | 2 | |
| WO₃ | | | | |
| Ta₂O₅ | | | | |
| Al₂O₃ + rare earth oxide | 15 | 13 | 13 | 13 |
| Y₂O₃ + Gd₂O₃ + La₂O₃ + Nd₂O₃ + Ta₂O₅ + Nb₂O₅ | 6 | 4 | 4 | 4 |
| Parameter A = (Al₂O₃ + RO)/(SiO₂ + Al₂O₃ + RO) | 0.45 | 0.45 | 0.45 | 0.45 |
| (Al₂O₃ + MgO)/(SiO₂ + Al₂O₃ + B₂O₃ + MgO) | 0.37 | 0.36 | 0.36 | 0.36 |
| MgO/ΣRO | 0.73 | 0.73 | 0.73 | 0.73 |
| N | 12 | 11 | 11 | 11 |
| Young's modulus E (GPa) | 103 | 99 | 99 | 99 |
| Coefficient of thermal expansion α (ppm/° C.) | 5.93 | 5.72 | 5.50 | 5.57 |
| Liquidus temperature TL (° C.) | 1199 | 1188 | 1149 | 1157 |
| Young's modulus parameter Y | 1.03 | 0.98 | 0.98 | 0.98 |
| Liquidus parameter L | 9.2 | 9.0 | 9.2 | 9.2 |
| Thermal expansion parameter C | 1.16 | 1.10 | 1.09 | 1.09 |
| Glass transition point (° C.) | 706 | 697 | 699 | 697 |
| Density (g/cm³) | 3.33 | 3.20 | 3.10 | 3.12 |
| Liquidus viscosity log η_{L} (dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.32 | 0.35 | 0.49 | 0.37 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

| (mol %) | Example 59 | Example 60 | Example 61 |
|---|---|---|---|
| SiO₂ | 48 | 48 | 48 |
| Al₂O₃ | 10 | 10 | 10 |
| B₂O₃ | 4 | 6 | 6 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | 2 |
| Gd₂O₃ | 2 | 2 | |
| La₂O₃ | 2 | 2 | 2 |
| WO₃ | | | |
| Ta₂O₅ | | | |
| Al₂O₃ + rare earth oxide | 16 | 14 | 14 |
| Y₂O₃ + Gd₂O₃ + La₂O₃ + Nd₂O₃ + Ta₂O₅ + Nb₂O₅ | 6 | 4 | 4 |
| Parameter A = (Al₂O₃ + RO)/(SiO₂ + Al₂O₃ + RO) | 0.45 | 0.45 | 0.45 |
| (Al₂O₃ + MgO)/(SiO₂ + Al₂O₃ + B₂O₃ + MgO) | 0.38 | 0.37 | 0.37 |
| MgO/ΣRO | 0.73 | 0.73 | 0.73 |
| N | 12 | 11 | 11 |
| Young's modulus E (GPa) | 104 | 100 | 100 |
| Coefficient of thermal expansion α (ppm/° C.) | 5.89 | 5.69 | 5.46 |
| Liquidus temperature TL (° C.) | 1225 | 1210 | 1170 |
| Young's modulus parameter Y | 1.05 | 0.99 | 1.00 |
| Liquidus parameter L | 9.4 | 9.2 | 9.5 |
| Thermal expansion parameter C | 1.15 | 1.10 | 1.08 |
| Glass transition point (° C.) | 716 | 704 | 705 |
| Density (g/cm³) | 3.34 | 3.21 | 3.11 |
| Liquidus viscosity log η_{L} (dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.32 | 0.34 | 0.48 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ∘ | ∘ | ∘ |
| Manufacturability determination | ∘ | ∘ | ∘ |
| Transmission ability determination | ∘ | ∘ | ∘ |

TABLE 9

| (mol %) | Example 62 | Example 63 | Example 64 | Example 65 |
|---|---|---|---|---|
| SiO₂ | 48 | 48 | 48 | 48 |
| Al₂O₃ | 10 | 10 | 10 | 10 |
| B₂O₃ | 6 | 8 | 8 | 8 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | 2 |
| Gd₂O₃ | 2 | | 2 | |
| La₂O₃ | | 2 | | |
| WO₃ | | | | |
| Ta₂O₅ | | | | |
| Al₂O₃ + rare earth oxide | 14 | 12 | 12 | 12 |
| Y₂O₃ + Gd₂O₃ + La₂O₃ + Nd₂O₃ + Ta₂O₅ + Nb₂O₅ | 4 | 2 | 2 | 2 |
| Parameter A = (Al₂O₃ + RO)/(SiO₂ + Al₂O₃ + RO) | 0.45 | 0.45 | 0.45 | 0.45 |
| (Al₂O₃ + MgO)/(SiO₂ + Al₂O₃ + B₂O₃ + MgO) | 0.37 | 0.36 | 0.36 | 0.36 |
| MgO/ΣRO | 0.73 | 0.73 | 0.73 | 0.73 |
| N | 11 | 10 | 10 | 10 |
| Young's modulus E (GPa) | 100 | 97 | 97 | 97 |
| Coefficient of thermal expansion α (ppm/° C.) | 5.54 | 5.26 | 5.33 | 5.11 |
| Liquidus temperature TL (° C.) | 1174 | 1190 | 1186 | 1148 |
| Young's modulus parameter Y | 1.00 | 0.94 | 0.94 | 0.95 |
| Liquidus parameter L | 9.5 | 9.3 | 9.3 | 9.5 |
| Thermal expansion parameter C | 1.08 | 1.03 | 1.03 | 1.01 |
| Glass transition point (° C.) | 704 | 699 | 697 | 699 |
| Density (g/cm³) | 3.13 | 2.99 | 3.00 | 2.91 |
| Liquidus viscosity log η_{L} (dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.37 | 0.51 | 0.39 | 0.54 |
| Transmittance (%) @1064 nm, 0.7 mmt | 80≤ | 80≤ | 80≤ | 80≤ |
| T₂ (° C.) | <1350 | <1350 | <1300 | <1300 |
| T₃ (° C.) | <1200 | <1200 | <1200 | <1200 |
| T₄ (° C.) | <1100 | <1100 | <1100 | <1100 |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

| (mol %) | Example 66 | Example 67 | Example 68 |
|---|---|---|---|
| SiO₂ | 48 | 48 | 48 |
| Al₂O₃ | 11 | 11 | 11 |
| B₂O₃ | 5 | 5 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | 2 | 2 |
| Gd₂O₃ | 2 | | 2 |
| La₂O₃ | 2 | 2 | |
| WO₃ | | | |
| Ta₂O₅ | | | |
| Al₂O₃ + rare earth oxide | 15 | 15 | 15 |
| Y₂O₃ + Gd₂O₃ + La₂O₃ + Nd₂O₃ + Ta₂O₅ + Nb₂O₅ | 4 | 4 | 4 |
| Parameter A = (Al₂O₃ + RO)/(SiO₂ + Al₂O₃ + RO) | 0.46 | 0.46 | 0.46 |
| (Al₂O₃ + MgO)/(SiO₂ + Al₂O₃ + B₂O₃ + MgO) | 0.38 | 0.38 | 0.38 |
| MgO/ΣRO | 0.73 | 0.73 | 0.73 |
| N | 11 | 11 | 11 |
| Young's modulus E (GPa) | 101 | 101 | 101 |
| Coefficient of thermal expansion α (ppm/° C.) | 5.66 | 5.43 | 5.50 |
| Liquidus temperature TL (° C.) | 1233 | 1193 | 1196 |
| Young's modulus parameter Y | 1.01 | 1.01 | 1.01 |
| Liquidus parameter L | 9.5 | 9.7 | 9.7 |
| Thermal expansion parameter C | 1.09 | 1.07 | 1.07 |
| Glass transition point (° C.) | 707 | 709 | 707 |
| Density (g/cm³) | 3.22 | 3.13 | 3.14 |
| Liquidus viscosity log η_{L} (dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.33 | 0.48 | 0.36 |
| Transmittance (%) @1064 nm, 0.7 mmt | 80≤ | 80≤ | 80≤ |
| T₂ (° C.) | <1300 | <1300 | <1300 |
| T₃ (° C.) | <1200 | <1200 | <1200 |
| T₄ (° C.) | <1100 | <1100 | <1100 |
| Deflection determination | ∘ | ∘ | ∘ |
| Manufacturability determination | ∘ | ∘ | ∘ |
| Transmission ability determination | ∘ | ∘ | ∘ |

TABLE 10

| (mol %) | Example 69 | Example 70 | Example 71 | Example 72 |
|---|---|---|---|---|
| SiO₂ | 48 | 48 | 48 | 48 |
| Al₂O₃ | 11 | 11 | 12 | 12 |
| B₂O₃ | 7 | 7 | 4 | 4 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | | | | 2 |
| Gd₂O₃ | | 2 | 2 | |
| La₂O₃ | 2 | | 2 | 2 |
| WO₃ | | | | |
| Ta₂O₅ | | | | |
| Al₂O₃ + rare earth oxide | 13 | 13 | 16 | 16 |
| Y₂O₃ + Gd₂O₃ + La₂O₃ + Nd₂O₃ + Ta₂O₅ + Nb₂O₅ | 2 | 2 | 4 | 4 |
| Parameter A = (Al₂O₃ + RO)/(SiO₂ + Al₂O₃ + RO) | 0.46 | 0.46 | 0.47 | 0.47 |
| (Al₂O₃ + MgO)/(SiO₂ + Al₂O₃ + B₂O₃ + MgO) | 0.38 | 0.38 | 0.40 | 0.40 |
| MgO/ΣRO | 0.73 | 0.73 | 0.73 | 0.73 |
| N | 10 | 10 | 11 | 11 |
| Young's modulus E (GPa) | 98 | 98 | 103 | 103 |
| Coefficient of thermal expansion α (ppm/° C.) | 5.23 | 5.30 | 5.63 | 5.40 |
| Liquidus temperature TL (° C.) | 1190 | 1186 | 1262 | 1231 |
| Young's modulus parameter Y | 0.96 | 0.96 | 1.02 | 1.03 |
| Liquidus parameter L | 9.5 | 9.5 | 9.7 | 9.9 |
| Thermal expansion parameter C | 1.02 | 1.02 | 1.08 | 1.07 |
| Glass transition point (° C.) | 700 | 698 | 716 | 718 |
| Density (g/cm³) | 3.00 | 3.01 | 3.23 | 3.14 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.50 | 0.38 | 0.33 | 0.47 |
| Transmittance (%) @1064 nm, 0.7 mmt | 80≤ | 80≤ | 80≤ | 80≤ |
| T₂ (° C.) | <1300 | <1400 | <1400 | <1400 |
| T₃ (° C.) | <1200 | <1300 | <1300 | <1300 |
| T₄ (° C.) | <1100 | <1200 | <1200 | <1200 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 73 | Example 74 | Example 75 |
|---|---|---|---|
| SiO₂ | 48 | 48 | 48 |
| Al₂O₃ | 12 | 12 | 12 |
| B₂O₃ | 4 | 6 | 6 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | |
| Gd₂O₃ | 2 | | 2 |
| La₂O₃ | | 2 | |
| WO₃ | | | |
| Ta₂O₅ | | | |
| Al₂O₃ + rare earth oxide | 16 | 14 | 14 |
| Y₂O₃ + Gd₂O₃ + La₂O₃ + Nd₂O₃ + Ta₂O₅ + Nb₂O₅ | 4 | 2 | 2 |
| Parameter A = (Al₂O₃ + RO)/(SiO₂ + Al₂O₃ + RO) | 0.47 | 0.47 | 0.47 |
| (Al₂O₃ + MgO)/(SiO₂ + Al₂O₃ + B₂O₃ + MgO) | 0.40 | 0.39 | 0.39 |
| MgO/ΣRO | 0.73 | 0.73 | 0.73 |
| N | 11 | 10 | 10 |
| Young's modulus E (GPa) | 103 | 99 | 99 |
| Coefficient of thermal expansion α (ppm/° C.) | 5.47 | 5.20 | 5.27 |
| Liquidus temperature TL (° C.) | 1233 | 1212 | 1205 |
| Young's modulus parameter Y | 1.03 | 0.97 | 0.97 |
| Liquidus parameter L | 9.9 | 9.8 | 9.8 |
| Thermal expansion parameter C | 1.07 | 1.01 | 1.01 |
| Glass transition point (° C.) | 716 | 705 | 704 |
| Density (g/cm³) | 3.15 | 3.01 | 3.02 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.35 | 0.50 | 0.38 |
| Transmittance (%) @1064 nm, 0.7 mmt | 80≤ | 80≤ | 80≤ |
| T₂ (° C.) | <1300 | <1400 | <1400 |
| T₃ (° C.) | <1200 | <1300 | <1300 |
| T₄ (° C.) | <1100 | <1200 | <1200 |
| Deflection determination | ◯ | ◯ | ◯ |
| Manufacturability determination | ◯ | ◯ | ◯ |
| Transmission ability determination | ◯ | ◯ | ◯ |

TABLE 11

| (mol %) | Example 78 | Example 77 | Example 78 | Example 79 |
|---|---|---|---|---|
| SiO₂ | 48 | 48 | 48.0 | 48.0 |
| Al₂O₃ | 12 | 12 | 13.0 | 13.0 |
| B₂O₃ | 6 | 8 | 5.0 | 5.0 |
| MgO | 22 | 22 | 22.0 | 22.0 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | |
| Gd₂O₃ | | | | 2 |
| La₂O₃ | | | 2 | |
| WO₃ | | | | |
| Ta₂O₅ | | | | |
| Al₂O₃ + rare earth oxide | 14 | 12 | 15 | 15 |
| Y₂O₃ + Gd₂O₃ + La₂O₃ + Nd₂O₃ + Ta₂O₅ + Nb₂O₅ | 2 | 0 | 2 | 2 |
| Parameter A = (Al₂O₃ + RO)/(SiO₂ + Al₂O₃ + RO) | 0.47 | 0.47 | 0.47 | 0.47 |
| (Al₂O₃ + MgO)/(SiO₂ + Al₂O₃ + B₂O₃ + MgO) | 0.39 | 0.38 | 0.40 | 0.40 |
| MgO/ΣRO | 0.73 | 0.73 | 0.73 | 0.73 |
| N | 10 | 9 | 10 | 10 |
| Young's modulus E (GPa) | 99 | 95 | 100 | 100 |
| Coefficient of thermal expansion α (ppm/° C.) | 5.04 | 4.84 | 5.16 | 5.24 |
| Liquidus temperature TL (° C.) | 1168 | 1185 | 1239 | 1233 |
| Young's modulus parameter Y | 0.98 | 0.92 | 0.99 | 0.99 |
| Liquidus parameter L | 10.0 | 9.8 | 10.0 | 10.0 |
| Thermal expansion parameter C | 1.00 | 0.94 | 1.01 | 1.01 |
| Glass transition point (° C.) | 705 | 700 | 713 | 711 |
| Density (g/cm³) | 2.93 | 2.80 | 3.02 | 3.03 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.52 | 0.55 | 0.49 | 0.37 |
| Transmittance (%) @1064 nm, 0.7 mmt | 80≤ | 80≤ | 80≤ | 80≤ |
| T₂ (° C.) | <1400 | <1300 | <1300 | <1300 |
| T₃ (° C.) | <1300 | <1200 | <1200 | <1200 |
| T₄ (° C.) | <1200 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 80 | Example 81 | Example 82 |
|---|---|---|---|
| SiO₂ | 48.0 | 48.0 | 48.0 |
| Al₂O₃ | 13.0 | 13.0 | 9.0 |
| B₂O₃ | 5.0 | 7.0 | 4.0 |
| MgO | 22.0 | 22.0 | 22.0 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | 2 |
| Gd₂O₃ | | | |
| La₂O₃ | | | 2 |
| WO₃ | | | |
| Ta₂O₅ | | | |
| Al₂O₃ + rare earth oxide | 15 | 13 | 15 |
| Y₂O₃ + Gd₂O₃ + La₂O₃ + Nd₂O₃ + Ta₂O₅ + Nb₂O₅ | 2 | 0 | 6 |
| Parameter A = (Al₂O₃ + RO)/(SiO₂ + Al₂O₃ + RO) | 0.47 | 0.47 | 0.44 |
| (Al₂O₃ + MgO)/(SiO₂ + Al₂O₃ + B₂O₃ + MgO) | 0.40 | 0.39 | 0.37 |
| MgO/ΣRO | 0.73 | 0.73 | 0.73 |
| N | 10 | 9 | 12 |
| Young's modulus E (GPa) | 100 | 97 | 103 |
| Coefficient of thermal expansion α (ppm/° C.) | 5.01 | 4.81 | 5.91 |
| Liquidus temperature TL (° C.) | 1198 | 1208 | 1225 |
| Young's modulus parameter Y | 0.99 | 0.94 | 1.04 |
| Liquidus parameter L | 10.2 | 10.1 | 9.3 |
| Thermal expansion parameter C | 0.99 | 0.94 | 1.15 |
| Glass transition point (° C.) | 713 | 705 | 716 |
| Density (g/cm³) | 2.94 | 2.81 | 3.33 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.51 | 0.54 | 0.40 |
| Transmittance (%) @1064 nm, 0.7 mmt | 80≤ | 80≤ | 80≤ |
| T₂ (° C.) | <1300 | <1300 | <1300 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 12

| (mol %) | Example 83 | Example 84 | Example 85 | Example 86 |
|---|---|---|---|---|
| SiO₂ | 49 | 49 | 49 | 49 |
| Al₂O₃ | 9 | 9 | 9 | 9 |
| B₂O₃ | 6 | 6 | 6 | 8 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | | 2 | 2 | |
| Gd₂O₃ | 2 | | 2 | |
| La₂O₃ | 2 | 2 | | 2 |
| WO₃ | | | | |
| Ta₂O₅ | | | | |
| Al₂O₃ + rare earth oxide | 13 | 13 | 13 | 11 |
| Y₂O₃ + Gd₂O₃ + La₂O₃ + Nd₂O₃ + Ta₂O₅ + Nb₂O₅ | 4 | 4 | 4 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.35 |
| MgO/ΣRO | 0.73 | 0.73 | 0.73 | 0.73 |
| N | 11 | 11 | 11 | 10 |
| Young's modulus E (GPa) | 99 | 99 | 99 | 96 |
| Coefficient of thermal expansion α (ppm/° C.) | 5.71 | 5.48 | 5.55 | 5.28 |
| Liquidus temperature TL (° C.) | 1211 | 1174 | 1173 | 1194 |
| Young's modulus parameter Y | 0.98 | 0.99 | 0.99 | 0.93 |
| Liquidus parameter L | 9.2 | 9.4 | 9.4 | 9.2 |
| Thermal expansion parameter C | 1.10 | 1.08 | 1.08 | 1.03 |
| Glass transition point (° C.) | 703 | 704 | 703 | 698 |
| Density (g/cm³) | 3.20 | 3.11 | 3.12 | 2.98 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.42 | 0.57 | 0.45 | 0.59 |
| Transmittance (%) @1064 nm, 0.7 mmt | 80≤ | 80≤ | 80≤ | 80≤ |
| T₂ (° C.) | <1300 | <1300 | <1350 | <1300 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 87 | Example 88 | Example 89 |
|---|---|---|---|
| SiO₂ | 49 | 49 | 49 |
| Al₂O₃ | 9 | 9 | 10 |
| B₂O₃ | 8 | 8 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | 2 | |
| Gd₂O₃ | 2 | | 2 |
| La₂O₃ | | | 2 |
| WO₃ | | | |
| Ta₂O₅ | | | |
| Al₂O₃ + rare earth oxide | 11 | 11 | 14 |
| Y₂O₃ + Gd₂O₃ + La₂O₃ + Nd₂O₃ + Ta₂O₅ + Nb₂O₅ | 2 | 2 | 4 |
| Parameter A = (Al₂O₃ + RO)/(SiO₂ + Al₂O₃ + RO) | 0.44 | 0.44 | 0.45 |
| (Al₂O₃ + MgO)/(SiO₂ + Al₂O₃ + B₂O₃ + MgO) | 0.35 | 0.35 | 0.37 |
| MgO/ΣRO | 0.73 | 0.73 | 0.73 |
| N | 10 | 10 | 11 |
| Young's modulus E (GPa) | 96 | 96 | 100 |
| Coefficient of thermal expansion α (ppm/° C.) | 5.35 | 5.12 | 5.68 |
| Liquidus temperature TL (° C.) | 1185 | 1155 | 1232 |
| Young's modulus parameter Y | 0.93 | 0.94 | 1.00 |
| Liquidus parameter L | 9.2 | 9.4 | 9.4 |
| Thermal expansion parameter C | 1.03 | 1.01 | 1.09 |
| Glass transition point (° C.) | 696 | 698 | 707 |
| Density (g/cm³) | 2.99 | 2.90 | 3.21 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.47 | 0.62 | 0.42 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 13

| (mol %) | Example 90 | Example 91 | Example 92 | Example 93 |
|---|---|---|---|---|
| SiO₂ | 49 | 49 | 49 | 49 |
| Al₂O₃ | 10 | 10 | 10 | 10 |
| B₂O₃ | 5 | 5 | 7 | 7 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | | |
| Gd₂O₃ | | 2 | | 2 |
| La₂O₃ | 2 | | 2 | |
| WO₃ | | | | |
| Ta₂O₅ | | | | |
| Al₂O₃ + rare earth oxide | 14 | 14 | 12 | 12 |
| Y₂O₃ + Gd₂O₃ + La₂O₃ + Nd₂O₃ + Ta₂O₅ + Nb₂O₅ | 4 | 4 | 2 | 2 |
| Parameter A = (Al₂O₃ + RO)/(SiO₂ + Al₂O₃ + RO) | 0.45 | 0.45 | 0.45 | 0.45 |
| (Al₂O₃ + MgO)/(SiO₂ + Al₂O₃ + B₂O₃ + MgO) | 0.37 | 0.37 | 0.36 | 0.36 |
| MgO/ΣRO | 0.73 | 0.73 | 0.73 | 0.73 |
| N | 11 | 11 | 10 | 10 |
| Young's modulus E (GPa) | 101 | 101 | 97 | 97 |
| Coefficient of thermal expansion α (ppm/° C.) | 5.45 | 5.52 | 5.25 | 5.32 |
| Liquidus temperature TL (° C.) | 1195 | 1196 | 1195 | 1187 |
| Young's modulus parameter Y | 1.00 | 1.00 | 0.95 | 0.95 |
| Liquidus parameter L | 9.6 | 9.6 | 9.4 | 9.4 |
| Thermal expansion parameter C | 1.08 | 1.08 | 1.02 | 1.02 |
| Glass transition point (° C.) | 709 | 707 | 700 | 698 |
| Density (g/cm³) | 3.12 | 3.13 | 2.99 | 3.00 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.56 | 0.44 | 0.59 | 0.47 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 94 | Example 95 | Example 96 |
|---|---|---|---|
| SiO₂ | 49 | 49 | 49 |
| Al₂O₃ | 10 | 11 | 11 |
| B₂O₃ | 7 | 4 | 4 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | 2 |
| Gd₂O₃ | | 2 | |
| La₂O₃ | | 2 | 2 |
| WO₃ | | | |
| Ta₂O₅ | | | |
| Al₂O₃ + rare earth oxide | 12 | 15 | 15 |
| Y₂O₃ + Gd₂O₃ + La₂O₃ + Nd₂O₃ + Ta₂O₅ + Nb₂O₅ | 2 | 4 | 4 |
| Parameter A = (Al₂O₃ + RO)/(SiO₂ + Al₂O₃ + RO) | 0.45 | 0.46 | 0.46 |
| (Al₂O₃ + MgO)/(SiO₂ + Al₂O₃ + B₂O₃ + MgO) | 0.36 | 0.38 | 0.38 |
| MgO/ΣRO | 0.73 | 0.73 | 0.73 |
| N | 10 | 11 | 11 |
| Young's modulus E (GPa) | 97 | 102 | 102 |
| Coefficient of thermal expansion α (ppm/° C.) | 5.09 | 5.64 | 5.42 |
| Liquidus temperature TL (° C.) | 1159 | 1258 | 1223 |
| Young's modulus parameter Y | 0.95 | 1.01 | 1.02 |
| Liquidus parameter L | 9.7 | 9.6 | 9.8 |
| Thermal expansion parameter C | 1.01 | 1.09 | 1.07 |
| Glass transition point (° C.) | 700 | 716 | 719 |
| Density (g/cm³) | 2.91 | 3.22 | 3.13 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.61 | 0.41 | 0.55 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 14

| (mol %) | Example 97 | Example 98 | Example 99 | Example 100 |
|---|---|---|---|---|
| SiO₂ | 49 | 49 | 49 | 49 |
| Al₂O₃ | 11 | 11 | 11 | 11 |
| B₂O₃ | 4 | 6 | 6 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | 2 |
| Gd₂O₃ | 2 | | 2 | |
| La₂O₃ | | 2 | | |
| WO₃ | | | | |
| Ta₂O₅ | | | | |
| Al₂O₃ + rare earth oxide | 15 | 13 | 13 | 13 |
| Y₂O₃ + Gd₂O₃ + La₂O₃ + Nd₂O₃ + Ta₂O₅ + Nb₂O₅ | 4 | 2 | 2 | 2 |
| Parameter A = (Al₂O₃ + RO)/(SiO₂ + Al₂O₃ + RO) | 0.46 | 0.46 | 0.46 | 0.48 |
| (Al₂O₃ + MgO)/(SiO₂ + Al₂O₃ + B₂O₃ + MgO) | 0.38 | 0.38 | 0.38 | 0.38 |
| MgO/ΣRO | 0.73 | 0.73 | 0.73 | 0.73 |
| N | 11 | 10 | 10 | 10 |
| Young's modulus E (GPa) | 102 | 98 | 98 | 98 |
| Coefficient of thermal expansion α (ppm/° C.) | 5.49 | 5.21 | 5.28 | 5.08 |
| Liquidus temperature TL (° C.) | 1223 | 1213 | 1205 | 1171 |
| Young's modulus parameter Y | 1.02 | 0.96 | 0.96 | 0.97 |
| Liquidus parameter L | 9.8 | 9.7 | 9.7 | 9.9 |
| Thermal expansion parameter C | 1.07 | 1.02 | 1.02 | 1.00 |
| Glass transition point (° C.) | 716 | 705 | 704 | 705 |
| Density (g/cm³) | 3.14 | 3.00 | 3.01 | 2.92 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.43 | 0.58 | 0.46 | 0.60 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 101 | Example 102 | Example 103 |
|---|---|---|---|
| SiO₂ | 49 | 49 | 49 |
| Al₂O₃ | 11 | 12 | 12 |
| B₂O₃ | 8 | 5 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | | |
| Gd₂O₃ | | | 2 |
| La₂O₃ | | 2 | |
| WO₃ | | | |
| Ta₂O₅ | | | |
| Al₂O₃ + rare earth oxide | 11 | 14 | 14 |
| Y₂O₃ + Gd₂O₃ + La₂O₃ + Nd₂O₃ + Ta₂O₅ + Nb₂O₅ | 0 | 2 | 2 |
| Parameter A = (Al₂O₃ + RO)/(SiO₂ + Al₂O₃ + RO) | 0.46 | 0.46 | 0.46 |
| (Al₂O₃ + MgO)/(SiO₂ + Al₂O₃ + B₂O₃ + MgO) | 0.37 | 0.39 | 0.39 |
| MgO/ΣRO | 0.73 | 0.73 | 0.73 |
| N | 9 | 10 | 10 |
| Young's modulus E (GPa) | 94 | 99 | 99 |
| Coefficient of thermal expansion α (ppm/° C.) | 4.85 | 5.18 | 5.25 |
| Liquidus temperature TL (° C.) | 1189 | 1237 | 1227 |
| Young's modulus parameter Y | 0.91 | 0.98 | 0.98 |
| Liquidus parameter L | 9.7 | 9.9 | 9.9 |
| Thermal expansion parameter C | 0.95 | 1.01 | 1.01 |
| Glass transition point (° C.) | 699 | 709 | 707 |
| Density (g/cm³) | 2.79 | 3.01 | 3.03 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.63 | 0.57 | 0.45 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 15

| (mol %) | Example 104 | Example 105 | Example 106 | Example 107 |
|---|---|---|---|---|
| SiO₂ | 49 | 49 | 49 | 49 |
| Al₂O₃ | 12 | 12 | 13 | 13 |
| B₂O₃ | 5 | 7 | 4 | 4 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | |
| Gd₂O₃ | | | | 2 |
| La₂O₃ | | | 2 | |
| WO₃ | | | | |
| Ta₂O₅ | | | | |
| Al₂O₃ + rare earth oxide | 14 | 12 | 15 | 15 |
| Y₂O₃ + Gd₂O₃ + La₂O₃ + Nd₂O₃ + Ta₂O₅ + Nb₂O₅ | 2 | 0 | 2 | 2 |
| Parameter A = (Al₂O₃ + RO)/(SiO₂ + Al₂O₃ + RO) | 0.46 | 0.46 | 0.47 | 0.47 |
| (Al₂O₃ + MgO)/(SiO₂ + Al₂O₃ + B₂O₃ + MgO) | 0.39 | 0.38 | 0.40 | 0.40 |
| MgO/ΣRO | 0.73 | 0.73 | 0.73 | 0.73 |
| N | 10 | 9 | 10 | 10 |
| Young's modulus E (GPa) | 99 | 96 | 100 | 100 |
| Coefficient of thermal expansion α (ppm/° C.) | 5.02 | 4.82 | 5.15 | 5.22 |
| Liquidus temperature TL (° C.) | 1196 | 1190 | 1265 | 1257 |
| Young's modulus parameter Y | 0.98 | 0.93 | 0.99 | 0.99 |
| Liquidus parameter L | 10.1 | 10.0 | 10.1 | 10.1 |
| Thermal expansion parameter C | 0.99 | 0.94 | 1.00 | 1.00 |
| Glass transition point (° C.) | 709 | 701 | 722 | 720 |
| Density (g/cm³) | 2.93 | 2.80 | 3.02 | 3.04 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.60 | 0.62 | 0.56 | 0.45 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 108 | Example 109 | Example 110 |
|---|---|---|---|
| SiO₂ | 49 | 49 | 50 |
| Al₂O₃ | 13 | 13 | 9 |
| B₂O₃ | 4 | 6 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | |
| Gd₂O₃ | | | 2 |
| La₂O₃ | | | 2 |
| WO₃ | | | |
| Ta₂O₅ | | | |
| Al₂O₃ + rare earth oxide | 15 | 13 | 13 |
| Y₂O₃ + Gd₂O₃ + La₂O₃ + Nd₂O₃ + Ta₂O₅ + Nb₂O₅ | 2 | 0 | 4 |
| Parameter A = (Al₂O₃ + RO)/(SiO₂ + Al₂O₃ + RO) | 0.47 | 0.47 | 0.44 |
| (Al₂O₃ + MgO)/(SiO₂ + Al₂O₃ + B₂O₃ + MgO) | 0.40 | 0.39 | 0.36 |
| MgO/ΣRO | 0.73 | 0.73 | 0.73 |
| N | 10 | 9 | 11 |
| Young's modulus E (GPa) | 100 | 97 | 100 |
| Coefficient of thermal expansion α (ppm/° C.) | 4.99 | 4.79 | 5.69 |
| Liquidus temperature TL (° C.) | 1230 | 1218 | 1232 |
| Young's modulus parameter Y | 1.00 | 0.94 | 0.99 |
| Liquidus parameter L | 10.4 | 10.2 | 9.3 |
| Thermal expansion parameter C | 0.99 | 0.93 | 1.09 |
| Glass transition point (° C.) | 722 | 709 | 706 |
| Density (g/cm³) | 2.94 | 2.81 | 3.20 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.59 | 0.61 | 0.50 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 16

| (mol %) | Example 111 | Example 112 | Example 113 | Example 114 |
|---|---|---|---|---|
| SiO₂ | 50 | 50 | 50 | 50 |
| Al₂O₃ | 9 | 9 | 9 | 9 |
| B₂O₃ | 5 | 5 | 7 | 7 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | | |
| Gd₂O₃ | | 2 | | 2 |
| La₂O₃ | 2 | | 2 | |
| WO₃ | | | | |
| Ta₂O₅ | | | | |
| Al₂O₃ + rare earth oxide | 13 | 13 | 11 | 11 |
| Y₂O₃ + Gd₂O₃ + La₂O₃ + Nd₂O₃ + Ta₂O₅ + Nb₂O₅ | 4 | 4 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.35 | 0.35 |
| MgO/ΣRO | 0.73 | 0.73 | 0.73 | 0.73 |
| N | 11 | 11 | 10 | 10 |
| Young's modulus E (GPa) | 100 | 100 | 96 | 96 |
| Coefficient of thermal expansion α (ppm/° C.) | 5.46 | 5.54 | 5.26 | 5.33 |
| Liquidus temperature TL (° C.) | 1205 | 1207 | 1204 | 1198 |
| Young's modulus parameter Y | 1.00 | 0.99 | 0.94 | 0.94 |
| Liquidus parameter L | 9.5 | 9.5 | 9.4 | 9.4 |
| Thermal expansion parameter C | 1.08 | 1.08 | 1.02 | 1.02 |
| Glass transition point (° C.) | 708 | 706 | 699 | 697 |
| Density (g/cm³) | 3.11 | 3.12 | 2.98 | 3.00 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.64 | 0.53 | 0.67 | 0.55 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 115 | Example 116 | Example 117 |
|---|---|---|---|
| SiO₂ | 50 | 50 | 50 |
| Al₂O₃ | 9 | 10 | 10 |
| B₂O₃ | 7 | 4 | 4 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | | 2 |
| Gd₂O₃ | | 2 | |
| La₂O₃ | | 2 | 2 |
| WO₃ | | | |
| Ta₂O₅ | | | |
| Al₂O₃ + rare earth oxide | 11 | 14 | 14 |
| Y₂O₃ + Gd₂O₃ + La₂O₃ + Nd₂O₃ + Ta₂O₅ + Nb₂O₅ | 2 | 4 | 4 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.35 | 0.37 | 0.37 |
| MgO/ΣRO | 0.73 | 0.73 | 0.73 |
| N | 10 | 11 | 11 |
| Young's modulus E (GPa) | 96 | 101 | 101 |
| Coefficient of thermal expansion α (ppm/° C.) | 5.11 | 5.66 | 5.43 |
| Liquidus temperature TL (° C.) | 1185 | 1257 | 1227 |
| Young's modulus parameter Y | 0.94 | 1.00 | 1.01 |
| Liquidus parameter L | 9.6 | 9.5 | 9.7 |
| Thermal expansion parameter C | 1.01 | 1.09 | 1.07 |
| Glass transition point (° C.) | 699 | 716 | 718 |
| Density (g/cm³) | 2.90 | 3.21 | 3.12 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.69 | 0.49 | 0.64 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 17

| (mol %) | Example 118 | Example 119 | Example 120 | Example 121 |
|---|---|---|---|---|
| SiO₂ | 50 | 50 | 50 | 50 |
| Al₂O₃ | 10 | 10 | 10 | 11 |
| B₂O₃ | 4 | 6 | 6 | 5 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | |
| Gd₂O₃ | 2 | | 2 | |
| La₂O₃ | | 2 | | 2 |
| WO₃ | | | | |
| Ta₂O₅ | | | | |
| Al₂O₃ + rare earth oxide | 14 | 12 | 12 | 13 |
| Y₂O₃ + Gd₂O₃ + La₂O₃ + Nd₂O₃ + Ta₂O₅ + Nb₂O₅ | 4 | 2 | 2 | 2 |
| Parameter A = (Al₂O₃ + RO)/(SiO₂ + Al₂O₃ + RO) | 0.44 | 0.44 | 0.44 | 0.45 |
| (Al₂O₃ + MgO)/(SiO₂ + Al₂O₃ + B₂O₃ + MgO) | 0.37 | 0.36 | 0.36 | 0.38 |
| MgO/ΣRO | 0.73 | 0.73 | 0.73 | 0.73 |
| N | 11 | 10 | 10 | 10 |
| Young's modulus E (GPa) | 101 | 97 | 97 | 98 |
| Coefficient of thermal expansion α (ppm/° C.) | 5.50 | 5.23 | 5.30 | 5.20 |
| Liquidus temperature TL (° C.) | 1229 | 1218 | 1209 | 1233 |
| Young's modulus parameter Y | 1.01 | 0.95 | 0.95 | 0.97 |
| Liquidus parameter L | 9.7 | 9.6 | 9.6 | 9.8 |
| Thermal expansion parameter C | 1.07 | 1.02 | 1.02 | 1.01 |
| Glass transition point (° C.) | 716 | 705 | 704 | 709 |
| Density (g/cm³) | 3.13 | 2.99 | 3.01 | 3.00 |
| Liquidus viscosity log η_{L}(dPa · s) | 2< | 2< | 2< | 2< |
| K_{IC} (MPa · m^{0.5}) | 0.8< | 0.8< | 0.8 | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.52 | 0.66 | 0.54 | 0.65 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 122 | Example 123 | Example 124 |
|---|---|---|---|
| SiO₂ | 50 | 50 | 50 |
| Al₂O₃ | 11 | 11 | 11 |
| B₂O₃ | 5 | 5 | 7 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | 2 | |
| Gd₂O₃ | 2 | | |
| La₂O₃ | | | |
| WO₃ | | | |
| Ta₂O₅ | | | |
| Al₂O₃ + rare earth oxide | 13 | 13 | 11 |
| Y₂O₃ + Gd₂O₃ + La₂O₃ + Nd₂O₃ + Ta₂O₅ + Nb₂O₅ | 2 | 2 | 0 |
| Parameter A = (Al₂O₃ + RO)/(SiO₂ + Al₂O₃ + RO) | 0.45 | 0.45 | 0.45 |
| (Al₂O₃ + MgO)/(SiO₂ + Al₂O₃ + B₂O₃ + MgO) | 0.38 | 0.38 | 0.37 |
| MgO/ΣRO | 0.73 | 0.73 | 0.73 |
| N | 10 | 10 | 9 |
| Young's modulus E (GPa) | 98 | 98 | 95 |
| Coefficient of thermal expansion α (ppm/° C.) | 5.27 | 5.04 | 4.84 |
| Liquidus temperature TL (° C.) | 1224 | 1201 | 1201 |
| Young's modulus parameter Y | 0.97 | 0.97 | 0.92 |
| Liquidus parameter L | 9.8 | 10.0 | 9.9 |
| Thermal expansion parameter C | 1.01 | 0.99 | 0.94 |
| Glass transition point (° C.) | 707 | 709 | 700 |
| Density (g/cm³) | 3.02 | 2.92 | 2.79 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.54 | 0.68 | 0.70 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 18

| (mol %) | Example 125 | Example 126 | Example 127 | Example 128 |
|---|---|---|---|---|
| SiO₂ | 50 | 50 | 50 | 50 |
| Al₂O₃ | 12 | 12 | 12 | 12 |
| B₂O₃ | 4 | 4 | 4 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | | | 2 | |
| Gd₂O₃ | | 2 | | |
| La₂O₃ | 2 | | | |
| WO₃ | | | | |
| Ta₂O₅ | | | | |
| Al₂O₃ + rare earth oxide | 14 | 14 | 14 | 12 |
| Y₂O₃ + Gd₂O₃ + La₂O₃ + Nd₂O₃ + Ta₂O₅ + Nb₂O₅ | 2 | 2 | 2 | 0 |
| Parameter A = (Al₂O₃ + RO)/(SiO₂ + Al₂O₃ + RO) | 0.46 | 0.46 | 0.46 | 0.46 |
| (Al₂O₃ + MgO)/(SiO₂ + Al₂O₃ + B₂O₃ + MgO) | 0.39 | 0.39 | 0.39 | 0.38 |
| MgO/ΣRO | 0.73 | 0.73 | 0.73 | 0.73 |
| N | 10 | 10 | 10 | 9 |
| Young's modulus E (GPa) | 99 | 99 | 100 | 96 |
| Coefficient of thermal expansion α (ppm/° C.) | 5.16 | 5.24 | 5.01 | 4.81 |
| Liquidus temperature TL (° C.) | 1265 | 1254 | 1236 | 1211 |
| Young's modulus parameter Y | 0.98 | 0.98 | 0.99 | 0.93 |
| Liquidus parameter L | 10.1 | 10.1 | 10.3 | 10.1 |
| Thermal expansion parameter C | 1.00 | 1.00 | 0.99 | 0.93 |
| Glass transition point (° C.) | 718 | 715 | 718 | 705 |
| Density (g/cm³) | 3.01 | 3.03 | 2.93 | 2.80 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.65 | 0.53 | 0.67 | 0.70 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 129 | Example 130 | Example 131 |
|---|---|---|---|
| SiO₂ | 50 | 51 | 51 |
| Al₂O₃ | 13 | 9 | 9 |
| B₂O₃ | 5 | 4 | 4 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | | 2 |
| Gd₂O₃ | | 2 | |
| La₂O₃ | | 2 | 2 |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 0 | 4 | 4 |
| Parameter A = (Al₂O₃ + RO)/(SiO₂ + Al₂O₃ + RO) | 0.46 | 0.43 | 0.43 |
| (Al₂O₃ + MgO)/(SiO₂ + Al₂O₃ + B₂O₃ + MgO) | 0.39 | 0.36 | 0.36 |
| MgO/ΣRO | 0.73 | 0.73 | 0.73 |
| N | 9 | 11 | 11 |
| Young's modulus E (GPa) | 97 | 100 | 100 |
| Coefficient of thermal expansion α (ppm/° C.) | 4.77 | 5.67 | 5.45 |
| Liquidus temperature TL (° C.) | 1233 | 1253 | 1222 |
| Young's modulus parameter Y | 0.95 | 1.00 | 1.00 |
| Liquidus parameter L | 10.4 | 9.4 | 9.7 |
| Thermal expansion parameter C | 0.93 | 1.09 | 1.07 |
| Glass transition point (° C.) | 713 | 715 | 718 |
| Density (g/cm³) | 2.82 | 3.20 | 3.11 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.69 | 0.58 | 0.72 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 19

| (mol %) | Example 132 | Example 133 | Example 134 | Example 135 |
|---|---|---|---|---|
| SiO₂ | 51 | 51 | 51 | 51 |
| Al₂O₃ | 9 | 9 | 9 | 9 |
| B₂O₃ | 4 | 6 | 6 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | | | 2 |
| Gd₂O₃ | 2 | | 2 | |
| La₂O₃ | | 2 | | |
| WO₃ | | | | |
| Ta₂O₅ | | | | |
| Al₂O₃ + rare earth oxide | 13 | 11 | 11 | 11 |
| Y₂O₃ + Gd₂O₃ + La₂O₃ + Nd₂O₃ + Ta₂O₅ + Nb₂O₅ | 4 | 2 | 2 | 2 |
| Parameter A = (Al₂O₃ + RO)/(SiO₂ + Al₂O₃ + RO) | 0.43 | 0.43 | 0.43 | 0.43 |
| (Al₂O₃ + MgO)/(SiO₂ + Al₂O₃ + B₂O₃ + MgO) | 0.36 | 0.35 | 0.35 | 0.35 |
| MgO/ΣRO | 0.73 | 0.73 | 0.73 | 0.73 |
| N | 11 | 10 | 10 | 10 |
| Young's modulus E (GPa) | 100 | 96 | 96 | 96 |
| Coefficient of thermal expansion α (ppm/° C.) | 5.52 | 5.24 | 5.32 | 5.09 |
| Liquidus temperature TL (° C.) | 1223 | 1217 | 1208 | 1189 |
| Young's modulus parameter Y | 1.00 | 0.95 | 0.95 | 0.95 |
| Liquidus parameter L | 9.7 | 9.5 | 9.5 | 9.7 |
| Thermal expansion parameter C | 1.07 | 1.02 | 1.02 | 1.00 |
| Glass transition point (° C.) | 715 | 704 | 703 | 704 |
| Density (g/cm³) | 3.13 | 2.98 | 3.00 | 2.90 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30 | 30 | 30 | 30 |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.60 | 0.74 | 0.63 | 0.77 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 136 | Example 137 | Example 138 |
|---|---|---|---|
| SiO₂ | 51 | 51 | 51 |
| Al₂O₃ | 10 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | | 2 |
| Gd₂O₃ | | 2 | |
| La₂O₃ | 2 | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.73 | 0.73 | 0.73 |
| N | 10 | 10 | 10 |
| Young's modulus E (GPa) | 97 | 97 | 97 |
| Coefficient of thermal expansion α (ppm/° C.) | 5.21 | 5.28 | 5.06 |
| Liquidus temperature TL (° C.) | 1230 | 1222 | 1193 |
| Young's modulus parameter Y | 0.96 | 0.96 | 0.97 |
| Liquidus parameter L | 9.7 | 9.7 | 9.9 |
| Thermal expansion parameter C | 1.01 | 1.01 | 1.00 |
| Glass transition point (° C.) | 709 | 707 | 709 |
| Density (g/cm³) | 2.99 | 3.01 | 2.91 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.74 | 0.62 | 0.76 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 20

| (mol %) | Example 139 | Example 140 | Example 141 | Example 142 |
|---|---|---|---|---|
| SiO₂ | 51 | 51 | 51 | 51 |
| Al₂O₃ | 11 | 11 | 11 | 11 |
| B₂O₃ | 4 | 4 | 4 | 6 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | | | 2 | |
| Gd₂O₃ | | 2 | | |
| La₂O₃ | 2 | | | |
| WO₃ | | | | |
| Ta₂O₅ | | | | |
| Al₂O₃ + rare earth oxide | 13 | 13 | 13 | 11 |
| Y₂O₃ + Gd₂O₃ + La₂O₃ + Nd₂O₃ + Ta₂O₅ + Nb₂O₅ | 2 | 2 | 2 | 0 |
| Parameter A = (Al₂O₃ + RO)/(SiO₂ + Al₂O₃ + RO) | 0.45 | 0.45 | 0.45 | 0.45 |
| (Al₂O₃ + MgO)/(SiO₂ + Al₂O₃ + B₂O₃ + MgO) | 0.38 | 0.38 | 0.38 | 0.37 |
| MgO/ΣRO | 0.73 | 0.73 | 0.73 | 0.73 |
| N | 10 | 10 | 10 | 9 |
| Young's modulus E (GPa) | 99 | 99 | 99 | 95 |
| Coefficient of thermal expansion α (ppm/° C.) | 5.18 | 5.25 | 5.02 | 4.82 |
| Liquidus temperature TL (° C.) | 1255 | 1246 | 1219 | 1209 |
| Young's modulus parameter Y | 0.98 | 0.97 | 0.98 | 0.92 |
| Liquidus parameter L | 10.0 | 10.0 | 10.2 | 10.0 |
| Thermal expansion parameter C | 1.01 | 1.01 | 0.99 | 0.94 |
| Glass transition point (° C.) | 718 | 716 | 718 | 705 |
| Density (g/cm³) | 3.00 | 3.02 | 2.92 | 2.80 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.73 | 0.61 | 0.75 | 0.78 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 143 | Example 144 | Example 145 |
|---|---|---|---|
| SiO₂ | 51 | 52 | 52 |
| Al₂O₃ | 12 | 9 | 9 |
| B₂O₃ | 5 | 5 | 5 |
| MgO | 22 | 22 | 22 |
| CaO | 2 | 2 | 2 |
| SrO | 2 | 2 | 2 |
| BaO | 4 | 4 | 4 |
| Li₂O | | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | | | |
| Gd₂O₃ | | | 2 |
| La₂O₃ | | 2 | |
| WO₃ | | | |
| Ta₂O₅ | | | |
| Al₂O₃ + rare earth oxide | 12 | 11 | 11 |
| Y₂O₃ + Gd₂O₃ + La₂O₃ + Nd₂O₃ + Ta₂O₅ + Nb₂O₅ | 0 | 2 | 2 |
| Parameter A = (Al₂O₃ + RO)/(SiO₂ + Al₂O₃ + RO) | 0.45 | 0.43 | 0.43 |
| (Al₂O₃ + MgO)/(SiO₂ + Al₂O₃ + B₂O₃ + MgO) | 0.38 | 0.35 | 0.35 |
| MgO/ΣRO | 0.73 | 0.73 | 0.73 |
| N | 9 | 10 | 10 |
| Young's modulus E (GPa) | 96 | 97 | 96 |
| Coefficient of thermal expansion α (ppm/° C.) | 4.79 | 5.23 | 5.30 |
| Liquidus temperature TL (° C.) | 1226 | 1232 | 1224 |
| Young's modulus parameter Y | 0.94 | 0.95 | 0.95 |
| Liquidus parameter L | 10.3 | 9.6 | 9.6 |
| Thermal expansion parameter C | 0.93 | 1.01 | 1.01 |
| Glass transition point (° C.) | 709 | 708 | 706 |
| Density (g/cm³) | 2.81 | 2.98 | 3.00 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.77 | 0.82 | 0.70 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 21

| (mol %) | Example 146 | Example 147 | Example 148 | Example 149 |
|---|---|---|---|---|
| SiO₂ | 52 | 52 | 52 | 52 |
| Al₂O₃ | 9 | 10 | 10 | 10 |
| B₂O₃ | 5 | 4 | 4 | 4 |
| MgO | 22 | 22 | 22 | 22 |
| CaO | 2 | 2 | 2 | 2 |
| SrO | 2 | 2 | 2 | 2 |
| BaO | 4 | 4 | 4 | 4 |
| Li₂O | | | | |
| Na₂O | | | | |
| K₂O | | | | |
| ZnO | | | | |
| P₂O₅ | | | | |
| ZrO₂ | 1 | 1 | 1 | 1 |
| TiO₂ | 4 | 1 | 1 | 1 |
| Y₂O₃ | 2 | | | 2 |
| Gd₂O₃ | | | 2 | |
| La₂O₃ | | 2 | | |
| WO₃ | | | | |
| Ta₂O₅ | | | | |
| Al₂O₃ + rare earth oxide | 11 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.43 | 0.43 |
| (Al₂O₃ + MgO)/(SiO₂ + Al₂O₃ + B₂O₃ + MgO) | 0.35 | 0.36 | 0.36 | 0.36 |
| MgO/ΣRO | 0.73 | 0.73 | 0.73 | 0.73 |
| N | 10 | 10 | 10 | 10 |
| Young's modulus E (GPa) | 97 | 98 | 98 | 98 |
| Coefficient of thermal expansion α (ppm/° C.) | 5.07 | 5.20 | 5.27 | 5.04 |
| Liquidus temperature TL (° C.) | 1202 | 1256 | 1247 | 1221 |
| Young's modulus parameter Y | 0.96 | 0.97 | 0.97 | 0.97 |
| Liquidus parameter L | 9.9 | 9.9 | 9.9 | 10.1 |
| Thermal expansion parameter C | 1.00 | 1.01 | 1.01 | 0.99 |
| Glass transition point (° C.) | 708 | 718 | 716 | 718 |
| Density (g/cm³) | 2.90 | 2.99 | 3.01 | 2.92 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.85 | 0.81 | 0.69 | 0.84 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 150 | Example 151 | Example 152 |
|---|---|---|---|
| SiO₂ | 52 | 49 | 49 |
| Al₂O₃ | 11 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 4 | 2 | 2 |
| Li₂O | | 1 | 2 |
| Na₂O | | 1 | |
| K₂O | | 2 | 2 |
| ZnO | | | |
| P₂O₅ | | | |
| ZrO₂ | 1 | 1 | 1 |
| TiO₂ | 1 | 1 | 1 |
| Y₂O₃ | | 2 | 2 |
| Gd₂O₃ | | | |
| La₂O₃ | | | |
| WO₃ | | | |
| Ta₂O₅ | | | |
| Al₂O₃ + rare earth oxide | 11 | 12 | 12 |
| Y₂O₃ + Gd₂O₃ + La₂O₃ + Nd₂O₃ + Ta₂O₅ + Nb₂O₅ | 0 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.37 | 0.37 | 0.37 |
| MgO/ΣRO | 0.73 | 0.79 | 0.79 |
| N | 9 | 13 | 12 |
| Young's modulus E (GPa) | 95 | 97 | 99 |
| Coefficient of thermal expansion α (ppm/° C.) | 4.80 | 5.85 | 5.88 |
| Liquidus temperature TL (° C.) | 1223 | 1177 | 1180 |
| Young's modulus parameter Y | 0.93 | 0.95 | 0.96 |
| Liquidus parameter L | 10.2 | 9.7 | 9.6 |
| Thermal expansion parameter C | 0.93 | 1.13 | 1.06 |
| Glass transition point (° C.) | 709 | 696 | 696 |
| Density (g/cm³) | 2.80 | 2.82 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.86 | 0.60 | 0.64 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 22

| (mol %) | Example 153 | Example 154 | Example 155 | Example 156 |
|---|---|---|---|---|
| SiO₂ | 49 | 49 | 49 | 49 |
| Al₂O₃ | 10 | 10 | 10 | 10 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 3 | 3 | 3 |
| Li₂O | 2 | 1 | 1 | 2 |
| Na₂O | 1 | | 1 | |
| K₂O | 1 | 2 | 1 | 1 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.79 | 0.76 | 0.76 | 0.76 |
| N | 13 | 12 | 13 | 12 |
| Young's modulus E (GPa) | 101 | 97 | 98 | 101 |
| Coefficient of thermal expansion α (ppm/° C.) | 5.62 | 5.87 | 5.62 | 5.65 |
| Liquidus temperature TL (° C.) | 1178 | 1179 | 1177 | 1180 |
| Young's modulus parameter Y | 0.99 | 0.94 | 0.97 | 0.98 |
| Liquidus parameter L | 9.3 | 9.9 | 9.6 | 9.6 |
| Thermal expansion parameter C | 1.13 | 1.05 | 1.13 | 1.06 |
| Glass transition point (° C.) | 696 | 693 | 693 | 693 |
| Density (g/cm³) | 2.83 | 2.87 | 2.87 | 2.88 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.64 | 0.60 | 0.60 | 0.63 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 157 | Example 158 | Example 159 |
|---|---|---|---|
| SiO₂ | 49 | 49 | 49 |
| Al₂O₃ | 10 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 2 | 4 | 4 |
| Li₂O | 2 | | 1 |
| Na₂O | 1 | 1 | |
| K₂O | | 1 | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.45 | 0.45 |
| (Al₂O₃ + MgO)/(SiO₂ + Al₂O₃ + B₂O₃ + MgO) | 0.37 | 0.37 | 0.37 |
| MgO/ΣRO | 0.76 | 0.73 | 0.73 |
| N | 12 | 12 | 12 |
| Young's modulus E (GPa) | 102 | 96 | 98 |
| Coefficient of thermal expansion α (ppm/° C.) | 5.39 | 5.61 | 5.64 |
| Liquidus temperature TL (° C.) | 1185 | 1184 | 1184 |
| Young's modulus parameter Y | 1.01 | 0.95 | 0.96 |
| Liquidus parameter L | 9.3 | 9.9 | 9.9 |
| Thermal expansion parameter C | 1.14 | 1.12 | 1.05 |
| Glass transition point (° C.) | 703 | 699 | 694 |
| Density (g/cm³) | 2.88 | 2.90 | 2.91 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.63 | 0.56 | 0.60 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 23

| (mol %) | Example 160 | Example 161 | Example 162 | Example 163 |
|---|---|---|---|---|
| SiO₂ | 49 | 49 | 49 | 49 |
| Al₂O₃ | 10 | 10 | 10 | 10 |
| B₂O₃ | 5 | 5 | 6 | 6 |
| MgO | 22 | 22 | 22 | 22 |
| CaO | 2 | 2 | 2 | 2 |
| SrO | 2 | 2 | 2 | 2 |
| BaO | 4 | 4 | 2 | 2 |
| Li₂O | 1 | 2 | | 1 |
| Na₂O | 1 | | 2 | |
| K₂O | | | 1 | 2 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.44 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.73 | 0.73 | 0.79 | 0.79 |
| N | 12 | 11 | 12 | 12 |
| Young's modulus E (GPa) | 100 | 102 | 95 | 96 |
| Coefficient of thermal expansion α (ppm/° C.) | 5.38 | 5.41 | 5.43 | 5.72 |
| Liquidus temperature TL (° C.) | 1189 | 1191 | 1170 | 1170 |
| Young's modulus parameter Y | 0.99 | 1.00 | 0.96 | 0.94 |
| Liquidus parameter L | 9.6 | 9.5 | 9.4 | 9.7 |
| Thermal expansion parameter C | 1.13 | 1.08 | 1.18 | 1.03 |
| Glass transition point (° C.) | 704 | 704 | 699 | 693 |
| Density (g/cm³) | 2.91 | 2.92 | 2.81 | 2.82 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.60 | 0.63 | 0.59 | 0.62 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 164 | Example 165 | Example 166 |
|---|---|---|---|
| SiO₂ | 49 | 49 | 49 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 2 | 2 | 2 |
| Li₂O | 1 | 1 | 2 |
| Na₂O | 1 | 2 | |
| K₂O | 1 | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.37 | 0.37 | 0.37 |
| MgO/ΣRO | 0.79 | 0.79 | 0.79 |
| N | 13 | 12 | 12 |
| Young's modulus E (GPa) | 98 | 100 | 101 |
| Coefficient of thermal expansion α (ppm/° C.) | 5.46 | 5.21 | 5.49 |
| Liquidus temperature TL (° C.) | 1170 | 1170 | 1170 |
| Young's modulus parameter Y | 0.97 | 1.00 | 0.98 |
| Liquidus parameter L | 9.4 | 9.1 | 9.3 |
| Thermal expansion parameter C | 4.11 | 1.18 | 1.03 |
| Glass transition point (° C.) | 693 | 704 | 693 |
| Density (g/cm³) | 2.82 | 2.82 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.62 | 0.62 | 0.66 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 24

| (mol %) | Example 167 | Example 168 | Example 169 | Example 170 |
|---|---|---|---|---|
| SiO₂ | 49 | 49 | 49 | 49 |
| Al₂O₃ | 10 | 10 | 10 | 10 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 2 | 3 | 3 | 3 |
| Li₂O | 2 | | | 1 |
| Na₂O | 1 | 1 | 2 | |
| K₂O | | 1 | | 1 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.79 | 0.76 | 0.76 | 0.78 |
| N | 12 | 12 | 11 | 12 |
| Young's modulus E (GPa) | 102 | 95 | 97 | 98 |
| Coefficient of thermal expansion α (ppm/° C.) | 5.24 | 5.46 | 5.20 | 5.49 |
| Liquidus temperature TL (° C.) | 1170 | 1172 | 1172 | 1171 |
| Young's modulus parameter Y | 1.01 | 0.95 | 0.98 | 0.96 |
| Liquidus parameter L | 9.0 | 9.7 | 9.4 | 9.6 |
| Thermal expansion parameter C | 1.11 | 1.10 | 1.18 | 1.03 |
| Glass transition point (° C.) | 704 | 694 | 704 | 689 |
| Density (g/cm³) | 2.83 | 2.86 | 2.86 | 2.87 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.66 | 0.59 | 0.59 | 0.62 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 171 | Example 172 | Example 173 |
|---|---|---|---|
| SiO₂ | 49 | 49 | 49 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 3 | 3 | 4 |
| Li₂O | 1 | 2 | |
| Na₂O | 1 | | |
| K₂O | | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.45 |
| (Al₂O₃ + MgO)/(SiO₂ + Al₂O₃ + B₂O₃ + MgO) | 0.37 | 0.37 | 0.37 |
| MgO/ΣRO | 0.76 | 0.76 | 0.73 |
| N | 12 | 11 | 11 |
| Young's modulus E (GPa) | 100 | 102 | 95 |
| Coefficient of thermal expansion α (ppm/° C.) | 5.23 | 5.26 | 5.48 |
| Liquidus temperature TL (° C.) | 1172 | 1172 | 1174 |
| Young's modulus parameter Y | 0.99 | 1.00 | 0.94 |
| Liquidus parameter L | 9.3 | 9.3 | 9.9 |
| Thermal expansion parameter C | 1.11 | 1.04 | 1.03 |
| Glass transition point (° C.) | 699 | 699 | 695 |
| Density (g/cm³) | 2.67 | 2.88 | 2.91 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.62 | 0.66 | 0.59 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 25

| (mol %) | Example 174 | Example 175 | Example 176 | Example 177 |
|---|---|---|---|---|
| SiO₂ | 49 | 49 | 49 | 49 |
| Al₂O₃ | 10 | 10 | 10 | 10 |
| B₂O₃ | 6 | 6 | 7 | 7 |
| MgO | 22 | 22 | 22 | 22 |
| CaO | 2 | 2 | 2 | 2 |
| SrO | 2 | 2 | 2 | 2 |
| BaO | 4 | 4 | 2 | 2 |
| Li₂O | | 1 | | |
| Na₂O | 1 | | 1 | 2 |
| K₂O | | | 1 | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.44 | 0.44 |
| (Al₂O₃ + MgO)/(SiO₂ + Al₂O₃ + B₂O₃ + MgO) | 0.37 | 0.37 | 0.36 | 0.36 |
| MgO/ΣRO | 0.73 | 0.73 | 0.79 | 0.79 |
| N | 11 | 11 | 12 | 11 |
| Young's modulus E (GPa) | 97 | 100 | 95 | 97 |
| Coefficient of thermal expansion α (ppm/° C.) | 5.22 | 5.25 | 5.30 | 5.05 |
| Liquidus temperature TL (° C.) | 1174 | 1174 | 1156 | 1156 |
| Young's modulus parameter Y | 0.96 | 0.97 | 0.95 | 0.98 |
| Liquidus parameter L | 9.6 | 9.6 | 9.5 | 9.2 |
| Thermal expansion parameter C | 1.10 | 1.03 | 1.08 | 1.16 |
| Glass transition point (° C.) | 705 | 700 | 694 | 705 |
| Density (g/cm³) | 2.91 | 2.92 | 2.82 | 2.82 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.59 | 0.62 | 0.61 | 0.61 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 178 | Example 179 | Example 180 |
|---|---|---|---|
| SiO₂ | 49 | 49 | 49 |
| Al₂O₃ | 10 | 10 | 10 |
| B₂O₃ | 7 | 7 | 7 |
| MgO | 22 | 22 | 22 |
| CaO | 2 | 2 | 2 |
| SrO | 2 | 2 | 2 |
| BaO | 2 | 2 | 2 |
| Li₂O | 1 | 1 | |
| Na₂O | | 1 | |
| K₂O | 1 | | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.38 | 0.36 |
| MgO/ΣRO | 0.79 | 0.79 | 0.79 |
| N | 12 | 12 | 11 |
| Young's modulus E (GPa) | 98 | 100 | 102 |
| Coefficient of thermal expansion α (ppm/° C.) | 5.33 | 5.08 | 5.11 |
| Liquidus temperature TL (° C.) | 1156 | 1157 | 1156 |
| Young's modulus parameter Y | 0.96 | 0.99 | 1.00 |
| Liquidus parameter L | 9.4 | 9.1 | 9.1 |
| Thermal expansion parameter C | 1.01 | 1.09 | 1.01 |
| Glass transition point (° C.) | 689 | 700 | 700 |
| Density (g/cm³) | 2.83 | 2.83 | 2.84 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.65 | 0.65 | 0.68 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 26

| (mol %) | Example 181 | Example 182 | Example 183 | Example 184 |
|---|---|---|---|---|
| SiO₂ | 49 | 49 | 49 | 49 |
| Al₂O₃ | 10 | 10 | 10 | 11 |
| B₂O₃ | 7 | 7 | 7 | 5 |
| MgO | 22 | 22 | 22 | 22 |
| CaO | 2 | 2 | 2 | 2 |
| SrO | 2 | 2 | 2 | 2 |
| BaO | 3 | 3 | 3 | 2 |
| Li₂O | | | 1 | |
| Na₂O | | 1 | | 1 |
| K₂O | 1 | | | 2 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.38 |
| MgO/ΣRO | 0.76 | 0.76 | 0.76 | 0.79 |
| N | 11 | 11 | 11 | 12 |
| Young's modulus E (GPa) | 95 | 97 | 100 | 95 |
| Coefficient of thermal expansion α (ppm/° C.) | 5.32 | 5.07 | 5.10 | 5.66 |
| Liquidus temperature TL (° C.) | 1157 | 1158 | 1158 | 1178 |
| Young's modulus parameter Y | 0.94 | 0.97 | 0.98 | 0.95 |
| Liquidus parameter L | 9.7 | 9.4 | 9.4 | 10.0 |
| Thermal expansion parameter C | 1.00 | 1.08 | 1.01 | 1.09 |
| Glass transition point (° C.) | 690 | 699 | 696 | 703 |
| Density (g/cm³) | 2.86 | 2.86 | 2.87 | 2.82 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.61 | 0.81 | 0.65 | 0.58 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 185 | Example 186 | Example 187 |
|---|---|---|---|
| SiO₂ | 49 | 49 | 49 |
| Al₂O₃ | 11 | 11 | 11 |
| B₂O₃ | 5 | 5 | 5 |
| MgO | 22 | 22 | 22 |
| CaO | 2 | 2 | 2 |
| SrO | 2 | 2 | 2 |
| BaO | 2 | 2 | 2 |
| Li₂O | | 1 | 1 |
| Na₂O | 2 | | 1 |
| K₂O | 1 | 2 | 1 |
| ZnO | | | |
| P₂O₅ | | | |
| ZrO₂ | 1 | 3 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.38 | 0.38 | 0.38 |
| MgO/ΣRO | 0.79 | 0.79 | 0.79 |
| N | 12 | 12 | 13 |
| Young's modulus E (GPa) | 97 | 98 | 99 |
| Coefficient of thermal expansion α (ppm/° C.) | 5.40 | 5.69 | 5.43 |
| Liquidus temperature TL (° C.) | 1178 | 1177 | 1176 |
| Young's modulus parameter Y | 0.98 | 0.96 | 0.99 |
| Liquidus parameter L | 9.7 | 9.9 | 9.6 |
| Thermal expansion parameter C | 1.17 | 1.02 | 1.10 |
| Glass transition point (° C.) | 703 | 696 | 696 |
| Density (g/cm³) | 2.82 | 2.83 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.58 | 0.62 | 0.62 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 27

| (mol %) | Example 188 | Example 189 | Example 190 | Example 191 |
|---|---|---|---|---|
| SiO₂ | 49 | 49 | 49 | 49 |
| Al₂O₃ | 11 | 11 | 11 | 11 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 2 | 2 | 3 |
| Li₂O | 1 | 2 | 2 | |
| Na₂O | 2 | | 1 | |
| K₂O | | 1 | | 2 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.45 |
| (Al₂O₃ + MgO)/(SiO₂ + Al₂O₃ + B₂O₃ + MgO) | 0.38 | 0.38 | 0.38 | 0.38 |
| MgO/ΣRO | 0.79 | 0.79 | 0.79 | 0.76 |
| N | 12 | 12 | 12 | 11 |
| Young's modulus E (GPa) | 101 | 102 | 103 | 95 |
| Coefficient of thermal expansion α (ppm/° C.) | 5.17 | 5.46 | 5.20 | 5.68 |
| Liquidus temperature TL (° C.) | 1183 | 1178 | 1183 | 1180 |
| Young's modulus parameter Y | 1.01 | 1.00 | 1.02 | 0.94 |
| Liquidus parameter L | 9.3 | 9.6 | 9.3 | 10.2 |
| Thermal expansion parameter C | 1.18 | 1.03 | 1.11 | 1.02 |
| Glass transition point (° C.) | 707 | 696 | 707 | 698 |
| Density (g/cm³) | 2.83 | 2.84 | 2.84 | 2.87 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.62 | 0.65 | 0.65 | 0.58 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 192 | Example 193 | Example 194 |
|---|---|---|---|
| SiO₂ | 49 | 49 | 49 |
| Al₂O₃ | 11 | 11 | 11 |
| B₂O₃ | 5 | 5 | 5 |
| MgO | 22 | 22 | 22 |
| CaO | 2 | 2 | 2 |
| SrO | 2 | 2 | 2 |
| BaO | 3 | 3 | 3 |
| Li₂O | | | 1 |
| Na₂O | 1 | 2 | |
| K₂O | 1 | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.45 | 0.45 | 0.45 |
| (Al₂O₃ + MgO)/(SiO₂ + Al₂O₃ + B₂O₃ + MgO) | 0.38 | 0.38 | 0.38 |
| MgO/ΣRO | 0.76 | 0.76 | 0.76 |
| N | 12 | 11 | 12 |
| Young's modulus E (GPa) | 97 | 98 | 99 |
| Coefficient of thermal expansion α (ppm/° C.) | 5.42 | 5.17 | 5.45 |
| Liquidus temperature TL (° C.) | 1178 | 1186 | 1178 |
| Young's modulus parameter Y | 0.96 | 0.99 | 0.97 |
| Liquidus parameter L | 9.9 | 9.6 | 9.9 |
| Thermal expansion parameter C | 1.10 | 1.17 | 1.02 |
| Glass transition point (° C.) | 698 | 709 | 693 |
| Density (g/cm³) | 2.87 | 2.87 | 2.88 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.58 | 0.58 | 0.62 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 28

| (mol %) | Example 195 | Example 196 | Example 197 | Example 198 |
|---|---|---|---|---|
| SiO₂ | 49 | 49 | 49 | 49 |
| Al₂O₃ | 11 | 11 | 11 | 11 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 3 | 3 | 4 | 4 |
| Li₂O | 1 | 2 | | |
| Na₂O | 1 | | | 1 |
| K₂O | | | 1 | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.46 | 0.46 |
| (Al₂O₃ + MgO)/(SiO₂ + Al₂O₃ + B₂O₃ + MgO) | 0.38 | 0.38 | 0.38 | 0.38 |
| MgO/ΣRO | 0.76 | 0.76 | 0.73 | 0.73 |
| N | 12 | 11 | 11 | 11 |
| Young's modulus E (GPa) | 101 | 103 | 97 | 98 |
| Coefficient of thermal expansion α (ppm/° C.) | 5.20 | 5.23 | 5.44 | 5.19 |
| Liquidus temperature TL (° C.) | 1183 | 1185 | 1184 | 1189 |
| Young's modulus parameter Y | 1.00 | 1.01 | 0.95 | 0.98 |
| Liquidus parameter L | 9.6 | 9.5 | 10.2 | 9.9 |
| Thermal expansion parameter C | 1.10 | 1.03 | 1.02 | 1.10 |
| Glass transition point (° C.) | 703 | 703 | 699 | 709 |
| Density (g/cm³) | 2.88 | 2.89 | 2.92 | 2.92 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.62 | 0.65 | 0.58 | 0.58 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 199 | Example 200 | Example 201 |
|---|---|---|---|
| SiO₂ | 49 | 49 | 49 |
| Al₂O₃ | 11 | 11 | 11 |
| B₂O₃ | 5 | 6 | 6 |
| MgO | 22 | 22 | 22 |
| CaO | 2 | 2 | 2 |
| SrO | 2 | 2 | 2 |
| BaO | 4 | 2 | 2 |
| Li₂O | 1 | | |
| Na₂O | | | 1 |
| K₂O | | 2 | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.46 | 0.44 | 0.44 |
| (Al₂O₃ + MgO)/(SiO₂ + Al₂O₃ + B₂O₃ + MgO) | 0.38 | 0.38 | 0.38 |
| MgO/ΣRO | 0.73 | 0.79 | 0.79 |
| N | 11 | 11 | 12 |
| Young's modulus E (GPa) | 101 | 95 | 97 |
| Coefficient of thermal expansion α (ppm/° C.) | 5.22 | 5.53 | 5.27 |
| Liquidus temperature TL (° C.) | 1189 | 1167 | 1168 |
| Young's modulus parameter Y | 0.99 | 0.94 | 0.96 |
| Liquidus parameter L | 9.8 | 10.0 | 9.7 |
| Thermal expansion parameter C | 1.03 | 0.99 | 1.07 |
| Glass transition point (° C.) | 704 | 699 | 699 |
| Density (g/cm³) | 2.93 | 2.83 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.62 | 0.61 | 0.61 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 29

| (mol %) | Example 202 | Example 203 | Example 204 | Example 205 |
|---|---|---|---|---|
| SiO₂ | 49 | 49 | 49 | 49 |
| Al₂O₃ | 11 | 11 | 11 | 11 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 2 | 2 | 2 | 2 |
| Li₂O | | 1 | 1 | 2 |
| Na₂O | 2 | | 1 | |
| K₂O | | 1 | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.38 | 0.38 | 0.38 | 0.38 |
| MgO/ΣRO | 0.79 | 0.79 | 0.79 | 0.79 |
| N | 11 | 12 | 12 | 11 |
| Young's modulus E (GPa) | 98 | 99 | 101 | 103 |
| Coefficient of thermal expansion α (ppm/° C.) | 5.01 | 5.30 | 5.04 | 5.07 |
| Liquidus temperature TL (° C.) | 1168 | 1168 | 1169 | 1168 |
| Young's modulus parameter Y | 0.99 | 0.97 | 1.00 | 1.01 |
| Liquidus parameter L | 9.4 | 9.6 | 9.3 | 9.3 |
| Thermal expansion parameter C | 1.15 | 1.00 | 1.08 | 1.01 |
| Glass transition point (° C.) | 710 | 693 | 704 | 704 |
| Density (g/cm³) | 2.83 | 2.84 | 2.84 | 2.85 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.61 | 0.64 | 0.64 | 0.68 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 206 | Example 207 | Example 208 |
|---|---|---|---|
| SiO₂ | 49 | 49 | 49 |
| Al₂O₃ | 11 | 11 | 11 |
| B₂O₃ | 6 | 6 | 6 |
| MgO | 22 | 22 | 22 |
| CaO | 2 | 2 | 2 |
| SrO | 2 | 2 | 2 |
| BaO | 3 | 3 | 3 |
| Li₂O | | | 1 |
| Na₂O | | 1 | |
| K₂O | 1 | | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.45 | 0.45 | 0.45 |
| (Al₂O₃ + MgO)/(SiO₂ + Al₂O₃ + B₂O₃ + MgO) | 0.38 | 0.38 | 0.38 |
| MgO/ΣRO | 0.76 | 0.76 | 0.76 |
| N | 11 | 11 | 11 |
| Young's modulus E (GPa) | 97 | 98 | 101 |
| Coefficient of thermal expansion α (ppm/° C.) | 5.29 | 5.03 | 5.07 |
| Liquidus temperature TL (° C.) | 1169 | 1170 | 1170 |
| Young's modulus parameter Y | 0.95 | 0.98 | 0.99 |
| Liquidus parameter L | 10.0 | 9.6 | 9.6 |
| Thermal expansion parameter C | 1.00 | 1.07 | 1.00 |
| Glass transition point (° C.) | 695 | 705 | 700 |
| Density (g/cm³) | 2.87 | 2.87 | 2.88 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.60 | 0.60 | 0.64 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 30

| (mol %) | Example 209 | Example 210 | Example 211 | Example 212 |
|---|---|---|---|---|
| SiO₂ | 49 | 49 | 49 | 49 |
| Al₂O₃ | 11 | 11 | 11 | 11 |
| B₂O₃ | 7 | 7 | 7 | 7 |
| MgO | 22 | 22 | 22 | 22 |
| CaO | 2 | 2 | 2 | 2 |
| SrO | 2 | 2 | 2 | 2 |
| BaO | 2 | 2 | 2 | 3 |
| Li₂O | | | 1 | |
| Na₂O | | 1 | | |
| K₂O | 1 | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.45 |
| (Al₂O₃ + MgO)/(SiO₂ + Al₂O₃ + B₂O₃ + MgO) | 0.37 | 0.37 | 0.37 | 0.37 |
| MgO/ΣRO | 0.79 | 0.79 | 0.79 | 0.76 |
| N | 11 | 11 | 11 | 10 |
| Young's modulus E (GPa) | 96 | 98 | 101 | 98 |
| Coefficient of thermal expansion α (ppm/° C.) | 5.14 | 4.88 | 4.91 | 4.90 |
| Liquidus temperature TL (° C.) | 1152 | 1153 | 1154 | 1154 |
| Young's modulus parameter Y | 0.95 | 0.98 | 0.99 | 0.97 |
| Liquidus parameter L | 9.7 | 9.4 | 9.4 | 9.7 |
| Thermal expansion parameter C | 0.97 | 1.05 | 0.98 | 0.98 |
| Glass transition point (° C.) | 695 | 705 | 701 | 700 |
| Density (g/cm³) | 2.83 | 2.83 | 2.84 | 2.88 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.63 | 0.63 | 0.67 | 0.63 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 213 | Example 214 | Example 215 |
|---|---|---|---|
| SiO₂ | 49 | 49 | 49 |
| Al₂O₃ | 12 | 12 | 12 |
| B₂O₃ | 5 | 5 | 5 |
| MgO | 22 | 22 | 22 |
| CaO | 2 | 2 | 2 |
| SrO | 2 | 2 | 2 |
| BaO | 2 | 2 | 2 |
| Li₂O | | | |
| Na₂O | | 1 | 2 |
| K₂O | 2 | 1 | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 14 | 14 | 14 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.45 | 0.45 | 0.45 |
| (Al₂O₃ + MgO)/(SiO₂ + Al₂O₃ + B₂O₃ + MgO) | 0.39 | 0.39 | 0.39 |
| MgO/ΣRO | 0.79 | 0.79 | 0.79 |
| N | 11 | 12 | 11 |
| Young's modulus E (GPa) | 96 | 98 | 99 |
| Coefficient of thermal expansion α (ppm/° C.) | 5.49 | 5.24 | 4.98 |
| Liquidus temperature TL (° C.) | 1185 | 1181 | 1188 |
| Young's modulus parameter Y | 0.95 | 0.98 | 1.01 |
| Liquidus parameter L | 10.2 | 9.9 | 9.6 |
| Thermal expansion parameter C | 0.99 | 1.07 | 1.14 |
| Glass transition point (° C.) | 702 | 702 | 713 |
| Density (g/cm³) | 2.84 | 2.84 | 2.84 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.60 | 0.60 | 0.60 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 31

| (mol %) | Example 216 | Example 217 | Example 218 | Example 219 |
|---|---|---|---|---|
| SiO₂ | 49 | 49 | 49 | 49 |
| Al₂O₃ | 12 | 12 | 12 | 12 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 2 | 2 | 3 |
| Li₂O | 1 | 1 | 2 | |
| Na₂O | | 1 | | |
| K₂O | 1 | | | 1 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 14 | 14 | 14 | 14 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.45 | 0.46 |
| (Al₂O₃ + MgO)/(SiO₂ + Al₂O₃ + B₂O₃ + MgO) | 0.39 | 0.39 | 0.39 | 0.39 |
| MgO/ΣRO | 0.79 | 0.79 | 0.79 | 0.76 |
| N | 12 | 12 | 11 | 11 |
| Young's modulus E (GPa) | 100 | 102 | 105 | 98 |
| Coefficient of thermal expansion α (ppm/° C.) | 5.27 | 5.01 | 5.04 | 5.28 |
| Liquidus temperature TL (° C.) | 1183 | 1185 | 1189 | 1186 |
| Young's modulus parameter Y | 0.99 | 1.02 | 1.03 | 0.97 |
| Liquidus parameter L | 9.9 | 9.6 | 9.5 | 10.2 |
| Thermal expansion parameter C | 0.99 | 1.07 | 1.00 | 0.99 |
| Glass transition point (° C.) | 695 | 706 | 706 | 698 |
| Density (g/cm³) | 2.85 | 2.85 | 2.86 | 2.88 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.63 | 0.63 | 0.67 | 0.60 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 220 | Example 221 | Example 222 |
|---|---|---|---|
| SiO₂ | 49 | 49 | 49 |
| Al₂O₃ | 12 | 12 | 12 |
| B₂O₃ | 5 | 5 | 6 |
| MgO | 22 | 22 | 22 |
| CaO | 2 | 2 | 2 |
| SrO | 2 | 2 | 2 |
| BaO | 3 | 3 | 2 |
| Li₂O | | 1 | |
| Na₂O | 1 | | |
| K₂O | | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 14 | 14 | 14 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.46 | 0.46 | 0.45 |
| (Al₂O₃ + MgO)/(SiO₂ + Al₂O₃ + B₂O₃ + MgO) | 0.39 | 0.39 | 0.38 |
| MgO/ΣRO | 0.76 | 0.76 | 0.79 |
| N | 11 | 11 | 11 |
| Young's modulus E (GPa) | 99 | 102 | 98 |
| Coefficient of thermal expansion α (ppm/° C.) | 5.00 | 5.03 | 5.11 |
| Liquidus temperature TL (° C.) | 1188 | 1190 | 1168 |
| Young's modulus parameter Y | 0.99 | 1.00 | 0.97 |
| Liquidus parameter L | 9.9 | 9.8 | 10.0 |
| Thermal expansion parameter C | 1.07 | 1.00 | 0.97 |
| Glass transition point (° C.) | 708 | 703 | 693 |
| Density (g/cm³) | 2.88 | 2.89 | 2.84 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.60 | 0.63 | 0.62 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 32

| (mol %) | Example 223 | Example 224 | Example 225 | Example 226 |
|---|---|---|---|---|
| SiO₂ | 49 | 49 | 49 | 49 |
| Al₂O₃ | 12 | 12 | 12 | 12 |
| B₂O₃ | 6 | 6 | 6 | 7 |
| MgO | 22 | 22 | 22 | 22 |
| CaO | 2 | 2 | 2 | 2 |
| SrO | 2 | 2 | 2 | 2 |
| BaO | 2 | 2 | 3 | 2 |
| Li₂O | | 1 | | |
| Na₂O | 1 | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 14 | 14 | 14 | 14 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.46 | 0.45 |
| (Al₂O₃ + MgO)/(SiO₂ + Al₂O₃ + B₂O₃ + MgO) | 0.38 | 0.38 | 0.38 | 0.38 |
| MgO/ΣRO | 0.79 | 0.79 | 0.76 | 0.79 |
| N | 11 | 11 | 10 | 10 |
| Young's modulus E (GPa) | 99 | 102 | 99 | 99 |
| Coefficient of thermal expansion α (ppm/° C.) | 4.85 | 4.88 | 4.87 | 4.72 |
| Liquidus temperature TL (° C.) | 1168 | 1168 | 1170 | 1151 |
| Young's modulus parameter Y | 0.99 | 1.00 | 0.98 | 0.98 |
| Liquidus parameter L | 9.7 | 9.6 | 9.9 | 9.7 |
| Thermal expansion parameter C | 1.05 | 0.97 | 0.97 | 0.95 |
| Glass transition point (° C.) | 710 | 704 | 705 | 705 |
| Density (g/cm³) | 2.84 | 2.85 | 2.89 | 2.84 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.62 | 0.66 | 0.62 | 0.65 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 227 | Example 228 | Example 229 |
|---|---|---|---|
| SiO₂ | 50 | 50 | 50 |
| Al₂O₃ | 10 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 2 | 2 | 2 |
| Li₂O | | 1 | 1 |
| Na₂O | 2 | | 1 |
| K₂O | 1 | 2 | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.43 | 0.43 | 0.43 |
| (Al₂O₃ + MgO)/(SiO₂ + Al₂O₃ + B₂O₃ + MgO) | 0.37 | 0.37 | 0.37 |
| MgO/ΣRO | 0.79 | 0.79 | 0.79 |
| N | 12 | 12 | 13 |
| Young's modulus E (GPa) | 96 | 97 | 98 |
| Coefficient of thermal expansion α (ppm/° C.) | 5.42 | 5.70 | 5.45 |
| Liquidus temperature TL (° C.) | 1191 | 1192 | 1190 |
| Young's modulus parameter Y | 0.97 | 0.95 | 0.98 |
| Liquidus parameter L | 9.6 | 9.8 | 9.5 |
| Thermal expansion parameter C | 1.17 | 1.02 | 1.10 |
| Glass transition point (° C.) | 702 | 696 | 696 |
| Density (g/cm³) | 2.81 | 2.82 | 2.82 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.66 | 0.70 | 0.70 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 33

| (mol %) | Example 230 | Example 231 | Example 232 | Example 233 |
|---|---|---|---|---|
| SiO₂ | 50 | 50 | 50 | 50 |
| Al₂O₃ | 10 | 10 | 10 | 10 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 2 | 2 | 3 |
| Li₂O | 1 | 2 | 2 | |
| Na₂O | 2 | | 1 | 1 |
| K₂O | | 1 | | 1 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.43 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.79 | 0.79 | 0.79 | 0.76 |
| N | 12 | 12 | 12 | 12 |
| Young's modulus E (GPa) | 100 | 101 | 103 | 96 |
| Coefficient of thermal expansion α (ppm/° C.) | 5.19 | 5.48 | 5.22 | 5.44 |
| Liquidus temperature TL (° C.) | 1197 | 1193 | 1197 | 1190 |
| Young's modulus parameter Y | 1.00 | 0.99 | 1.01 | 0.95 |
| Liquidus parameter L | 9.2 | 9.5 | 9.2 | 9.8 |
| Thermal expansion parameter C | 1.18 | 1.03 | 1.11 | 1.10 |
| Glass transition point (° C.) | 707 | 696 | 707 | 698 |
| Density (g/cm³) | 2.82 | 2.83 | 2.83 | 2.86 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.70 | 0.74 | 0.74 | 0.66 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 234 | Example 235 | Example 236 |
|---|---|---|---|
| SiO₂ | 50 | 50 | 50 |
| Al₂O₃ | 10 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 3 | 3 | 3 |
| Li₂O | | 1 | 1 |
| Na₂O | 2 | | 1 |
| K₂O | | 1 | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.37 | 0.37 | 0.37 |
| MgO/ΣRO | 0.76 | 0.76 | 0.76 |
| N | 11 | 12 | 12 |
| Young's modulus E (GPa) | 97 | 98 | 100 |
| Coefficient of thermal expansion α (ppm/° C.) | 5.18 | 5.47 | 5.21 |
| Liquidus temperature TL (° C.) | 1197 | 1191 | 1197 |
| Young's modulus parameter Y | 0.98 | 0.96 | 0.99 |
| Liquidus parameter L | 9.5 | 9.8 | 9.5 |
| Thermal expansion parameter C | 1.18 | 1.03 | 1.10 |
| Glass transition point (° C.) | 708 | 693 | 703 |
| Density (g/cm³) | 2.86 | 2.87 | 2.87 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.66 | 0.70 | 0.70 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 34

| (mol %) | Example 237 | Example 238 | Example 239 | Example 240 |
|---|---|---|---|---|
| SiO₂ | 50 | 50 | 50 | 50 |
| Al₂O₃ | 10 | 10 | 10 | 10 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 3 | 4 | 4 | 4 |
| Li₂O | 2 | | | 1 |
| Na₂O | | | 1 | |
| K₂O | | 1 | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.76 | 0.73 | 0.73 | 0.73 |
| N | 11 | 11 | 11 | 11 |
| Young's modulus E (GPa) | 103 | 96 | 97 | 100 |
| Coefficient of thermal expansion α (ppm/° C.) | 5.24 | 5.46 | 5.20 | 5.23 |
| Liquidus temperature TL (° C.) | 1198 | 1195 | 1200 | 1202 |
| Young's modulus parameter Y | 1.00 | 0.94 | 0.97 | 0.98 |
| Liquidus parameter L | 9.4 | 10.1 | 9.8 | 9.7 |
| Thermal expansion parameter C | 1.03 | 1.02 | 1.10 | 1.03 |
| Glass transition point (° C.) | 703 | 699 | 709 | 703 |
| Density (g/cm³) | 2.88 | 2.91 | 2.91 | 2.92 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.74 | 0.66 | 0.66 | 0.70 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 241 | Example 242 | Example 243 |
|---|---|---|---|
| SiO₂ | 50 | 50 | 50 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 2 | 2 | 2 |
| Li₂O | | | 1 |
| Na₂O | 1 | 2 | |
| K₂O | 1 | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.43 | 0.43 | 0.43 |
| (Al₂O₃ + MgO)/(SiO₂ + Al₂O₃ + B₂O₃ + MgO) | 0.36 | 0.36 | 0.36 |
| MgO/ΣRO | 0.79 | 0.79 | 0.79 |
| N | 12 | 11 | 12 |
| Young's modulus E (GPa) | 96 | 97 | 98 |
| Coefficient of thermal expansion α (ppm/° C.) | 5.29 | 5.03 | 5.32 |
| Liquidus temperature TL (° C.) | 1188 | 1188 | 1188 |
| Young's modulus parameter Y | 0.96 | 0.98 | 0.97 |
| Liquidus parameter L | 9.6 | 9.3 | 9.6 |
| Thermal expansion parameter C | 1.07 | 1.15 | 1.00 |
| Glass transition point (° C.) | 699 | 709 | 692 |
| Density (g/cm³) | 2.82 | 2.82 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.69 | 0.69 | 0.72 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 35

| (mol %) | Example 244 | Example 245 | Example 246 | Example 247 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 2 | 2 | 3 | 3 |
| Li₂O | 1 | 2 | | |
| Na₂O | 1 | | | 1 |
| K₂O | | | 1 | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.79 | 0.79 | 0.76 | 0.78 |
| N | 12 | 11 | 11 | 11 |
| Young's modulus E (GPa) | 100 | 102 | 96 | 97 |
| Coefficient of thermal expansion α (ppm/° C.) | 5.06 | 5.09 | 5.31 | 5.05 |
| Liquidus temperature TL (° C.) | 1188 | 1188 | 1189 | 1188 |
| Young's modulus parameter Y | 0.99 | 1.00 | 0.94 | 0.97 |
| Liquidus parameter L | 9.2 | 9.2 | 9.9 | 9.6 |
| Thermal expansion parameter C | 1.08 | 1.01 | 1.00 | 1.08 |
| Glass transition point (° C.) | 704 | 704 | 694 | 704 |
| Density (g/cm³) | 2.83 | 2.84 | 2.86 | 2.86 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.72 | 0.76 | 0.69 | 0.69 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 248 | Example 249 | Example 250 |
|---|---|---|---|
| SiO₂ | 50 | 50 | 50 |
| Al₂O₃ | 10 | 10 | 10 |
| B₂O₃ | 6 | 7 | 7 |
| MgO | 22 | 22 | 22 |
| CaO | 2 | 2 | 2 |
| SrO | 2 | 2 | 2 |
| BaO | 3 | 2 | 2 |
| Li₂O | 1 | | |
| Na₂O | | | 1 |
| K₂O | | 1 | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.43 | 0.43 |
| (Al₂O₃ + MgO)/(SiO₂ + Al₂O₃ + B₂O₃ + MgO) | 0.36 | 0.36 | 0.36 |
| MgO/ΣRO | 0.76 | 0.79 | 0.79 |
| N | 11 | 11 | 11 |
| Young's modulus E (GPa) | 100 | 96 | 97 |
| Coefficient of thermal expansion α (ppm/° C.) | 5.08 | 5.16 | 4.90 |
| Liquidus temperature TL (° C.) | 1189 | 1183 | 1182 |
| Young's modulus parameter Y | 0.98 | 0.94 | 0.97 |
| Liquidus parameter L | 9.5 | 9.6 | 9.3 |
| Thermal expansion parameter C | 1.01 | 0.97 | 1.05 |
| Glass transition point (° C.) | 699 | 694 | 705 |
| Density (g/cm³) | 2.88 | 2.82 | 2.82 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.72 | 0.71 | 0.71 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 36

| (mol %) | Example 251 | Example 252 | Example 253 | Example 254 |
|---|---|---|---|---|
| SiO₂ | 50 | 50 | 50 | 50 |
| Al₂O₃ | 10 | 10 | 11 | 11 |
| B₂O₃ | 7 | 7 | 5 | 5 |
| MgO | 22 | 22 | 22 | 22 |
| CaO | 2 | 2 | 2 | 2 |
| SrO | 2 | 2 | 2 | 2 |
| BaO | 2 | 3 | 2 | 2 |
| Li₂O | 1 | | | |
| Na₂O | | | | 1 |
| K₂O | | | 2 | 1 |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.44 | 0.44 | 0.44 |
| (Al₂O₃ + MgO)/(SiO₂ + Al₂O₃ + B₂O₃ + MgO) | 0.36 | 0.36 | 0.38 | 0.38 |
| MgO/ΣRO | 0.79 | 0.76 | 0.79 | 0.79 |
| N | 11 | 10 | 11 | 12 |
| Young's modulus E (GPa) | 100 | 97 | 95 | 97 |
| Coefficient of thermal expansion α (ppm/° C.) | 4.93 | 4.92 | 5.51 | 5.25 |
| Liquidus temperature TL (° C.) | 1183 | 1183 | 1192 | 1190 |
| Young's modulus parameter Y | 0.98 | 0.96 | 0.94 | 0.97 |
| Liquidus parameter L | 9.3 | 9.6 | 10.1 | 9.8 |
| Thermal expansion parameter C | 0.98 | 0.98 | 0.99 | 1.07 |
| Glass transition point (° C.) | 700 | 699 | 703 | 703 |
| Density (g/cm³) | 2.83 | 2.87 | 2.83 | 2.83 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.75 | 0.71 | 0.68 | 0.68 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 255 | Example 256 | Example 257 |
|---|---|---|---|
| SiO₂ | 50 | 50 | 50 |
| Al₂O₃ | 11 | 11 | 11 |
| B₂O₃ | 5 | 5 | 5 |
| MgO | 22 | 22 | 22 |
| CaO | 2 | 2 | 2 |
| SrO | 2 | 2 | 2 |
| BaO | 2 | 2 | 2 |
| Li₂O | | 1 | 1 |
| Na₂O | 2 | | 1 |
| K₂O | | 1 | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.38 | 0.38 | 0.38 |
| MgO/ΣRO | 0.79 | 0.79 | 0.79 |
| N | 11 | 12 | 12 |
| Young's modulus E (GPa) | 98 | 99 | 101 |
| Coefficient of thermal expansion α (ppm/° C.) | 5.00 | 5.28 | 5.03 |
| Liquidus temperature TL (° C.) | 1197 | 1191 | 1196 |
| Young's modulus parameter Y | 1.00 | 0.98 | 1.01 |
| Liquidus parameter L | 9.5 | 9.8 | 9.5 |
| Thermal expansion parameter C | 1.15 | 1.00 | 1.07 |
| Glass transition point (° C.) | 713 | 696 | 707 |
| Density (g/cm³) | 2.83 | 2.84 | 2.84 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.68 | 0.72 | 0.72 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 37

| (mol %) | Example 258 | Example 259 | Example 260 | Example 261 |
|---|---|---|---|---|
| SiO₂ | 50 | 50 | 50 | 50 |
| Al₂O₃ | 11 | 11 | 11 | 11 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 3 | 3 | 3 |
| Li₂O | 2 | | | 1 |
| Na₂O | | | 1 | |
| K₂O | | 1 | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.38 | 0.38 | 0.38 | 0.38 |
| MgO/ΣRO | 0.79 | 0.76 | 0.76 | 0.78 |
| N | 11 | 11 | 11 | 11 |
| Young's modulus E (GPa) | 104 | 97 | 98 | 101 |
| Coefficient of thermal expansion α (ppm/° C.) | 5.06 | 5.28 | 5.02 | 5.05 |
| Liquidus temperature TL (° C.) | 1198 | 1191 | 1197 | 1197 |
| Young's modulus parameter Y | 1.02 | 0.96 | 0.99 | 1.00 |
| Liquidus parameter L | 9.4 | 10.1 | 9.8 | 9.7 |
| Thermal expansion parameter C | 1.00 | 0.99 | 1.07 | 1.00 |
| Glass transition point (° C.) | 707 | 698 | 708 | 703 |
| Density (g/cm³) | 2.85 | 2.87 | 2.87 | 2.89 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.75 | 0.68 | 0.68 | 0.72 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 262 | Example 263 | Example 264 |
|---|---|---|---|
| SiO₂ | 50 | 50 | 50 |
| Al₂O₃ | 11 | 11 | 11 |
| B₂O₃ | 6 | 6 | 6 |
| MgO | 22 | 22 | 22 |
| CaO | 2 | 2 | 2 |
| SrO | 2 | 2 | 2 |
| BaO | 2 | 2 | 2 |
| Li₂O | | | 1 |
| Na₂O | | 1 | |
| K₂O | 1 | | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 13 | 13 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.37 | 0.37 | 0.37 |
| MgO/ΣRO | 0.79 | 0.79 | 0.79 |
| N | 11 | 11 | 11 |
| Young's modulus E (GPa) | 97 | 98 | 101 |
| Coefficient of thermal expansion α (ppm/° C.) | 5.12 | 4.87 | 4.90 |
| Liquidus temperature TL (° C.) | 1186 | 1186 | 1187 |
| Young's modulus parameter Y | 0.96 | 0.99 | 1.00 |
| Liquidus parameter L | 9.9 | 9.6 | 9.5 |
| Thermal expansion parameter C | 0.97 | 1.05 | 0.98 |
| Glass transition point (° C.) | 699 | 710 | 704 |
| Density (g/cm³) | 2.83 | 2.83 | 2.84 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.79 | 0.71 | 0.74 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 38

| (mol %) | Example 265 | Example 266 | Example 267 | Example 268 |
|---|---|---|---|---|
| SiO₂ | 50 | 50 | 50 | 50 |
| Al₂O₃ | 11 | 11 | 12 | 12 |
| B₂O₃ | 6 | 7 | 5 | 5 |
| MgO | 22 | 22 | 22 | 22 |
| CaO | 2 | 2 | 2 | 2 |
| SrO | 2 | 2 | 2 | 2 |
| BaO | 3 | 2 | 2 | 2 |
| Li₂O | | | | |
| Na₂O | | | | 1 |
| K₂O | | | 1 | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 13 | 13 | 14 | 14 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.37 | 0.37 | 0.38 | 0.38 |
| MgO/ΣRO | 0.76 | 0.79 | 0.79 | 0.79 |
| N | 10 | 10 | 11 | 11 |
| Young's modulus E (GPa) | 98 | 98 | 98 | 99 |
| Coefficient of thermal expansion α (ppm/° C.) | 4.89 | 4.74 | 5.09 | 4.83 |
| Liquidus temperature TL (° C.) | 1187 | 1181 | 1197 | 1200 |
| Young's modulus parameter Y | 0.97 | 0.97 | 0.97 | 1.00 |
| Liquidus parameter L | 9.8 | 9.6 | 10.1 | 9.8 |
| Thermal expansion parameter C | 0.97 | 0.95 | 0.96 | 1.04 |
| Glass transition point (° C.) | 704 | 705 | 702 | 713 |
| Density (g/cm³) | 2.88 | 2.84 | 2.84 | 2.84 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.70 | 0.73 | 0.70 | 0.70 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 269 | Example 270 | Example 271 |
|---|---|---|---|
| SiO₂ | 50 | 50 | 50 |
| Al₂O₃ | 12 | 12 | 12 |
| B₂O₃ | 5 | 5 | 6 |
| MgO | 22 | 22 | 22 |
| CaO | 2 | 2 | 2 |
| SrO | 2 | 2 | 2 |
| BaO | 2 | 3 | 2 |
| Li₂O | 1 | | |
| Na₂O | | | |
| K₂O | | | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 14 | 14 | 14 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.45 | 0.44 |
| (Al₂O₃ + MgO)/(SiO₂ + Al₂O₃ + B₂O₃ + MgO) | 0.38 | 0.38 | 0.38 |
| MgO/ΣRO | 0.79 | 0.76 | 0.79 |
| N | 11 | 10 | 10 |
| Young's modulus E (GPa) | 102 | 99 | 99 |
| Coefficient of thermal expansion α (ppm/° C.) | 4.86 | 4.86 | 4.70 |
| Liquidus temperature TL (° C.) | 1203 | 1203 | 1187 |
| Young's modulus parameter Y | 1.01 | 0.99 | 0.99 |
| Liquidus parameter L | 9.7 | 10.0 | 9.8 |
| Thermal expansion parameter C | 0.97 | 0.97 | 0.94 |
| Glass transition point (° C.) | 706 | 708 | 710 |
| Density (g/cm³) | 2.85 | 2.89 | 2.85 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.73 | 0.70 | 0.72 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 39

| (mol %) | Example 272 | Example 273 | Example 274 | Example 275 |
|---|---|---|---|---|
| SiO₂ | 51 | 51 | 51 | 51 |
| Al₂O₃ | 10 | 10 | 10 | 10 |
| B₂O₃ | 5 | 5 | 5 | 5 |
| MgO | 22 | 22 | 22 | 22 |
| CaO | 2 | 2 | 2 | 2 |
| SrO | 2 | 2 | 2 | 2 |
| BaO | 2 | 2 | 2 | 2 |
| Li₂O | | | 1 | 1 |
| Na₂O | 1 | 2 | | 1 |
| K₂O | 1 | | 1 | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₃ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.43 | 0.43 |
| (Al₂O₃ + MgO)/(SiO₂ + Al₂O₃ + B₂O₃ + MgO) | 0.36 | 0.38 | 0.38 | 0.36 |
| MgO/ΣRO | 0.79 | 0.79 | 0.79 | 0.79 |
| N | 12 | 11 | 12 | 12 |
| Young's modulus E (GPa) | 96 | 97 | 98 | 100 |
| Coefficient of thermal expansion α (ppm/° C.) | 5.27 | 5.01 | 5.30 | 5.04 |
| Liquidus temperature TL (° C.) | 1188 | 1195 | 1190 | 1195 |
| Young's modulus parameter Y | 0.96 | 0.99 | 0.97 | 1.00 |
| Liquidus parameter L | 9.8 | 9.4 | 9.7 | 9.4 |
| Thermal expansion parameter C | 1.07 | 1.15 | 1.00 | 1.08 |
| Glass transition point (° C.) | 702 | 713 | 696 | 707 |
| Density (g/cm³) | 2.62 | 2.82 | 2.83 | 2.83 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.76 | 0.76 | 0.80 | 0.80 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 276 | Example 277 | Example 278 |
|---|---|---|---|
| SiO₂ | 51 | 51 | 51 |
| Al₂O₃ | 10 | 10 | 10 |
| B₂O₃ | 5 | 5 | 5 |
| MgO | 22 | 22 | 22 |
| CaO | 2 | 2 | 2 |
| SrO | 2 | 2 | 2 |
| BaO | 2 | 3 | 3 |
| Li₂O | 2 | | |
| Na₂O | | | 1 |
| K₂O | | 1 | |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₃ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.43 | 0.43 | 0.43 |
| (Al₂O₃ + MgO)/(SiO₂ + Al₂O₃ + B₂O₃ + MgO) | 0.36 | 0.38 | 0.36 |
| MgO/ΣRO | 0.79 | 0.76 | 0.76 |
| N | 11 | 11 | 11 |
| Young's modulus E (GPa) | 103 | 96 | 97 |
| Coefficient of thermal expansion α (ppm/° C.) | 5.07 | 5.29 | 5.03 |
| Liquidus temperature TL (° C.) | 1196 | 1189 | 1194 |
| Young's modulus parameter Y | 1.01 | 0.95 | 0.98 |
| Liquidus parameter L | 9.3 | 10.0 | 9.7 |
| Thermal expansion parameter C | 1.01 | 0.99 | 1.07 |
| Glass transition point (° C.) | 707 | 698 | 708 |
| Density (g/cm³) | 2.84 | 2.87 | 2.87 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.84 | 0.76 | 0.76 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 40

| (mol %) | Example 279 | Example 280 | Example 281 | Example 282 |
|---|---|---|---|---|
| SiO₂ | 51 | 51 | 51 | 51 |
| Al₂O₃ | 10 | 10 | 10 | 10 |
| B₂O₃ | 5 | 6 | 6 | 6 |
| MgO | 22 | 22 | 22 | 22 |
| CaO | 2 | 2 | 2 | 2 |
| SrO | 2 | 2 | 2 | 2 |
| BaO | 3 | 2 | 2 | 2 |
| Li₂O | 1 | | | 1 |
| Na₂O | | | 1 | |
| K₂O | | 1 | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.43 | 0.43 |
| (Al₂O₃ + MgO)/(SiO₂ + Al₂O₃ + B₂O₃ + MgO) | 0.36 | 0.36 | 0.36 | 0.36 |
| MgO/ΣRO | 0.76 | 0.79 | 0.79 | 0.79 |
| N | 11 | 11 | 11 | 11 |
| Young's modulus E (GPa) | 100 | 96 | 97 | 100 |
| Coefficient of thermal expansion α (ppm/° C.) | 5.06 | 5.14 | 4.88 | 4.91 |
| Liquidus temperature TL (° C.) | 1196 | 1187 | 1187 | 1187 |
| Young's modulus parameter Y | 0.99 | 0.95 | 0.98 | 0.99 |
| Liquidus parameter L | 9.6 | 9.8 | 9.5 | 9.4 |
| Thermal expansion parameter C | 1.00 | 0.97 | 1.05 | 0.98 |
| Glass transition point (° C.) | 703 | 699 | 709 | 704 |
| Density (g/cm³) | 2.88 | 2.82 | 2.82 | 2.83 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.80 | 0.79 | 0.79 | 0.82 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 283 | Example 284 | Example 285 |
|---|---|---|---|
| SiO₂ | 51 | 51 | 51 |
| Al₂O₃ | 10 | 10 | 11 |
| B₂O₃ | 6 | 7 | 5 |
| MgO | 22 | 22 | 22 |
| CaO | 2 | 2 | 2 |
| SrO | 2 | 2 | 2 |
| BaO | 3 | 2 | 2 |
| Li₂O | | | |
| Na₂O | | | |
| K₂O | | | 1 |
| ZnO | | | |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 13 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.43 | 0.43 | 0.43 |
| (Al₂O₃ + MgO)/(SiO₂ + Al₂O₃ + B₂O₃ + MgO) | 0.36 | 0.38 | 0.37 |
| MgO/ΣRO | 0.76 | 0.79 | 0.79 |
| N | 10 | 10 | 11 |
| Young's modulus E (GPa) | 97 | 97 | 97 |
| Coefficient of thermal expansion α (ppm/° C.) | 4.90 | 4.75 | 5.11 |
| Liquidus temperature TL (° C.) | 1187 | 1182 | 1189 |
| Young's modulus parameter Y | 0.97 | 0.97 | 0.96 |
| Liquidus parameter L | 9.7 | 9.5 | 10.0 |
| Thermal expansion parameter C | 0.97 | 0.95 | 0.96 |
| Glass transition point (° C.) | 704 | 705 | 703 |
| Density (g/cm³) | 2.87 | 2.83 | 2.83 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.79 | 0.81 | 0.78 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 41

| (mol %) | Example 286 | Example 287 | Example 288 | Example 289 |
|---|---|---|---|---|
| SiO₂ | 51 | 51 | 51 | 51 |
| Al₂O₃ | 11 | 11 | 11 | 11 |
| B₂O₃ | 5 | 5 | 5 | 6 |
| MgO | 22 | 22 | 22 | 22 |
| CaO | 2 | 2 | 2 | 2 |
| SrO | 2 | 2 | 2 | 2 |
| BaO | 2 | 2 | 3 | 2 |
| Li₂O | | 1 | | |
| Na₂O | 1 | | | |
| K₂O | | | | |
| ZnO | | | | |
| P₂O₅ | | | | |
| ZrO₂ | 1 | 1 | 1 | 1 |
| TiO₂ | 1 | 1 | 1 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 13 | 13 | 13 | 13 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.43 | 0.43 | 0.44 | 0.43 |
| (Al₂O₃ + MgO)/(SiO₂ + Al₂O₃ + B₂O₃ + MgO) | 0.37 | 0.37 | 0.37 | 0.37 |
| MgO/ΣRO | 0.79 | 0.79 | 0.76 | 0.79 |
| N | 11 | 11 | 10 | 10 |
| Young's modulus E (GPa) | 99 | 101 | 99 | 98 |
| Coefficient of thermal expansion α (ppm/° C.) | 4.85 | 4.88 | 4.87 | 4.72 |
| Liquidus temperature TL (° C.) | 1194 | 1195 | 1195 | 1185 |
| Young's modulus parameter Y | 0.99 | 1.00 | 0.98 | 0.98 |
| Liquidus parameter L | 9.7 | 9.6 | 10.0 | 9.7 |
| Thermal expansion parameter C | 1.04 | 0.97 | 0.97 | 0.94 |
| Glass transition point (° C.) | 713 | 707 | 708 | 710 |
| Density (g/cm³) | 2.83 | 2.84 | 2.88 | 2.84 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.78 | 0.82 | 0.78 | 0.81 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 290 | Example 291 | Example 292 |
|---|---|---|---|
| SiO₂ | 51 | 50 | 50 |
| Al₂O₃ | 12 | 10 | 10 |
| B₂O₃ | 5 | 6 | 6 |
| MgO | 22 | 21 | 21 |
| CaO | 2 | 2 | 2 |
| SrO | 2 | 2 | 2 |
| BaO | 2 | 3 | 3.5 |
| Li₂O | | | |
| Na₂O | | | |
| K₂O | | | |
| ZnO | | | |
| P₂O₅ | | | |
| ZrO₂ | 1 | 2 | 1.5 |
| TiO₂ | 1 | 2 | 2 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 14 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.43 | 0.44 |
| (Al₂O₃ + MgO)/(SiO₂ + Al₂O₃ + B₂O₃ + MgO) | 0.38 | 0.36 | 0.36 |
| MgO/ΣRO | 0.79 | 0.75 | 0.74 |
| N | 10 | 10 | 10 |
| Young's modulus E (GPa) | 100 | 99 | 98 |
| Coefficient of thermal expansion α (ppm/° C.) | 4.69 | 4.96 | 5.00 |
| Liquidus temperature TL (° C.) | 1201 | 1195 | 1190 |
| Young's modulus parameter Y | 1.00 | 0.98 | 0.97 |
| Liquidus parameter L | 10.0 | 10.0 | 10.0 |
| Thermal expansion parameter C | 0.94 | 0.99 | 0.99 |
| Glass transition point (° C.) | 713 | 705 | 705 |
| Density (g/cm³) | 2.85 | 2.89 | 2.90 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.80 | 0.94 | 0.85 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 42

| (mol %) | Example 293 | Example 294 | Example 295 | Example 296 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 21 | 21 | 21 | 21 |
| CaO | 2 | 2 | 2 | 2 |
| SrO | 2 | 2 | 2 | 2 |
| BaO | 3.5 | 4 | 4 | 4 |
| Li₂O | | | | |
| Na₂O | | | | |
| K₂O | | | | |
| ZnO | | | | |
| P₂O₅ | | | | |
| ZrO₂ | 2 | 1 | 1.5 | 2 |
| TiO₂ | 1.5 | 2 | 1.5 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.74 | 0.72 | 0.72 | 0.72 |
| N | 10 | 10 | 10 | 10 |
| Young's modulus E (GPa) | 99 | 97 | 98 | 98 |
| Coefficient of thermal expansion α (ppm/° C.) | 5.02 | 5.04 | 5.07 | 5.09 |
| Liquidus temperature TL (° C.) | 1194 | 1190 | 1189 | 1193 |
| Young's modulus parameter Y | 0.98 | 0.96 | 0.96 | 0.97 |
| Liquidus parameter L | 10.0 | 10.0 | 10.0 | 9.9 |
| Thermal expansion parameter C | 1.00 | 1.00 | 1.00 | 1.00 |
| Glass transition point (° C.) | 705 | 706 | 706 | 705 |
| Density (g/cm³) | 2.91 | 2.91 | 2.92 | 2.93 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.88 | 0.76 | 0.79 | 0.83 |
| Transmittance (%) @1064 nm, 0.7 mmt | 80≤ | 80< | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 297 | Example 298 | Example 299 |
|---|---|---|---|
| SiO₂ | 50 | 50 | 50 |
| Al₂O₃ | 10 | 10 | 10 |
| B₂O₃ | 6 | 6 | 6 |
| MgO | 21.5 | 21.5 | 21.5 |
| CaO | 2 | 2 | 2 |
| SrO | 2 | 2 | 2 |
| BaO | 3 | 3 | 3.5 |
| Li₂O | | | |
| Na₂O | | | |
| K₂O | | | |
| ZnO | | | |
| P₂O₅ | | | |
| ZrO₂ | 1.5 | 2 | 1 |
| TiO₂ | 2 | 1.5 | 2 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.75 | 0.75 | 0.74 |
| N | 10 | 10 | 10 |
| Young's modulus E (GPa) | 99 | 99 | 98 |
| Coefficient of thermal expansion α (ppm/° C.) | 4.95 | 4.97 | 4.99 |
| Liquidus temperature TL (° C.) | 1193 | 1196 | 1192 |
| Young's modulus parameter Y | 0.98 | 0.98 | 0.96 |
| Liquidus parameter L | 9.9 | 9.9 | 10.0 |
| Thermal expansion parameter C | 0.98 | 0.99 | 0.99 |
| Glass transition point (° C.) | 705 | 705 | 705 |
| Density (g/cm³) | 2.88 | 2.89 | 2.89 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.87 | 0.90 | 0.78 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 43

| (mol %) | Example 300 | Example 301 | Example 302 | Example 303 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 21.5 | 21.5 | 21.5 | 21.5 |
| CaO | 2 | 2 | 2 | 2 |
| SrO | 2 | 2 | 2 | 2 |
| BaO | 3.5 | 3.5 | 4 | 4 |
| Li₂O | | | | |
| Na₂O | | | | |
| K₂O | | | | |
| ZnO | | | | |
| P₂O₅ | | | | |
| ZrO₂ | 1.5 | 2 | 0.5 | 1 |
| TiO₂ | 1.5 | 1 | 2 | 1.5 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.74 | 0.74 | 0.73 | 0.73 |
| N | 10 | 10 | 10 | 10 |
| Young's modulus E (GPa) | 98 | 99 | 97 | 97 |
| Coefficient of thermal expansion α (ppm/° C.) | 5.01 | 5.04 | 5.03 | 5.06 |
| Liquidus temperature TL (° C.) | 1191 | 1195 | 1193 | 1192 |
| Young's modulus parameter Y | 0.97 | 0.98 | 0.95 | 0.98 |
| Liquidus parameter L | 9.9 | 9.8 | 10.0 | 9.9 |
| Thermal expansion parameter C | 0.99 | 1.00 | 0.99 | 1.00 |
| Glass transition point (° C.) | 705 | 704 | 705 | 706 |
| Density (g/cm³) | 2.90 | 2.91 | 2.90 | 2.91 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.81 | 0.85 | 0.69 | 0.72 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 304 | Example 305 | Example 306 |
|---|---|---|---|
| SiO₂ | 50 | 50 | 50 |
| Al₂O₃ | 10 | 10 | 10 |
| B₂O₃ | 6 | 6 | 6 |
| MgO | 21.5 | 21.5 | 22 |
| CaO | 2 | 2 | 2 |
| SrO | 2 | 2 | 2 |
| BaO | 4 | 4 | 3 |
| Li₂O | | | |
| Na₂O | | | |
| K₂O | | | |
| ZnO | | | |
| P₂O₅ | | | |
| ZrO₂ | 1.5 | 2 | 1 |
| TiO₂ | 1 | 0.5 | 2 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.73 | 0.73 | 0.76 |
| N | 10 | 10 | 10 |
| Young's modulus E (GPa) | 98 | 98 | 98 |
| Coefficient of thermal expansion α (ppm/° C.) | 5.08 | 5.11 | 4.94 |
| Liquidus temperature TL (° C.) | 1189 | 1197 | 1192 |
| Young's modulus parameter Y | 0.97 | 0.97 | 0.97 |
| Liquidus parameter L | 9.9 | 9.8 | 9.9 |
| Thermal expansion parameter C | 1.00 | 1.01 | 0.98 |
| Glass transition point (° C.) | 705 | 710 | 705 |
| Density (g/cm³) | 2.92 | 2.93 | 2.88 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.76 | 0.79 | 0.80 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 44

| (mol %) | Example 307 | Example 308 | Example 309 | Example 310 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22 | 22 | 22 | 22 |
| CaO | 2 | 2 | 2 | 2 |
| SrO | 2 | 2 | 2 | 2 |
| BaO | 3 | 3 | 3.5 | 3.5 |
| Li₂O | | | | |
| Na₂O | | | | |
| K₂O | | | | |
| ZnO | | | | |
| P₂O₅ | | | | |
| ZrO₂ | 1.5 | 2 | 0.5 | 1 |
| TiO₂ | 1.5 | 1 | 2 | 1.5 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.36 | 0.36 | 0.36 |
| MgO/ΣRO | 0.76 | 0.76 | 0.75 | 0.75 |
| N | 10 | 10 | 10 | 10 |
| Young's modulus E (GPa) | 99 | 99 | 97 | 98 |
| Coefficient of thermal expansion α (ppm/° C.) | 4.96 | 4.99 | 4.98 | 5.01 |
| Liquidus temperature TL (° C.) | 1191 | 1195 | 1193 | 1191 |
| Young's modulus parameter Y | 0.98 | 0.99 | 0.96 | 0.97 |
| Liquidus parameter L | 9.8 | 9.8 | 9.9 | 9.8 |
| Thermal expansion parameter C | 0.99 | 0.99 | 0.99 | 0.99 |
| Glass transition point (° C.) | 705 | 704 | 705 | 705 |
| Density (g/cm³) | 2.88 | 2.89 | 2.89 | 2.89 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.84 | 0.87 | 0.71 | 0.74 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 311 | Example 312 | Example 313 |
|---|---|---|---|
| SiO₂ | 50 | 50 | 50 |
| Al₂O₃ | 10 | 10 | 10 |
| B₂O₃ | 6 | 6 | 6 |
| MgO | 22 | 22 | 22 |
| CaO | 2 | 2 | 2 |
| SrO | 2 | 2 | 2 |
| BaO | 3.5 | 3.5 | 4 |
| Li₂O | | | |
| Na₂O | | | |
| K₂O | | | |
| ZnO | | | |
| P₂O₅ | | | |
| ZrO₂ | 1.5 | 2 | 0.5 |
| TiO₂ | 1 | 0.5 | 1.5 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.36 | 0.36 | 0.36 |
| MgO/ΣRO | 0.75 | 0.75 | 0.73 |
| N | 10 | 10 | 10 |
| Young's modulus E (GPa) | 98 | 99 | 97 |
| Coefficient of thermal expansion α (ppm/° C.) | 5.03 | 5.06 | 5.05 |
| Liquidus temperature TL (° C.) | 1189 | 1196 | 1192 |
| Young's modulus parameter Y | 0.97 | 0.98 | 0.95 |
| Liquidus parameter L | 9.8 | 9.7 | 9.9 |
| Thermal expansion parameter C | 1.00 | 1.00 | 1.00 |
| Glass transition point (° C.) | 704 | 710 | 705 |
| Density (g/cm³) | 2.90 | 2.91 | 2.90 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.78 | 0.81 | 0.65 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 45

| (mol %) | Example 314 | Example 315 | Example 316 | Example 317 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22 | 22.5 | 22.5 | 22.5 |
| CaO | 2 | 2 | 2 | 2 |
| SrO | 2 | 2 | 2 | 2 |
| BaO | 4 | 3 | 3 | 3 |
| Li₂O | | | | |
| Na₂O | | | | |
| K₂O | | | | |
| ZnO | | | | |
| P₂O₅ | | | | |
| ZrO₂ | 1.5 | 0.5 | 1 | 1.5 |
| TiO₂ | 0.5 | 2 | 1.5 | 1 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.44 | 0.44 | 0.44 |
| (Al₂O₃ + MgO)/(SiO₂ + Al₂O₃ + B₂O₃ + MgO) | 0.36 | 0.37 | 0.37 | 0.37 |
| MgO/ΣRO | 0.73 | 0.76 | 0.76 | 0.76 |
| N | 10 | 10 | 10 | 10 |
| Young's modulus E (GPa) | 98 | 98 | 98 | 99 |
| Coefficient of thermal expansion α (ppm/° C.) | 5.10 | 4.93 | 4.95 | 4.98 |
| Liquidus temperature TL (° C.) | 1190 | 1193 | 1192 | 1190 |
| Young's modulus parameter Y | 0.97 | 0.96 | 0.97 | 0.98 |
| Liquidus parameter L | 9.7 | 9.8 | 9.8 | 9.7 |
| Thermal expansion parameter C | 1.00 | 0.98 | 0.98 | 0.99 |
| Glass transition point (° C.) | 710 | 705 | 705 | 704 |
| Density (g/cm³) | 2.92 | 2.87 | 2.88 | 2.89 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.72 | 0.73 | 0.77 | 0.80 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 318 | Example 319 | Example 320 |
|---|---|---|---|
| SiO₂ | 50 | 50 | 50 |
| Al₂O₃ | 10 | 10 | 10 |
| B₂O₃ | 6 | 6 | 6 |
| MgO | 22.5 | 22.5 | 22.5 |
| CaO | 2 | 2 | 2 |
| SrO | 2 | 2 | 2 |
| BaO | 3 | 3.5 | 3.5 |
| Li₂O | | | |
| Na₂O | | | |
| K₂O | | | |
| ZnO | | | |
| P₂O₅ | | | |
| ZrO₂ | 2 | 0.5 | 1 |
| TiO₂ | 0.5 | 1.5 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.44 |
| (Al₂O₃ + MgO)/(SiO₂ + Al₂O₃ + B₂O₃ + MgO) | 0.37 | 0.37 | 0.37 |
| MgO/ΣRO | 0.76 | 0.75 | 0.75 |
| N | 10 | 10 | 10 |
| Young's modulus E (GPa) | 99 | 97 | 98 |
| Coefficient of thermal expansion α (ppm/° C.) | 5.01 | 5.00 | 5.02 |
| Liquidus temperature TL (° C.) | 1197 | 1193 | 1190 |
| Young's modulus parameter Y | 0.99 | 0.96 | 0.97 |
| Liquidus parameter L | 9.6 | 9.8 | 9.7 |
| Thermal expansion parameter C | 0.99 | 0.99 | 0.99 |
| Glass transition point (° C.) | 709 | 705 | 704 |
| Density (g/cm³) | 2.89 | 2.89 | 2.90 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30< | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.84 | 0.67 | 0.71 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 46

| (mol %) | Example 321 | Example 322 | Example 323 | Example 324 |
|---|---|---|---|---|
| SiO₂ | 50 | 50 | 50 | 50 |
| Al₂O₃ | 10 | 10 | 10 | 10 |
| B₂O₃ | 6 | 6 | 6 | 6 |
| MgO | 22.5 | 22.5 | 22.5 | 23 |
| CaO | 2 | 2 | 2 | 2 |
| SrO | 2 | 2 | 2 | 2 |
| BaO | 3.5 | 4 | 4 | 3 |
| Li₂O | | | | |
| Na₂O | | | | |
| K₂O | | | | |
| ZnO | | | | |
| P₂O₅ | | | | |
| ZrO₂ | 1.5 | 0.5 | 1 | 0.5 |
| TiO₂ | 0.5 | 1 | 0.5 | 1.5 |
| Y₂O₃ | 2 | 2 | 2 | 2 |
| Gd₂O₃ | | | | |
| La₂O₃ | | | | |
| WO₃ | | | | |
| Ta₂O₅ | | | | |
| Al₂O₂ + rare earth oxide | 12 | 12 | 12 | 12 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.44 | 0.45 | 0.45 | 0.44 |
| (Al₂O₃ + MgO)/(SiO₂ + Al₂O₃ + B₂O₃ + MgO) | 0.37 | 0.37 | 0.37 | 0.37 |
| MgO/ΣRO | 0.75 | 0.74 | 0.74 | 0.77 |
| N | 10 | 10 | 10 | 10 |
| Young's modulus E (GPa) | 98 | 97 | 97 | 98 |
| Coefficient of thermal expansion α (ppm/° C.) | 5.05 | 5.06 | 5.09 | 4.95 |
| Liquidus temperature TL (° C.) | 1191 | 1191 | 1191 | 1194 |
| Young's modulus parameter Y | 0.97 | 0.95 | 0.96 | 0.97 |
| Liquidus parameter L | 9.7 | 9.7 | 9.7 | 9.7 |
| Thermal expansion parameter C | 1.00 | 1.00 | 1.00 | 0.98 |
| Glass transition point (° C.) | 709 | 705 | 710 | 705 |
| Density (g/cm³) | 2.90 | 2.90 | 2.91 | 2.87 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.74 | 0.62 | 0.65 | 0.70 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 325 | Example 326 | Example 327 |
|---|---|---|---|
| SiO₂ | 50 | 50 | 50 |
| Al₂O₃ | 10 | 10 | 10 |
| B₂O₃ | 6 | 6 | 6 |
| MgO | 23 | 23 | 23 |
| CaO | 2 | 2 | 2 |
| SrO | 2 | 2 | 2 |
| BaO | 3 | 3 | 3.5 |
| Li₂O | | | |
| Na₂O | | | |
| K₂O | | | |
| ZnO | | | |
| P₂O₅ | | | |
| ZrO₂ | 1 | 1.5 | 0.5 |
| TiO₂ | 1 | 0.5 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 12 | 12 | 12 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.44 | 0.44 | 0.45 |
| (Al₂O₃ + MgO)/(SiO₂ + Al₂O₃ + B₂O₃ + MgO) | 0.37 | 0.37 | 0.37 |
| MgO/ΣRO | 0.77 | 0.77 | 0.75 |
| N | 10 | 10 | 10 |
| Young's modulus E (GPa) | 98 | 99 | 97 |
| Coefficient of thermal expansion α (ppm/° C.) | 4.97 | 5.00 | 5.01 |
| Liquidus temperature TL (° C.) | 1191 | 1193 | 1192 |
| Young's modulus parameter Y | 0.97 | 0.98 | 0.96 |
| Liquidus parameter L | 9.6 | 9.6 | 9.7 |
| Thermal expansion parameter C | 0.99 | 0.99 | 0.99 |
| Glass transition point (° C.) | 704 | 709 | 704 |
| Density (g/cm³) | 2.88 | 2.89 | 2.89 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.73 | 0.77 | 0.64 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 47

| (mol %) | Example 328 | Example 329 | Example 330 | Example 331 |
|---|---|---|---|---|
| SiO₂ | 50 | 50 | 48 | 48 |
| Al₂O₃ | 10 | 10 | 9 | 9 |
| B₂O₃ | 6 | 6 | 3 | 4 |
| MgO | 23 | 23 | 19 | 19 |
| CaO | 2 | 2 | 4 | 4 |
| SrO | 2 | 2 | 3 | 3 |
| BaO | 3.5 | 4 | 4 | 3 |
| Li₂O | | | | |
| Na₂O | | | | |
| K₂O | | | | |
| ZnO | | | 6 | 6 |
| P₂O₅ | | | | |
| ZrO₂ | 1 | 0.5 | 1 | 1 |
| TiO₂ | 0.5 | 0.5 | 1 | 1 |
| Y₂O₃ | 2 | 2 | 2 | |
| Gd₂O₃ | | | | |
| La₂O₃ | | | | 2 |
| WO₃ | | | | |
| Ta₂O₅ | | | | |
| Al₂O₂ + rare earth oxide | 12 | 12 | 11 | 11 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.45 | 0.45 | 0.48 | 0.48 |
| (Al₂O₃ + MgO)/(SiO₂ + Al₂O₃ + B₂O₃ + MgO) | 0.37 | 0.37 | 0.35 | 0.35 |
| MgO/ΣRO | 0.75 | 0.74 | 0.53 | 0.54 |
| N | 10 | 10 | 11 | 11 |
| Young's modulus E (GPa) | 98 | 97 | 99 | 99 |
| Coefficient of thermal expansion α (ppm/° C.) | 5.04 | 5.08 | 5.50 | 5.50 |
| Liquidus temperature TL (° C.) | 1192 | 1191 | 1217 | 1219 |
| Young's modulus parameter Y | 0.97 | 0.95 | 0.99 | 0.99 |
| Liquidus parameter L | 9.6 | 9.6 | 9.7 | 9.3 |
| Thermal expansion parameter C | 1.00 | 1.00 | 1.10 | 1.10 |
| Glass transition point (° C.) | 709 | 710 | 719 | 714 |
| Density (g/cm³) | 2.90 | 2.91 | 3.14 | 3.17 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.67 | 0.58 | 0.28 | 0.28 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 332 | Example 333 | Example 334 |
|---|---|---|---|
| SiO₂ | 49 | 48 | 49 |
| Al₂O₃ | 9 | 8 | 9 |
| B₂O₃ | 3 | 4 | 4 |
| MgO | 18 | 20 | 18 |
| CaO | 5 | 5 | 4 |
| SrO | 4 | 3 | 3 |
| BaO | 3 | 3 | 3 |
| Li₂O | | | |
| Na₂O | | | |
| K₂O | | | |
| ZnO | 5 | 5 | 6 |
| P₂O₅ | | | |
| ZrO₂ | 1 | 1 | 1 |
| TiO₂ | 1 | 1 | 1 |
| Y₂O₃ | 2 | 2 | |
| Gd₂O₃ | | | 2 |
| La₂O₃ | | | |
| WO₃ | | | |
| Ta₂O₅ | | | |
| Al₂O₂ + rare earth oxide | 11 | 10 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.47 | 0.48 | 0.47 |
| (Al₂O₃ + MgO)/(SiO₂ + Al₂O₃ + B₂O₃ + MgO) | 0.34 | 0.35 | 0.34 |
| MgO/ΣRO | 0.51 | 0.56 | 0.53 |
| N | 11 | 11 | 11 |
| Young's modulus E (GPa) | 99 | 99 | 98 |
| Coefficient of thermal expansion α (ppm/° C.) | 5.51 | 5.51 | 5.51 |
| Liquidus temperature TL (° C.) | 1216 | 1216 | 1216 |
| Young's modulus parameter Y | 0.98 | 0.99 | 0.98 |
| Liquidus parameter L | 9.6 | 9.4 | 9.4 |
| Thermal expansion parameter C | 1.11 | 1.11 | 1.08 |
| Glass transition point (° C.) | 715 | 712 | 711 |
| Density (g/cm³) | 3.09 | 3.07 | 3.18 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.34 | 0.33 | 0.22 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 48

| (mol %) | Example 335 | Example 336 | Example 337 | Example 338 |
|---|---|---|---|---|
| SiO₂ | 49 | 49 | 49 | 49 |
| Al₂O₃ | 9 | 9 | 8 | 8 |
| B₂O₃ | 3 | 4 | 3 | 4 |
| MgO | 18 | 18 | 19 | 20 |
| CaO | 5 | 5 | 4 | 4 |
| SrO | 3 | 3 | 4 | 3 |
| BaO | 4 | 3 | 3 | 4 |
| Li₂O | | | | |
| Na₂O | | | | |
| K₂O | | | | |
| ZnO | 5 | 5 | 6 | 4 |
| P₂O₅ | | | | |
| ZrO₂ | 1 | 1 | 1 | 1 |
| TiO₂ | 1 | 1 | 1 | 1 |
| Y₂O₃ | 2 | | 2 | 2 |
| Gd₂O₃ | | | | |
| La₂O₃ | | 2 | | |
| WO₃ | | | | |
| Ta₂O₅ | | | | |
| Al₂O₂ + rare earth oxide | 11 | 11 | 10 | 10 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.47 | 0.47 | 0.47 | 0.47 |
| (Al₂O₃ + MgO)/(SiO₂ + Al₂O₃ + B₂O₃ + MgO) | 0.34 | 0.34 | 0.34 | 0.35 |
| MgO/ΣRO | 0.51 | 0.53 | 0.53 | 0.57 |
| N | 11 | 11 | 11 | 11 |
| Young's modulus E (GPa) | 98 | 98 | 99 | 98 |
| Coefficient of thermal expansion α (ppm/° C.) | 5.51 | 5.51 | 5.51 | 5.51 |
| Liquidus temperature TL (° C.) | 1214 | 1218 | 1218 | 1215 |
| Young's modulus parameter Y | 0.98 | 0.98 | 1.00 | 0.97 |
| Liquidus parameter L | 9.8 | 9.4 | 9.4 | 9.6 |
| Thermal expansion parameter C | 1.11 | 1.10 | 1.11 | 1.10 |
| Glass transition point (° C.) | 719 | 714 | 714 | 713 |
| Density (g/cm³) | 3.11 | 3.14 | 3.11 | 3.07 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.34 | 0.34 | 0.36 | 0.43 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 339 | Example 340 | Example 343 |
|---|---|---|---|
| SiO₂ | 47 | 49 | 47 |
| Al₂O₃ | 9 | 8 | 9 |
| B₂O₃ | 4 | 3 | 4 |
| MgO | 19 | 19 | 19 |
| CaO | 4 | 4 | 4 |
| SrO | 4 | 3 | 3 |
| BaO | 3 | 4 | 4 |
| Li₂O | | | |
| Na₂O | | | |
| K₂O | | | |
| ZnO | 6 | 6 | 6 |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 11 | 10 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.49 | 0.47 | 0.49 |
| (Al₂O₃ + MgO)/(SiO₂ + Al₂O₃ + B₂O₃ + MgO) | 0.35 | 0.34 | 0.35 |
| MgO/ΣRO | 0.53 | 0.53 | 0.53 |
| N | 11 | 11 | 11 |
| Young's modulus E (GPa) | 100 | 98 | 99 |
| Coefficient of thermal expansion α (ppm/° C.) | 5.51 | 5.52 | 5.52 |
| Liquidus temperature TL (° C.) | 1219 | 1214 | 1216 |
| Young's modulus parameter Y | 1.00 | 0.98 | 0.99 |
| Liquidus parameter L | 9.3 | 9.6 | 9.6 |
| Thermal expansion parameter C | 1.12 | 1.11 | 1.11 |
| Glass transition point (° C.) | 712 | 717 | 715 |
| Density (g/cm³) | 3.12 | 3.13 | 3.14 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.20 | 0.36 | 0.20 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 49

| (mol %) | Example 342 | Example 343 | Example 344 | Example 345 |
|---|---|---|---|---|
| SiO₂ | 49 | 48 | 48 | 49 |
| Al₂O₃ | 8 | 9 | 9 | 9 |
| B₂O₃ | 4 | 4 | 4 | 4 |
| MgO | 19 | 18 | 18 | 18 |
| CaO | 4 | 5 | 5 | 4 |
| SrO | 3 | 4 | 3 | 4 |
| BaO | 3 | 3 | 4 | 4 |
| Li₂O | | | | |
| Na₂O | | | | |
| K₂O | | | | |
| ZnO | 6 | 5 | 5 | 4 |
| P₂O₅ | | | | |
| ZrO₂ | 1 | 1 | 1 | 1 |
| TiO₂ | 1 | 1 | 1 | 1 |
| Y₂O₃ | | 2 | 2 | 2 |
| Gd₂O₃ | | | | |
| La₂O₃ | 2 | | | |
| WO₃ | | | | |
| Ta₂O₅ | | | | |
| Al₂O₂ + rare earth oxide | 10 | 11 | 11 | 11 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.47 | 0.48 | 0.48 | 0.47 |
| (Al₂O₃ + MgO)/(SiO₂ + Al₂O₃ + B₂O₃ + MgO) | 0.34 | 0.34 | 0.34 | 0.34 |
| MgO/ΣRO | 0.54 | 0.51 | 0.51 | 0.53 |
| N | 11 | 11 | 11 | 11 |
| Young's modulus E (GPa) | 98 | 99 | 98 | 97 |
| Coefficient of thermal expansion α (ppm/° C.) | 5.52 | 5.52 | 5.53 | 5.53 |
| Liquidus temperature TL (° C.) | 1216 | 1216 | 1215 | 1218 |
| Young's modulus parameter Y | 0.98 | 0.99 | 0.98 | 0.97 |
| Liquidus parameter L | 9.2 | 9.5 | 9.7 | 9.7 |
| Thermal expansion parameter C | 1.10 | 1.12 | 1.11 | 1.11 |
| Glass transition point (° C.) | 712 | 711 | 715 | 712 |
| Density (g/cm³) | 3.17 | 3.09 | 3.11 | 3.08 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.36 | 0.26 | 0.26 | 0.35 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 346 | Example 347 | Example 348 |
|---|---|---|---|
| SiO₂ | 48 | 49 | 49 |
| Al₂O₃ | 8 | 9 | 9 |
| B₂O₃ | 4 | 4 | 3 |
| MgO | 19 | 19 | 19 |
| CaO | 4 | 4 | 5 |
| SrO | 4 | 3 | 3 |
| BaO | 3 | 3 | 4 |
| Li₂O | | | |
| Na₂O | | | |
| K₂O | | | |
| ZnO | 6 | 5 | 4 |
| P₂O₅ | | | |
| ZrO₂ | 1 | 1 | 1 |
| TiO₂ | 1 | 1 | 1 |
| Y₂O₃ | 2 | | 2 |
| Gd₂O₃ | | 2 | |
| La₂O₃ | | | |
| WO₃ | | | |
| Ta₂O₅ | | | |
| Al₂O₂ + rare earth oxide | 10 | 11 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.48 | 0.47 | 0.47 |
| (Al₂O₃ + MgO)/(SiO₂ + Al₂O₃ + B₂O₃ + MgO) | 0.34 | 0.35 | 0.35 |
| MgO/ΣRO | 0.53 | 0.56 | 0.54 |
| N | 11 | 11 | 11 |
| Young's modulus E (GPa) | 99 | 99 | 99 |
| Coefficient of thermal expansion α (ppm/° C.) | 5.53 | 5.53 | 5.53 |
| Liquidus temperature TL (° C.) | 1217 | 1218 | 1216 |
| Young's modulus parameter Y | 0.99 | 0.98 | 0.98 |
| Liquidus parameter L | 9.3 | 9.4 | 9.8 |
| Thermal expansion parameter C | 1.12 | 1.08 | 1.11 |
| Glass transition point (° C.) | 710 | 711 | 719 |
| Density (g/cm³) | 3.11 | 3.16 | 3.08 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.28 | 0.26 | 0.38 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 50

| (mol %) | Example 349 | Example 350 | Example 351 | Example 352 |
|---|---|---|---|---|
| SiO₂ | 48 | 49 | 49 | 49 |
| Al₂O₃ | 8 | 8 | 9 | 8 |
| B₂O₃ | 4 | 4 | 3 | 3 |
| MgO | 19 | 18 | 18 | 20 |
| CaO | 4 | 5 | 5 | 4 |
| SrO | 3 | 4 | 3 | 3 |
| BaO | 4 | 3 | 3 | 4 |
| Li₂O | | | | |
| Na₂O | | | | |
| K₂O | | | | |
| ZnO | 6 | 5 | 6 | 5 |
| P₂O₅ | | | | |
| ZrO₂ | 1 | 1 | 1 | 1 |
| TiO₂ | 1 | 1 | 1 | 1 |
| Y₂O₃ | 2 | 2 | | 2 |
| Gd₂O₃ | | | | |
| La₂O₃ | | | 2 | |
| WO₃ | | | | |
| Ta₂O₅ | | | | |
| Al₂O₂ + rare earth oxide | 10 | 10 | 11 | 10 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.48 | 0.47 | 0.47 | 0.47 |
| (Al₂O₃ + MgO)/(SiO₂ + Al₂O₃ + B₂O₃ + MgO) | 0.34 | 0.33 | 0.34 | 0.35 |
| MgO/ΣRO | 0.53 | 0.51 | 0.51 | 0.56 |
| N | 11 | 11 | 11 | 11 |
| Young's modulus E (GPa) | 98 | 98 | 99 | 99 |
| Coefficient of thermal expansion α (ppm/° C.) | 5.53 | 5.54 | 5.54 | 5.54 |
| Liquidus temperature TL (° C.) | 1214 | 1211 | 1220 | 1217 |
| Young's modulus parameter Y | 0.98 | 0.98 | 0.99 | 0.99 |
| Liquidus parameter L | 9.5 | 9.4 | 9.5 | 9.6 |
| Thermal expansion parameter C | 1.11 | 1.12 | 1.10 | 1.11 |
| Glass transition point (° C.) | 713 | 709 | 718 | 717 |
| Density (g/cm³) | 3.13 | 3.08 | 3.18 | 3.10 |
| Liquidus viscosity log η_{L}(dPa · s) | 2< | 2< | 2< | 2< |
| K_{IC} (MPa · m^{0.5}) | 0.8< | 0.8< | 0.84 | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.29 | 0.34 | 0.31 | 0.40 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 353 | Example 354 | Example 355 |
|---|---|---|---|
| SiO₂ | 49 | 47 | 48 |
| Al₂O₃ | 8 | 9 | 9 |
| B₂O₃ | 4 | 4 | 4 |
| MgO | 18 | 20 | 19 |
| CaO | 5 | 4 | 5 |
| SrO | 3 | 3 | 4 |
| BaO | 4 | 4 | 3 |
| Li₂O | | | |
| Na₂O | | | |
| K₂O | | | |
| ZnO | 5 | 5 | 4 |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 10 | 11 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.47 | 0.49 | 0.48 |
| (Al₂O₃ + MgO)/(SiO₂ + Al₂O₃ + B₂O₃ + MgO) | 0.33 | 0.36 | 0.35 |
| MgO/ΣRO | 0.51 | 0.56 | 0.54 |
| N | 11 | 11 | 11 |
| Young's modulus E (GPa) | 97 | 99 | 99 |
| Coefficient of thermal expansion α (ppm/° C.) | 5.54 | 5.54 | 5.55 |
| Liquidus temperature TL (° C.) | 1210 | 1220 | 1219 |
| Young's modulus parameter Y | 0.97 | 0.99 | 0.99 |
| Liquidus parameter L | 9.6 | 9.6 | 9.5 |
| Thermal expansion parameter C | 1.19 | 1.11 | 1.12 |
| Glass transition point (° C.) | 713 | 715 | 711 |
| Density (g/cm³) | 3.10 | 3.11 | 3.06 |
| Liquidus viscosity log η_{L}(dPa · s) | 2< | 2< | 2< |
| K_{IC} (MPa · m^{0.5}) | 0.8< | 0.8% | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.34 | 0.24 | 0.30 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 51

| (mol %) | Example 356 | Example 357 | Example 358 | Example 359 |
|---|---|---|---|---|
| SiO₂ | 48 | 48 | 48 | 48 |
| Al₂O₃ | 9 | 9 | 9 | 9 |
| B₂O₃ | 3 | 4 | 3 | 4 |
| MgO | 18 | 19 | 18 | 18 |
| CaO | 5 | 5 | 5 | 5 |
| SrO | 4 | 3 | 3 | 3 |
| BaO | 3 | 4 | 4 | 3 |
| Li₂O | | | | |
| Na₂O | | | | |
| K₂O | | | | |
| ZnO | 6 | 4 | 6 | 6 |
| P₂O₅ | | | | |
| ZrO₂ | 1 | 1 | 1 | 1 |
| TiO₂ | 1 | 1 | 1 | 1 |
| Y₂O₃ | 2 | 2 | 2 | |
| Gd₂O₃ | | | | |
| La₂O₃ | | | | 2 |
| WO₃ | | | | |
| Ta₂O₅ | | | | |
| Al₂O₂ + rare earth oxide | 11 | 11 | 11 | 11 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.48 | 0.48 | 0.48 | 0.48 |
| (Al₂O₃ + MgO)/(SiO₂ + Al₂O₃ + B₂O₃ + MgO) | 0.35 | 0.35 | 0.35 | 0.34 |
| MgO/ΣRO | 0.50 | 0.54 | 0.50 | 0.51 |
| N | 11 | 11 | 11 | 11 |
| Young's modulus E (GPa) | 99 | 98 | 99 | 99 |
| Coefficient of thermal expansion α (ppm/° C.) | 5.55 | 5.55 | 5.55 | 5.58 |
| Liquidus temperature TL (° C.) | 1219 | 1215 | 1218 | 1219 |
| Young's modulus parameter Y | 1.00 | 0.98 | 0.99 | 0.99 |
| Liquidus parameter L | 9.5 | 9.7 | 9.8 | 9.3 |
| Thermal expansion parameter C | 1.12 | 1.11 | 1.12 | 1.11 |
| Glass transition point (° C.) | 716 | 715 | 719 | 714 |
| Density (g/cm³) | 3.13 | 3.08 | 3.14 | 3.18 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.24 | 0.30 | 0.24 | 0.24 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 360 | Example 361 | Example 362 |
|---|---|---|---|
| SiO₂ | 49 | 48 | 49 |
| Al₂O₃ | 9 | 8 | 9 |
| B₂O₃ | 3 | 4 | 4 |
| MgO | 18 | 20 | 18 |
| CaO | 4 | 4 | 4 |
| SrO | 4 | 3 | 4 |
| BaO | 4 | 4 | 3 |
| Li₂O | | | |
| Na₂O | | | |
| K₂O | | | |
| ZnO | 5 | 5 | 5 |
| P₂O₅ | | | |
| ZrO₂ | 1 | 1 | 1 |
| TiO₂ | 1 | 1 | 1 |
| Y₂O₃ | 2 | 2 | |
| Gd₂O₃ | | | |
| La₂O₃ | | | 2 |
| WO₃ | | | |
| Ta₂O₅ | | | |
| Al₂O₂ + rare earth oxide | 11 | 10 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.47 | 0.48 | 0.47 |
| (Al₂O₃ + MgO)/(SiO₂ + Al₂O₃ + B₂O₃ + MgO) | 0.34 | 0.35 | 0.34 |
| MgO/ΣRO | 0.51 | 0.56 | 0.53 |
| N | 11 | 11 | 11 |
| Young's modulus E (GPa) | 98 | 98 | 98 |
| Coefficient of thermal expansion α (ppm/° C.) | 5.56 | 5.56 | 5.56 |
| Liquidus temperature TL (° C.) | 1219 | 1218 | 1219 |
| Young's modulus parameter Y | 0.98 | 0.98 | 0.98 |
| Liquidus parameter L | 9.7 | 9.5 | 9.3 |
| Thermal expansion parameter C | 1.11 | 1.11 | 1.11 |
| Glass transition point (° C.) | 716 | 713 | 711 |
| Density (g/cm³) | 3.12 | 3.10 | 3.16 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.33 | 0.33 | 0.33 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 52

| (mol %) | Example 363 | Example 364 | Example 365 | Example 366 |
|---|---|---|---|---|
| SiO₂ | 49 | 49 | 49 | 49 |
| Al₂O₃ | 9 | 8 | 8 | 8 |
| B₂O₃ | 3 | 4 | 3 | 4 |
| MgO | 19 | 19 | 18 | 19 |
| CaO | 4 | 5 | 5 | 5 |
| SrO | 3 | 4 | 4 | 3 |
| BaO | 3 | 3 | 3 | 4 |
| Li₂O | | | | |
| Na₂O | | | | |
| K₂O | | | | |
| ZnO | 6 | 4 | 6 | 4 |
| P₂O₅ | | | | |
| ZrO₂ | 1 | 1 | 1 | 1 |
| TiO₂ | 1 | 1 | 1 | 1 |
| Y₂O₃ | | 2 | 2 | 2 |
| Gd₂O₃ | 2 | | | |
| La₂O₃ | | | | |
| WO₃ | | | | |
| Ta₂O₅ | | | | |
| Al₂O₂ + rare earth oxide | 11 | 10 | 10 | 10 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.47 | 0.47 | 0.47 | 0.47 |
| (Al₂O₃ + MgO)/(SiO₂ + Al₂O₃ + B₂O₃ + MgO) | 0.35 | 0.34 | 0.33 | 0.34 |
| MgO/ΣRO | 0.54 | 0.54 | 0.50 | 0.54 |
| N | 11 | 11 | 11 | 11 |
| Young's modulus E (GPa) | 99 | 98 | 99 | 97 |
| Coefficient of thermal expansion α (ppm/° C.) | 5.56 | 5.56 | 5.56 | 5.57 |
| Liquidus temperature TL (° C.) | 1219 | 1217 | 1214 | 1211 |
| Young's modulus parameter Y | 0.99 | 0.98 | 0.99 | 0.97 |
| Liquidus parameter L | 9.4 | 9.4 | 9.4 | 9.6 |
| Thermal expansion parameter C | 1.09 | 1.12 | 1.13 | 1.11 |
| Glass transition point (° C.) | 717 | 709 | 713 | 713 |
| Density (g/cm³) | 3.19 | 3.05 | 3.12 | 3.07 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.24 | 0.39 | 0.32 | 0.39 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 367 | Example 368 | Example 369 |
|---|---|---|---|
| SiO₂ | 47 | 49 | 47 |
| Al₂O₃ | 9 | 8 | 9 |
| B₂O₃ | 4 | 3 | 4 |
| MgO | 18 | 18 | 18 |
| CaO | 5 | 5 | 5 |
| SrO | 4 | 3 | 3 |
| BaO | 3 | 4 | 4 |
| Li₂O | | | |
| Na₂O | | | |
| K₂O | | | |
| ZnO | 6 | 6 | 6 |
| P₂O₅ | | | |
| ZrO₂ | 1 | 1 | 1 |
| TiO₂ | 1 | 1 | 1 |
| Y₂O₃ | 2 | 2 | 2 |
| Gd₂O₃ | | | |
| La₂O₃ | | | |
| WO₃ | | | |
| Ta₂O₅ | | | |
| Al₂O₂ + rare earth oxide | 11 | 10 | 11 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.49 | 0.47 | 0.49 |
| (Al₂O₃ + MgO)/(SiO₂ + Al₂O₃ + B₂O₃ + MgO) | 0.35 | 0.33 | 0.35 |
| MgO/ΣRO | 0.50 | 0.50 | 0.50 |
| N | 11 | 11 | 11 |
| Young's modulus E (GPa) | 99 | 98 | 99 |
| Coefficient of thermal expansion α (ppm/° C.) | 5.57 | 5.57 | 5.57 |
| Liquidus temperature TL (° C.) | 1216 | 1213 | 1216 |
| Young's modulus parameter Y | 0.99 | 0.98 | 0.98 |
| Liquidus parameter L | 9.4 | 9.7 | 9.6 |
| Thermal expansion parameter C | 1.13 | 1.12 | 1.12 |
| Glass transition point (° C.) | 711 | 717 | 715 |
| Density (g/cm³) | 3.12 | 3.13 | 3.14 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.16 | 0.32 | 0.16 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 53

| (mol %) | Example 370 | Example 371 | Example 372 | Example 373 |
|---|---|---|---|---|
| SiO₂ | 49 | 48 | 48 | 48 |
| Al₂O₃ | 8 | 9 | 9 | 8 |
| B₂O₃ | 4 | 4 | 3 | 4 |
| MgO | 18 | 19 | 19 | 18 |
| CaO | 5 | 4 | 5 | 5 |
| SrO | 3 | 3 | 3 | 4 |
| BaO | 3 | 3 | 4 | 3 |
| Li₂O | | | | |
| Na₂O | | | | |
| K₂O | | | | |
| ZnO | 6 | 6 | 5 | 6 |
| P₂O₅ | | | | |
| ZrO₂ | 1 | 1 | 1 | 1 |
| TiO₂ | 1 | 1 | 1 | 1 |
| Y₂O₃ | | | 2 | 2 |
| Gd₂O₃ | | 2 | | |
| La₂O₃ | 2 | | | |
| WO₃ | | | | |
| Ta₂O₅ | | | | |
| Al₂O₂ + rare earth oxide | 10 | 11 | 11 | 10 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.47 | 0.48 | 0.48 | 0.48 |
| (Al₂O₃ + MgO)/(SiO₂ + Al₂O₃ + B₂O₃ + MgO) | 0.33 | 0.35 | 0.35 | 0.33 |
| MgO/ΣRO | 0.51 | 0.54 | 0.53 | 0.50 |
| N | 11 | 11 | 11 | 11 |
| Young's modulus E (GPa) | 98 | 99 | 99 | 98 |
| Coefficient of thermal expansion α (ppm/° C.) | 5.57 | 5.58 | 5.58 | 5.58 |
| Liquidus temperature TL (° C.) | 1215 | 1218 | 1219 | 1215 |
| Young's modulus parameter Y | 0.98 | 0.99 | 0.99 | 0.99 |
| Liquidus parameter L | 9.2 | 9.3 | 9.8 | 9.3 |
| Thermal expansion parameter C | 1.11 | 1.10 | 1.12 | 1.13 |
| Glass transition point (° C.) | 712 | 712 | 719 | 709 |
| Density (g/cm³) | 3.17 | 3.19 | 3.12 | 3.11 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.32 | 0.16 | 0.28 | 0.24 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 374 | Example 375 | Example 376 |
|---|---|---|---|
| SiO₂ | 49 | 48 | 49 |
| Al₂O₃ | 9 | 8 | 8 |
| B₂O₃ | 4 | 4 | 4 |
| MgO | 18 | 18 | 18 |
| CaO | 5 | 5 | 4 |
| SrO | 3 | 3 | 5 |
| BaO | 3 | 4 | 3 |
| Li₂O | | | |
| Na₂O | | | |
| K₂O | | | |
| ZnO | 5 | 6 | 5 |
| P₂O₅ | | | |
| ZrO₂ | 1 | 1 | 1 |
| TiO₂ | 1 | 1 | 1 |
| Y₂O₃ | | 2 | 2 |
| Gd₂O₃ | 2 | | |
| La₂O₃ | | | |
| WO₃ | | | |
| Ta₂O₅ | | | |
| Al₂O₂ + rare earth oxide | 11 | 10 | 10 |
| Y₂O₃ + Gd₂O₃ + La₂O₃ + Nd₂O₃ + Ta₂O₅ + Nb₂O₅ | 2 | 2 | 2 |
| Parameter A = (Al₂O₃ + RO)/(SiO₂ + Al₂O₃ + RO) | 0.47 | 0.48 | 0.47 |
| (Al₂O₃ + MgO)/(SiO₂ + Al₂O₃ + B₂O₃ + MgO) | 0.34 | 0.33 | 0.33 |
| MgO/ΣRO | 0.53 | 0.50 | 0.51 |
| N | 11 | 11 | 11 |
| Young's modulus E (GPa) | 98 | 98 | 98 |
| Coefficient of thermal expansion α (ppm/° C.) | 5.58 | 5.58 | 5.58 |
| Liquidus temperature TL (° C.) | 1218 | 1214 | 1218 |
| Young's modulus parameter Y | 0.98 | 0.97 | 0.98 |
| Liquidus parameter L | 9.4 | 9.5 | 9.3 |
| Thermal expansion parameter C | 1.10 | 1.12 | 1.13 |
| Glass transition point (° C.) | 711 | 713 | 709 |
| Density (g/cm³) | 3.16 | 3.13 | 3.09 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.22 | 0.24 | 0.34 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 54

| (mol %) | Example 377 | Example 378 | Example 379 | Example 380 |
|---|---|---|---|---|
| SiO₂ | 49 | 49 | 47 | 49 |
| Al₂O₃ | 8 | 8 | 9 | 8 |
| B₂O₃ | 4 | 3 | 4 | 4 |
| MgO | 18 | 19 | 19 | 19 |
| CaO | 4 | 5 | 5 | 4 |
| SrO | 4 | 4 | 4 | 3 |
| BaO | 4 | 3 | 3 | 3 |
| Li₂O | | | | |
| Na₂O | | | | |
| K₂O | | | | |
| ZnO | 5 | 5 | 5 | 6 |
| P₂O₅ | | | | |
| ZrO₂ | 1 | 1 | 1 | 1 |
| TiO₂ | 1 | 1 | 1 | 1 |
| Y₂O₃ | 2 | 2 | 2 | |
| Gd₂O₃ | | | | 2 |
| La₂O₃ | | | | |
| WO₃ | | | | |
| Ta₂O₅ | | | | |
| Al₂O₂ + rare earth oxide | 10 | 10 | 11 | 10 |
| Y₂O₃ + Gd₂O₃ + La₂O₃ + Nd₂O₃ + Ta₂O₅ + Nb₂O₅ | 2 | 2 | 2 | 2 |
| Parameter A = (Al₂O₃ + RO)/(SiO₂ + Al₂O₃ + RO) | 0.47 | 0.47 | 0.49 | 0.47 |
| (Al₂O₃ + MgO)/(SiO₂ + Al₂O₃ + B₂O₃ + MgO) | 0.33 | 0.34 | 0.35 | 0.34 |
| MgO/ΣRO | 0.51 | 0.53 | 0.53 | 0.54 |
| N | 11 | 11 | 11 | 11 |
| Young's modulus E (GPa) | 97 | 99 | 99 | 98 |
| Coefficient of thermal | 5.59 | 5.59 | 5.59 | 5.59 |
| expansion α (ppm/° C.) | | | | |
| Liquidus temperature TL (° C.) | 1215 | 1219 | 1220 | 1216 |
| Young's modulus parameter Y | 0.97 | 0.99 | 1.00 | 0.98 |
| Liquidus parameter L | 9.5 | 9.4 | 9.4 | 9.2 |
| Thermal expansion parameter C | 1.12 | 1.13 | 1.13 | 1.10 |
| Glass transition point (° C.) | 710 | 713 | 711 | 711 |
| Density (g/cm³) | 3.11 | 3.09 | 3.10 | 3.18 |
| Liquidus viscosity log η_{L}(dPa · s) | 2< | 2< | 2< | 2< |
| K_{IC} (MPa · m^{0.5}) | 0.8< | 0.8< | 0.8< | 0.8< |
| Transmittance (%) @308 nm, 0.7 mmt | 30≤ | 30≤ | 30≤ | 30≤ |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Acid resistance parameter T | 0.34 | 0.36 | 0.20 | 0.24 |
| Transmittance (%) @1064 nm, 0.7 mmt | 80≤ | 80≤ | 80≤ | 80≤ |
| T₂ (° C.) | <1350 | <1350 | <1350 | <1350 |
| T₃ (° C.) | <1200 | <1200 | <1200 | <1200 |
| T₄ (° C.) | <1100 | <1100 | <1100 | <1100 |
| Deflection determination | ◯ | ◯ | ◯ | ◯ |
| Manufacturability determination | ◯ | ◯ | ◯ | ◯ |
| Transmission ability determination | ◯ | ◯ | ◯ | ◯ |

| (mol %) | Example 381 | Example 382 | Example 383 |
|---|---|---|---|
| SiO₂ | 49 | 47 | 49 |
| Al₂O₃ | 8 | 9 | 8 |
| B₂O₃ | 3 | 4 | 4 |
| MgO | 19 | 19 | 19 |
| CaO | 5 | 5 | 5 |
| SrO | 3 | 3 | 3 |
| BaO | 4 | 4 | 3 |
| Li₂O | | | |
| Na₂O | | | |
| K₂O | | | |
| ZnO | 5 | 5 | 5 |
| P₂O₅ | | | |
| ZrO₂ | 1 | 1 | 1 |
| TiO₂ | 1 | 1 | 1 |
| Y₂O₃ | 2 | 2 | |
| Gd₂O₃ | | | |
| La₂O₃ | | | 2 |
| WO₃ | | | |
| Ta₂O₅ | | | |
| Al₂O₂ + rare earth oxide | 10 | 11 | 10 |
| Y₂O₃ + Gd₂O₃ + La₂O₃ + Nd₂O₃ + Ta₂O₅ + Nb₂O₅ | 2 | 2 | 3 |
| Parameter A = (Al₂O₃ + RO)/(SiO₂ + Al₂O₃ + RO) | 0.47 | 0.49 | 0.47 |
| (Al₂O₃ + MgO)/(SiO₂ + Al₂O₃ + B₂O₃ + MgO) | 0.34 | 0.35 | 0.34 |
| MgO/ΣRO | 0.53 | 0.53 | 0.54 |
| N | 11 | 11 | 11 |
| Young's modulus E (GPa) | 98 | 99 | 98 |
| Coefficient of thermal expansion α (ppm/° C.) | 5.59 | 5.59 | 5.60 |
| Liquidus temperature TL (° C.) | 1216 | 1217 | 1217 |
| Young's modulus parameter Y | 0.98 | 0.98 | 0.98 |
| Liquidus parameter L | 9.7 | 9.6 | 9.2 |
| Thermal expansion parameter C | 1.12 | 1.13 | 1.11 |
| Glass transition point (° C.) | 717 | 715 | 712 |
| Density (g/cm³) | 3.11 | 3.11 | 3.14 |
| Liquidus viscosity log η_{L}(dPa · s) | 2< | 2< | 2< |
| K_{IC} (MPa · m^{0.5}) | 0.8< | 0.8< | 0.8< |
| Transmittance (%) @308 nm, 0.7 mmt | 30≤ | 30≤ | 30≤ |
| Transmittance (%) @350 nm, 0.7 mmt | 75≤ | 75≤ | 75≤ |
| Transmittance (%) @550 nm, 0.7 mmt | 88≤ | 88≤ | 88≤ |
| Acid resistance parameter T | 0.36 | 0.20 | 0.36 |
| Transmittance (%) @1064 nm, 0.7 mmt | 80≤ | 80≤ | 80≤ |
| T₂ (° C.) | <1350 | <1350 | <1350 |
| T₃ (° C.) | <1200 | <1200 | <1200 |
| T₄ (° C.) | <1100 | <1100 | <1100 |
| Deflection determination | ◯ | ◯ | ◯ |
| Manufacturability determination | ◯ | ◯ | ◯ |
| Transmission ability determination | ◯ | ◯ | ◯ |

TABLE 55

| | Example | Example | Example | Example | Example | Example | Example |
|---|---|---|---|---|---|---|---|
| (mol %) | 384 | 385 | 386 | 387 | 388 | 389 | 390 |
| SiO₂ | 48 | 48 | 49 | 49 | 49 | 47 | 49 |
| Al₂O₃ | 8 | 8 | 9 | 8 | 8 | 9 | 8 |
| B₂O₃ | 4 | 4 | 3 | 3 | 3 | 4 | 4 |
| MgO | 19 | 19 | 18 | 18 | 20 | 20 | 18 |
| CaO | 5 | 5 | 5 | 4 | 5 | 5 | 4 |
| SrO | 4 | 3 | 3 | 4 | 3 | 3 | 4 |
| BaO | 3 | 4 | 3 | 4 | 4 | 4 | 3 |
| Li₂O | | | | | | | |
| Na₂O | | | | | | | |
| K₂O | | | | | | | |
| ZnO | 5 | 5 | 6 | 6 | 4 | 4 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | | 2 | 2 | 2 | |
| Gd₂O₃ | | | 2 | | | | |
| La₂O₃ | | | | | | | 2 |
| WO₃ | | | | | | | |
| Ta₂O₅ | | | | | | | |
| Al₂O₃ + rare earth oxide | 10 | 10 | 11 | 10 | 10 | 11 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.48 | 0.47 | 0.47 | 0.47 | 0.49 | 0.47 |
| (Al₂O₃ + MgO)/(SiO₂ + Al₂O₃ + B₂O₃ + MgO) | 0.34 | 0.34 | 0.34 | 0.33 | 0.35 | 0.36 | 0.33 |
| MgO/ΣRO | 0.53 | 0.53 | 0.51 | 0.50 | 0.56 | 0.56 | 0.51 |
| N | 11 | 11 | 11 | 11 | 11 | 11 | 11 |
| Young's modulus E (GPa) | 98 | 98 | 99 | 98 | 98 | 99 | 98 |
| Coefficient of thermal expansion α (ppm/° C.) | 5.61 | 5.61 | 5.61 | 5.62 | 5.62 | 5.62 | 5.62 |
| Liquidus temperature TL (° C.) | 1218 | 1215 | 1218 | 1217 | 1218 | 1220 | 1216 |
| Young's modulus parameter Y | 0.99 | 0.98 | 0.99 | 0.98 | 0.98 | 0.99 | 0.98 |
| Liquidus parameter L | 9.3 | 9.5 | 9.5 | 9.6 | 9.7 | 9.6 | 9.1 |
| Thermal expansion parameter C | 1.13 | 1.13 | 1.10 | 1.13 | 1.12 | 1.13 | 1.12 |
| Glass transition point (° C.) | 709 | 713 | 716 | 715 | 717 | 714 | 709 |
| Density (g/cm³) | 3.09 | 3.11 | 3.20 | 3.15 | 3.08 | 3.09 | 3.18 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.29 | 0.29 | 0.19 | 0.32 | 0.41 | 0.25 | 0.32 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 56

| | Example | Example | Example | Example | Example | Example | Example |
|---|---|---|---|---|---|---|---|
| (mol %) | 391 | 392 | 393 | 394 | 395 | 396 | 397 |
| SiO₂ | 47 | 49 | 49 | 48 | 49 | 48 | 48 |
| Al₂O₃ | 9 | 8 | 8 | 9 | 9 | 8 | 8 |
| B₂O₃ | 3 | 4 | 3 | 4 | 4 | 4 | 4 |
| MgO | 19 | 18 | 19 | 18 | 18 | 18 | 20 |
| CaO | 5 | 4 | 5 | 5 | 4 | 4 | 5 |
| SrO | 3 | 3 | 3 | 3 | 4 | 4 | 3 |
| BaO | 4 | 4 | 3 | 3 | 3 | 4 | 4 |
| Li₂O | | | | | | | |
| Na₂O | | | | | | | |
| K₂O | | | | | | | |
| ZnO | 6 | 6 | 6 | 6 | 5 | 6 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | | | | 2 | 2 |
| Gd₂O₃ | | | | 2 | 2 | | |
| La₂O₃ | | 2 | 2 | | | | |
| WO₃ | | | | | | | |
| Ta₂O₅ | | | | | | | |
| Al₂O₃ + rare earth oxide | 11 | 10 | 10 | 11 | 11 | 10 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.49 | 0.47 | 0.47 | 0.48 | 0.47 | 0.48 | 0.48 |
| (Al₂O₃ + MgO)/(SiO₂ + Al₂O₃ + B₂O₃ + MgO) | 0.36 | 0.33 | 0.34 | 0.34 | 0.34 | 0.33 | 0.35 |
| MgO/ΣRO | 0.51 | 0.51 | 0.53 | 0.51 | 0.53 | 0.50 | 0.56 |
| N | 11 | 11 | 11 | 11 | 11 | 11 | 11 |
| Young's modulus E (GPa) | 100 | 97 | 99 | 99 | 98 | 98 | 98 |
| Coefficient of thermal expansion α (ppm/° C.) | 5.62 | 5.62 | 5.62 | 5.63 | 5.63 | 5.63 | 5.63 |
| Liquidus temperature TL (° C.) | 1220 | 1218 | 1219 | 1219 | 1219 | 1219 | 1217 |
| Young's modulus parameter Y | 1.00 | 0.97 | 0.99 | 0.98 | 0.98 | 0.98 | 0.98 |
| Liquidus parameter L | 9.7 | 9.4 | 9.3 | 9.3 | 9.3 | 9.4 | 9.5 |
| Thermal expansion parameter C | 1.13 | 1.11 | 1.12 | 1.11 | 1.11 | 1.13 | 1.13 |
| Glass transition point (° C.) | 719 | 713 | 717 | 712 | 710 | 711 | 713 |
| Density (g/cm³) | 3.15 | 3.20 | 3.18 | 3.19 | 3.17 | 3.14 | 3.08 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.18 | 0.32 | 0.34 | 0.12 | 0.21 | 0.24 | 0.33 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 57

| | Example | Example | Example | Example | Example | Example | Example |
|---|---|---|---|---|---|---|---|
| (mol %) | 398 | 399 | 400 | 401 | 402 | 403 | 404 |
| SiO₂ | 48 | 48 | 49 | 49 | 47 | 48 | 49 |
| Al₂O₃ | 8 | 8 | 8 | 7 | 8 | 9 | 7 |
| B₂O₃ | 3 | 4 | 4 | 3 | 4 | 4 | 3 |
| MgO | 19 | 19 | 18 | 19 | 19 | 19 | 19 |
| CaO | 5 | 5 | 5 | 5 | 5 | 5 | 5 |
| SrO | 3 | 3 | 3 | 4 | 4 | 3 | 3 |
| BaO | 4 | 3 | 3 | 3 | 3 | 3 | 4 |
| Li₂O | | | | | | | |
| Na₂O | | | | | | | |
| K₂O | | | | | | | |
| ZnO | 6 | 6 | 6 | 6 | 6 | 5 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | | 2 | 2 | | 2 |
| Gd₂O₃ | | | 2 | | | 2 | |
| La₂O₃ | | 2 | | | | | |
| WO₃ | | | | | | | |
| Ta₂O₅ | | | | | | | |
| Al₂O₃ + rare earth oxide | 10 | 10 | 10 | 9 | 10 | 11 | 9 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.48 | 0.47 | 0.47 | 0.49 | 0.48 | 0.47 |
| (Al₂O₃ + MgO)/(SiO₂ + Al₂O₃ + B₂O₃ + MgO) | 0.35 | 0.34 | 0.33 | 0.33 | 0.35 | 0.35 | 0.33 |
| MgO/ΣRO | 0.51 | 0.53 | 0.51 | 0.51 | 0.51 | 0.54 | 0.51 |
| N | 11 | 11 | 11 | 11 | 11 | 11 | 11 |
| Young's modulus E (GPa) | 99 | 99 | 98 | 98 | 99 | 99 | 98 |
| Coefficient of thermal expansion α (ppm/° C.) | 5.64 | 5.64 | 5.64 | 5.65 | 5.65 | 5.65 | 5.65 |
| Liquidus temperature TL (° C.) | 1218 | 1217 | 1215 | 1211 | 1218 | 1219 | 1208 |
| Young's modulus parameter Y | 0.99 | 0.98 | 0.98 | 0.99 | 0.99 | 0.99 | 0.98 |
| Liquidus parameter L | 9.6 | 9.2 | 9.2 | 9.3 | 9.2 | 9.3 | 9.5 |
| Thermal expansion parameter C | 1.13 | 1.13 | 1.11 | 1.14 | 1.15 | 1.11 | 1.13 |
| Glass transition point (° C.) | 717 | 712 | 710 | 713 | 710 | 712 | 717 |
| Density (g/cm³) | 3.14 | 3.18 | 3.18 | 3.12 | 3.12 | 3.17 | 3.13 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.26 | 0.20 | 0.35 | 0.19 | 0.16 | 0.35 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 58

| | Example | Example | Example | Example | Example | Example | Example |
|---|---|---|---|---|---|---|---|
| (mol %) | 405 | 406 | 407 | 408 | 409 | 410 | 411 |
| SiO₂ | 47 | 49 | 49 | 49 | 49 | 48 | 49 |
| Al₂O₃ | 8 | 9 | 9 | 8 | 9 | 8 | 7 |
| B₂O₃ | 4 | 3 | 3 | 4 | 3 | 3 | 3 |
| MgO | 19 | 18 | 18 | 19 | 18 | 19 | 20 |
| CaO | 5 | 4 | 4 | 5 | 4 | 5 | 5 |
| SrO | 3 | 4 | 3 | 3 | 5 | 4 | 4 |
| BaO | 4 | 3 | 4 | 3 | 3 | 4 | 3 |
| Li₂O | | | | | | | |
| Na₂O | | | | | | | |
| K₂O | | | | | | | |
| ZnO | 6 | 6 | 6 | 5 | 5 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | | | 2 | 2 | 2 |
| Gd₂O₃ | | 2 | 2 | 2 | | | |
| La₂O₃ | | | | | | | |
| WO₃ | | | | | | | |
| Ta₂O₅ | | | | | | | |
| Al₂O₃ + rare earth oxide | 10 | 11 | 11 | 10 | 11 | 10 | 9 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.49 | 0.47 | 0.47 | 0.47 | 0.47 | 0.48 | 0.47 |
| (Al₂O₃ + MgO)/(SiO₂ + Al₂O₃ + B₂O₃ + MgO) | 0.35 | 0.34 | 0.34 | 0.34 | 0.34 | 0.35 | 0.34 |
| MgO/ΣRO | 0.51 | 0.51 | 0.51 | 0.54 | 0.51 | 0.51 | 0.54 |
| N | 11 | 11 | 11 | 11 | 11 | 11 | 11 |
| Young's modulus E (GPa) | 99 | 99 | 99 | 98 | 99 | 99 | 99 |
| Coefficient of thermal expansion α (ppm/° C.) | 5.65 | 5.66 | 5.66 | 5.67 | 5.55 | 5.76 | 5.67 |
| Liquidus temperature TL (° C.) | 1216 | 1219 | 1219 | 1217 | 1225 | 1225 | 1214 |
| Young's modulus parameter Y | 0.98 | 0.99 | 0.98 | 0.98 | 1.00 | 0.99 | 0.99 |
| Liquidus parameter L | 9.5 | 9.3 | 9.6 | 9.2 | 9.5 | 9.5 | 9.3 |
| Thermal expansion parameter C | 1.14 | 1.11 | 1.11 | 1.11 | 1.12 | 1.16 | 1.14 |
| Glass transition point (° C.) | 713 | 715 | 717 | 710 | 714 | 714 | 713 |
| Density (g/cm³) | 3.14 | 3.21 | 3.23 | 3.16 | 3.10 | 3.13 | 3.09 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.19 | 0.19 | 0.19 | 0.24 | 0.33 | 0.26 | 0.39 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 59

| | Example | Example | Example | Example | Example | Example | Example |
|---|---|---|---|---|---|---|---|
| (mol %) | 412 | 413 | 414 | 415 | 416 | 417 | 418 |
| SiO₂ | 49 | 47 | 49 | 47 | 49 | 47 | 48 |
| Al₂O₃ | 9 | 9 | 8 | 8 | 7 | 8 | 9 |
| B₂O₃ | 3 | 3 | 3 | 4 | 3 | 4 | 3 |
| MgO | 19 | 20 | 19 | 19 | 20 | 20 | 20 |
| CaO | 4 | 5 | 4 | 4 | 5 | 5 | 5 |
| SrO | 4 | 4 | 4 | 4 | 3 | 3 | 4 |
| BaO | 4 | 3 | 4 | 4 | 4 | 4 | 3 |
| Li₂O | | | | | | | |
| Na₂O | | | | | | | |
| K₂O | | | | | | | |
| ZnO | 4 | 5 | 5 | 6 | 5 | 5 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | | | 2 | 2 | 2 |
| Gd₂O₃ | | | | | | | |
| La₂O₃ | | | 2 | 2 | | | |
| WO₃ | | | | | | | |
| Ta₂O₅ | | | | | | | |
| Al₂O₃ + rare earth oxide | 11 | 11 | 10 | 10 | 9 | 10 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.49 | 0.47 | 0.49 | 0.47 | 0.49 | 0.48 |
| (Al₂O₃ + MgO)/(SiO₂ + Al₂O₃ + B₂O₃ + MgO) | 0.35 | 0.37 | 0.34 | 0.35 | 0.34 | 0.35 | 0.36 |
| MgO/ΣRO | 0.54 | 0.54 | 0.53 | 0.51 | 0.54 | 0.54 | 0.56 |
| N | 11 | 11 | 11 | 11 | 11 | 11 | 11 |
| Young's modulus E (GPa) | 98 | 100 | 98 | 98 | 98 | 99 | 100 |
| Coefficient of thermal expansion α (ppm/° C.) | 5.58 | 5.64 | 5.79 | 5.85 | 5.68 | 5.68 | 5.60 |
| Liquidus temperature TL (° C.) | 1225 | 1225 | 1225 | 1225 | 1212 | 1220 | 1225 |
| Young's modulus parameter Y | 0.99 | 1.01 | 0.98 | 0.98 | 0.98 | 0.98 | 1.00 |
| Liquidus parameter L | 9.7 | 9.5 | 9.3 | 9.1 | 9.5 | 9.5 | 9.5 |
| Thermal expansion parameter C | 1.12 | 1.14 | 1.15 | 1.16 | 1.14 | 1.14 | 1.13 |
| Glass transition point (° C.) | 716 | 716 | 715 | 711 | 717 | 713 | 715 |
| Density (g/cm³) | 3.09 | 3.11 | 3.20 | 3.23 | 3.11 | 3.11 | 3.07 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.37 | 0.22 | 0.33 | 0.16 | 0.39 | 0.23 | 0.32 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 60

| | Example | Example | Example | Example | Example | Example | Example |
|---|---|---|---|---|---|---|---|
| (mol %) | 419 | 420 | 421 | 422 | 423 | 424 | 425 |
| SiO₂ | 49 | 48 | 48 | 48 | 49 | 48 | 47 |
| Al₂O₃ | 9 | 9 | 9 | 8 | 8 | 8 | 9 |
| B₂O₃ | 3 | 3 | 3 | 4 | 3 | 3 | 4 |
| MgO | 19 | 20 | 19 | 20 | 20 | 20 | 19 |
| CaO | 4 | 5 | 5 | 4 | 4 | 5 | 5 |
| SrO | 4 | 3 | 3 | 4 | 4 | 4 | 3 |
| BaO | 3 | 3 | 3 | 3 | 4 | 3 | 4 |
| Li₂O | | | | | | | |
| Na₂O | | | | | | | |
| K₂O | | | | | | | |
| ZnO | 5 | 5 | 6 | 5 | 4 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | 2 | | |
| Gd₂O₃ | | | 2 | | | | |
| La₂O₃ | 2 | 2 | | 2 | | 2 | 2 |
| WO₃ | | | | | | | |
| Ta₂O₅ | | | | | | | |
| Al₂O₃ + rare earth oxide | 11 | 11 | 11 | 10 | 10 | 10 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.48 | 0.48 | 0.48 | 0.47 | 0.48 | 0.49 |
| (Al₂O₃ + MgO)/(SiO₂ + Al₂O₃ + B₂O₃ + MgO) | 0.35 | 0.36 | 0.35 | 0.35 | 0.35 | 0.35 | 0.35 |
| MgO/ΣRO | 0.54 | 0.56 | 0.53 | 0.56 | 0.56 | 0.54 | 0.53 |
| N | 11 | 11 | 11 | 11 | 11 | 11 | 11 |
| Young's modulus E (GPa) | 99 | 100 | 100 | 99 | 98 | 99 | 99 |
| Coefficient of thermal expansion α (ppm/° C.) | 5.61 | 5.63 | 5.68 | 5.71 | 5.66 | 5.81 | 5.75 |
| Liquidus temperature TL (° C.) | 1225 | 1225 | 1220 | 1225 | 1225 | 1225 | 1225 |
| Young's modulus parameter Y | 0.99 | 1.00 | 1.00 | 0.99 | 0.99 | 1.00 | 0.98 |
| Liquidus parameter L | 9.3 | 9.4 | 9.4 | 9.0 | 9.6 | 9.2 | 9.4 |
| Thermal expansion parameter C | 1.12 | 1.12 | 1.12 | 1.14 | 1.13 | 1.16 | 1.14 |
| Glass transition point (° C.) | 716 | 718 | 717 | 709 | 714 | 713 | 715 |
| Density (g/cm³) | 3.17 | 3.16 | 3.20 | 3.16 | 3.09 | 3.18 | 3.19 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.35 | 0.30 | 0.14 | 0.30 | 0.40 | 0.28 | 0.18 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 61

| | Example | Example | Example | Example | Example | Example | Example |
|---|---|---|---|---|---|---|---|
| (mol %) | 426 | 427 | 428 | 429 | 430 | 431 | 432 |
| SiO₂ | 48 | 47 | 48 | 49 | 49 | 48 | 48 |
| Al₂O₃ | 9 | 9 | 8 | 8 | 8 | 9 | 9 |
| B₂O₃ | 4 | 3 | 4 | 4 | 3 | 4 | 4 |
| MgO | 20 | 18 | 19 | 18 | 18 | 18 | 18 |
| CaO | 4 | 5 | 4 | 4 | 5 | 4 | 4 |
| SrO | 3 | 4 | 3 | 4 | 4 | 4 | 5 |
| BaO | 3 | 4 | 4 | 3 | 4 | 4 | 3 |
| Li₂O | | | | | | | |
| Na₂O | | | | | | | |
| K₂O | | | | | | | |
| ZnO | 5 | 6 | 6 | 6 | 5 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | 2 | | | 2 | | 2 |
| Gd₂O₃ | | | | 2 | | | |
| La₂O₃ | 2 | | 2 | | | 2 | |
| WO₃ | | | | | | | |
| Ta₂O₅ | | | | | | | |
| Al₂O₃ + rare earth oxide | 11 | 11 | 10 | 10 | 10 | 11 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.49 | 0.48 | 0.47 | 0.47 | 0.48 | 0.48 |
| (Al₂O₃ + MgO)/(SiO₂ + Al₂O₃ + B₂O₃ + MgO) | 0.36 | 0.35 | 0.34 | 0.33 | 0.33 | 0.34 | 0.34 |
| MgO/ΣRO | 0.57 | 0.49 | 0.53 | 0.51 | 0.50 | 0.51 | 0.51 |
| N | 11 | 11 | $1 | 11 | 11 | 11 | 11 |
| Young's modulus E (GPa) | 99 | 99 | 98 | 98 | 98 | 98 | 98 |
| Coefficient of thermal expansion α (ppm/° C.) | 5.53 | 5.72 | 5.69 | 5.69 | 5.69 | 5.73 | 5.57 |
| Liquidus temperature TL (° C.) | 1225 | 1225 | 1220 | 1216 | 1218 | 1225 | 1224 |
| Young's modulus parameter Y | 0.99 | 0.99 | 0.97 | 0.98 | 0.98 | 0.97 | 0.99 |
| Liquidus parameter L | 9.3 | 9.6 | 9.3 | 9.1 | 9.6 | 9.4 | 9.3 |
| Thermal expansion parameter C | 1.10 | 1.15 | 1.13 | 1.12 | 1.14 | 1.13 | 1.13 |
| Glass transition point (° C.) | 714 | 716 | 713 | 709 | 714 | 712 | 710 |
| Density (g/cm³) | 3.15 | 3.17 | 3.21 | 3.20 | 3.12 | 3.20 | 3.10 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.32 | 0.14 | 0.26 | 0.20 | 0.32 | 0.23 | 0.25 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 62

| | Example | Example | Example | Example | Example | Example | Example |
|---|---|---|---|---|---|---|---|
| (mol %) | 433 | 434 | 435 | 436 | 437 | 438 | 439 |
| SiO₂ | 49 | 49 | 49 | 49 | 48 | 49 | 49 |
| Al₂O₃ | 8 | 8 | 8 | 8 | 9 | 7 | 9 |
| B₂O₃ | 3 | 4 | 4 | 3 | 3 | 3 | 3 |
| MgO | 20 | 18 | 18 | 19 | 18 | 19 | 20 |
| CaO | 4 | 4 | 5 | 5 | 5 | 4 | 4 |
| SrO | 3 | 3 | 4 | 3 | 4 | 5 | 3 |
| BaO | 4 | 4 | 3 | 3 | 4 | 3 | 3 |
| Li₂O | | | | | | | |
| Na₂O | | | | | | | |
| K₂O | | | | | | | |
| ZnO | 5 | 6 | 5 | 6 | 5 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | 2 | 2 | |
| Gd₂O₃ | | 2 | | 2 | | | |
| La₂O₃ | 2 | | 2 | | | | 2 |
| WO₃ | | | | | | | |
| Ta₂O₅ | | | | | | | |
| Al₂O₃ + rare earth oxide | 10 | 10 | 10 | 10 | 11 | 9 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.47 | 0.47 | 0.47 | 0.48 | 0.47 | 0.47 |
| (Al₂O₃ + MgO)/(SiO₂ + Al₂O₃ + B₂O₃ + MgO) | 0.35 | 0.33 | 0.33 | 0.34 | 0.35 | 0.33 | 0.36 |
| MgO/ΣRO | 0.56 | 0.51 | 0.51 | 0.53 | 0.50 | 0.51 | 0.57 |
| N | 11 | 11 | 11 | 11 | 11 | 11 | 11 |
| Young's modulus E (GPa) | 99 | 97 | 98 | 99 | 99 | 98 | 100 |
| Coefficient of thermal expansion α (ppm/° C.) | 5.70 | 5.69 | 5.69 | 5.69 | 5.67 | 5.70 | 5.51 |
| Liquidus temperature TL (° C.) | 1224 | 1217 | 1218 | 1217 | 1224 | 1218 | 1224 |
| Young's modulus parameter Y | 0.98 | 0.97 | 0.98 | 0.99 | 0.99 | 0.99 | 1.00 |
| Liquidus parameter L | 9.4 | 9.4 | 9.2 | 9.3 | 9.7 | 9.2 | 9.4 |
| Thermal expansion parameter C | 1.12 | 1.11 | 1.13 | 1.12 | 1.14 | 1.15 | 1.09 |
| Glass transition point (° C.) | 717 | 711 | 709 | 716 | 716 | 713 | 718 |
| Density (g/cm³) | 3.18 | 3.21 | 3.16 | 3.19 | 3.13 | 3.13 | 3.15 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.38 | 0.20 | 0.32 | 0.22 | 0.23 | 0.34 | 0.40 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 63

| | Example | Example | Example | Example | Example | Example | Example |
|---|---|---|---|---|---|---|---|
| (mol %) | 440 | 441 | 442 | 443 | 444 | 445 | 446 |
| SiO₂ | 48 | 49 | 48 | 47 | 49 | 48 | 47 |
| Al₂O₃ | 8 | 8 | 8 | 8 | 7 | 9 | 9 |
| B₂O₃ | 4 | 4 | 4 | 4 | 3 | 3 | 4 |
| MgO | 19 | 18 | 20 | 19 | 19 | 19 | 19 |
| CaO | 4 | 5 | 4 | 4 | 4 | 4 | 4 |
| SrO | 4 | 3 | 4 | 5 | 4 | 4 | 4 |
| BaO | 4 | 4 | 4 | 3 | 4 | 3 | 3 |
| Li₂O | | | | | | | |
| Na₂O | | | | | | | |
| K₂O | | | | | | | |
| ZnO | 5 | 5 | 4 | 6 | 6 | 6 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | 2 | 2 | 2 | | |
| Gd₂O₃ | | | | | | | |
| La₂O₃ | 2 | 2 | | | | 2 | 2 |
| WO₃ | | | | | | | |
| Ta₂O₅ | | | | | | | |
| Al₂O₃ + rare earth oxide | 10 | 10 | 10 | 10 | 9 | 11 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.48 | 0.49 | 0.47 | 0.48 | 0.49 |
| (Al₂O₃ + MgO)/(SiO₂ + Al₂O₃ + B₂O₃ + MgO) | 0.34 | 0.33 | 0.35 | 0.35 | 0.33 | 0.35 | 0.35 |
| MgO/ΣRO | 0.53 | 0.51 | 0.56 | 0.51 | 0.51 | 0.53 | 0.53 |
| N | 11 | 11 | 11 | 11 | 11 | 11 | 11 |
| Young's modulus E (GPa) | 98 | 97 | 98 | 99 | 98 | 100 | 99 |
| Coefficient of thermal expansion α (ppm/° C.) | 5.81 | 5.70 | 5.68 | 5.70 | 5.70 | 5.65 | 5.67 |
| Liquidus temperature TL (° C.) | 1224 | 1220 | 1224 | 1224 | 1214 | 1224 | 1224 |
| Young's modulus parameter Y | 0.97 | 0.96 | 0.98 | 0.99 | 0.98 | 1.00 | 0.99 |
| Liquidus parameter L | 9.2 | 9.4 | 9.4 | 9.1 | 9.4 | 9.3 | 9.1 |
| Thermal expansion parameter C | 1.15 | 1.13 | 1.14 | 1.15 | 1.14 | 1.13 | 1.13 |
| Glass transition point (° C.) | 711 | 713 | 710 | 709 | 714 | 716 | 712 |
| Density (g/cm³) | 3.20 | 3.18 | 3.09 | 3.14 | 3.15 | 3.20 | 3.20 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.32 | 0.32 | 0.18 | 0.34 | 0.25 | 0.18 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 64

| | Example | Example | Example | Example | Example | Example | Example |
|---|---|---|---|---|---|---|---|
| (mol %) | 447 | 448 | 449 | 450 | 451 | 452 | 453 |
| SiO₂ | 48 | 49 | 48 | 47 | 48 | 48 | 48 |
| Al₂O₃ | 8 | 9 | 8 | 9 | 8 | 8 | 9 |
| B₂O₃ | 4 | 3 | 4 | 3 | 3 | 3 | 3 |
| MgO | 20 | 18 | 18 | 19 | 20 | 19 | 18 |
| CaO | 4 | 4 | 5 | 5 | 5 | 4 | 4 |
| SrO | 3 | 4 | 4 | 3 | 3 | 4 | 4 |
| BaO | 4 | 4 | 4 | 4 | 4 | 4 | 4 |
| Li₂O | | | | | | | |
| Na₂O | | | | | | | |
| K₂O | | | | | | | |
| ZnO | 5 | 5 | 5 | 6 | 5 | 6 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | 2 | | | 2 | |
| Gd₂O₃ | | | | | | | |
| La₂O₃ | 2 | 2 | | 2 | 2 | | 2 |
| WO₃ | | | | | | | |
| Ta₂O₅ | | | | | | | |
| Al₂O₃ + rare earth oxide | 10 | 11 | 10 | 11 | 10 | 10 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.48 | 0.49 | 0.48 | 0.48 | 0.48 |
| (Al₂O₃ + MgO)/(SiO₂ + Al₂O₃ + B₂O₃ + MgO) | 0.35 | 0.34 | 0.33 | 0.36 | 0.35 | 0.35 | 0.35 |
| MgO/ΣRO | 0.56 | 0.51 | 0.50 | 0.51 | 0.54 | 0.51 | 0.50 |
| N | 11 | 11 | 11 | 11 | 11 | 11 | 11 |
| Young's modulus E (GPa) | 98 | 98 | 98 | 100 | 99 | 99 | 99 |
| Coefficient of thermal expansion α (ppm/° C.) | 5.71 | 5.71 | 5.71 | 5.78 | 5.82 | 5.68 | 5.76 |
| Liquidus temperature TL (° C.) | 1224 | 1224 | 1220 | 1224 | 1224 | 1224 | 1224 |
| Young's modulus parameter Y | 0.98 | 0.98 | 0.97 | 0.99 | 0.99 | 0.99 | 0.99 |
| Liquidus parameter L | 9.3 | 9.5 | 9.5 | 9.5 | 9.4 | 9.5 | 9.4 |
| Thermal expansion parameter C | 1.13 | 1.13 | 1.15 | 1.15 | 1.15 | 1.14 | 1.14 |
| Glass transition point (° C.) | 713 | 716 | 710 | 719 | 717 | 715 | 717 |
| Density (g/cm³) | 3.18 | 3.20 | 3.12 | 3.23 | 3.19 | 3.15 | 3.23 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.30 | 0.31 | 0.24 | 0.16 | 0.28 | 0.26 | 0.21 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 65

| | Example | Example | Example | Example | Example | Example | Example |
|---|---|---|---|---|---|---|---|
| (mol %) | 454 | 455 | 456 | 457 | 458 | 459 | 460 |
| SiO₂ | 48 | 48 | 49 | 47 | 49 | 49 | 49 |
| Al₂O₃ | 8 | 8 | 9 | 9 | 8 | 8 | 8 |
| B₂O₃ | 4 | 4 | 3 | 4 | 3 | 4 | 3 |
| MgO | 19 | 18 | 19 | 18 | 20 | 19 | 19 |
| CaO | 5 | 4 | 4 | 5 | 4 | 4 | 5 |
| SrO | 3 | 5 | 3 | 3 | 4 | 3 | 4 |
| BaO | 3 | 3 | 4 | 4 | 3 | 4 | 4 |
| Li₂O | | | | | | | |
| Na₂O | | | | | | | |
| K₂O | | | | | | | |
| ZnO | 6 | 6 | 5 | 6 | 5 | 5 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | | | 2 |
| Gd₂O₃ | 2 | | | | | 2 | |
| La₂O₃ | | 2 | 2 | 2 | 2 | | |
| WO₃ | | | | | | | |
| Ta₂O₅ | | | | | | | |
| Al₂O₃ + rare earth oxide | 10 | 10 | 11 | 11 | 10 | 10 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.48 | 0.47 | 0.49 | 0.47 | 0.47 | 0.47 |
| (Al₂O₃ + MgO)/(SiO₂ + Al₂O₃ + B₂O₃ + MgO) | 0.34 | 0.33 | 0.35 | 0.35 | 0.35 | 0.34 | 0.34 |
| MgO/ΣRO | 0.53 | 0.50 | 0.54 | 0.50 | 0.56 | 0.54 | 0.53 |
| N | 11 | 11 | 11 | 11 | 11 | 11 | 11 |
| Young's modulus E (GPa) | 99 | 98 | 99 | 99 | 99 | 98 | 98 |
| Coefficient of thermal expansion α (ppm/° C.) | 5.71 | 5.78 | 5.61 | 5.72 | 5.69 | 5.72 | 5.71 |
| Liquidus temperature TL (° C.) | 1216 | 1224 | 1224 | 1224 | 1224 | 1219 | 1224 |
| Young's modulus parameter Y | 0.98 | 0.98 | 0.98 | 0.98 | 0.99 | 0.97 | 0.98 |
| Liquidus parameter L | 9.2 | 9.0 | 9.6 | 9.4 | 9.2 | 9.4 | 9.6 |
| Thermal expansion parameter C | 1.13 | 1.15 | 1.11 | 1.14 | 1.13 | 1.11 | 1.15 |
| Glass transition point (° C.) | 711 | 709 | 719 | 715 | 714 | 711 | 714 |
| Density (g/cm³) | 3.19 | 3.21 | 3.18 | 3.22 | 3.16 | 3.19 | 3.10 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.15 | 0.21 | 0.35 | 0.14 | 0.38 | 0.24 | 0.36 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 66

| | Exampla | Example | Example | Example | Example | Example | Example |
|---|---|---|---|---|---|---|---|
| (mol %) | 461 | 462 | 463 | 464 | 465 | 466 | 467 |
| SiO₂ | 48 | 49 | 48 | 49 | 49 | 48 | 49 |
| Al₂O₃ | 9 | 7 | 9 | 8 | 8 | 8 | 7 |
| B₂O₃ | 3 | 3 | 4 | 3 | 3 | 3 | 3 |
| MgO | 19 | 20 | 19 | 18 | 18 | 19 | 20 |
| CaO | 5 | 4 | 4 | 5 | 4 | 4 | 4 |
| SrO | 3 | 5 | 4 | 4 | 5 | 4 | 4 |
| BaO | 4 | 3 | 4 | 3 | 3 | 4 | 4 |
| Li₂O | | | | | | | |
| Na₂O | | | | | | | |
| K₂O | | | | | | | |
| ZnO | 5 | 5 | 4 | 6 | 6 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | 2 | 2 | | | | 2 |
| Gd₂O₃ | | | | | | | |
| La₂O₃ | 2 | | | 2 | 2 | 2 | |
| WO₃ | | | | | | | |
| Ta₂O₅ | | | | | | | |
| Al₂O₃ + rare earth oxide | 11 | 9 | 11 | 10 | 10 | 10 | 9 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.48 | 0.47 | 0.47 | 0.48 | 0.47 |
| (Al₂O₃ + MgO)/(SiO₂ + Al₂O₃ + B₂O₃ + MgO) | 0.35 | 0.34 | 0.35 | 0.33 | 0.33 | 0.35 | 0.34 |
| MgO/ΣRO | 0.53 | 0.54 | 0.54 | 0.50 | 0.50 | 0.51 | 0.54 |
| N | 11 | 11 | 11 | 11 | 11 | 11 | 11 |
| Young's modulus E (GPa) | 99 | 98 | 98 | 98 | 98 | 99 | 98 |
| Coefficient of thermal expansion α (ppm/° C.) | 5.73 | 5.72 | 5.60 | 5.72 | 5.77 | 5.84 | 5.72 |
| Liquidus temperature TL (° C.) | 1224 | 1220 | 1224 | 1219 | 1224 | 1224 | 1216 |
| Young's modulus parameter Y | 0.99 | 0.99 | 0.98 | 0.99 | 0.99 | 0.98 | 0.98 |
| Liquidus parameter L | 9.6 | 9.2 | 9.6 | 9.2 | 9.1 | 9.3 | 9.4 |
| Thermal expansion parameter C | 1.14 | 1.15 | 1.12 | 1.14 | 1.15 | 1.16 | 1.15 |
| Glass transition point (° C.) | 719 | 713 | 712 | 713 | 713 | 715 | 714 |
| Density (g/cm³) | 3.19 | 3.10 | 3.09 | 3.19 | 3.21 | 3.23 | 3.12 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.25 | 0.38 | 0.30 | 0.29 | 0.29 | 0.23 | 0.39 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 67

| | Example | Example | Example | Example | Example | Example | Example |
|---|---|---|---|---|---|---|---|
| (mol %) | 468 | 469 | 470 | 471 | 472 | 473 | 474 |
| SiO₂ | 47 | 49 | 47 | 48 | 48 | 48 | 48 |
| Al₂O₃ | 9 | 8 | 8 | 8 | 9 | 8 | 9 |
| B₂O₃ | 3 | 3 | 4 | 4 | 4 | 3 | 3 |
| MgO | 20 | 18 | 19 | 19 | 19 | 20 | 20 |
| CaO | 5 | 5 | 5 | 4 | 4 | 5 | 4 |
| SrO | 3 | 3 | 4 | 5 | 4 | 4 | 4 |
| BaO | 4 | 4 | 4 | 3 | 3 | 3 | 3 |
| Li₂O | | | | | | | |
| Na₂O | | | | | | | |
| K₂O | | | | | | | |
| ZnO | 5 | 6 | 5 | 5 | 5 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | 2 | 2 | | 2 | 2 |
| Gd₂O₃ | | | | | | | |
| La₂O₃ | | 2 | | | 2 | | |
| WO₃ | | | | | | | |
| Ta₂O₅ | | | | | | | |
| Al₂O₃ + rare earth oxide | 11 | 10 | 10 | 10 | 11 | 10 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.49 | 0.47 | 0.49 | 0.48 | 0.48 | 0.48 | 0.48 |
| (Al₂O₃ + MgO)/(SiO₂ + Al₂O₃ + B₂O₃ + MgO) | 0.37 | 0.33 | 0.35 | 0.34 | 0.35 | 0.35 | 0.36 |
| MgO/ΣRO | 0.54 | 0.50 | 0.51 | 0.53 | 0.54 | 0.54 | 0.56 |
| N | 11 | 11 | 11 | 11 | 11 | 11 | 11 |
| Young's modulus E (GPa) | 100 | 98 | 98 | 98 | 99 | 99 | 100 |
| Coefficient of thermal expansion α (ppm/° C.) | 5.64 | 5.72 | 5.77 | 5.65 | 5.63 | 5.66 | 5.52 |
| Liquidus temperature TL (° C.) | 1224 | 1220 | 1224 | 1223 | 1223 | 1223 | 1223 |
| Young's modulus parameter Y | 1.00 | 0.98 | 0.98 | 0.99 | 0.99 | 1.00 | 1.01 |
| Liquidus parameter L | 9.7 | 9.5 | 9.4 | 9.2 | 9.2 | 9.4 | 9.5 |
| Thermal expansion parameter C | 1.14 | 1.13 | 1.16 | 1.14 | 1.12 | 1.14 | 1.11 |
| Glass transition point (° C.) | 719 | 717 | 710 | 709 | 712 | 713 | 716 |
| Density (g/cm³) | 3.12 | 3.21 | 3.13 | 3.10 | 3.16 | 3.10 | 3.10 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.22 | 0.29 | 0.19 | 0.28 | 0.28 | 0.31 | 0.32 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 68

| | Example | Example | Example | Example | Exampla | Example | Example |
|---|---|---|---|---|---|---|---|
| (mol %) | 475 | 476 | 477 | 478 | 479 | 480 | 481 |
| SiO₂ | 49 | 49 | 48 | 48 | 48 | 47 | 48 |
| Al₂O₃ | 9 | 8 | 8 | 7 | 8 | 9 | 9 |
| B₂O₃ | 3 | 3 | 4 | 3 | 4 | 4 | 4 |
| MgO | 18 | 19 | 18 | 19 | 18 | 19 | 18 |
| CaO | 5 | 5 | 5 | 4 | 5 | 4 | 5 |
| SrO | 3 | 4 | 4 | 5 | 3 | 3 | 3 |
| BaO | 4 | 3 | 3 | 4 | 4 | 4 | 4 |
| Li₂O | | | | | | | |
| Na₂O | | | | | | | |
| K₂O | | | | | | | |
| ZnO | 5 | 5 | 6 | 6 | 6 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | 2 | | | |
| Gd₂O₃ | | | | | | | |
| La₂O₃ | 2 | 2 | 2 | | 2 | 2 | 2 |
| WO₃ | | | | | | | |
| Ta₂O₅ | | | | | | | |
| Al₂O₃ + rare earth oxide | 11 | 10 | 10 | 9 | 10 | 11 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.47 | 0.48 | 0.48 | 0.48 | 0.49 | 0.48 |
| (Al₂O₃ + MgO)/(SiO₂ + Al₂O₃ + B₂O₃ + MgO) | 0.34 | 0.34 | 0.33 | 0.34 | 0.33 | 0.35 | 0.34 |
| MgO/ΣRO | 0.51 | 0.53 | 0.50 | 0.50 | 0.50 | 0.53 | 0.51 |
| N | 11 | 11 | 11 | 11 | 11 | 11 | 11 |
| Young's modulus E (GPa) | 98 | 99 | 98 | 98 | 98 | 99 | 98 |
| Coefficient of thermal expansion α (ppm/° C.) | 5.66 | 5.74 | 5.74 | 5.86 | 5.74 | 5.67 | 5.68 |
| Liquidus temperature TL (° C.) | 1223 | 1223 | 1219 | 1223 | 1220 | 1223 | 1223 |
| Young's modulus parameter Y | 0.98 | 0.99 | 0.98 | 0.99 | 0.97 | 0.98 | 0.97 |
| Liquidus parameter L | 9.6 | 9.2 | 9.1 | 9.2 | 9.3 | 9.4 | 9.5 |
| Thermal expansion parameter C | 1.12 | 1.14 | 1.15 | 1.18 | 1.14 | 1.12 | 1.13 |
| Glass transition point (° C.) | 719 | 713 | 709 | 714 | 713 | 715 | 715 |
| Density (g/cm³) | 3.19 | 3.17 | 3.19 | 3.17 | 3.21 | 3.22 | 3.18 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.31 | 0.34 | 0.22 | 0.24 | 0.22 | 0.18 | 0.23 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 69

| | Example | Example | Example | Example | Example | Example | Example |
|---|---|---|---|---|---|---|---|
| (mol %) | 482 | 483 | 484 | 485 | 486 | 487 | 488 |
| SiO₂ | 48 | 49 | 47 | 47 | 47 | 48 | 47 |
| Al₂O₃ | 9 | 8 | 9 | 9 | 8 | 9 | 9 |
| B₂O₃ | 3 | 3 | 4 | 4 | 4 | 3 | 4 |
| MgO | 18 | 19 | 18 | 20 | 19 | 18 | 18 |
| CaO | 5 | 4 | 5 | 5 | 4 | 4 | 5 |
| SrO | 4 | 3 | 4 | 4 | 4 | 4 | 4 |
| BaO | 3 | 4 | 3 | 3 | 4 | 4 | 4 |
| Li₂O | | | | | | | |
| Na₂O | | | | | | | |
| K₂O | | | | | | | |
| ZnO | 6 | 6 | 6 | 4 | 6 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | 2 | 2 | 2 | 2 |
| Gd₂O₃ | | 2 | | | | | |
| La₂O₃ | 2 | | 2 | | | | |
| WO₃ | | | | | | | |
| Ta₂O₅ | | | | | | | |
| Al₂O₃ + rare earth oxide | 11 | 10 | 11 | 11 | 10 | 11 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.49 | 0.49 | 0.49 | 0.48 | 0.49 |
| (Al₂O₃ + MgO)/(SiO₂ + Al₂O₃ + B₂O₃ + MgO) | 0.35 | 0.34 | 0.35 | 0.36 | 0.35 | 0.35 | 0.35 |
| MgO/ΣRO | 0.50 | 0.53 | 0.50 | 0.56 | 0.51 | 0.50 | 0.50 |
| N | 11 | 11 | 11 | 11 | 11 | 11 | 11 |
| Young's modulus E (GPa) | 99 | 98 | 99 | 99 | 98 | 99 | 98 |
| Coefficient of thermal expansion α (ppm/° C.) | 5.70 | 5.74 | 5.72 | 5.61 | 5.70 | 5.60 | 5.69 |
| Liquidus temperature TL (° C.) | 1223 | 1218 | 1223 | 1223 | 1223 | 1223 | 1223 |
| Young's modulus parameter Y | 1.00 | 0.98 | 0.99 | 1.00 | 0.98 | 0.99 | 0.98 |
| Liquidus parameter L | 9.3 | 9.4 | 9.2 | 9.4 | 9.3 | 9.7 | 9.6 |
| Thermal expansion parameter C | 1.14 | 1.12 | 1.14 | 1.14 | 1.15 | 1.13 | 1.15 |
| Glass transition point (° C.) | 716 | 717 | 711 | 711 | 711 | 717 | 712 |
| Density (g/cm³) | 3.20 | 3.23 | 3.20 | 3.07 | 3.15 | 3.16 | 3.13 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.21 | 0.22 | 0.14 | 0.25 | 0.18 | 0.23 | 0.16 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 70

| | Example | Example | Example | Example | Example | Example | Example |
|---|---|---|---|---|---|---|---|
| (mol %) | 489 | 490 | 491 | 492 | 493 | 494 | 495 |
| SiO₂ | 48 | 48 | 48 | 49 | 48 | 48 | 49 |
| Al₂O₃ | 8 | 9 | 8 | 8 | 9 | 8 | 8 |
| B₂O₃ | 4 | 4 | 4 | 4 | 3 | 4 | 3 |
| MgO | 20 | 18 | 18 | 19 | 19 | 19 | 20 |
| CaO | 5 | 4 | 5 | 4 | 5 | 4 | 5 |
| SrO | 3 | 3 | 4 | 5 | 4 | 3 | 3 |
| BaO | 3 | 4 | 4 | 3 | 3 | 4 | 3 |
| Li₂O | | | | | | | |
| Na₂O | | | | | | | |
| K₂O | | | | | | | |
| ZnO | 5 | 4 | 5 | 4 | 5 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | 2 | | 2 | 2 | | |
| Gd₂O₃ | | | | | | 2 | |
| La₂O₃ | 2 | 2 | 2 | | | | 2 |
| WO₃ | | | | | | | |
| Ta₂O₅ | | | | | | | |
| Al₂O₃ + rare earth oxide | 10 | 13 | 10 | 10 | 11 | 10 | 10 |
| Y₂O₃ + Gd₂O₃ + La₂O₃ + Nd₂O₃ + Ta₂O₅ + Nb₂O₅ | 2 | 4 | 2 | 2 | 2 | 2 | 2 |
| Parameter A = (Al₂O₃ + RO)/(SiO₂ + Al₂O₃ + RO) | 0.48 | 0.47 | 0.48 | 0.47 | 0.48 | 0.48 | 0.47 |
| (Al₂O₃ + MgO)/(SiO₂ + Al₂O₃ + B₂O₃ + MgO) | 0.35 | 0.34 | 0.33 | 0.34 | 0.35 | 0.34 | 0.35 |
| MgO/ΣRO | 0.56 | 0.55 | 0.50 | 0.54 | 0.53 | 0.53 | 0.56 |
| N | 11 | 12 | 11 | 11 | 11 | 11 | 11 |
| Young's modulus E (GPa) | 99 | 100 | 97 | 98 | 100 | 98 | 99 |
| Coefficient of thermal expansion α (ppm/° C.) | 5.66 | 5.75 | 5.86 | 5.61 | 5.57 | 5.78 | 5.65 |
| Liquidus temperature TL (° C.) | 1223 | 1214 | 1223 | 1223 | 1223 | 1219 | 1223 |
| Young's modulus parameter Y | 0.99 | 1.01 | 0.97 | 0.98 | 1.00 | 0.97 | 0.99 |
| Liquidus parameter L | 9.2 | 9.5 | 9.2 | 9.3 | 9.5 | 9.3 | 9.3 |
| Thermal expansion parameter C | 1.13 | 1.15 | 1.16 | 1.13 | 1.13 | 1.13 | 1.12 |
| Glass transition point (° C.) | 712 | 715 | 710 | 709 | 716 | 712 | 716 |
| Density (g/cm³) | 3.15 | 3.26 | 3.20 | 3.07 | 3.10 | 3.22 | 3.15 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.31 | 0.25 | 0.22 | 0.38 | 0.28 | 0.14 | 0.38 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 71

| | Example | Example | Example | Example | Example | Example | Example |
|---|---|---|---|---|---|---|---|
| (mol %) | 496 | 497 | 498 | 499 | 500 | 501 | 502 |
| SiO₂ | 47 | 49 | 49 | 49 | 48 | 49 | 49 |
| Al₂O₃ | 9 | 8 | 8 | 9 | 9 | 8 | 8 |
| B₂O₃ | 3 | 3 | 4 | 3 | 3 | 4 | 4 |
| MgO | 19 | 20 | 18 | 18 | 18 | 18 | 18 |
| CaO | 5 | 5 | 5 | 5 | 5 | 5 | 4 |
| SrO | 4 | 4 | 4 | 4 | 3 | 3 | 3 |
| BaO | 3 | 3 | 3 | 3 | 4 | 4 | 4 |
| Li₂O | | | | | | | |
| Na₂O | | | | | | | |
| K₂O | | | | | | | |
| ZnO | 6 | 4 | 5 | 5 | 6 | 5 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | | | | | 2 |
| Gd₂O₃ | | | 2 | | | 2 | |
| La₂O₃ | | | | 2 | 2 | | 2 |
| WO₃ | | | | | | | |
| Ta₂O₅ | | | | | | | |
| Al₂O₃ + rare earth oxide | 11 | 10 | 10 | 11 | 11 | 10 | 12 |
| Y₂O₃ + Gd₂O₃ + La₂O₃ + Nd₂O₃ + Ta₂O₅ + Nb₂O₅ | 2 | 2 | 2 | 2 | 2 | 2 | 4 |
| Parameter A = (Al₂O₃ + RO)/(SiO₂ + Al₂O₃ + RO) | 0.49 | 0.47 | 0.47 | 0.47 | 0.48 | 0.47 | 0.46 |
| (Al₂O₃ + MgO)/(SiO₂ + Al₂O₃ + B₂O₃ + MgO) | 0.36 | 0.35 | 0.33 | 0.34 | 0.35 | 0.33 | 0.33 |
| MgO/ΣRO | 0.51 | 0.56 | 0.51 | 0.51 | 0.50 | 0.51 | 0.55 |
| N | 11 | 11 | 11 | 11 | 11 | 11 | 12 |
| Young's modulus E (GPa) | 100 | 99 | 98 | 99 | 99 | 97 | 98 |
| Coefficient of thermal expansion α (ppm/° C.) | 5.62 | 5.61 | 5.76 | 5.66 | 5.71 | 5.77 | 5.77 |
| Liquidus temperature TL (° C.) | 1223 | 1222 | 1218 | 1222 | 1222 | 1218 | 1211 |
| Young's modulus parameter Y | 1.01 | 1.00 | 0.97 | 0.99 | 0.98 | 0.96 | 1.00 |
| Liquidus parameter L | 9.5 | 9.4 | 9.2 | 9.4 | 9.6 | 9.4 | 9.4 |
| Thermal expansion parameter C | 1.14 | 1.13 | 1.13 | 1.13 | 1.13 | 1.13 | 1.15 |
| Glass transition point (° C.) | 716 | 713 | 709 | 715 | 719 | 711 | 713 |
| Density (g/cm³) | 3.13 | 3.06 | 3.17 | 3.17 | 3.22 | 3.19 | 3.25 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.18 | 0.40 | 0.20 | 0.31 | 0.21 | 0.20 | 0.34 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 72

| | Example | Example | Example | Example | Example | Example | Example |
|---|---|---|---|---|---|---|---|
| (mol %) | 503 | 504 | 505 | 506 | 507 | 508 | 509 |
| SiO₂ | 47 | 48 | 47 | 49 | 49 | 48 | 48 |
| Al₂O₃ | 9 | 8 | 8 | 7 | 9 | 9 | 9 |
| B₂O₃ | 4 | 3 | 4 | 3 | 4 | 4 | 4 |
| MgO | 20 | 19 | 19 | 19 | 18 | 19 | 18 |
| CaO | 4 | 5 | 5 | 5 | 4 | 4 | 5 |
| SrO | 4 | 4 | 4 | 4 | 5 | 3 | 4 |
| BaO | 3 | 3 | 3 | 4 | 3 | 4 | 3 |
| Li₂O | | | | | | | |
| Na₂O | | | | | | | |
| K₂O | | | | | | | |
| ZnO | 5 | 6 | 6 | 5 | 4 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | | 2 | 2 | | |
| Gd₂O₃ | | | | | | | |
| La₂O₃ | | 2 | 2 | | | 2 | 2 |
| WO₃ | | | | | | | |
| Ta₂O₅ | | | | | | | |
| Al₂O₃ + rare earth oxide | 11 | 10 | 10 | 9 | 11 | 11 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.49 | 0.48 | 0.49 | 0.47 | 0.47 | 0.48 | 0.48 |
| (Al₂O₃ + MgO)/(SiO₂ + Al₂O₃ + B₂O₃ + MgO) | 0.36 | 0.35 | 0.35 | 0.33 | 0.34 | 0.35 | 0.34 |
| MgO/ΣRO | 0.56 | 0.51 | 0.51 | 0.51 | 0.53 | 0.54 | 0.51 |
| N | 11 | 11 | 11 | 11 | 11 | 11 | 11 |
| Young's modulus E (GPa) | 100 | 99 | 99 | 98 | 98 | 98 | 99 |
| Coefficient of thermal expansion α (ppm/° C.) | 5.54 | 5.79 | 5.80 | 5.77 | 5.53 | 5.63 | 5.68 |
| Liquidus temperature TL (° C.) | 1222 | 1222 | 1222 | 1215 | 1222 | 1222 | 1222 |
| Young's modulus parameter Y | 1.00 | 0.99 | 0.99 | 0.98 | 0.98 | 0.98 | 0.98 |
| Liquidus parameter L | 9.3 | 9.2 | 9.0 | 9.4 | 9.4 | 9.4 | 9.3 |
| Thermal expansion parameter C | 1.12 | 1.16 | 1.16 | 1.16 | 1.11 | 1.11 | 1.13 |
| Glass transition point (° C.) | 711 | 714 | 710 | 714 | 710 | 715 | 711 |
| Density (g/cm³) | 3.09 | 3.20 | 3.20 | 3.12 | 3.07 | 3.18 | 3.17 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.24 | 0.24 | 0.16 | 0.34 | 0.35 | 0.28 | 0.23 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 73

| | Example | Example | Example | Example | Example | Example | Example |
|---|---|---|---|---|---|---|---|
| (mol %) | 510 | 511 | 512 | 513 | 514 | 515 | 516 |
| SiO₂ | 49 | 49 | 48 | 48 | 49 | 47 | 49 |
| Al₂O₃ | 8 | 9 | 8 | 9 | 8 | 8 | 8 |
| B₂O₃ | 3 | 3 | 3 | 3 | 4 | 4 | 4 |
| MgO | 18 | 19 | 18 | 18 | 20 | 20 | 18 |
| CaO | 5 | 5 | 5 | 4 | 4 | 5 | 4 |
| SrO | 4 | 3 | 4 | 3 | 3 | 4 | 5 |
| BaO | 4 | 3 | 4 | 4 | 3 | 3 | 3 |
| Li₂O | | | | | | | |
| Na₂O | | | | | | | |
| K₂O | | | | | | | |
| ZnO | 5 | 5 | 6 | 5 | 5 | 5 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | 2 | | 2 | |
| Gd₂O₃ | | | | | | | |
| La₂O₃ | 2 | 2 | 2 | 2 | 2 | | 2 |
| WO₃ | | | | | | | |
| Ta₂O₅ | | | | | | | |
| Al₂O₃ + rare earth oxide | 10 | 11 | 10 | 13 | 10 | 10 | 10 |
| Y₂O₃ + Gd₂O₃ + La₂O₃ + Nd₂O₃ + Ta₂O₅ + Nb₂O₅ | 2 | 2 | 2 | 4 | 2 | 2 | 2 |
| Parameter A = (Al₂O₃ + RO)/(SiO₂ + Al₂O₃ + RO) | 0.47 | 0.47 | 0.48 | 0.47 | 0.47 | 0.49 | 0.47 |
| (Al₂O₃ + MgO)/(SiO₂ + Al₂O₃ + B₂O₃ + MgO) | 0.33 | 0.35 | 0.34 | 0.35 | 0.35 | 0.35 | 0.33 |
| MgO/ΣRO | 0.50 | 0.54 | 0.49 | 0.53 | 0.57 | 0.54 | 0.51 |
| N | 11 | 11 | 11 | 12 | 11 | 11 | 11 |
| Young's modulus E (GPa) | 98 | 99 | 98 | 101 | 98 | 99 | 97 |
| Coefficient of thermal expansion α (ppm/° C.) | 5.85 | 5.56 | 5.89 | 5.78 | 5.54 | 5.67 | 5.74 |
| Liquidus temperature TL (° C.) | 1222 | 1222 | 1222 | 1219 | 1222 | 1222 | 1222 |
| Young's modulus parameter Y | 0.97 | 0.99 | 0.98 | 1.02 | 0.98 | 0.99 | 0.98 |
| Liquidus parameter L | 9.4 | 9.5 | 9.3 | 9.5 | 9.2 | 9.2 | 9.0 |
| Thermal expansion parameter C | 1.16 | 1.11 | 1.17 | 1.16 | 1.10 | 1.15 | 1.14 |
| Glass transition point (° C.) | 714 | 718 | 714 | 719 | 712 | 709 | 709 |
| Density (g/cm³) | 3.20 | 3.15 | 3.24 | 3.30 | 3.14 | 3.10 | 3.17 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.29 | 0.36 | 0.19 | 0.23 | 0.40 | 0.23 | 0.31 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 74

| | Example | Example | Example | Example | Example | Example | Example |
|---|---|---|---|---|---|---|---|
| (mol %) | 517 | 518 | 519 | 520 | 521 | 522 | 523 |
| SiO₂ | 47 | 49 | 48 | 49 | 48 | 49 | 49 |
| Al₂O₃ | 9 | 8 | 8 | 8 | 9 | 8 | 8 |
| B₂O₃ | 4 | 3 | 4 | 3 | 3 | 3 | 3 |
| MgO | 18 | 19 | 19 | 18 | 20 | 18 | 18 |
| CaO | 4 | 5 | 5 | 5 | 5 | 5 | 4 |
| SrO | 4 | 3 | 4 | 4 | 3 | 3 | 5 |
| BaO | 4 | 4 | 4 | 3 | 4 | 4 | 3 |
| Li₂O | | | | | | | |
| Na₂O | | | | | | | |
| K₂O | | | | | | | |
| ZnO | 6 | 5 | 4 | 6 | 4 | 6 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | | 2 | | 2 | | 2 |
| Gd₂O₃ | | | | 2 | | 2 | |
| La₂O₃ | | 2 | | | | | |
| WO₃ | | | | | | | |
| Ta₂O₅ | | | | | | | |
| Al₂O₃ + rare earth oxide | 11 | 10 | 10 | 10 | 11 | 10 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.49 | 0.47 | 0.48 | 0.47 | 0.48 | 0.47 | 0.47 |
| (Al₂O₃ + MgO)/(SiO₂ + Al₂O₃ + B₂O₃ + MgO) | 0.35 | 0.34 | 0.34 | 0.33 | 0.36 | 0.33 | 0.33 |
| MgO/ΣRO | 0.50 | 0.53 | 0.53 | 0.50 | 0.56 | 0.50 | 0.50 |
| N | 11 | 11 | 11 | 11 | 11 | 11 | 11 |
| Young's modulus E (GPa) | 99 | 98 | 98 | 98 | 99 | 98 | 98 |
| Coefficient of thermal expansion α (ppm/° C.) | 5.62 | 5.75 | 5.73 | 5.79 | 5.60 | 5.80 | 5.61 |
| Liquidus temperature TL (° C.) | 1222 | 1222 | 1222 | 1218 | 1222 | 1217 | 1222 |
| Young's modulus parameter Y | 0.98 | 0.98 | 0.97 | 0.99 | 0.99 | 0.98 | 0.99 |
| Liquidus parameter L | 9.5 | 9.5 | 9.5 | 9.2 | 9.8 | 9.5 | 9.3 |
| Thermal expansion parameter C | 1.13 | 1.14 | 1.15 | 1.14 | 1.12 | 1.13 | 1.13 |
| Glass transition point (° C.) | 712 | 717 | 710 | 714 | 719 | 716 | 713 |
| Density (g/cm³) | 3.15 | 3.19 | 3.09 | 3.21 | 3.09 | 3.23 | 3.13 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.16 | 0.34 | 0.28 | 0.18 | 0.32 | 0.18 | 0.31 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 75

| | Exampla | Example | Example | Example | Example | Example | Example |
|---|---|---|---|---|---|---|---|
| (mol %) | 524 | 525 | 526 | 527 | 528 | 529 | 530 |
| SiO₂ | 48 | 49 | 48 | 49 | 48 | 49 | 48 |
| Al₂O₃ | 8 | 7 | 8 | 7 | 9 | 9 | 8 |
| B₂O₃ | 4 | 3 | 4 | 3 | 3 | 3 | 4 |
| MgO | 19 | 18 | 18 | 20 | 19 | 19 | 19 |
| CaO | 4 | 4 | 4 | 5 | 4 | 5 | 5 |
| SrO | 4 | 5 | 5 | 4 | 3 | 4 | 4 |
| BaO | 4 | 4 | 3 | 4 | 4 | 3 | 3 |
| Li₂O | | | | | | | |
| Na₂O | | | | | | | |
| K₂O | | | | | | | |
| ZnO | 5 | 6 | 6 | 4 | 6 | 4 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | 2 | 2 | | 2 | |
| Gd₂O₃ | | | | | | | |
| La₂O₃ | | | | | 2 | | 2 |
| WO₃ | | | | | | | |
| Ta₂O₅ | | | | | | | |
| Al₂O₃ + rare earth oxide | 10 | 9 | 10 | 9 | 11 | 11 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.48 | 0.47 | 0.48 | 0.47 | 0.48 |
| (Al₂O₃ + MgO)/(SiO₂ + Al₂O₃ + B₂O₃ + MgO) | 0.34 | 0.32 | 0.33 | 0.34 | 0.35 | 0.35 | 0.34 |
| MgO/ΣRO | 0.53 | 0.49 | 0.50 | 0.54 | 0.53 | 0.54 | 0.53 |
| N | 11 | 11 | 11 | 11 | 11 | 11 | 11 |
| Young's modulus E (GPa) | 98 | 97 | 98 | 98 | 99 | 99 | 98 |
| Coefficient of thermal expansion α (ppm/° C.) | 5.66 | 5.80 | 5.63 | 5.80 | 5.66 | 5.53 | 5.76 |
| Liquidus temperature TL (° C.) | 1222 | 1218 | 1222 | 1219 | 1222 | 1222 | 1222 |
| Young's modulus parameter Y | 0.98 | 0.98 | 0.99 | 0.98 | 0.99 | 1.00 | 0.98 |
| Liquidus parameter L | 9.4 | 9.3 | 9.2 | 9.4 | 9.5 | 9.6 | 9.1 |
| Thermal expansion parameter C | 1.13 | 1.16 | 1.14 | 1.16 | 1.12 | 1.12 | 1.15 |
| Glass transition point (° C.) | 711 | 714 | 709 | 714 | 719 | 715 | 709 |
| Density (g/cm³) | 3.12 | 3.16 | 3.13 | 3.10 | 3.22 | 3.06 | 3.17 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.28 | 0.30 | 0.24 | 0.39 | 0.25 | 0.38 | 0.26 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 76

| | Example | Example | Example | Example | Example | Example | Example |
|---|---|---|---|---|---|---|---|
| (mol %) | 531 | 532 | 533 | 534 | 535 | 536 | 537 |
| SiO₂ | 49 | 49 | 49 | 48 | 48 | 48 | 49 |
| Al₂O₃ | 7 | 9 | 7 | 8 | 9 | 8 | 8 |
| B₂O₃ | 3 | 3 | 3 | 4 | 4 | 4 | 3 |
| MgO | 19 | 18 | 19 | 18 | 18 | 18 | 19 |
| CaO | 5 | 5 | 5 | 4 | 4 | 5 | 4 |
| SrO | 4 | 4 | 3 | 4 | 3 | 4 | 4 |
| BaO | 3 | 4 | 4 | 4 | 4 | 3 | 4 |
| Li₂O | | | | | | | |
| Na₂O | | | | | | | |
| K₂O | | | | | | | |
| ZnO | 6 | 4 | 6 | 6 | 6 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | 2 | | | | | 2 |
| Gd₂O₃ | | | | | | 2 | |
| La₂O₃ | 2 | | 2 | 2 | 2 | | |
| WO₃ | | | | | | | |
| Ta₂O₅ | | | | | | | |
| Al₂O₃ + rare earth oxide | 9 | 11 | 9 | 10 | 11 | 10 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.47 | 0.47 | 0.48 | 0.48 | 0.48 | 0.47 |
| (Al₂O₃ + MgO)/(SiO₂ + Al₂O₃ + B₂O₃ + MgO) | 0.33 | 0.34 | 0.33 | 0.33 | 0.34 | 0.33 | 0.34 |
| MgO/ΣRO | 0.51 | 0.51 | 0.51 | 0.50 | 0.51 | 0.50 | 0.53 |
| N | 11 | 11 | 11 | 11 | 11 | 11 | 11 |
| Young's modulus E (GPa) | 98 | 98 | 98 | 98 | 98 | 98 | 98 |
| Coefficient of thermal expansion α (ppm/° C.) | 5.80 | 5.63 | 5.81 | 5.79 | 5.61 | 5.81 | 5.64 |
| Liquidus temperature TL (° C.) | 1216 | 1222 | 1215 | 1222 | 1222 | 1219 | 1222 |
| Young's modulus parameter Y | 0.99 | 0.98 | 0.98 | 0.97 | 0.98 | 0.98 | 0.98 |
| Liquidus parameter L | 9.1 | 9.8 | 9.3 | 9.2 | 9.4 | 9.1 | 9.6 |
| Thermal expansion parameter C | 1.16 | 1.13 | 1.15 | 1.15 | 1.11 | 1.15 | 1.13 |
| Glass transition point (° C.) | 713 | 716 | 717 | 711 | 715 | 709 | 715 |
| Density (g/cm³) | 3.19 | 3.10 | 3.21 | 3.22 | 3.21 | 3.21 | 3.12 |
| Liquidus viscosity log η_{L}(dPa · s) | 2< | 2< | 2< | 2< | 2< | 2< | 2< |
| K_{IC} (MPa · m^{0.5}) | 0.8 | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.32 | 0.33 | 0.32 | 0.21 | 0.23 | 0.10 | 0.36 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 77

| | Example | Example | Example | Example | Example | Example | Example |
|---|---|---|---|---|---|---|---|
| (mol %) | 538 | 539 | 540 | 541 | 542 | 543 | 544 |
| SiO₂ | 48 | 48 | 49 | 48 | 49 | 48 | 49 |
| Al₂O₃ | 9 | 8 | 8 | 8 | 8 | 7 | 8 |
| B₂O₃ | 4 | 4 | 4 | 4 | 3 | 3 | 3 |
| MgO | 18 | 18 | 18 | 18 | 19 | 19 | 19 |
| CaO | 5 | 5 | 5 | 4 | 4 | 5 | 5 |
| SrO | 4 | 3 | 3 | 3 | 4 | 4 | 3 |
| BaO | 4 | 4 | 4 | 4 | 3 | 4 | 4 |
| Li₂O | | | | | | | |
| Na₂O | | | | | | | |
| K₂O | | | | | | | |
| ZnO | 4 | 6 | 5 | 6 | 6 | 6 | 5 |
| P₂O₅ | | | | | | | |
| ZrO₂ | 1 | 1 | | 1 | 1 | 1 | 1 |
| TiO₂ | 1 | 1 | | 1 | 1 | 1 | 1 |
| Y₂O₃ | 2 | | 2 | 2 | | 2 | |
| Gd₂O₃ | | 2 | | | | | 2 |
| La₂O₃ | | | 2 | 2 | 2 | | |
| WO₃ | | | | | | | |
| Ta₂O₅ | | | | | | | |
| Al₂O₃ + rare earth oxide | 11 | 10 | 12 | 12 | 10 | 9 | 10 |
| Y₂O₃ + Gd₂O₃ + La₂O₃ + Nd₂O₃ + Ta₂O₅ + Nb₂O₅ | 2 | 2 | 4 | 4 | 2 | 2 | 2 |
| Parameter A = (Al₂O₃ + RO)/(SiO₂ + Al₂O₃ + RO) | 0.48 | 0.48 | 0.47 | 0.47 | 0.47 | 0.48 | 0.47 |
| (Al₂O₃ + MgO)/(SiO₂ + Al₂O₃ + B₂O₃ + MgO) | 0.34 | 0.33 | 0.33 | 0.33 | 0.34 | 0.34 | 0.34 |
| MgO/ΣRO | 0.51 | 0.50 | 0.51 | 0.53 | 0.53 | 0.50 | 0.53 |
| N | 11 | 11 | 10 | 12 | 11 | 11 | 11 |
| Young's modulus E (GPa) | 98 | 98 | 98 | 100 | 99 | 98 | 98 |
| Coefficient of thermal expansion α (ppm/° C.) | 5.65 | 5.81 | 5.81 | 5.81 | 5.67 | 5.82 | 5.82 |
| Liquidus temperature TL (° C.) | 1222 | 1219 | 1206 | 1215 | 1222 | 1217 | 1220 |
| Young's modulus parameter Y | 0.98 | 0.97 | 0.98 | 1.00 | 0.99 | 0.98 | 0.98 |
| Liquidus parameter L | 9.6 | 9.3 | 9.1 | 9.3 | 9.2 | 9.4 | 9.5 |
| Thermal expansion parameter C | 1.13 | 1.14 | 1.16 | 1.16 | 1.13 | 1.17 | 1.14 |
| Glass transition point (° C.) | 712 | 711 | 710 | 713 | 714 | 714 | 716 |
| Density (g/cm³) | 3.10 | 3.23 | 3.27 | 3.29 | 3.19 | 3.16 | 3.20 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.10 | 0.04 | 0.24 | 0.34 | 0.25 | 0.22 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 78

| | Example | Example | Example | Example | Example | Example | Example |
|---|---|---|---|---|---|---|---|
| (mol %) | 545 | 546 | 547 | 548 | 549 | 550 | 551 |
| SiO₂ | 47 | 48 | 49 | 47 | 47 | 47 | 48 |
| Al₂O₃ | 9 | 8 | 8 | 9 | 8 | 9 | 8 |
| B₂O₃ | 3 | 4 | 3 | 4 | 4 | 3 | 4 |
| MgO | 19 | 20 | 19 | 19 | 19 | 18 | 20 |
| CaO | 4 | 5 | 4 | 4 | 5 | 4 | 4 |
| SrO | 3 | 4 | 3 | 3 | 3 | 3 | 4 |
| BaO | 4 | 3 | 4 | 4 | 4 | 4 | 3 |
| Li₂O | | | | | | | |
| Na₂O | | | | | | | |
| K₂O | | | | | | | |
| ZnO | 5 | 4 | 4 | 4 | 6 | 6 | 5 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | 2 | 2 | | 2 | 2 |
| Gd₂O₃ | | | | | | | |
| La₂O₃ | 2 | | 2 | 2 | 2 | 2 | |
| WO₃ | | | | | | | |
| Ta₂O₅ | | | | | | | |
| Al₂O₃ + rare earth oxide | 13 | 10 | 12 | 13 | 10 | 13 | 10 |
| Y₂O₃ + Gd₂O₃ + La₂O₃ + Nd₂O₃ + Ta₂O₅ + Nb₂O₅ | 4 | 2 | 4 | 4 | 2 | 4 | 2 |
| Parameter A = (Al₂O₃ + RO)/(SiO₂ + Al₂O₃ + RO) | 0.48 | 0.48 | 0.46 | 0.48 | 0.49 | 0.48 | 0.48 |
| (Al₂O₃ + MgO)/(SiO₂ + Al₂O₃ + B₂O₃ + MgO) | 0.36 | 0.35 | 0.34 | 0.35 | 0.35 | 0.35 | 0.35 |
| MgO/ΣRO | 0.54 | 0.56 | 0.56 | 0.56 | 0.51 | 0.51 | 0.56 |
| N | 12 | 11 | 12 | 12 | 11 | 12 | 11 |
| Young's modulus E (GPa) | 102 | 99 | 100 | 101 | 99 | 102 | 99 |
| Coefficient of thermal expansion α (ppm/° C.) | 5.85 | 5.63 | 5.82 | 5.82 | 5.81 | 5.83 | 5.55 |
| Liquidus temperature TL (° C.) | 1221 | 1221 | 1218 | 1217 | 1221 | 1220 | 1221 |
| Young's modulus parameter Y | 1.03 | 0.99 | 1.01 | 1.01 | 0.98 | 1.02 | 0.99 |
| Liquidus parameter L | 9.5 | 9.3 | 9.4 | 9.4 | 9.3 | 9.5 | 9.3 |
| Thermal expansion parameter C | 1.17 | 1.14 | 1.16 | 1.17 | 1.15 | 1.17 | 1.12 |
| Glass transition point (° C.) | 719 | 709 | 717 | 715 | 713 | 719 | 709 |
| Density (g/cm³) | 3.31 | 3.06 | 3.26 | 3.27 | 3.22 | 3.33 | 3.08 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.17 | 0.33 | 0.36 | 0.20 | 0.16 | 0.13 | 0.33 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 79

| | Example | Example | Example | Example | Example | Example | Example |
|---|---|---|---|---|---|---|---|
| (mol %) | 552 | 553 | 554 | 555 | 556 | 557 | 558 |
| SiO₂ | 49 | 49 | 48 | 49 | 48 | 49 | 48 |
| Al₂O₃ | 7 | 9 | 8 | 7 | 8 | 9 | 8 |
| B₂O₃ | 3 | 3 | 3 | 3 | 3 | 4 | 4 |
| MgO | 20 | 18 | 20 | 20 | 18 | 18 | 19 |
| CaO | 5 | 4 | 5 | 5 | 5 | 4 | 4 |
| SrO | 4 | 3 | 3 | 3 | 4 | 3 | 3 |
| BaO | 3 | 4 | 4 | 4 | 4 | 4 | 4 |
| Li₂O | | | | | | | |
| Na₂O | | | | | | | |
| K₂O | | | | | | | |
| ZnO | 5 | 6 | 5 | 5 | 6 | 5 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | 2 | | 2 | | 2 |
| Gd₂O₃ | | | | | | | |
| La₂O₃ | 2 | 2 | | 2 | | 2 | 2 |
| WO₃ | | | | | | | |
| Ta₂O₅ | | | | | | | |
| Al₂O₃ + rare earth oxide | 9 | 11 | 10 | 9 | 10 | 11 | 12 |
| Y₂O₃ + Gd₂O₃ + La₂O₃ + Nd₂O₃ + Ta₂O₅ + Nb₂O₅ | 2 | 2 | 2 | 2 | 2 | 2 | 4 |
| Parameter A = (Al₂O₃ + RO)/(SiO₂ + Al₂O₃ + RO) | 0.47 | 0.47 | 0.48 | 0.47 | 0.48 | 0.47 | 0.47 |
| (Al₂O₃ + MgO)/(SiO₂ + Al₂O₃ + B₂O₃ + MgO) | 0.34 | 0.34 | 0.35 | 0.34 | 0.34 | 0.34 | 0.34 |
| MgO/ΣRO | 0.54 | 0.51 | 0.54 | 0.54 | 0.49 | 0.53 | 0.56 |
| N | 11 | 11 | 11 | 11 | 11 | 11 | 12 |
| Young's modulus E (GPa) | 98 | 99 | 99 | 98 | 98 | 98 | 100 |
| Coefficient of thermal expansion α (ppm/° C.) | 5.83 | 5.59 | 5.66 | 5.83 | 5.73 | 5.56 | 5.84 |
| Liquidus temperature TL (° C.) | 1218 | 1221 | 1221 | 1219 | 1221 | 1221 | 1214 |
| Young's modulus parameter Y | 0.99 | 0.98 | 0.99 | 0.98 | 0.99 | 0.97 | 1.01 |
| Liquidus parameter L | 9.1 | 9.6 | 9.6 | 9.3 | 9.5 | 9.5 | 9.3 |
| Thermal expansion parameter C | 1.16 | 1.11 | 1.14 | 1.15 | 1.15 | 1.10 | 1.17 |
| Glass transition point (° C.) | 713 | 719 | 717 | 717 | 714 | 715 | 713 |
| Density (g/cm³) | 3.17 | 3.21 | 3.12 | 3.19 | 3.16 | 3.17 | 3.26 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.36 | 0.31 | 0.31 | 0.36 | 0.22 | 0.33 | 0.28 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 80

| | Example | Example | Example | Example | Example | Example | Example |
|---|---|---|---|---|---|---|---|
| (mol %) | 559 | 560 | 561 | 562 | 563 | 564 | 565 |
| SiO₂ | 48 | 48 | 48 | 49 | 48 | 48 | 49 |
| Al₂O₃ | 9 | 8 | 7 | 8 | 9 | 8 | 8 |
| B₂O₃ | 3 | 3 | 3 | 3 | 4 | 3 | 4 |
| MgO | 20 | 18 | 20 | 18 | 18 | 19 | 20 |
| CaO | 4 | 4 | 5 | 4 | 4 | 5 | 4 |
| SrO | 3 | 3 | 4 | 4 | 4 | 4 | 4 |
| BaO | 4 | 4 | 4 | 4 | 4 | 3 | 3 |
| Li₂O | | | | | | | |
| Na₂O | | | | | | | |
| K₂O | 5 | 6 | 5 | 6 | 5 | 6 | 4 |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 2 | 2 | 2 | | 2 | 2 | 2 |
| Gd₂O₃ | | | | 2 | | | |
| La₂O₃ | | 2 | | | | | |
| WO₃ | | | | | | | |
| Ta₂O₅ | | | | | | | |
| Al₂O₃ + rare earth oxide | 11 | 12 | 9 | 10 | 11 | 10 | 10 |
| Y₂O₃ + Gd₂O₃ + La₂O₃ + Nd₂O₃ + Ta₂O₅ + Nb₂O₅ | 2 | 4 | 2 | 2 | 2 | 2 | 2 |
| Parameter A = (Al₂O₃ + RO)/(SiO₂ + Al₂O₃ + RO) | 0.48 | 0.47 | 0.48 | 0.47 | 0.48 | 0.48 | 0.47 |
| (Al₂O₃ + MgO)/(SiO₂ + Al₂O₃ + B₂O₃ + MgO) | 0.36 | 0.34 | 0.35 | 0.33 | 0.34 | 0.35 | 0.35 |
| MgO/ΣRO | 0.56 | 0.51 | 0.53 | 0.50 | 0.51 | 0.51 | 0.57 |
| N | 11 | 12 | 11 | 11 | 11 | 11 | 11 |
| Young's modulus E (GPa) | 100 | 101 | 98 | 98 | 98 | 99 | 98 |
| Coefficient of thermal expansion α (ppm/° C.) | 5.53 | 5.84 | 5.84 | 5.84 | 5.57 | 5.63 | 5.51 |
| Liquidus temperature TL (° C.) | 1221 | 1218 | 1219 | 1219 | 1221 | 1221 | 1221 |
| Young's modulus parameter Y | 0.99 | 1.02 | 0.99 | 0.98 | 0.98 | 1.00 | 0.99 |
| Liquidus parameter L | 9.7 | 9.4 | 9.4 | 9.3 | 9.6 | 9.4 | 9.3 |
| Thermal expansion parameter C | 1.11 | 1.17 | 1.17 | 1.14 | 1.12 | 1.14 | 1.11 |
| Glass transition point (° C.) | 719 | 718 | 714 | 715 | 712 | 714 | 708 |
| Density (g/cm³) | 3.11 | 3.33 | 3.13 | 3.24 | 3.12 | 3.12 | 3.05 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.32 | 0.21 | 0.29 | 0.17 | 0.26 | 0.26 | 0.43 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 81

| | Example | Example | Example | Example | Example | Example | Example |
|---|---|---|---|---|---|---|---|
| (mol %) | 566 | 567 | 568 | 569 | 570 | 571 | 572 |
| SiO₂ | 48 | 48 | 49 | 47 | 49 | 49 | 48 |
| Al₂O₃ | 9 | 9 | 7 | 9 | 7 | 7 | 9 |
| B₂O₃ | 3 | 4 | 3 | 4 | 3 | 3 | 3 |
| MgO | 19 | 18 | 19 | 19 | 19 | 19 | 18 |
| CaO | 5 | 4 | 4 | 5 | 4 | 4 | 5 |
| SrO | 3 | 4 | 5 | 3 | 4 | 5 | 3 |
| BaO | 3 | 3 | 3 | 3 | 4 | 4 | 4 |
| Li₂O | | | | | | | |
| Na₂O | | | | | | | |
| K₂O | | | | | | | |
| ZnO | 6 | 6 | 6 | 6 | 6 | 5 | 4 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | | 2 | 2 |
| Gd₂O₃ | | | | | | | |
| La₂O₃ | 2 | 2 | 2 | 2 | 2 | | 2 |
| WO₃ | | | | | | | |
| Ta₂O₅ | | | | | | | |
| Al₂O₃ + rare earth oxide | 11 | 11 | 9 | 11 | 9 | 9 | 13 |
| Y₂O₃ + Gd₂O₃ + La₂O₃ + Nd₂O₃ + Ta₂O₅ + Nb₂O₅ | 2 | 2 | 2 | 2 | 2 | 2 | 4 |
| Parameter A = (Al₂O₃ + RO)/(SiO₂ + Al₂O₃ + RO) | 0.48 | 0.48 | 0.47 | 0.49 | 0.47 | 0.47 | 0.47 |
| (Al₂O₃ + MgO)/(SiO₂ + Al₂O₃ + B₂O₃ + MgO) | 0.35 | 0.34 | 0.33 | 0.35 | 0.33 | 0.33 | 0.35 |
| MgO/ΣRO | 0.53 | 0.51 | 0.51 | 0.53 | 0.51 | 0.51 | 0.53 |
| N | 11 | 11 | 11 | 11 | 11 | 11 | 12 |
| Young's modulus E (GPa) | 100 | 99 | 98 | 100 | 98 | 97 | 101 |
| Coefficient of thermal expansion α (ppm/° C.) | 5.61 | 5.60 | 5.85 | 5.62 | 5.85 | 5.82 | 5.86 |
| Liquidus temperature TL (° C.) | 1221 | 1221 | 1219 | 1221 | 1218 | 1221 | 1220 |
| Young's modulus parameter Y | 1.00 | 0.99 | 0.99 | 0.99 | 0.98 | 0.98 | 1.02 |
| Liquidus parameter L | 9.4 | 9.2 | 8.9 | 9.3 | 9.2 | 9.3 | 9.6 |
| Thermal expansion parameter C | 1.12 | 1.12 | 1.17 | 1.12 | 1.16 | 1.17 | 1.17 |
| Glass transition point (° C.) | 718 | 712 | 713 | 714 | 714 | 714 | 719 |
| Density (g/cm³) | 3.19 | 3.19 | 3.21 | 3.19 | 3.22 | 3.14 | 3.28 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.23 | 0.32 | 0.18 | 0.32 | 0.34 | 0.23 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 82

| | Example | Example | Example | Example | Example | Example | Example |
|---|---|---|---|---|---|---|---|
| (mol %) | 573 | 574 | 576 | 576 | 577 | 578 | 578 |
| SiO₂ | 48 | 49 | 48 | 49 | 48 | 49 | 49 |
| Al₂O₃ | 8 | 8 | 8 | 8 | 8 | 7 | 9 |
| B₂O₃ | 4 | 3 | 3 | 4 | 4 | 3 | 3 |
| MgO | 19 | 18 | 19 | 18 | 19 | 19 | 18 |
| CaO | 5 | 4 | 5 | 4 | 4 | 5 | 4 |
| SrO | 3 | 4 | 3 | 4 | 4 | 4 | 4 |
| BaO | 4 | 4 | 4 | 4 | 4 | 3 | 3 |
| Li₂O | | | | | | | |
| Na₂O | | | | | | | |
| K₂O | | | | | | | |
| ZnO | 5 | 6 | 6 | 5 | 4 | 6 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | 2 | | |
| Gd₂O₃ | | | 2 | | | 2 | |
| La₂O₃ | 2 | 2 | | 2 | | | 2 |
| WO₃ | | | | | | | |
| Ta₂O₅ | | | | | | | |
| Al₂O₃ + rare earth oxide | 10 | 10 | 10 | 10 | 10 | 9 | 11 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.48 | 0.47 | 0.48 | 0.47 | 0.47 | 0.47 | 0.47 |
| (Al₂O₃ + MgO)/(SiO₂ + Al₂O₃ + B₂O₃ + MgO) | 0.34 | 0.33 | 0.35 | 0.33 | 0.34 | 0.33 | 0.34 |
| MgO/ΣRO | 0.53 | 0.50 | 0.51 | 0.51 | 0.54 | 0.51 | 0.51 |
| N | 11 | 11 | 11 | 11 | 11 | 11 | 11 |
| Young's modulus E (GPa) | 98 | 98 | 99 | 97 | 97 | 98 | 99 |
| Coefficient of thermal expansion α (ppm/° C.) | 5.76 | 5.77 | 5.86 | 5.74 | 5.61 | 5.88 | 5.59 |
| Liquidus temperature TL (° C.) | 1221 | 1221 | 1219 | 1221 | 1221 | 1215 | 1221 |
| Young's modulus parameter Y | 0.97 | 0.98 | 0.98 | 0.97 | 0.97 | 0.99 | 0.99 |
| Liquidus parameter L | 9.3 | 9.3 | 9.4 | 9.3 | 9.5 | 9.1 | 9.3 |
| Thermal expansion parameter C | 1.14 | 1.14 | 1.15 | 1.14 | 1.12 | 1.16 | 1.11 |
| Glass transition point (° C.) | 713 | 715 | 717 | 710 | 710 | 714 | 716 |
| Density (g/cm³) | 3.18 | 3.22 | 3.24 | 3.19 | 3.08 | 3.21 | 3.19 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.29 | 0.12 | 0.31 | 0.38 | 0.20 | 0.31 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 83

| | Example | Example | Example | Example | Example | Example | Example |
|---|---|---|---|---|---|---|---|
| (mol %) | 580 | 581 | 582 | 583 | 584 | 585 | 586 |
| SiO₂ | 49 | 49 | 49 | 48 | 49 | 49 | 47 |
| Al₂O₃ | 7 | 7 | 8 | 8 | 8 | 8 | 8 |
| B₂O₃ | 3 | 3 | 3 | 4 | 4 | 3 | 4 |
| MgO | 20 | 19 | 19 | 19 | 19 | 20 | 18 |
| CaO | 4 | 5 | 4 | 4 | 4 | 4 | 5 |
| SrO | 4 | 3 | 3 | 4 | 3 | 4 | 4 |
| BaO | 4 | 4 | 4 | 3 | 4 | 3 | 4 |
| Li₂O | | | | | | | |
| Na₂O | | | | | | | |
| K₂O | | | | | | | |
| ZnO | 5 | 6 | 6 | 6 | 5 | 5 | 6 |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | | | | | | 2 | 2 |
| Gd₂O₃ | | 2 | | | | | |
| La₂O₃ | 2 | | 2 | 2 | 2 | | |
| WO₃ | | | | | | | |
| Ta₂O₅ | | | | | | | |
| Al₂O₃ + rare earth oxide | 9 | 9 | 10 | 10 | 10 | 10 | 10 |
| Y₂O₃ + Gd₂O₃ + La₂O₃ + Nd₂O₃ + Ta₂O₅ + Nb₂O₅ | 2 | 2 | 2 | 2 | 2 | 2 | 2 |
| Parameter A = (Al₂O₃ + RO)/(SiO₂ + Al₂O₃ + RO) | 0.47 | 0.47 | 0.47 | 0.48 | 0.47 | 0.47 | 0.49 |
| (Al₂O₃ + MgO)/(SiO₂ + Al₂O₃ + B₂O₃ + MgO) | 0.34 | 0.33 | 0.34 | 0.34 | 0.34 | 0.35 | 0.34 |
| MgO/ΣRO | 0.54 | 0.51 | 0.53 | 0.53 | 0.54 | 0.56 | 0.49 |
| N | 11 | 11 | 11 | 11 | 11 | 11 | 11 |
| Young's modulus E (GPa) | 98 | 98 | 98 | 99 | 98 | 99 | 98 |
| Coefficient of thermal expansion α (ppm/° C.) | 5.88 | 5.88 | 5.67 | 5.69 | 5.65 | 5.54 | 5.75 |
| Liquidus temperature TL (° C.) | 1220 | 1213 | 1221 | 1221 | 1220 | 1220 | 1220 |
| Young's modulus parameter Y | 0.98 | 0.97 | 0.98 | 0.99 | 0.97 | 1.00 | 0.98 |
| Liquidus parameter L | 9.2 | 9.3 | 9.4 | 9.0 | 9.4 | 9.4 | 9.4 |
| Thermal expansion parameter C | 1.16 | 1.15 | 1.12 | 1.13 | 1.11 | 1.12 | 1.16 |
| Glass transition point (° C.) | 714 | 716 | 717 | 710 | 713 | 714 | 710 |
| Density (g/cm³) | 3.20 | 3.23 | 3.21 | 3.19 | 3.17 | 3.09 | 3.16 |
| Liquidus viscosity log η_{L}(dPa · s) | 2< | 2< | 2< | 2< | 2 | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.36 | 0.20 | 0.34 | 0.26 | 0.36 | 0.40 | 0.14 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 84

| | Example | Example | Example | Example | Example | Example | Example |
|---|---|---|---|---|---|---|---|
| (mol %) | 587 | 588 | 589 | 590 | 591 | 592 | 593 |
| SiO₂ | 48 | 49 | 49 | 48 | 48 | 49 | 49 |
| Al₂O₃ | 9 | 8 | 7 | 8 | 12 | 11 | 12 |
| B₂O₃ | 4 | 4 | 3 | 3 | 6 | 6 | 6 |
| MgO | 19 | 19 | 20 | 19 | 17 | 17 | 17 |
| CaO | 5 | 4 | 5 | 5 | 2 | 2 | 3 |
| SrO | 3 | 4 | 4 | 3 | 5 | 5 | 5 |
| BaO | 3 | 3 | 3 | 4 | 2 | 2 | 2 |
| Li₂O | | | | | | | |
| Na₂O | | | | | | | |
| K₂O | | | | | | | |
| ZnO | 5 | 5 | 5 | 6 | | | |
| P₂O₅ | | | | | | | |
| ZrO₂ | 1 | 1 | 1 | 1 | | | |
| TiO₂ | 1 | 1 | 1 | 1 | | | |
| Y₂O₃ | | | | | 2 | 2 | 2 |
| Gd₂O₃ | | | 2 | | 2 | 4 | 4 |
| La₂O₃ | 2 | 2 | | 2 | 4 | 2 | |
| WO₃ | | | | | | | |
| Ta₂O₅ | | | | | | | |
| Al₂O₃ + rare earth oxide | 11 | 10 | 9 | 10 | 20 | 19 | 18 |
| Y₂O₃ + Gd₂O₃ + La₂O₃ + Nd₂O₃ + Ta₂O₅ + Nb₂O₅ | 2 | 2 | 2 | 2 | 8 | 8 | 6 |
| Parameter A = (Al₂O₃ + RO)/(SiO₂ + Al₂O₃ + RO) | 0.48 | 0.47 | 0.47 | 0.48 | 0.44 | 0.43 | 0.44 |
| (Al₂O₃ + MgO)/(SiO₂ + Al₂O₃ + B₂O₃ + MgO) | 0.35 | 0.34 | 0.34 | 0.35 | 0.35 | 0.34 | 0.35 |
| MgO/ΣRO | 0.54 | 0.54 | 0.54 | 0.51 | 0.65 | 0.65 | 0.63 |
| N | 11 | 11 | 11 | 11 | 10 | 10 | 9 |
| Young's modulus E (GPa) | 99 | 98 | 98 | 99 | 103 | 102 | 100 |
| Coefficient of thermal expansion α (ppm/° C.) | 5.58 | 5.64 | 5.90 | 5.79 | 5.99 | 6.08 | 5.79 |
| Liquidus temperature TL (° C.) | 1220 | 1220 | 1217 | 1220 | 1220 | 1215 | 1212 |
| Young's modulus parameter Y | 0.99 | 0.98 | 0.99 | 0.98 | 1.05 | 1.05 | 1.02 |
| Liquidus parameter L | 9.3 | 9.1 | 9.1 | 9.4 | 8.5 | 8.4 | 8.8 |
| Thermal expansion parameter C | 1.11 | 1.12 | 1.16 | 1.15 | 1.18 | 1.18 | 1.13 |
| Glass transition point (° C.) | 714 | 709 | 714 | 717 | 702 | 703 | 702 |
| Density (g/cm³) | 3.15 | 3.15 | 3.18 | 3.22 | 3.47 | 3.48 | 3.30 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.28 | 0.36 | 0.25 | 0.24 | −0.12 | −0.16 | −0.14 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 85

| | Example | Example | Example | Example | Example | Example | Example |
|---|---|---|---|---|---|---|---|
| (mol %) | 594 | 595 | 598 | 597 | 598 | 599 | 600 |
| SiO₂ | 49 | 49 | 48 | 49 | 47 | 49 | 49 |
| Al₂O₃ | 11 | 11 | 12 | 12 | 11 | 10 | 12 |
| B₂O₃ | 6 | 6 | 6 | 6 | 6 | 6 | 6 |
| MgO | 17 | 17 | 17 | 17 | 17 | 17 | 17 |
| CaO | 2 | 2 | 3 | 3 | 3 | 3 | 4 |
| SrO | 5 | 5 | 5 | 5 | 7 | 5 | 5 |
| BaO | 2 | 2 | 2 | 2 | 3 | 2 | 2 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | |
| TiO₂ | 1 | 1 | | 1 | 1 | 1 | 1 |
| Y₂O₃ | 2 | 2 | 2 | 2 | 2 | 2 | 2 |
| Gd₂O₃ | | 4 | 2 | | 2 | | |
| La₂O₃ | 4 | | 2 | 2 | | 4 | 2 |
| WO₃ | | | | | | | |
| Ta₂O₅ | | | | | | | |
| Al₂O₃ + rare earth oxide | 17 | 17 | 18 | 16 | 15 | 16 | 16 |
| Y₂O₃ + Gd₂O₃ + La₂O₃ + Nd₂O₃ + Ta₂O₅ + Nb₂O₅ | 6 | 6 | 6 | 4 | 4 | 6 | 4 |
| Parameter A = (Al₂O₃ + RO)/(SiO₂ + Al₂O₃ + RO) | 0.43 | 0.43 | 0.45 | 0.44 | 0.47 | 0.43 | 0.45 |
| (Al₂O₃ + MgO)/(SiO₂ + Al₂O₃ + B₂O₃ + MgO) | 0.34 | 0.34 | 0.35 | 0.35 | 0.35 | 0.33 | 0.35 |
| MgO/ΣRO | 0.65 | 0.65 | 0.63 | 0.63 | 0.57 | 0.63 | 0.61 |
| N | 11 | 11 | 11 | 11 | 11 | 11 | 10 |
| Young's modulus E (GPa) | 102 | 102 | 102 | 100 | 99 | 101 | 98 |
| Coefficient of thermal expansion α (ppm/° C.) | 5.66 | 5.80 | 5.80 | 5.37 | 5.96 | 5.80 | 5.41 |
| Liquidus temperature TL (° C.) | 1220 | 1222 | 1216 | 1215 | 1221 | 1210 | 1221 |
| Young's modulus parameter Y | 1.03 | 1.03 | 1.04 | 1.01 | 1.00 | 1.03 | 0.99 |
| Liquidus parameter L | 8.9 | 8.9 | 8.8 | 9.4 | 9.1 | 8.8 | 9.3 |
| Thermal expansion parameter C | 1.13 | 1.13 | 1.15 | 1.08 | 1.18 | 1.16 | 1.09 |
| Glass transition point (° C.) | 705 | 705 | 703 | 704 | 700 | 704 | 701 |
| Density (g/cm³) | 3.27 | 3.31 | 3.30 | 3.09 | 3.19 | 3.28 | 3.08 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.38 | 0.14 | 0.07 | 0.40 | 0.06 | 0.36 | 0.22 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 86

| | Example | Example | Example | Example | Example | Example | Example |
|---|---|---|---|---|---|---|---|
| (mol %) | 601 | 602 | 603 | 604 | 605 | 606 | 607 |
| SiO₂ | 47 | 47 | 49 | 47 | 49 | 47 | 49 |
| Al₂O₃ | 12 | 11 | 11 | 12 | 12 | 12 | 12 |
| B₂O₃ | 6 | 6 | 6 | 6 | 6 | 6 | 6 |
| MgO | 17 | 17 | 17 | 17 | 17 | 17 | 17 |
| CaO | 2 | 4 | 3 | 3 | 2 | 3 | 3 |
| SrO | 5 | 7 | 6 | 6 | 6 | 7 | 6 |
| BaO | 3 | 3 | 2 | 3 | 3 | 3 | 2 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | | | 1 | | | 1 |
| TiO₂ | 1 | 1 | | 1 | 1 | 1 | |
| Y₂O₃ | 2 | 2 | 2 | 2 | 2 | 2 | 2 |
| Gd₂O₃ | | 2 | | 2 | | 2 | |
| La₂O₃ | 4 | | 4 | | 2 | | 2 |
| WO₃ | | | | | | | |
| Ta₂O₅ | | | | | | | |
| Al₂O₃ + rare earth oxide | 18 | 15 | 17 | 16 | 16 | 16 | 16 |
| Y₂O₃ + Gd₂O₃ + La₂O₃ + Nd₂O₃ + Ta₂O₅ + Nb₂O₅ | 6 | 4 | 6 | 4 | 4 | 4 | 4 |
| Parameter A = (Al₂O₃ + RO)/(SiO₂ + Al₂O₃ + RO) | 0.45 | 0.47 | 0.44 | 0.47 | 0.45 | 0.47 | 0.45 |
| (Al₂O₃ + MgO)/(SiO₂ + Al₂O₃ + B₂O₃ + MgO) | 0.35 | 0.35 | 0.34 | 0.35 | 0.35 | 0.35 | 0.35 |
| MgO/ΣRO | 0.63 | 0.55 | 0.61 | 0.59 | 0.61 | 0.57 | 0.61 |
| N | 11 | 10 | 9 | 11 | 10 | 10 | 10 |
| Young's modulus E (GPa) | 102 | 98 | 100 | 100 | 98 | 98 | 99 |
| Coefficient of thermal expansion α (ppm/° C.) | 5.82 | 5.99 | 5.83 | 5.78 | 5.50 | 5.86 | 5.50 |
| Liquidus temperature TL (° C.) | 1223 | 1222 | 1204 | 1218 | 1220 | 1219 | 1214 |
| Young's modulus parameter Y | 1.03 | 0.98 | 1.02 | 1.00 | 0.98 | 0.99 | 1.01 |
| Liquidus parameter L | 9.1 | 9.0 | 8.6 | 9.3 | 9.3 | 9.1 | 9.0 |
| Thermal expansion parameter C | 1.16 | 1.19 | 1.17 | 1.15 | 1.10 | 1.16 | 1.11 |
| Glass transition point (° C.) | 699 | 697 | 701 | 700 | 698 | 700 | 703 |
| Density (g/cm³) | 3.32 | 3.18 | 3.28 | 3.17 | 3.12 | 3.17 | 3.11 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.19 | −0.12 | 0.08 | 0.08 | 0.21 | −0.11 | 0.28 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 87

| | Example | Example | Example | Example | Example | Example | Example |
|---|---|---|---|---|---|---|---|
| (mol %) | 608 | 609 | 610 | 611 | 612 | 613 | 614 |
| SiO₂ | 47 | 47 | 47 | 48 | 48 | 48 | 48 |
| Al₂O₃ | 12 | 12 | 12 | 10 | 11 | 10 | 11 |
| B₂O₃ | 6 | 6 | 6 | 6 | 6 | 6 | 6 |
| MgO | 17 | 17 | 17 | 17 | 17 | 17 | 17 |
| CaO | 3 | 4 | 4 | 3 | 2 | 4 | 3 |
| SrO | 7 | 6 | 7 | 7 | 6 | 7 | 5 |
| BaO | 3 | 3 | 3 | 3 | 3 | 3 | 2 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | | | 1 | | | |
| TiO₂ | | 1 | | 1 | 1 | 1 | |
| Y₂O₃ | 2 | 2 | 2 | 2 | 2 | 2 | 4 |
| Gd₂O₃ | 2 | 2 | 2 | 2 | 4 | 2 | 2 |
| La₂O₃ | | | | | | | 2 |
| WO₃ | | | | | | | |
| Ta₂O₅ | | | | | | | |
| Al₂O₃ + rare earth oxide | 16 | 16 | 16 | 14 | 17 | 14 | 19 |
| Y₂O₃ + Gd₂O₃ + La₂O₃ + Nd₂O₃ + Ta₂O₅ + Nb₂O₅ | 4 | 4 | 4 | 4 | 6 | 4 | 8 |
| Parameter A = (Al₂O₃ + RO)/(SiO₂ + Al₂O₃ + RO) | 0.47 | 0.47 | 0.48 | 0.45 | 0.45 | 0.46 | 0.44 |
| (Al₂O₃ + MgO)/(SiO₂ + Al₂O₃ + B₂O₃ + MgO) | 0.35 | 0.35 | 0.35 | 0.33 | 0.34 | 0.33 | 0.34 |
| MgO/ΣRO | 0.57 | 0.57 | 0.55 | 0.57 | 0.61 | 0.55 | 0.63 |
| N | 10 | 10 | 9 | 11 | 10 | 10 | 10 |
| Young's modulus E (GPa) | 99 | 96 | 98 | 98 | 100 | 97 | 102 |
| Coefficient of thermal expansion α (ppm/° C.) | 5.91 | 5.81 | 5.94 | 5.98 | 6.05 | 6.01 | 5.97 |
| Liquidus temperature TL (° C.) | 1223 | 1222 | 1222 | 1223 | 1223 | 1223 | 1225 |
| Young's modulus parameter Y | 1.00 | 0.99 | 0.99 | 0.99 | 1.01 | 0.98 | 1.05 |
| Liquidus parameter L | 9.0 | 9.2 | 8.9 | 9.0 | 8.8 | 8.9 | 8.6 |
| Thermal expansion parameter C | 1.17 | 1.15 | 1.18 | 1.18 | 1.18 | 1.19 | 1.20 |
| Glass transition point (° C.) | 699 | 697 | 693 | 700 | 700 | 696 | 703 |
| Density (g/cm³) | 3.19 | 3.16 | 3.18 | 3.18 | 3.35 | 3.17 | 3.40 |
| Liquidus viscosity log η_{L}(dPa · s) | 2< | 2< | 2< | 2< | 24 | | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | −0.04 | −0.10 | −0.22 | 0.14 | −0.14 | −0.04 | −0.11 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 88

| | Example | Example | Example | Example | Example | Example | Example |
|---|---|---|---|---|---|---|---|
| (mol %) | 615 | 616 | 617 | 618 | 619 | 620 | 621 |
| SiO₂ | 48 | 48 | 48 | 48 | 48 | 48 | 48 |
| Al₂O₃ | 11 | 11 | 11 | 11 | 11 | 11 | 11 |
| B₂O₃ | 6 | 6 | 6 | 6 | 6 | 6 | 6 |
| MgO | 17 | 17 | 17 | 17 | 17 | 17 | 17 |
| CaO | 3 | 3 | 3 | 3 | 3 | 3 | 4 |
| SrO | 6 | 6 | 6 | 7 | 7 | 7 | 6 |
| BaO | 3 | 3 | 3 | 2 | 3 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | | 1 | 1 | | 1 | |
| TiO₂ | | | 1 | 1 | 1 | | 1 |
| Y₂O₃ | 4 | 4 | 2 | 2 | 2 | 2 | 2 |
| Gd₂O₃ | | 2 | 2 | 2 | 2 | 2 | 2 |
| La₂O₃ | 2 | | | | | | |
| WO₃ | | | | | | | |
| Ta₂O₅ | | | | | | | |
| Al₂O₃ + rare earth oxide | 17 | 17 | 15 | 15 | 15 | 15 | 15 |
| Y₂O₃ + Gd₂O₃ + La₂O₃ + Nd₂O₃ + Ta₂O₅ + Nb₂O₅ | 6 | 6 | 4 | 4 | 4 | 4 | 4 |
| Parameter A = (Al₂O₃ + RO)/(SiO₂ + Al₂O₃ + RO) | 0.45 | 0.45 | 0.45 | 0.45 | 0.46 | 0.46 | 0.46 |
| (Al₂O₃ + MgO)/(SiO₂ + Al₂O₃ + B₂O₃ + MgO) | 0.34 | 0.34 | 0.34 | 0.34 | 0.34 | 0.34 | 0.34 |
| MgO/ΣRO | 0.59 | 0.59 | 0.59 | 0.59 | 0.57 | 0.57 | 0.57 |
| N | 9 | 9 | 11 | 11 | 10 | 10 | 10 |
| Young's modulus E (GPa) | 99 | 99 | 99 | 99 | 97 | 98 | 97 |
| Coefficient of thermal expansion α (ppm/° C.) | 5.84 | 5.91 | 5.80 | 5.79 | 5.88 | 5.93 | 5.83 |
| Liquidus temperature TL (° C.) | 1223 | 1223 | 1215 | 1224 | 1217 | 1219 | 1220 |
| Young's modulus parameter Y | 1.01 | 1.01 | 1.00 | 1.01 | 0.98 | 1.00 | 0.98 |
| Liquidus parameter L | 8.9 | 8.9 | 9.2 | 9.0 | 9.0 | 8.9 | 9.1 |
| Thermal expansion parameter C | 1.18 | 1.18 | 1.15 | 1.15 | 1.16 | 1.17 | 1.16 |
| Glass transition point (° C.) | 697 | 698 | 700 | 704 | 700 | 699 | 697 |
| Density (g/cm³) | 3.24 | 3.26 | 3.16 | 3.15 | 3.16 | 3.18 | 3.15 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.01 | −0.11 | 0.16 | 0.16 | −0.02 | 0.05 | −0.02 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 89

| | Example | Example | Example | Example | Example | Example | Example |
|---|---|---|---|---|---|---|---|
| (mol %) | 622 | 623 | 624 | 625 | 626 | 627 | 628 |
| SiO₂ | 48 | 49 | 48 | 48 | 48 | 48 | 48 |
| Al₂O₃ | 11 | 11 | 11 | 12 | 12 | 12 | 12 |
| B₂O₃ | 6 | 6 | 6 | 6 | 6 | 6 | 6 |
| MgO | 17 | 17 | 17 | 17 | 17 | 17 | 17 |
| CaO | 4 | 2 | 4 | 3 | 3 | 3 | 3 |
| SrO | 6 | 6 | 7 | 5 | 6 | 6 | 6 |
| BaO | 3 | 3 | 3 | 3 | 2 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | | 1 | 1 | | 1 |
| TiO₂ | | 1 | | 1 | 1 | 1 | |
| Y₂O₃ | 2 | 2 | 2 | 2 | 2 | 2 | 2 |
| Gd₂O₃ | 2 | | 2 | 2 | 2 | 2 | 2 |
| La₂O₃ | | 2 | | | | | |
| WO₃ | | | | | | | |
| Ta₂O₅ | | | | | | | |
| Al₂O₃ + rare earth oxide | 15 | 15 | 15 | 18 | 16 | 16 | 16 |
| Y₂O₃ + Gd₂O₃ + La₂O₃ + Nd₂O₃ + Ta₂O₅ + Nb₂O₅ | 4 | 4 | 4 | 4 | 4 | 4 | 4 |
| Parameter A = (Al₂O₃ + RO)/(SiO₂ + Al₂O₃ + RO) | 0.46 | 0.44 | 0.47 | 0.45 | 0.45 | 0.46 | 0.46 |
| (Al₂O₃ + MgO)/(SiO₂ + Al₂O₃ + B₂O₃ + MgO) | 0.34 | 0.34 | 0.34 | 0.35 | 0.35 | 0.35 | 0.35 |
| MgO/ΣRO | 0.57 | 0.61 | 0.55 | 0.81 | 0.81 | :0.59 | 0.53 |
| N | 10 | 11 | | 11 | 11 | 10 | 10 |
| Young's modulus E (GPa) | 98 | 99 | 97 | 100 | 100 | 98 | 99 |
| Coefficient of thermal expansion α (ppm/° C.) | 5.88 | 5.61 | 5.96 | 6.81 | 5.61 | 5.69 | 5.74 |
| Liquidus temperature TL (° C.) | 1223 | 1218 | 1219 | 1219 | 1221 | 1216 | 1217 |
| Young's modulus parameter Y | 0.99 | 0,99 | 0.98 | 1.00 | 1.01 | 0.96 | 1.00 |
| Liquidus parameter L | 9.0 | 9.2 | 8.8 | 9.4 | 9.2 | 9.3 | 9.1 |
| Thermal expansion parameter C | 1.16 | 1,12 | 1.18 | 1.11 | 1.12 | 1.13 | 1.13 |
| Glass transition point (° C.) | 695 | 699 | 694 | 700 | 704 | 700 | 698 |
| Density (g/cm³) | 3.17 | 3.14 | 3.17 | 3.15 | 3.13 | 3.15 | 3.17 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.06 | 0.38 | −0.13 | 0,18 | 0.18 | 0.00 | 0.06 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 90

| | Example | Example | Example | Example | Example | Example | Example |
|---|---|---|---|---|---|---|---|
| (mol %) | 629 | 630 | 631 | 632 | 633 | 634 | 635 |
| SiO₂ | 48 | 48 | 48 | 48 | 49 | 49 | 49 |
| Al₂O₃ | 12 | 12 | 12 | 12 | 10 | 10 | 10 |
| B₂O₃ | 6 | 6 | 6 | 6 | 6 | 6 | 6 |
| MgO | 17 | 17 | 17 | 17 | 17 | 17 | 17 |
| CaO | 3 | 3 | 4 | 4 | 3 | 3 | 3 |
| SrO | 7 | 7 | 5 | 6 | 5 | 5 | 5 |
| BaO | 2 | 3 | 3 | 3 | 2 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | | | | | | |
| TiO₂ | 1 | | 1 | | | 1 | 1 |
| Y₂O₃ | 2 | 2 | 2 | 2 | 4 | 4 | 4 |
| Gd₂O₃ | 2 | 2 | 2 | 2 | 2 | | 2 |
| La₂O₃ | | | | | 2 | 2 | |
| WO₃ | | | | | | | |
| Ta₂O₅ | | | | | | | |
| Al₂O₃ + rare earth oxide | 16 | 16 | 16 | 18 | 18 | 16 | 16 |
| Y₂O₃ + Gd₂O₃ + La₂O₃ + Nd₂O₃ + Ta₂O₅ + Nb₂O₅ | 4 | 4 | 4 | 4 | 8 | 6 | 6 |
| Parameter A = (Al₂O₃ + RO)/(SiO₂ + Al₂O₃ + RO) | 0.46 | 0.47 | 0.46 | 0.47 | 0.43 | 0.44 | 0.44 |
| (Al₂O₃ + MgO)/(SiO₂ + Al₂O₃ + B₂O₃ + MgO) | 0.35 | 0.35 | 0.35 | 0.35 | 0.33 | 0.33 | 0.33 |
| MgO/ΣRO | 0.59 | 0.57 | 0.59 | 0.57 | 0,63 | 0.61 | 0.61 |
| N | 10 | 9 | 10 | 9 | 10 | 10 | 10 |
| Young's modulus E (GPa) | 98 | 97 | 98 | 97 | 101 | 99 | 99 |
| Coefficient of thermal expansion α (ppm/° C.) | 5.69 | 5.83 | 5.65 | 5.78 | 5.98 | 5.72 | 5.80 |
| Liquidus temperature TL (° C.) | 1223 | 1217 | 1224 | 1220 | 1221 | 1224 | 1224 |
| Young's modulus parameter Y | 1.00 | 0.98 | 0.98 | 0.98 | 1.05 | 1.01 | 1.01 |
| Liquidus parameter L | 9.0 | 8.9 | 9.4 | 9.1 | 8.5 | 9.1 | 9.1 |
| Thermal expansion parameter C | 1.13 | 1.15 | 1.12 | 1.14 | 1.20 | 1.18 | 1.16 |
| Glass transition point (° C.) | 703 | 698 | 697 | 693 | 702 | 698 | 699 |
| Density (g/cm³) | 3.13 | 3.17 | 3.14 | 3.15 | 3.39 | 3.22 | 3.23 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.00 | −0.12 | 0.00 | −0.11 | −0.03 | 0.20 | 0.09 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 91

| | Example | Example | Example | Example | Example | Example | Example |
|---|---|---|---|---|---|---|---|
| (mol %) | 636 | 637 | 638 | 639 | 640 | 641 | 642 |
| SiO₂ | 49 | 49 | 49 | 49 | 49 | 48 | 49 |
| Al₂O₃ | 10 | 10 | 10 | 10 | 10 | 12 | 10 |
| B₂O₃ | 6 | 6 | 6 | 6 | 6 | 6 | 6 |
| MgO | 17 | 17 | 17 | 17 | 17 | 17 | 17 |
| CaO | 3 | 3 | 3 | 3 | 3 | 4 | 3 |
| SrO | 6 | 6 | 6 | 7 | 7 | 7 | 7 |
| BaO | 3 | 3 | 3 | 2 | 3 | 2 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | | 1 | 1 | | | 1 |
| TiO₂ | | | 1 | 1 | 1 | | |
| Y₂O₃ | 4 | 4 | 2 | 2 | 2 | 2 | 2 |
| Gd₂O₃ | | 2 | 2 | 2 | 2 | | 2 |
| La₂O₃ | 2 | | | | | 2 | |
| WO₃ | | | | | | | |
| Ta₂O₅ | | | | | | | |
| Al₂O₃ + rare earth oxide | 16 | 16 | 14 | 14 | 14 | 16 | 14 |
| Y₂O₃ + Gd₂O₃ + La₂O₃ + Nd₂O₃ + Ta₂O₅ + Nb₂O₅ | 6 | 6 | 4 | 4 | 4 | 4 | 4 |
| Parameter A = (Al₂O₃ + RO)/(SiO₂ + Al₂O₃ + RO) | 0.44 | 0.44 | 0.44 | 0.44 | 0.45 | 0.47 | 0.45 |
| (Al₂O₃ + MgO)/(SiO₂ + Al₂O₃ + B₂O₃ + MgO) | 0.33 | 0.33 | 0.33 | 0.33 | 0.33 | 0.35 | 0.33 |
| MgO/ΣRO | 0.59 | 0.59 | 0.59 | 0.59 | 0.57 | 0.57 | 0.57 |
| N | 9 | 9 | 11 | 11 | 10 | 9 | 10 |
| Young's modulus E (GPa) | 99 | 98 | 98 | 98 | 96 | 98 | 97 |
| Coefficient of thermal expansion α (ppm/° C.) | 5.86 | 5.93 | 5.81 | 5.81 | 5.89 | 5.70 | 5.94 |
| Liquidus temperature TL (° C.) | 1219 | 1219 | 1212 | 1221 | 1213 | 1223 | 1217 |
| Young's modulus parameter Y | 1.01 | 1.01 | 0.99 | 1.00 | 0.97 | 0.99 | 0.99 |
| Liquidus parameter L | 8.8 | 8.8 | 9.1 | 8.9 | 8.9 | 8.8 | 8.8 |
| Thermal expansion parameter C | 1.18 | 1.18 | 1.15 | 1.15 | 1.16 | 1.15 | 1.17 |
| Glass transition point (° C.) | 696 | 698 | 700 | 703 | 699 | 695 | 699 |
| Density (g/cm³) | 3.23 | 3.25 | 3.15 | 3.14 | 3.15 | 3.12 | 3.17 |
| Liquidus viscosity log η_{L}(dPa · s) | 2< | 2< | 2< | 2< | 24 | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.09 | −0.03 | 0.24 | 0.24 | 0.06 | 0.00 | 0.13 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 92

| | Example | Example | Example | Example | Example | Example | Example |
|---|---|---|---|---|---|---|---|
| (mol %) | 643 | 644 | 645 | 646 | 647 | 648 | 649 |
| SiO₂ | 49 | 49 | 49 | 49 | 49 | 49 | 49 |
| Al₂O₃ | 10 | 10 | 10 | 10 | 10 | 10 | 10 |
| B₂O₃ | 6 | 6 | 6 | 6 | 6 | 6 | 6 |
| MgO | 17 | 17 | 17 | 17 | 17 | 17 | 17 |
| CaO | 4 | 4 | 4 | 4 | 4 | 4 | 4 |
| SrO | 5 | 5 | 5 | 6 | 6 | 6 | 6 |
| BaO | 3 | 3 | 3 | 2 | 2 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | | 1 | | | | 1 |
| TiO₂ | | | 1 | | | 1 | |
| Y₂O₃ | 4 | 4 | 2 | 4 | 4 | 2 | 2 |
| Gd₂O₃ | | 2 | 2 | | 2 | 2 | 2 |
| La₂O₃ | 2 | | | 2 | | | |
| WO₃ | | | | | | | |
| Ta₂O₅ | | | | | | | |
| Al₂O₃ + rare earth oxide | 16 | 16 | 14 | 16 | 16 | 14 | 14 |
| Y₂O₃ + Gd₂O₃ + La₂O₃ + Nd₂O₃ + Ta₂O₅ + Nb₂O₅ | 6 | 6 | 4 | 6 | 6 | 4 | 4 |
| Parameter A = (Al₂O₃ + RO)/(SiO₂ + Al₂O₃ + RO) | 0.44 | 0.44 | 0.44 | 0.44 | 0.44 | 0.45 | 0.45 |
| (Al₂O₃ + MgO)/(SiO₂ + Al₂O₃ + B₂O₃ + MgO) | 0.33 | 0.33 | 0.33 | 0.33 | 0.33 | 0.33 | 0.33 |
| MgO/ΣRO | 0.59 | 0.59 | 0.59 | 0.59 | 0,59 | 0.57 | 0.57 |
| N | | 9 | 11 | 9 | 9 | 10 | 10 |
| Young's modulus E (GPa) | 99 | 99 | 98 | 99 | 99 | 97 | 98 |
| Coefficient of thermal expansion α (ppm/° C.) | 5.81 | 5.88 | 5.76 | 5.81 | 5.88 | 5.84 | 5.90 |
| Liquidus temperature TL (° C.) | 1220 | 1220 | 1223 | 1223 | 1223 | 1216 | 1221 |
| Young's modulus parameter Y | 1.00 | 1.00 | 0.99 | 1.02 | 1.02 | 0.97 | 0.99 |
| Liquidus parameter L | 8.9 | 8.9 | 9.2 | 8.7 | 8.7 | 9.0 | 8.9 |
| Thermal expansion parameter C | 1.17 | 1.17 | 1.14 | 1.18 | 1.18 | 1.16 | 1.16 |
| Glass transition point (° C.) | 690 | 693 | 697 | 698 | 697 | 696 | 694 |
| Density (g/cm³) | 3.22 | 3.24 | 3.14 | 3.20 | 3.22 | 3.14 | 3.16 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.09 | −0.02 | 0.25 | 0.09 | −0.02 | 0.06 | 0.13 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 93

| | Example | Example | Example | Example | Example | Example | Example |
|---|---|---|---|---|---|---|---|
| (mol %) | 650 | 651 | 652 | 653 | 654 | 655 | 656 |
| SiO₂ | 49 | 49 | 49 | 49 | 49 | 49 | 49 |
| Al₂O₃ | 10 | 10 | 10 | 11 | 11 | 11 | 11 |
| B₂O₃ | 6 | 6 | 6 | 6 | 6 | 6 | 6 |
| MgO | 17 | 17 | 17 | 17 | 17 | 17 | 17 |
| CaO | 4 | 4 | 4 | 2 | 2 | 3 | 3 |
| SrO | 7 | 7 | 7 | 6 | 7 | 5 | 5 |
| BaO | 2 | 3 | 3 | 3 | 3 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | | | 1 | 1 | | |
| TiO₂ | 1 | | | | | | |
| Y₂O₃ | 2 | 2 | 4 | 2 | 2 | 4 | 4 |
| Gd₂O₃ | 2 | 2 | | 2 | 2 | | 2 |
| La₂O₃ | | | | | | 2 | |
| WO₃ | | | | | | | |
| Ta₂O₅ | | | | | | | |
| Al₂O₃ + rare earth oxide | 14 | 14 | 14 | 15 | 15 | 17 | 17 |
| Y₂O₃ + Gd₂O₃ + La₂O₃ + Nd₂O₃ + Ta₂O₅ + Nb₂O₅ | 4 | 4 | 4 | 4 | 4 | 6 | 6 |
| Parameter A = (Al₂O₃ + RO)/(SiO₂ + Al₂O₃ + RO) | 0.45 | 0.46 | 0.46 | 0.44 | 0.45 | 0.44 | 0.44 |
| (Al₂O₃ + MgO)/(SiO₂ + Al₂O₃ + B₂O₃ + MgO) | 0.33 | 0.33 | 0.33 | 0.34 | 0.34 | 0.34 | 0.34 |
| MgO/ΣRO | 0.57 | 0.55 | 0.55 | 0.61 | 0.59 | 0.61 | 0.61 |
| N | 10 | 9 | 8 | 11 | 10 | 9 | 9 |
| Young's modulus E (GPa) | 97 | 96 | 96 | 99 | 98 | 99 | 99 |
| Coefficient of thermal expansion α (ppm/° C.) | 5.84 | 5.98 | 5.75 | 5.68 | 5.81 | 5.67 | 5.75 |
| Liquidus temperature TL (° C.) | 1222 | 1216 | 1225 | 1221 | 1224 | 1219 | 1219 |
| Young's modulus parameter Y | 0.98 | 0.97 | 0.98 | 0.99 | 0.99 | 1.01 | 1.01 |
| Liquidus parameter L | 8.8 | 8.7 | 8.9 | 9.2 | 8.9 | 9.0 | 9.0 |
| Thermal expansion parameter C | 1.16 | 1.18 | 1.17 | 1.12 | 1.14 | 1.15 | 1.15 |
| Glass transition point (° C.) | 700 | 692 | 689 | 700 | 699 | 696 | 698 |
| Density (g/cm³) | 3.12 | 3.16 | 3.07 | 3.15 | 3.17 | 3.22 | 3.23 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.06 | −0.05 | 0.09 | 0.26 | 0.14 | 0.11 | −0.01 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 94

| | Example | Example | Example | Example | Exampla | Example | Example |
|---|---|---|---|---|---|---|---|
| (mol %) | 657 | 658 | 659 | 660 | 661 | 662 | 663 |
| SiO₂ | 49 | 49 | 49 | 49 | 49 | 49 | 49 |
| Al₂O₃ | 11 | 11 | 11 | 11 | 11 | 11 | 11 |
| B₂O₃ | 6 | 6 | 6 | 6 | 6 | 6 | 6 |
| MgO | 17 | 17 | 17 | 17 | 17 | 17 | 17 |
| CaO | 3 | 3 | 3 | 3 | 3 | 3 | 3 |
| SrO | 5 | 6 | 6 | 6 | 6 | 6 | 6 |
| BaO | 3 | 2 | 2 | 2 | 3 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | | | 1 | | | |
| TiO₂ | 1 | | | | 1 | 1 | |
| Y₂O₃ | 2 | 4 | 4 | 2 | 2 | 4 | 2 |
| Gd₂O₃ | 2 | | 2 | 2 | 2 | | 2 |
| La₂O₃ | | 2 | | | | | |
| WO₃ | | | | | | | |
| Ta₂O₅ | | | | | | | |
| Al₂O₃ + rare earth oxide | 15 | 17 | 17 | 15 | 15 | 15 | 15 |
| Y₂O₃ + Gd₂O₃ + La₂O₃ + Nd₂O₃ + Ta₂O₅ + Nb₂O₅ | 4 | 6 | 6 | 4 | 4 | 4 | 4 |
| Parameter A = (Al₂O₃ + RO)/(SiO₂ + Al₂O₃ + RO) | 0.44 | 0.44 | 0.44 | 0.44 | 0.45 | 0.45 | 0.45 |
| (Al₂O₃ + MgO)/(SiO₂ + Al₂O₃ + B₂O₃ + MgO) | 0.34 | 0.34 | 0.34 | 0.34 | 0.34 | 0.34 | 0.34 |
| MgO/ΣRO | 0.61 | 0.61 | 0.61 | 0.61 | 0.59 | 0.59 | 0.59 |
| N | 11 | 9 | 9 | 11 | 10 | 9 | 10 |
| Young's modulus E (GPa) | 99 | 100 | 100 | 99 | 97 | 97 | 98 |
| Coefficient of thermal expansion α (ppm/° C.) | 5.63 | 5.67 | 5.74 | 5.63 | 5.71 | 5.48 | 5.76 |
| Liquidus temperature TL (° C.) | 1210 | 1222 | 1221 | 1213 | 1208 | 1225 | 1208 |
| Young's modulus parameter Y | 0.99 | 1.02 | 1.02 | 1.00 | 0.98 | 0.98 | 0.99 |
| Liquidus parameter L | 9.4 | 8.8 | 8.8 | 9.1 | 9.2 | 9.4 | 9.0 |
| Thermal expansion parameter C | 1.11 | 1.15 | 1.15 | 1.12 | 1.13 | 1.11 | 1.14 |
| Glass transition point (° C.) | 700 | 701 | 702 | 704 | 699 | 698 | 699 |
| Density (g/cm³) | 3.14 | 3.20 | 3.22 | 3.12 | 3.14 | 3.05 | 3.16 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.26 | 0.11 | −0.01 | 0.26 | 0.08 | 0.22 | 0.15 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 95

| | Example | Example | Example | Example | Example | Example | Example |
|---|---|---|---|---|---|---|---|
| (mol %) | 664 | 665 | 666 | 667 | 668 | 669 | 670 |
| SiO₂ | 49 | 49 | 49 | 49 | 49 | 49 | 49 |
| Al₂O₃ | 11 | 11 | 11 | 11 | 11 | 11 | 11 |
| B₂O₃ | 6 | 6 | 6 | 6 | 6 | 6 | 6 |
| MgO | 17 | 17 | 17 | 17 | 17 | 17 | 17 |
| CaO | 3 | 3 | 3 | 3 | 3 | 4 | 4 |
| SrO | 7 | 7 | 7 | 7 | 7 | 5 | 5 |
| BaO | 2 | 2 | 3 | 3 | 3 | 2 | 2 |
| Li₂O | | | | | | | |
| Na₂O | | | | | | | |
| K₂O | | | | | | | |
| ZnO | | | | | | | |
| P₂O₅ | | | | | | | |
| ZrO₂ | | 1 | | | 1 | | |
| TiO₂ | 1 | | | | 1 | | |
| Y₂O₃ | 2 | 2 | 2 | 4 | 2 | 4 | 4 |
| Gd₂O₃ | 2 | 2 | 2 | | | | 2 |
| La₂O₃ | | | | | | 2 | |
| WO₃ | | | | | | | |
| Ta₂O₅ | | | | | | | |
| Al₂O₃ + rare earth oxide | 15 | 15 | 15 | 15 | 13 | 17 | 17 |
| Y₂O₃ + Gd₂O₃ + La₂O₃ + Nd₂O₃ + Ta₂O₅ + Nb₂O₅ | 4 | 4 | 4 | 4 | 2 | 6 | 6 |
| Parameter A = (Al₂O₃ + RO)/(SiO₂ + Al₂O₃ + RO) | 0.45 | 0.45 | 0.46 | 0.46 | 0.46 | 0.44 | 0.44 |
| (Al₂O₃ + MgO)/(SiO₂ + Al₂O₃ + B₂O₃ + MgO) | 0.34 | 0.34 | 0.34 | 0.34 | 0.34 | 0.34 | 0.34 |
| MgO/ΣRO | 0.59 | 0.59 | 0.57 | 0.57 | 0.57 | 0.61 | 0.61 |
| N | 10 | 10 | 9 | 8 | 10 | 9 | 9 |
| Young's modulus E (GPa) | 97 | 98 | 96 | 97 | 96 | 100 | 100 |
| Coefficient of thermal expansion α (ppm/° C.) | 5.71 | 5.76 | 5.84 | 5.61 | 5.50 | 5.62 | 5.70 |
| Liquidus temperature TL (° C.) | 1215 | 1218 | 1210 | 1225 | 1217 | 1224 | 1224 |
| Young's modulus parameter Y | 0.99 | 1.00 | 0.98 | 0.98 | 0.96 | 1.02 | 1.02 |
| Liquidus parameter L | 8.9 | 8.8 | 8.8 | 9.1 | 9.4 | 8.9 | 8.9 |
| Thermal expansion parameter C | 1.14 | 1.14 | 1.15 | 1.14 | 1.10 | 1.14 | 1.14 |
| Glass transition point (° C.) | 703 | 703 | 698 | 696 | 698 | 696 | 698 |
| Density (g/cm³) | 3.12 | 3.14 | 3.16 | 3.06 | 2.97 | 3.19 | 3.20 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.08 | 0.15 | −0.04 | 0.11 | 0.38 | 0.11 | −0.01 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | 41100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 96

| | Example | Example | Example | Example | Example | Example | Example |
|---|---|---|---|---|---|---|---|
| (mol %) | 671 | 672 | 673 | 674 | 675 | 676 | 677 |
| SiO₂ | 49 | 49 | 49 | 48 | 49 | 49 | 49 |
| Al₂O₃ | 11 | 11 | 11 | 11 | 11 | 11 | 11 |
| B₂O₃ | 6 | 6 | 6 | 6 | 6 | 6 | 6 |
| MgO | 17 | 17 | 17 | 17 | 17 | 17 | 17 |
| CaO | 4 | 4 | 4 | 3 | 4 | 4 | 4 |
| SrO | 5 | 5 | 5 | 7 | 6 | 6 | 6 |
| BaO | 2 | 3 | 3 | 3 | 2 | 2 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | | 1 | | | 1 | |
| TiO₂ | 1 | 1 | | 1 | 1 | | |
| Y₂O₃ | 2 | 2 | 2 | 2 | 2 | 2 | 2 |
| Gd₂O₃ | 2 | 2 | 2 | | 2 | 2 | 2 |
| La₂O₃ | | | | 2 | | | |
| WO₃ | | | | | | | |
| Ta₂O₅ | | | | | | | |
| Al₂O₃ + rare earth oxide | 15 | 15 | 15 | 15 | 15 | 15 | 15 |
| Y₂O₃ + Gd₂O₃ + La₂O₃ + Nd₂O₃ + Ta₂O₅ + Nb₂O₅ | 4 | 4 | 4 | 4 | 4 | 4 | 4 |
| Parameter A = (Al₂O₃ + RO)/(SiO₂ + Al₂O₃ + RO) | 0.44 | 0.45 | 0.45 | 0.46 | 0.45 | 0.45 | 0.48 |
| (Al₂O₃ + MgO)/(SiO₂ + Al₂O₃ + B₂O₃ + MgO) | 0.34 | 0.34 | 0.34 | 0.34 | 0.34 | 0.34 | 0.34 |
| MgO/ΣRO | 0.61 | 0.59 | 0.59 | 0.57 | 0,59 | 0.59 | 0.57 |
| N | 11 | 10 | 10 | 10 | 10 | 10 | 9 |
| Young's modulus E (GPa) | 99 | 97 | 98 | 97 | 98 | 99 | 97 |
| Coefficient of thermal expansion α (ppm/° C.) | 5.58 | 5.66 | 5.71 | 5.80 | 5.66 | 5.71 | 5.79 |
| Liquidus temperature TL (° C.) | 1224 | 1217 | 1219 | 1213 | 1219 | 1222 | 1213 |
| Young's modulus parameter Y | 1.00 | 0.97 | 0.99 | 0.98 | 0.99 | 1.00 | 0.97 |
| Liquidus parameter L | 9.2 | 9.3 | 9.2 | 9.0 | 9.1 | 8.9 | 9.0 |
| Thermal expansion parameter C | 1.11 | 1.12 | 1.13 | 1.16 | 1.13 | 1.13 | 1.15 |
| Glass transition point (° C.) | 702 | 697 | 694 | 698 | 701 | 699 | 693 |
| Density (g/cm³) | 3.11 | 3.13 | 3.14 | 3.15 | 3.11 | 3.13 | 3.15 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.27 | 0.08 | 0.15 | 0.10 | 0.08 | 0.15 | −0.03 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | 41100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 97

| | Example | Example | Example | Example | Example | Example | Example |
|---|---|---|---|---|---|---|---|
| (mol %) | 678 | 679 | 680 | 681 | 682 | 683 | 684 |
| SiO₂ | 49 | 48 | 49 | 49 | 49 | 49 | 49 |
| Al₂O₃ | 11 | 11 | 11 | 11 | 12 | 12 | 12 |
| B₂O₃ | 6 | 6 | 6 | 6 | 6 | 6 | 6 |
| MgO | 17 | 17 | 17 | 17 | 17 | 17 | 17 |
| CaO | 4 | 4 | 4 | 4 | 2 | 2 | 2 |
| SrO | 6 | 6 | 7 | 7 | 5 | 6 | 6 |
| BaO | 3 | 3 | 2 | 3 | 3 | 3 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | 1 | | 1 | 1 | | 1 |
| TiO₂ | | 1 | | | 1 | 1 | |
| Y₂O₃ | 4 | 2 | 2 | 2 | 2 | 2 | 2 |
| Gd₂O₃ | | | 2 | | 2 | 2 | 2 |
| La₂O₃ | | | | | | | |
| WO₃ | | | | | | | |
| Ta₂O₅ | | | | | | | |
| Al₂O₃ + rare earth oxide | 15 | 13 | 15 | 13 | 16 | 16 | 16 |
| Y₂O₃ + Gd₂O₃ + La₂O₃ + Nd₂O₃ + Ta₂O₅ + Nb₂O₅ | 4 | 2 | 4 | 2 | 4 | 4 | 4 |
| Parameter A = (Al₂O₃ + RO)/(SiO₂ + Al₂O₃ + RO) | 0.46 | 0.46 | 0.46 | 0.46 | 0.44 | 0.45 | 0.45 |
| (Al₂O₃ + MgO)/(SiO₂ + Al₂O₃ + B₂O₃ + MgO) | 0.34 | 0.34 | 0.34 | 0.34 | 0.35 | 0.35 | 0.35 |
| MgO/ΣRO | 0.57 | 0.57 | 0.57 | 0.55 | 0.63 | 0.61 | 0.61 |
| N | 8 | 10 | 9 | 9 | 11 | 10 | 10 |
| Young's modulus E (GPa) | 97 | 96 | 97 | 96 | 99 | 98 | 99 |
| Coefficient of thermal expansion α (ppm/° C.) | 5.57 | 5.45 | 5.79 | 5.58 | 5.49 | 5.58 | 5.63 |
| Liquidus temperature TL (° C.) | 1221 | 1222 | 1220 | 1223 | 1224 | 1223 | 1221 |
| Young's modulus parameter Y | 0.98 | 0.96 | 0.99 | 0.96 | 1.00 | 0.98 | 1.00 |
| Liquidus parameter L | 9.2 | 9.5 | 8.7 | 9.2 | 9.5 | 9.3 | 9.2 |
| Thermal expansion parameter C | 1.13 | 1.09 | 1.15 | 1.12 | 1.08 | 1.10 | 1.11 |
| Glass transition point (° C.) | 691 | 696 | 697 | 691 | 700 | 699 | 699 |
| Density (g/cm³) | 3.05 | 2.96 | 3.13 | 2.97 | 3.14 | 3.14 | 3.15 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.11 | 0.38 | −0.03 | 0.27 | 0.28 | 0.09 | 0.16 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 98

| | Example | Example | Example | Example | Example | Example | Example |
|---|---|---|---|---|---|---|---|
| (mol %) | 685 | 686 | 687 | 688 | 689 | 690 | 691 |
| SiO₂ | 49 | 49 | 49 | 49 | 49 | 49 | 49 |
| Al₂O₃ | 12 | 12 | 12 | 12 | 12 | 12 | 10 |
| B₂O₃ | 6 | 6 | 6 | 6 | 6 | 6 | 6 |
| MgO | 17 | 17 | 17 | 17 | 17 | 17 | 17 |
| CaO | 2 | 3 | 3 | 3 | 3 | 3 | 4 |
| SrO | 7 | 5 | 5 | 5 | 6 | 6 | 7 |
| BaO | 3 | 2 | 3 | 3 | 2 | 2 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | 1 | | 1 | | 1 | |
| TiO₂ | | 1 | 1 | | 1 | | |
| Y₂O₃ | 2 | 2 | 2 | 2 | 2 | 2 | 2 |
| Gd₂O₃ | 2 | 2 | 2 | 2 | 2 | 2 | |
| La₂O₃ | | | | | | | 2 |
| WO₃ | | | | | | | |
| Ta₂O₅ | | | | | | | |
| Al₂O₃ + rare earth oxide | 16 | 16 | 16 | 16 | 16 | 16 | 14 |
| Y₂O₃ + Gd₂O₃ + La₂O₃ + Nd₂O₃ + Ta₂O₅ + Nb₂O₅ | 4 | 4 | 4 | 4 | 4 | 4 | 4 |
| Parameter A = (Al₂O₃ + RO)/(SiO₂ + Al₂O₃ + RO) | 0.46 | 0.44 | 0.45 | 0.45 | 0.45 | 0.45 | 0.46 |
| (Al₂O₃ + MgO)/(SiO₂ + Al₂O₃ + B₂O₃ + MgO) | 0.35 | 0.35 | 0.35 | 0.35 | 0.35 | 0.35 | 0.33 |
| MgO/ΣRO | 0.59 | 0.63 | 0.61 | 0.61 | 0.61 | 0.61 | 0.55 |
| N | 9 | 11 | 10 | 10 | 10 | 10 | 9 |
| Young's modulus E (GPa) | 97 | 100 | 98 | 99 | 98 | 99 | 96 |
| Coefficient of thermal expansion α (ppm/° C.) | 5.71 | 5.44 | 5.53 | 5.58 | 5.52 | 5.58 | 5.90 |
| Liquidus temperature TL (° C.) | 1223 | 1217 | 1213 | 1213 | 1215 | 1216 | 1213 |
| Young's modulus parameter Y | 0.98 | 1.01 | 0.98 | 0.99 | 0.99 | 1.01 | 0.97 |
| Liquidus parameter L | 9.0 | 9.4 | 9.4 | 9.3 | 9.2 | 9.0 | 8.7 |
| Thermal expansion parameter C | 1.12 | 1.08 | 1.09 | 1.10 | 1.10 | 1.11 | 1.18 |
| Glass transition point (° C.) | 698 | 704 | 699 | 699 | 703 | 703 | 689 |
| Density (g/cm³) | 3.16 | 3.11 | 3.12 | 3.14 | 3.11 | 3.12 | 3.14 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | −0.02 | 0.28 | 0.10 | 0.17 | 0.10 | 0.17 | 0.07 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 99

| | Example | Example | Example | Example | Example | Example | Example |
|---|---|---|---|---|---|---|---|
| (mol %) | 692 | 693 | 694 | 695 | 696 | 697 | 698 |
| SiO₂ | 49 | 49 | 49 | 49 | 49 | 49 | 49 |
| Al₂O₃ | 12 | 12 | 12 | 12 | 12 | 12 | 12 |
| B₂O₃ | 6 | 6 | 6 | 6 | 6 | 6 | 6 |
| MgO | 17 | 17 | 17 | 17 | 17 | 17 | 17 |
| CaO | 3 | 3 | 3 | 3 | 3 | 4 | 4 |
| SrO | 6 | 6 | 7 | 7 | 7 | 5 | 5 |
| BaO | 3 | 3 | 2 | 3 | 3 | 2 | 3 |
| Li₂O | | | | | | | |
| Na₂O | | | | | | | |
| K₂O | | | | | | | |
| ZnO | | | | | | | |
| P₂O₅ | | | | | | | |
| ZrO₂ | | 1 | | | 1 | | |
| TiO₂ | | 1 | | 1 | | 1 | |
| Y₂O₃ | 2 | 2 | 2 | 2 | 2 | 2 | 2 |
| Gd₂O₃ | 2 | | 2 | | | 2 | 2 |
| La₂O₃ | | | | | | | |
| WO₃ | | | | | | | |
| Ta₂O₅ | | | | | | | |
| Al₂O₃ + rare earth oxide | 16 | 14 | 16 | 14 | 14 | 16 | 16 |
| Y₂O₃ + Gd₂O₃ + La₂O₃ + Nd₂O₃ + Ta₂O₅ + Nb₂O₅ | 4 | 2 | 4 | 2 | 2 | 4 | 4 |
| Parameter A = (Al₂O₃ + RO)/(SiO₂ + Al₂O₃ + RO) | 0.46 | 0.46 | 0.46 | 0.46 | 0.46 | 0.45 | 0.46 |
| (Al₂O₃ + MgO)/(SiO₂ + Al₂O₃ + B₂O₃ + MgO) | 0.35 | 0.35 | 0.35 | 0.35 | 0.35 | 0.35 | 0.35 |
| MgO/ΣRO | 0.59 | 0.59 | 0.59 | 0.57 | 0.57 | 0.61 | 0.59 |
| N | 9 | 10 | 9 | 9 | 9 | 10 | 9 |
| Young's modulus E (GPa) | 97 | 97 | 97 | 95 | 96 | 98 | 97 |
| Coefficient of thermal expansion α (ppm/° C.) | 5.66 | 5.32 | 5.66 | 5.40 | 5.45 | 5.48 | 5.61 |
| Liquidus temperature TL (° C.) | 1210 | 1216 | 1217 | 1217 | 1221 | 1223 | 1218 |
| Young's modulus parameter Y | 0.98 | 0.97 | 0.99 | 0.95 | 0.97 | 0.99 | 0.98 |
| Liquidus parameter L | 9.1 | 9.6 | 8.9 | 9.5 | 9.3 | 9.3 | 9.2 |
| Thermal expansion parameter C | 1.12 | 1.07 | 1.12 | 1.08 | 1.09 | 1.09 | 1.11 |
| Glass transition point (° C.) | 698 | 699 | 701 | 698 | 697 | 701 | 693 |
| Density (g/cm³) | 3.14 | 2.95 | 3.12 | 2.95 | 2.97 | 3.09 | 3.13 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | −0.02 | 0.40 | −0.02 | 0.21 | 0.28 | 0.10 | −0.01 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 100

| | Example | Example | Example | Example | Example | Example | Example |
|---|---|---|---|---|---|---|---|
| (mol %) | 699 | 700 | 701 | 702 | 703 | 704 | 705 |
| SiO₂ | 49 | 49 | 49 | 50 | 50 | 50 | 50 |
| Al₂O₃ | 12 | 12 | 12 | 10 | 10 | 10 | 10 |
| B₂O₃ | 6 | 6 | 6 | 6 | 6 | 6 | 6 |
| MgO | 17 | 17 | 17 | 21 | 21 | 21 | 21 |
| CaO | 4 | 4 | 4 | 2 | 2 | 2 | 2 |
| SrO | 6 | 6 | 6 | 2 | 2 | 2 | 2 |
| BaO | 2 | 3 | 3 | 4 | 4 | 4 | 4 |
| Li₂O | | | | | | | |
| Na₂O | | | | | | | |
| K₂O | | | | | | | |
| ZnO | | | | | | | 1 |
| P₂O₅ | | | | | | 1 | |
| ZrO₂ | | | 1 | 1 | 1 | 1 | 1 |
| TiO₂ | | 1 | | 1 | 1 | 1 | 1 |
| Y₂O₃ | 2 | 2 | 2 | 2 | 2 | 2 | 2 |
| Gd₂O₃ | 2 | | | | | | |
| La₂O₃ | | | | | | | |
| WO₃ | | | | | 1 | | |
| Ta₂O₅ | | | | 1 | | | |
| Al₂O₃ + rare earth oxide | 16 | 14 | 14 | 12 | 12 | 12 | 12 |
| Y₂O₃ + Gd₂O₃ + La₂O₃ + Nd₂O₃ + Ta₂O₅ + Nb₂O₅ | 4 | 2 | 2 | 3 | 2 | 2 | 2 |
| Parameter A = (Al₂O₃ + RO)/(SiO₂ + Al₂O₃ + RO) | 0.46 | 0.46 | 0.46 | 0.44 | 0.44 | 0.44 | 0.44 |
| (Al₂O₃ + MgO)/(SiO₂ + Al₂O₃ + B₂O₃ + MgO) | 0.35 | 0.35 | 0.35 | 0.36 | 0.36 | 0.36 | 0.36 |
| MgO/ΣRO | 0.59 | 0.57 | 0.57 | 0.72 | 0.72 | 0.72 | 0.70 |
| N | 9 | 9 | 9 | 11 | 11 | 11 | 11 |
| Young's modulus E (GPa) | 98 | 95 | 96 | 98 | 98 | 96 | 97 |
| Coefficient of thermal expansion α (ppm/° C.) | 5.61 | 5.35 | 5.40 | 5.00 | 5.06 | 5.09 | 5.05 |
| Liquidus temperature TL (° C.) | 1220 | 1221 | 1225 | 1194 | 1189 | 1189 | 1187 |
| Young's modulus parameter Y | 0.99 | 0.95 | 0.96 | 0.97 | 0.96 | 0.96 | 0.96 |
| Liquidus parameter L | 9.0 | 9.6 | 9.5 | 9.9 | 9.7 | 9.7 | 9.8 |
| Thermal expansion parameter C | 1.12 | 1.07 | 1.08 | 0.99 | 1.01 | 1.01 | 1.00 |
| Glass transition point (° C.) | 697 | 696 | 692 | 705 | 705 | 705 | 705 |
| Density (g/cm³) | 3.11 | 2.94 | 2.96 | 3.01 | 2.97 | 2.95 | 2.94 |
| Liquidus viscosity log η_{L}(dPa · s) | 2< | 2< | 2< | 2< | 2< | 2< | 2< |
| K_{IC} (MPa · m^{0.5}) | 0.8< | 0.8< | 0.8< | 0.8< | 0.8< | 0.8< | 0.8< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | −0.01 | 0.22 | 0.29 | 0.97 | 0.64 | 0.64 | 0.64 |
| Transmittance (%) @1064 nm, 0.7 mmt | 80≤ | 80≤ | 80≤ | 80≤ | 80≤ | 80≤ | 80≤ |
| T₂ (° C.) | <1350 | <1350 | <1350 | <1350 | <1350 | <1350 | <1350 |
| T₃ (° C.) | <1200 | <1200 | <1200 | <1200 | <1200 | <1200 | <1200 |
| T₄ (° C.) | <1100 | <1100 | <1100 | <1100 | <1100 | <1100 | <1100 |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 101

| | Example | Example | Example | Example | Example | Example | Example |
|---|---|---|---|---|---|---|---|
| (mol %) | 706 | 707 | 708 | 709 | 710 | 711 | 712 |
| SiO₂ | 51.5 | 51.5 | 51.5 | 51.5 | 51.5 | 51.5 | 51.5 |
| Al₂O₃ | 12 | 12.5 | 12.5 | 13 | 13 | 13 | 13.5 |
| B₂O₃ | 8.5 | 8 | 8.5 | 7.5 | 8 | 8.5 | 7 |
| MgO | 22 | 22 | 21.5 | 22 | 21.5 | 21 | 22 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 13.5 | 14 | 14 | 14.5 | 14.5 | 14.5 | 15 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.41 | 0.42 | 0.41 | 0.42 | 0.42 | 0.41 | 0.42 |
| Al₂O₃ + RO) | | | | | | | |
| (Al₂O₃ + MgO)/(SiO₂ + Al₂O₃ + B₂O₃ + MgO) | 0.36 | 0.37 | 0.36 | 0.37 | 0.37 | 0.36 | 0.38 |
| MgO/ΣRO | 0.90 | 0.90 | 0.90 | 0.90 | 0.90 | 0.89 | 0.90 |
| N | 10 | 10 | 10 | 10 | 10 | 10 | 10 |
| Young's modulus E (GPa) | 98 | 98 | 98 | 99 | 98 | 98 | 99 |
| Coefficient of thermal expansion α (ppm/° C.) | 4.15 | 4.13 | 4.11 | 4.11 | 4.09 | 4.06 | 4.10 |
| Liquidus temperature TL (° C.) | 1208 | 1217 | 1219 | 1220 | 1219 | 1217 | 1218 |
| Young's modulus parameter Y | 0.97 | 0.97 | 0.97 | 0.98 | 0.97 | 0.97 | 0.99 |
| Liquidus parameter L | 9.5 | 9.7 | 9.6 | 9.8 | 9.7 | 9.7 | 9.9 |
| Thermal expansion parameter C | 0.83 | 0.83 | 0.82 | 0.83 | 0.82 | 0.82 | 0.82 |
| Glass transition point (° C.) | 718 | 720 | 720 | 722 | 722 | 722 | 725 |
| Density (g/cm³) | 2.71 | 2.72 | 2.71 | 2.72 | 2.72 | 2.71 | 2.73 |
| Liquidus viscosity log η_{L}(dPa · s) | 2< | 2< | 2< | 2< | 2< | 2< | 2< |
| K_{IC} (MPa · m^{0.5}) | 0.9< | 0.10< | 0.11< | 0.12< | 0.13< | 0.14< | 0.15< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.93 | 0.92 | 0.91 | 0.92 | 0.91 | 0.90 | 0.92 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 102

| | Example | Example | Example | Example | Example | Example | Example |
|---|---|---|---|---|---|---|---|
| (mol %) | 713 | 714 | 715 | 716 | 717 | 718 | 719 |
| SiO₂ | 51.5 | 51.5 | 52 | 52 | 52 | 52 | 52 |
| Al₂O₃ | 13.5 | 13.5 | 11.5 | 12 | 12 | 12.5 | 12.5 |
| B₂O₃ | 7.5 | 8 | 8.5 | 8 | 8.5 | 7.5 | 8 |
| MgO | 21.5 | 21 | 22 | 22 | 21.5 | 22 | 21.5 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 15 | 15 | 13 | 13.5 | 13.5 | 14 | 14 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.42 | 0.42 | 0.41 | 0.41 | 0.41 | 0.42 | 0.41 |
| Al₂O₃ + RO) | | | | | | | |
| (Al₂O₃ + MgO)/(SiO₂ + Al₂O₃ + B₂O₃ + MgO) | 0.37 | 0.37 | 0.36 | 0.36 | 0.36 | 0.37 | 0.36 |
| MgO/ΣRO | 0.90 | 0.89 | 0.90 | 0.90 | 0.90 | 0.90 | 0.90 |
| N | 10 | 10 | 10 | 10 | 10 | 10 | 10 |
| Young's modulus E (GPa) | 99 | 98 | 97 | 98 | 97 | 98 | 98 |
| Coefficient of thermal expansion α (ppm/° C.) | 4.07 | 4.05 | 4.15 | 4.14 | 4.11 | 4.12 | 4.10 |
| Liquidus temperature TL (° C.) | 1220 | 1216 | 1218 | 1218 | 1217 | 1230 | 1228 |
| Young's modulus parameter Y | 0.98 | 0.97 | 0.96 | 0.97 | 0.96 | 0.98 | 0.97 |
| Liquidus parameter L | 9.9 | 9.8 | 9.5 | 9.6 | 9.6 | 9.7 | 9.7 |
| Thermal expansion parameter C | 0.82 | 0.81 | 0.83 | 0.83 | 0.82 | 0.83 | 0.82 |
| Glass transition point (° C.) | 725 | 725 | 718 | 718 | 718 | 720 | 720 |
| Density (g/cm³) | 2.72 | 2.72 | 2.71 | 2.71 | 2.71 | 2.72 | 2.71 |
| Liquidus viscosity log η_{L}(dPa · s) | 2< | 2< | 2< | 2< | 2< | 2< | 2< |
| K_{IC} (MPa · m^{0.5}) | 0.16< | 0.17< | 0.18< | 0.19< | 0.20< | 0.21< | 0.22< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.91 | 0.90 | 0.97 | 0.97 | 0.96 | 0.96 | 0.95 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 103

| | Example | Example | Example | Example | Example | Example | Example |
|---|---|---|---|---|---|---|---|
| (mol %) | 720 | 721 | 722 | 723 | 724 | 725 | 726 |
| SiO₂ | 52 | 52 | 52 | 52 | 52 | 52 | 52 |
| Al₂O₃ | 12.5 | 13 | 13 | 13 | 13.5 | 13.5 | 13.5 |
| B₂O₃ | 8.5 | 7 | 7.5 | 8 | 6.5 | 7 | 7.5 |
| MgO | 21 | 22 | 21.5 | 23 | 22 | 21.5 | 21 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 14 | 14.5 | 14.5 | 14.5 | 15 | 15 | 15 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.41 | 0.42 | 0.42 | 0.41 | 0.42 | 0.42 | 0.42 |
| Al₂O₃ + RO) | | | | | | | |
| (Al₂O₃ + MgO)/(SiO₂ + Al₂O₃ + B₂O₃ + MgO) | 0.36 | 0.37 | 0.37 | 0.36 | 0.38 | 0.37 | 0.37 |
| MgO/ΣRO | 0.89 | 0.90 | 0.90 | 0.89 | 0.90 | 0.90 | 0.89 |
| N | 10 | 10 | 10 | 10 | 10 | 10 | 10 |
| Young's modulus E (GPa) | 97 | 99 | 98 | 98 | 99 | 99 | 98 |
| Coefficient of thermal expansion α (ppm/° C.) | 4.07 | 4.11 | 4.08 | 4.06 | 4.09 | 4.06 | 4.04 |
| Liquidus temperature TL (° C.) | 1225 | 1226 | 1228 | 1224 | 1227 | 1225 | 1225 |
| Young's modulus parameter Y | 0.96 | 0.98 | 0.98 | 0.97 | 0.99 | 0.98 | 0.98 |
| Liquidus parameter L | 9.7 | 9.8 | 9.8 | 9.8 | 10.0 | 9.9 | 9.9 |
| Thermal expansion parameter C | 0.82 | 0.82 | 0.82 | 0.81 | 0.82 | 0.81 | 0.81 |
| Glass transition point (° C.) | 720 | 722 | 722 | 722 | 727 | 725 | 725 |
| Density (g/cm³) | 2.71 | 2.72 | 2.72 | 2.71 | 2.73 | 2.72 | 2.72 |
| Liquidus viscosity log η_{L}(dPa · s) | 2< | 2< | 2< | 2< | 2< | 2< | 2< |
| K_{IC} (MPa · m^{0.5}) | 0.23< | 0.24< | 0.25< | 0.26< | 0.27< | 0.28< | 0.29< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 0.94 | 0.96 | 0.95 | 0.94 | 0.95 | 0.94 | 0.93 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 104

| | Example | Example | Example | Example | Example | Example | Example |
|---|---|---|---|---|---|---|---|
| (mol %) | 727 | 728 | 729 | 730 | 731 | 732 | 733 |
| SiO₂ | 52.5 | 52.5 | 52.5 | 52.5 | 52.5 | 52.5 | 52.5 |
| Al₂O₃ | 11.5 | 11.5 | 12 | 12 | 12 | 12.5 | 12.5 |
| B₂O₃ | 8 | 8.5 | 7.5 | 8 | 8.5 | 7 | 8 |
| MgO | 22 | 21.5 | 22 | 21.5 | 21 | 22 | 21 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 13 | 13 | 13.5 | 13.5 | 13.5 | 14 | 14 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.41 | 0.40 | 0.41 | 0.41 | 0.40 | 0.41 | 0.41 |
| Al₂O₃ + RO) | | | | | | | |
| (Al₂O₃ + MgO)/(SiO₂ + Al₂O₃ + B₂O₃ + MgO) | 0.36 | 0.35 | 0.36 | 0.36 | 0.35 | 0.37 | 0.36 |
| MgO/ΣRO | 0.90 | 0.90 | 0.90 | 0.90 | 0.89 | 0.90 | 0.89 |
| N | 10 | 10 | 10 | 10 | 10 | 10 | 10 |
| Young's modulus E (GPa) | 97 | 97 | 98 | 97 | 97 | 98 | 97 |
| Coefficient of thermal expansion α (ppm/° C.) | 4.15 | 4.12 | 4.13 | 4.10 | 4.08 | 4.11 | 4.06 |
| Liquidus temperature TL (° C.) | 1223 | 1222 | 1224 | 1222 | 1220 | 1231 | 1230 |
| Young's modulus parameter Y | 0.96 | 0.96 | 0.97 | 0.96 | 0.96 | 0.98 | 0.97 |
| Liquidus parameter L | 9.6 | 9.5 | 9.7 | 9.6 | 9.6 | 9.8 | 9.7 |
| Thermal expansion parameter C | 0.83 | 0.82 | 0.83 | 0.82 | 0.82 | 0.82 | 0.81 |
| Glass transition point (° C.) | 718 | 718 | 718 | 718 | 718 | 720 | 720 |
| Density (g/cm³) | 2.71 | 2.70 | 2.71 | 2.71 | 2.70 | 2.72 | 2.71 |
| Liquidus viscosity log η_{L}(dPa · s) | 2< | 2< | 2< | 2< | 2< | 2< | 2< |
| K_{IC} (MPa · m^{0.5}) | 0.30< | 0.31< | 0.32< | 0.33< | 0.34< | 0.35< | 0.36< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 1.01 | 1.00 | 1.00 | 0.99 | 0.98 | 1.00 | 0.98 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 105

| | Example | Example | Example | Example | Example | Example | Example |
|---|---|---|---|---|---|---|---|
| (mol %) | 734 | 735 | 736 | 737 | 738 | 739 | 740 |
| SiO₂ | 52.5 | 52.5 | 52.5 | 52.5 | 52.5 | 53 | 53 |
| Al₂O₃ | 13 | 13 | 13 | 13.5 | 13.5 | 11.5 | 11.5 |
| B₂O₃ | 6.5 | 7 | 7.5 | 6.5 | 7 | 7.5 | 8 |
| MgO | 22 | 21.5 | 21 | 21.5 | 21 | 22 | 21.5 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | 1 | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 14.5 | 14.5 | 14.5 | 15 | 15 | 13 | 13 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.42 | 0.41 | 0.41 | 0.42 | 0.41 | 0.40 | 0.40 |
| Al₂O₃ + RO) | | | | | | | |
| (Al₂O₃ + MgO)/(SiO₂ + Al₂O₃ + B₂O₃ + MgO) | 0.37 | 0.37 | 0.36 | 0.37 | 0.37 | 0.36 | 0.35 |
| MgO/ΣRO | 0.90 | 0.90 | 0.89 | 0.90 | 0.89 | 0.90 | 0.90 |
| N | 10 | 10 | 10 | 10 | 10 | 10 | 10 |
| Young's modulus E (GPa) | 99 | 99 | 98 | 99 | 99 | 97 | 97 |
| Coefficient of thermal expansion α (ppm/° C.) | 4.10 | 4.07 | 4.05 | 4.06 | 4.03 | 4.14 | 4.11 |
| Liquidus temperature TL (° C.) | 1230 | 1229 | 1229 | 1229 | 1224 | 1225 | 1223 |
| Young's modulus parameter Y | 0.99 | 0.98 | 0.97 | 0.99 | 0.98 | 0.97 | 0.96 |
| Liquidus parameter L | 9.9 | 9.9 | 9.8 | 10.0 | 10.0 | 9.8 | 9.8 |
| Thermal expansion parameter C | 0.82 | 0.82 | 0.81 | 0.81 | 0.81 | 0.83 | 0.82 |
| Glass transition point (° C.) | 724 | 722 | 722 | 727 | 725 | 718 | 718 |
| Density (g/cm³) | 2.72 | 2.72 | 2.71 | 2.73 | 2.72 | 2.71 | 2.70 |
| Liquidus viscosity log η_{L}(dPa · s) | 2< | 2< | 2< | 2< | 2< | 2< | 2< |
| K_{IC} (MPa · m^{0.5}) | 0.37< | 0.38< | 0.39< | 0.40< | 0.41< | 0.42< | 0.43< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 1.00 | 0.99 | 0.98 | 0.98 | 0.97 | 1.04 | 1.04 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 106

| | Example | Example | Example | Example | Example | Example | Example |
|---|---|---|---|---|---|---|---|
| (mol %) | 741 | 742 | 743 | 744 | 745 | 746 | 747 |
| SiO₂ | 53 | 53 | 53 | 53 | 53 | 53 | 53 |
| Al₂O₃ | 11.5 | 12 | 12 | 12 | 12.5 | 12.5 | 12.5 |
| B₂O₃ | 8.5 | 7 | 7.5 | 8 | 6.5 | 7 | 7.5 |
| MgO | 21 | 22 | 21.5 | 21 | 22 | 21.5 | 21 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 13 | 13.5 | 13.5 | 13.5 | 14 | 14 | 14 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.40 | 0.41 | 0.40 | 0.40 | 0.41 | 0.41 | 0.40 |
| Al₂O₃ + RO) | | | | | | | |
| (Al₂O₃ + MgO)/(SiO₂ + Al₂O₃ + B₂O₃ + MgO) | 0.35 | 0.36 | 0.36 | 0.35 | 0.37 | 0.36 | 0.36 |
| MgO/ΣRO | 0.89 | 0.90 | 0.90 | 0.89 | 0,90 | 0.90 | 0.89 |
| N | 10 | 10 | 10 | 10 | 10 | 10 | 10 |
| Young's modulus E (GPa) | 96 | 98 | 97 | 97 | 99 | 98 | 98 |
| Coefficient of thermal expansion α (ppm/° C.) | 4.09 | 4.12 | 4.10 | 4.07 | 4.11 | 4.08 | 4.05 |
| Liquidus temperature TL (° C.) | 1220 | 1222 | 1224 | 1221 | 1231 | 1231 | 1231 |
| Young's modulus parameter Y | 0.95 | 0.97 | 0.97 | 0.96 | 0.98 | 0.98 | 0.97 |
| Liquidus parameter L | 9.6 | 9.8 | 9.7 | 9.7 | 9.9 | 9.8 | 9.8 |
| Thermal expansion parameter C | 0.82 | 0.82 | 0.82 | 0.81 | 0.82 | 0.82 | 0.81 |
| Glass transition point (° C.) | 718 | 719 | 718 | 718 | 722 | 721 | 720 |
| Density (g/cm³) | 2.70 | 2.72 | 2.71 | 2.70 | 2.72 | 2.72 | 2.71 |
| Liquidus viscosity log η_{L}(dPa · s) | 2< | 2< | 2< | 2< | 2< | 2< | 2< |
| K_{IC} (MPa · m^{0.5}) | 0.44< | 0.45< | 0.46< | 0.47< | 0.48< | 0.49< | 0.50< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 1.03 | 1.04 | 1.03 | 1.02 | 1.04 | 1.03 | 1.02 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 107

| | Example | Example | Example | Example | Example | Example | Example |
|---|---|---|---|---|---|---|---|
| (mol %) | 748 | 749 | 750 | 751 | 752 | 753 | 754 |
| SiO₂ | 53 | 53 | 53 | 53.5 | 53.5 | 53.5 | 53.5 |
| Al₂O₃ | 13 | 13 | 13.5 | 11.5 | 11.5 | 11.5 | 12 |
| B₂O₃ | 6.5 | 7 | 6.5 | 7 | 7.5 | 8 | 6.5 |
| MgO | 21.5 | 21 | 21 | 22 | 21.5 | 21 | 22 |
| CaO | 1 | 1 | 1 | 1 | 1 | 1 | 1 |
| SrO | 1 | 1 | 1 | 1 | 1 | 1 | 1 |
| BaO | 0.5 | 0.5 | 0.5 | 0.5 | 0.5 | 0.5 | 0.5 |
| Li₂O | | | | | | | |
| Na₂O | | | | | | | |
| K₂O | | | | | | | |
| ZnO | | | | | | | |
| P₂O₅ | | | | | | | |
| ZrO₂ | 1 | 1 | 1 | 1 | 1 | 1 | 1 |
| TiO₂ | 1 | 1 | 1 | 1 | 1 | 1 | 1 |
| Y₂O₃ | 1.5 | 1.5 | 1.5 | 1.5 | 1.5 | 1.5 | 1.5 |
| Gd₂O₃ | | | | | | | |
| La₂O₃ | | | | | | | |
| WO₃ | | | | | | | |
| Ta₂O₅ | | | | | | | |
| Al₂O₃ + rare earth oxide | 14.5 | 14.5 | 15 | 13 | 13 | 13 | 13.5 |
| Y₂O₃ + Gd₂O₃ + La₂O₃ + | 1.5 | 1.5 | 1.5 | 1.5 | 1.5 | 1.5 | 1.5 |
| Nd₂O₃ + Ta₂O₅ + Nb₂O₅ | | | | | | | |
| Parameter A = (Al₂O₃ + RO)/(SiO₂ + | 0.41 | 0.41 | 0.41 | 0.40 | 0.40 | 0.40 | 0.41 |
| Al₂O₃ + RO) | | | | | | | |
| (Al₂O₃ + MgO)/(SiO₂ + Al₂O₃ + B₂O₃ + MgO) | 0.37 | 0.36 | 0.37 | 0.36 | 0.35 | 0.35 | 0.36 |
| MgO/ΣRO | 0.90 | 0.89 | 0.89 | 0.90 | 0.90 | 0.89 | 0.90 |
| N | 10 | 10 | 10 | 10 | 10 | 10 | 10 |
| Young's modulus E (GPa) | 99 | 98 | 99 | 98 | 97 | 97 | 98 |
| Coefficient of thermal expansion α (ppm/° C.) | 4.06 | 4.04 | 4.02 | 4.13 | 4.10 | 4.08 | 4.11 |
| Liquidus temperature TL (° C.) | 1231 | 1226 | 1227 | 1221 | 1224 | 1220 | 1222 |
| Young's modulus parameter Y | 0.98 | 0.98 | 0.98 | 0.97 | 0.96 | 0.96 | 0.98 |
| Liquidus parameter L | 10.0 | 9.9 | 10.0 | 9.7 | 9.7 | 9.6 | 9.8 |
| Thermal expansion parameter C | 0.81 | 0.81 | 0.81 | 0.82 | 0.82 | 0.81 | 0.82 |
| Glass transition point (° C.) | 724 | 722 | 727 | 719 | 718 | 718 | 721 |
| Density (g/cm³) | 2.72 | 2.72 | 2.72 | 2.71 | 2.71 | 2.70 | 2.72 |
| Liquidus viscosity log η_{L}(dPa · s) | 2< | 2< | 2< | 2< | 2< | 2< | 2< |
| K_{IC} (MPa · m^{0.5}) | 0.51< | 0.52< | 0.53< | 0.54< | 0.55< | 0.56< | 0.57< |
| Transmittance (%) @308 nm, 0.7 mmt | 30≤ | 30≤ | 30≤ | 30≤ | 30≤ | 30≤ | 30≤ |
| Transmittance (%) @350 nm, 0.7 mmt | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ |
| Acid resistance parameter T | 1.02 | 1.01 | 1.01 | 1.08 | 1.07 | 1.06 | 1.08 |
| Transmittance (%) @1064 nm, 0.7 mmt | 80≤ | 80≤ | 80≤ | 80≤ | 80≤ | 80≤ | 80≤ |
| T₂ (° C.) | | | | | | | |
| T₃ (° C.) | | | | | | | |
| T₄ (° C.) | | | | | | | |
| Deflection determination | ∘ | ∘ | ∘ | ∘ | ∘ | ∘ | ∘ |
| Manufacturability determination | ∘ | ∘ | ∘ | ∘ | ∘ | ∘ | ∘ |
| Transmission ability determination | ∘ | ∘ | ∘ | ∘ | ∘ | ∘ | ∘ |

TABLE 108

| | Example | Example | Example | Example | Example |
|---|---|---|---|---|---|
| (mol %) | 755 | 756 | 757 | 758 | 759 |
| SiO₂ | 53.5 | 53.5 | 53.5 | 53.5 | 53.5 |
| Al₂O₃ | 12 | 12 | 12.5 | 12.5 | 13 |
| B₂O₃ | 7 | 7.5 | 6.5 | 7 | 6.5 |
| MgO | 21.5 | 21 | 21.5 | 21 | 21 |
| CaO | 1 | 1 | 1 | 1 | 1 |
| SrO | 1 | 1 | 1 | 1 | 1 |
| BaO | 0.5 | 0.5 | 0.5 | 0.5 | 0.5 |
| Li₂O | | | | | |
| Na₂O | | | | | |
| K₂O | | | | | |
| ZnO | | | | | |
| P₂O₅ | | | | | |
| ZrO₂ | 1 | 1 | 1 | 1 | 1 |
| TiO₂ | 1 | 1 | 1 | 1 | 1 |
| Y₂O₃ | 1.5 | 1.5 | 1.5 | 1.5 | 1.5 |
| Gd₂O₃ | | | | | |
| La₂O₃ | | | | | |
| WO₃ | | | | | |
| Ta₂O₃ | | | | | |
| Al₂O₃ + rare earth oxide | 13.5 | 13.5 | 14 | 14 | 14.5 |
| Y₂O₃ + Gd₂O₃ + La₂O₃ + Nd₂O₃ + Ta₂O₅ + Nb₂O₅ | 1.5 | 1.5 | 1.5 | 1.5 | 1.5 |
| Parameter A = (Al₂O₃ + RO)/(SiO₂ + Al₂O₃ + RO) | 0.40 | 0.40 | 0.41 | 0.40 | 0.41 |
| (Al₂O₃ + MgO)/(SiO₂ + Al₂O₃ + B₂O₃ + MgO) | 0.36 | 0.35 | 0.36 | 0.36 | 0.36 |
| MgO/ΣRO | 0.90 | 0.89 | 0.90 | 0.89 | 0.89 |
| N | 10 | 10 | 10 | 10 | 10 |
| Young's modulus E (GPa) | 98 | 97 | 98 | 98 | 98 |
| Coefficient of thermal expansion α (ppm/° C.) | 4.09 | 4.06 | 4.07 | 4.05 | 4.03 |
| Liquidus temperature TL (° C.) | 1221 | 1221 | 1232 | 1227 | 1228 |
| Young's modulus parameter Y | 0.97 | 0.96 | 0.98 | 0.97 | 0.98 |
| Liquidus parameter L | 9.8 | 9.8 | 9.9 | 9.9 | 10.0 |
| Thermal expansion parameter C. | 0.82 | 0.81 | 0.81 | 0.81 | 0.81 |
| Glass transition point (° C.) | 719 | 719 | 723 | 721 | 725 |
| Density (g/cm³) | 2.71 | 2.71 | 2.72 | 2.71 | 2.72 |
| Liquidus viscosity log η_{L}(dPa · s) | 2< | 2< | 2< | 2< | 2< |
| K_{IC} (MPa · m^{0.5}) | 0.58< | 0.59< | 0.60< | 0.61< | 0.62< |
| Transmittance (%) @308 nm, 0.7 mmt | 30≤ | 30≤ | 30≤ | 30≤ | 30≤ |
| Transmittance (%) @350 nm, 0.7 mmt | 75≤ | 75≤ | 75≤ | 75≤ | 75≤ |
| Transmittance (%) @550 nm, 0.7 mmt | 883 | 88≤ | 88≤ | 88≤ | 88≤ |
| Acid resistance parameter T | 1.07 | 1.06 | 1.07 | 1.06 | 1.05 |
| Transmittance (%) @1064 nm, 0.7 mmt | 80≤ | 80≤ | 80≤ | 80≤ | 80≤ |
| T₂ (° C.) | | | | | |
| T₃ (° C.) | | | | | |
| T₄ (° C.) | | | | | |
| Deflection determination | ∘ | ∘ | ∘ | ∘ | ∘ |
| Manufacturability determination | ∘ | ∘ | ∘ | ∘ | ∘ |
| Transmission ability determination | ∘ | ∘ | ∘ | ∘ | ∘ |

TABLE 109

| | Example | Example | Example | Example | Example | Example | Example |
|---|---|---|---|---|---|---|---|
| (mol %) | 760 | 761 | 762 | 763 | 764 | 765 | 766 |
| SiO₂ | 63.2 | 61.8 | 43 | 42.8 | 65.7 | 60.7 | 71.8 |
| Al₂O₃ | 11.6 | 10.6 | 13 | 8.1 | 12.1 | 13.3 | 6 |
| B₂O₃ | | 1.4 | | | 0.9 | 0.9 | |
| MgO | 14.9 | 15.9 | | 8.3 | 10.8 | 13.3 | |
| CaO | 8.7 | 8.7 | | | 10.4 | 10.7 | 3.1 |
| SrO | | | | | | | 9 |
| BaO | | | | | | | 10.1 |
| Li₂O | | | | | | | |
| Na₂O | | | | | | | |
| K₂O | | | | | | | |
| ZnO | | | | | | | |
| P₂O₅ | | | | | | | |
| ZrO₂ | | | | 2.4 | | 0.8 | |
| TiO₂ | | | 8 | 5.7 | | | |
| Y₂O₃ | 1.4 | 1.4 | | | | | |
| Gd₂O₃ | | | | | | | |
| La₂O₃ | | | | | | | |
| WO₃ | | | | | | | |
| Ta₂O₅ | | | | | | | |
| MnO | | | 36 | 32.7 | | | |
| Al₂O₃ + rare earth oxide | 13 | 12 | 13 | 8.1 | 12.1 | 13.3 | 6 |
| Y₂O₃ + Gd₂O₃ + La₂O₃ + | 1.4 | 1.4 | 0 | 0 | 0 | 0 | 0 |
| Nd₂O₃ + Ta₂O₅ + Nb₂O₅ | | | | | | | |
| Parameter A = (Al₂O₃ + RO)/(SiO₂ + | 0.36 | 0.36 | 0.53 | 0.53 | 0.34 | 0.38 | 0.28 |
| Al₂O₃ + RO) | | | | | | | |
| (Al₂O₃ + MgO)/(SiO₂ + | 0.30 | 0.30 | 0.23 | 0.28 | 0.26 | 0.30 | 0.08 |
| Al₂O₃ + B₂O₃ + MgO) | | | | | | | |
| MgO/ΣRO | 0.63 | 0.65 | 0.00 | 0.20 | 0.51 | 0.55 | 0.00 |
| N | 5 | 6 | 3 | 5 | 5 | 6 | 5 |
| Young's modulus E (GPa) | 95 | 94 | 101 | 102 | 90 | 95 | 75 |
| Coefficient of thermal expansion | 4.39 | 4.72 | 4.8 | 5.2 | 4 | 4.3 | 5.83 |
| α (ppm/° C.) | | | | | | | |
| Liquidus temperature TL (° C.) | 1191 | 1194 | 1120 | 1150 | 1235 | 1236 | 1260 |
| Young's modulus parameter Y | 0.96 | 0.95 | 1.03 | 1.07 | 0.90 | 0.95 | 0.72 |
| Liquidus parameter L | 10.9 | 10.6 | 7.9 | 7.1 | 11.2 | 11.1 | 11.3 |
| Thermal expansion parameter C | 0.82 | 0.85 | 1.29 | 1.36 | 0.77 | 0.83 | 1.01 |
| Glass transition point (° C.) | | | | | 773 | | 750 |
| Density (g/cm³) | 2.67 | 2.68 | 3.24 | 3.19 | 2.53 | | 2.99 |
| Liquidus viscosity log η_{L}(dPa · s) | 4.27 | | | | | | |
| K_{IC} (MPa · m^{0.5}) | | | | | | | <0.8 |
| Transmittance (%) @308 nm, 0.7 mmt | 30≤ | 30≤ | <0.1 | <0.1 | 30≤ | 30≤ | 30≤ |
| Transmittance (%) @350 nm, 0.7 mmt | 70≤ | 70≤ | <0.1 | <0.1 | 70≤ | 70≤ | 70≤ |
| Transmittance (%) @550 nm, 0.7 mmt | 85≤ | 85≤ | <0.1 | <0.1 | 85≤ | 85≤ | 85≤ |
| Transmittance (%) @1064 nm, 0.7 mmt | 80 | 80≤ | ≤65 | ≤65 | 80≤ | 80≤ | 80≤ |
| T₂ (° C.) | 1583 | 1506 | <1400 | <1400 | 1630 | 1500< | 1641 |
| T₃ (° C.) | 1342 | 1294 | | | | 1341 | 1413 |
| T₄ (° C.) | 1216 | 1174 | | | 1239 | | 1255 |
| Deflection determination | ∘ | x | ∘ | ∘ | x | ∘ | x |
| Manufacturability determination | × | x | ∘ | ∘ | x | x | x |
| Transmission ability determination | ∘ | ∘ | x | x | ∘ | ∘ | ∘ |

TABLE 110

| | Example | Example | Example |
|---|---|---|---|
| (mol %) | 767 | 768 | 769 |
| SiO₂ | 67 | 52.7 | 50 |
| Al₂O₃ | 7.7 | 12 | 11 |
| B₂O₃ | 6.1 | | |
| MgO | 3.6 | 21.2 | 15.2 |
| CaO | 4 | 14.1 | 23.8 |
| SrO | 4.7 | | |
| BaO | 7 | | |
| Li₂O | | | |
| Na₂O | | | |
| K₂O | | | |
| ZnO | | | |
| P₂O₅ | | | |
| ZrO₂ | | | |
| TiO₂ | | | |
| Y₂O₃ | | | |
| Gd₂O₃ | | | |
| La₂O₃ | | | |
| WO₃ | | | |
| Ta₂O₅ | | | |
| MnO | | | |
| Al₂O₃ + rare earth oxide | 7.7 | 12 | 11 |
| Y₂O₃ + Gd₂O₃ + La₂O₃ + Nd₂O₃ + Ta₂O₅ + Nb₂O₅ | 0 | 0 | 0 |
| Parameter A = (Al₂O₃ + RO)/(SiO₂ + Al₂O₃ + RO) | 0.29 | 0.47 | 0.50 |
| (Al₂O₃ + MgO)/(SiO₂ + Al₂O₃ + B₂O₃ + MgO) | 0.13 | 0.39 | 0.34 |
| MgO/ΣRO | 0.19 | 0.60 | 0.39 |
| N | 7 | 4 | 4 |
| Young's modulus E (GPa) | 76 | 100 | 100 |
| Coefficient of thermal expansion α (ppm/° C.) | 4.83 | 5.1 | 6 |
| Liquidus temperature TL (° C.) | 1255 | 1305 | 1335 |
| Young's modulus parameter Y | 0.73 | 1.00 | 0.98 |
| Liquidus parameter L | 10.7 | 10.5 | 10.6 |
| Thermal expansion parameter C. | 0.88 | 1.01 | 1.19 |
| Glass transition point (° C.) | 690 | 754 | 745 |
| Density (g/cm³) | 2.77 | 2.71 | 2.77 |
| Liquidus viscosity log η_{L} (dPa · s) | | 2.33 | 1.94 |
| K_{IC} (Mpa · m^{0.5}) | <0.8 | | |
| Transmittance (%) @308 nm, 0.7 mmt | 30≤ | 30≤ | 30≤ |
| Transmittance (%) @350 nm, 0.7 mmt | 70≤ | 70≤ | 70≤ |
| Transmittance (%) @550 nm, 0.7 mmt | 85≤ | 85≤ | 85≤ |
| Transmittance (%) @1064 nm, 0.7 mmt | 80≤ | 80≤ | 80≤ |
| T₂ (° C.) | 1629 | 1367 | 1321 |
| T₃ (° C.) | 1388 | | |
| T₄ (° C.) | 1225 | 1146 | 1091 |
| Deflection determination | x | ∘ | ∘ |
| Manufacturability determination | x | x | x |
| Transmission ability determination | ∘ | ∘ | ∘ |

TABLE 111

| | Example | Example | Example | Example | Example | Example | Example | Example |
|---|---|---|---|---|---|---|---|---|
| (mol %) | 770 | 771 | 772 | 773 | 774 | 775 | 776 | 777 |
| SiO₂ | 48 | 48.8 | 49 | 49.1 | 50 | 50 | 50 | 50 |
| Al₂O₃ | 8.7 | 7.2 | 10.1 | 10 | 10 | 10 | 8 | 8 |
| B₂O₃ | 6.9 | 6.8 | 6.7 | 6.6 | 6 | 6 | 6 | 6 |
| MgO | 17.7 | 18.3 | 18.5 | 18.3 | 20 | 18 | 22 | 20 |
| CaO | 0.5 | 2.8 | 2.2 | 0.5 | 2 | 2 | 2 | 2 |
| SrO | 0.3 | 1.9 | 3.6 | 1.4 | 2 | 2 | 2 | 2 |
| BaO | 3.5 | 3.2 | 1.2 | 1.1 | 4 | 4 | 4 | 4 |
| Li₂O | 1.3 | 2.8 | 1.4 | 2.8 | | | | |
| Na₂O | 2.7 | 0 | 1.6 | | | | | |
| K₂O | | | 0.9 | 0.5 | | | | |
| ZnO | 4.2 | 2.1 | | 0.4 | | | | |
| P₂O₅ | | | | | | | | |
| ZrO₂ | 0.6 | 1.2 | 0.8 | 0.9 | 1 | 1 | 1 | 1 |
| TiO₂ | 2.4 | 1.7 | 0.4 | 0.7 | 3 | 5 | 3 | 5 |
| Y₂O₃ | 2.5 | 1.6 | 2.9 | 4.1 | 2 | 2 | 2 | 2 |
| Gd₂O₃ | | | | | | | | |
| La₂O₃ | 0.7 | 1.6 | 0.7 | 3.6 | | | | |
| WO₃ | | | | | | | | |
| Ta₂O₅ | | | | | | | | |
| Al₂O₃ + rare earth oxide | 11.9 | 10.4 | 13.7 | 17.7 | 12.0 | 12.0 | 10.0 | 10.0 |
| Y₂O₃ + Gd₂O₃ + La₂O₃ + Nd₂O₃ + Ta₂O₅ + Nb₂O₅ | 3.2 | 3.2 | 3.6 | 7.7 | 2.0 | 2.0 | 2.0 | 2.0 |
| Parameter A = (Al₂O₃ + RO)/(SiO₂ + Al₂O₃ + RO) | 0.42 | 0.42 | 0.42 | 0.39 | 0.43 | 0.42 | 0.43 | 0.42 |
| (Al₂O₃ + MgO)/(SiO₂ + Al₂O₃ + B₂O₃ + MgO) | 0.32 | 0.31 | 0.34 | 0.34 | 0.35 | 0.33 | 0.35 | 0.33 |
| MgO/ΣRO | 0.68 | 0.65 | 0.73 | 0.84 | 0.71 | 0.69 | 0.73 | 0.71 |
| N | 13 | 13 | 13 | 13 | 10 | 10 | 10 | 10 |
| Young's modulus E (GPa) | 97 | 101 | 98 | 106 | 97 | 97 | 97 | 97 |
| Coefficient of thermal expansion α (ppm/° C.) | 5.90 | 5.82 | 6.00 | 5.83 | 5.08 | 5.17 | 5.22 | 4.97 |
| Liquidus temperature TL (° C.) | 1135 | 1135 | 1145 | 1095 | 1155 | 1185 | 1185 | 1155 |
| Young's modulus parameter Y | 0.98 | 1.00 | 0.99 | 1.08 | 0.95 | 0.95 | 0.95 | 0.95 |
| Liquidus parameter L | 9.2 | 8.7 | 8.8 | 8.5 | 10.3 | 10.8 | 10.0 | 10.4 |
| Thermal expansion parameter C | 1.25 | 1.13 | 1.22 | 1.12 | 0.99 | 0.98 | 1.02 | 1.02 |
| Glass transition point (° C.) | | | | | | 720 | | |
| Density (g/cm³) | 3.01 | 3.08 | 2.92 | 3.21 | 2.94 | 2.94 | 2.95 | 3.00 |
| Liquidus viscosity log η_{L}(dPa · s) | 2.5< | 2.5< | 3.09 | 2.5< | 3.2* | 2.92 | 2.9* | 3.3* |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 0.1≤ | 0.1≤ | 5≤ | 5≤ | 0.1≤ | 0< | 0.1≤ | 0< |
| Transmittance (%) @350 nm, 0.7 mmt | 75≤ | 75≤ | 80≤ | 80≤ | 80≤ | 75≤ | 80≤ | 75≤ |
| Transmittance (%) @550 nm, 0.7 mmt | 88≤ | 88≤ | 88≤ | 88≤ | 88≤ | 88≤ | 88≤ | 88≤ |
| Transmittance (%) @1064 nm, 0.7 mmt | 88≤ | 88≤ | 88≤ | 88≤ | 88≤ | 88≤ | 88≤ | 88≤ |
| T₂ (° C.) | <1350 | <1350 | <1350 | <1350 | <1350 | 1317 | <1350 | <1350 |
| T₃ (° C.) | <1200 | <1200 | <1200 | <1200 | <1200 | 1175 | <1200 | <1200 |
| T₄ (° C.) | <1100 | <1100 | <1100 | <1100 | <1100 | 1076 | <1100 | <1100 |
| Sulfuric acid resistance (amount of weight loss (mg/cm²)) | | | | | 0.023 | 0.010 | 0.017 | 0.009 |
| Sulfuric acid resistance (transmission ability) | | | | | x | x | x | x |
| Sulfuric acid resistance parameter S | | | | | −2.13 | −3.48 | −2.62 | −3.66 |
| Acid resistance parameter T | 0.44 | 0.59 | 0.41 | 0.52 | 0.83 | 0.96 | 0.88 | 1.02 |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 112

| | Example | Example | Example | Example | Example | Example | Example | Example |
|---|---|---|---|---|---|---|---|---|
| (mol %) | 778 | 779 | 780 | 781 | 782 | 783 | 784 | 785 |
| SiO₂ | 53 | 53 | 50 | 50 | 50 | 50 | 51 | 50 |
| Al₂O₃ | 9 | 9.5 | 10 | 9.33 | 8 | 8 | 8 | 8 |
| B₂O₃ | 6 | 6 | 6 | 6 | 6 | 6 | 6 | 6 |
| MgO | 17 | 17 | 21 | 18.7 | 19 | 20.5 | 19.5 | 20.5 |
| CaO | 2 | 2 | 2 | 2 | 3 | 4 | 2.5 | 4 |
| SrO | 2 | 2 | 2 | 2 | 3 | 3 | 3 | 3 |
| BaO | 4 | 4 | 4 | 4 | 2 | 0.5 | 2 | |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1.5 | 1 | 1 | 2 | 1 | 1 | 1 |
| TiO₂ | 2 | 0.5 | 1 | 5 | 5 | 5 | 5 | 5 |
| Y₂O₃ | 4 | 4 | 2 | 2 | 2 | 2 | 2 | 2.5 |
| Gd₂O₃ | | | | | | | | |
| La₂O₃ | | | | | | | | |
| WO₃ | | | | | | | | |
| Ta₂O₅ | | | 1 | | | | | |
| Al₂O₃ + rare earth oxide | 13.0 | 13.5 | 12.0 | 11.3 | 10.0 | 10.0 | 10.0 | 10.5 |
| Y₂O₃ + Gd₂O₃ + La₂O₃ + Nd₂O₃ + Ta₂O₅ + Nb₂O₅ | 4.0 | 4.0 | 3.0 | 2.0 | 2.0 | 2.0 | 2.0 | 2.5 |
| Parameter A = (Al₂O₃ + RO)/(SiO₂ + Al₂O₃ + RO) | 0.39 | 0.39 | 0.44 | 0.42 | 0.41 | 0.42 | 0.41 | 0.42 |
| (Al₂O₃ + MgO)/(SiO₂ + Al₂O₃ + B₂O₃ + MgO) | 0.31 | 0.31 | 0.36 | 0.33 | 0.33 | 0.34 | 0.33 | 0.34 |
| MgO/ΣRO | 0.68 | 0.68 | 0.72 | 0.70 | 0.70 | 0.73 | 0.72 | 0.75 |
| N | 10 | 10 | 11 | 10 | 10 | 10 | 10 | 9 |
| Young's modulus E (GPa) | 97 | 97 | 99 | 96 | 99 | 100 | 97 | 101 |
| Coefficient of thermal expansion α (ppm/° C.) | 5.02 | 4.99 | 4.98 | 5.01 | 5.12 | 5.05 | 5.02 | 5.04 |
| Liquidus temperature TL (° C.) | 1145 | 1175 | 1175 | 1155 | 1235 | 1185 | 1140 | 1155 |
| Young's modulus parameter Y | 0.96 | 0.97 | 0.97 | 0.95 | 0.98 | 0.99 | 0.96 | 1.00 |
| Liquidus parameter L | 10.1 | 9.9 | 9.9 | 10.6 | 10.2 | 9.9 | 10.1 | 9.8 |
| Thermal expansion parameter C | 1.00 | 1.01 | 0.99 | 0.99 | 1.03 | 1.01 | 1.00 | 1.02 |
| Glass transition point (° C.) | | | | 721 | 720 | 713 | 715 | 719 |
| Density (g/cm³) | 3.00 | 3.00 | 3.04 | 2.93 | 2.94 | 2.87 | 2.89 | 2.88 |
| Liquidus viscosity log η_{L}(dPa · s) | 3.4< | 3.1< | 3.08 | 3.11 | 2.5* | 2.70 | 3.2 | 2.95 |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 30≤ | 30≤ | 30≤ | 0< | 0< | 0< | 0< | 0< |
| Transmittance (%) @350 nm, 0.7 mmt | 85≤ | 85≤ | 85≤ | 75≤ | 75≤ | 75≤ | 75≤ | 75≤ |
| Transmittance (%) @550 nm, 0.7 mmt | 90≤ | 90≤ | 90≤ | 88≤ | 88≤ | 88≤ | 88≤ | 88≤ |
| Transmittance (%) @1064 nm, 0.7 mmt | 90≤ | 90≤ | 90≤ | 88≤ | 88≤ | 88≤ | 88≤ | 88≤ |
| T₂ (° C.) | <1400 | <1400 | 1323 | 1310 | <1350 | 1286 | 1304 | 1285 |
| T₃ (° C.) | <1250 | <1250 | 1184 | 1167 | <1200 | 1150 | 1162 | 1150 |
| T₄ (° C.) | <1150 | <1150 | 1088 | 1069 | <1100 | 1056 | 1065 | 1057 |
| Sulfuric acid resistance (amount of weight loss (mg/cm²)) | 0.014 | 0.023 | 0.011 | 0.010 | 0.005 | 0.009 | 0.006 | 0.010 |
| Sulfuric acid resistance (transmission ability) | x | x | x | x | ∘ | ∘ | ∘ | ∘ |
| Sulfuric acid resistance parameter S | −2.91 | −2.12 | −3.34 | −3.50 | −5.33 | −3.96 | −6.63 | −7.17 |
| Acid resistance parameter T | 0.89 | 0.82 | 0.97 | 0.98 | 1.16 | 1.05 | 1.10 | 1.05 |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 113

| | Example | Example | Example | Example | Example | Example | Example | Example |
|---|---|---|---|---|---|---|---|---|
| (mol %) | 786 | 787 | 788 | 789 | 790 | 791 | 792 | 793 |
| SiO₂ | 52.6 | 50.5 | 52 | 50 | 50 | 50 | 55 | 54 |
| Al₂O₃ | 7.7 | 7.75 | 6 | 6.5 | 7.5 | 5.5 | 6.5 | 6.5 |
| B₂O₃ | 3.8 | 6.25 | 5.5 | 4 | 6 | 6 | 3 | 3 |
| MgO | 19.6 | 15 | 15 | 20 | 18 | 18 | 20 | 18 |
| CaO | 2.9 | 1 | 3 | 6 | 3 | 3 | 5 | 1 |
| SrO | 3.8 | 3 | 8 | 3 | 7 | 4 | 3 | 10 |
| BaO | | 3 | | | | | | |
| Li₂O | | | | | | | | |
| Na₂O | | | | | | | | |
| K₂O | | | | | | | | |
| ZnO | | 1 | | | | 1 | | |
| P₂O₅ | | | | | | | | |
| ZrO₂ | 1.0 | 0.5 | 1 | 1 | 0.5 | 1.5 | 1.5 | 1 |
| TiO₂ | 4.8 | 5 | 4 | 5 | 2 | 5 | 1 | 1 |
| Y₂O₃ | 3.8 | 3 | 3.5 | 4.5 | 3 | 2.5 | 3 | 5.5 |
| Gd₂O₃ | | | | | | | | |
| La₂O₃ | | 3 | | | 3 | 3.5 | 2 | |
| WO₃ | | | | | | | | |
| Ta₂O₅ | | 1 | 2 | | | | | |
| Al₂O₃ + rare earth oxide | 11.5 | 13.8 | 9.5 | 11.0 | 13.5 | 11.5 | 11.5 | 12.0 |
| Y₂O₃ + Gd₂O₃ + La₂O₃ + Nd₂O₃ + Ta₂O₅ + Nb₂O₅ | 3.8 | 7.0 | 5.5 | 4.5 | 6.0 | 6.0 | 5.0 | 5.5 |
| Parameter A = (Al₂O₃ + RO)/(SiO₂ + Al₂O₃ + RO) | 0.39 | 0.38 | 0.38 | 0.42 | 0.42 | 0.39 | 0.39 | 0.40 |
| (Al₂O₃ + MgO)/(SiO₂ + Al₂O₃ + B₂O₃ + MgO) | 0.33 | 0.29 | 0.27 | 0.33 | 0.31 | 0.30 | 0.31 | 0.30 |
| MgO/ΣRO | 0.75 | 0.65 | 0.58 | 0.69 | 0.64 | 0.69 | 0.71 | 0.62 |
| N | 9 | 13 | 10 | 9 | 10 | 11 | 10 | 9 |
| Young's modulus E (GPa) | 104 | 101 | 107 | 101 | 103 | 105 | 103 | 103 |
| Coefficient of thermal expansion α (ppm/° C.) | 5.10 | 5.52 | 5.38 | 5.60 | 5.91 | 5.78 | 5.43 | 5.83 |
| Liquidus temperature TL (° C.) | 1175 | 1145 | 1275 | 1155 | 1135 | 1215 | 1195 | 1235 |
| Young's modulus parameter Y | 1.03 | 1.00 | 1.01 | 1.04 | 1.03 | 1.04 | 1.04 | 1.05 |
| Liquidus parameter L | 9.9 | 9.9 | 9.2 | 9.8 | 8.3 | 9.0 | 9.1 | 8.5 |
| Thermal expansion parameter C | 1.03 | 1.08 | 1.12 | 1.12 | 1.19 | 1.15 | 1.09 | 1.19 |
| Glass transition point (° C.) | | | | | | | | |
| Density (g/cm³) | 2.96 | 3.34 | 3.05 | 3.23 | 3.22 | 3.25 | 3.08 | 3.16 |
| Liquidus viscosity log η_{L}(dPa · s) | 2.98 | 2< | 2.12 | 2.84 | 2.95 | 2.08 | 2< | 2< |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 0< | 0< | 0< | 0< | 5≤ | 0< | 30≤ | 5≤ |
| Transmittance (%) @350 nm, 0.7 mmt | 75≤ | 75≤ | 75≤ | 75≤ | 85≤ | 75≤ | 85≤ | 85≤ |
| Transmittance (%) @550 nm, 0.7 mmt | 88≤ | 88≤ | 88≤ | 88≤ | 88≤ | 88≤ | 88≤ | 88≤ |
| Transmittance (%) @1064 nm, 0.7 mmt | 88≤ | 88≤ | 88≤ | 88≤ | 88≤ | 88≤ | 88≤ | 88≤ |
| T₂ (° C.) | 1306 | <1350 | 1294 | 1258 | 1250 | 1256 | <1300 | <1300 |
| T₃ (° C.) | 1174 | <1200 | 1163 | 1139 | 1130 | 1117 | <1200 | <1200 |
| T₄ (° C.) | 1082 | <1100 | 1073 | 1055 | 1047 | 1031 | <1100 | <1100 |
| Sulfuric acid resistance (amount of weight loss (mg/cm²)) | 0.004 | 0.006 | 0.001 | 0.008 | 0.088 | 0.016 | 0.005 | 0.023 |
| Sulfuric acid resistance (transmission ability) | ∘ | x | ∘ | ∘ | x | ∘ | ∘ | ∘ |
| Sulfuric acid resistance parameter S | −6.33 | −7.50 | −8.99 | −11.25 | −7.86 | −6.73 | −8.63 | −6.14 |
| Acid resistance parameter T | 1.20 | 1.09 | 1.51 | 0.99 | 0.50 | 0.99 | 1.08 | 0.81 |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 114

| | Example | Example | Example | Example | Example | Example | Example | Example |
|---|---|---|---|---|---|---|---|---|
| (mol %) | 794 | 795 | 796 | 797 | 798 | 799 | 800 | 801 |
| SiO₂ | 53 | 52.6 | 52.6 | 52.7 | 50 | 50 | 50 | 50 |
| Al₂O₃ | 7 | 7.7 | 7.7 | 8.2 | 7.1 | 8 | 8 | 8 |
| B₂O₃ | 3.5 | 3.8 | 3.8 | 3.9 | 5.9 | 6 | 6 | 6 |
| MgO | 16 | 19.6 | 19.6 | 18.7 | 20.2 | 20.5 | 20.5 | 20 |
| CaO | 9 | 2.9 | 2.6 | 2.3 | 3.5 | 2 | 2.5 | 3 |
| SrO | | 3.8 | 4.1 | 5.6 | 3.6 | 5 | 4.5 | 4 |
| BaO | | | | | | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 1 | 4.8 | 4.8 | 4.5 | 5.2 | 5 | 5 | 5 |
| Y₂O₃ | 6 | 3.8 | 3.8 | 3.1 | 3.5 | 2 | 2 | 2.5 |
| Gd₂O₃ | | | | | | | | |
| La₂O₃ | 3.5 | | | | | | | |
| WO₃ | | | | | | | | |
| Ta₂O₅ | | | | | | | | |
| Al₂O₃ + rare earth oxide | 16.5 | 11.5 | 11.5 | 11.3 | 10.6 | 10.0 | 10.0 | 10.5 |
| Y₂O₃ + Gd₂O₃ + La₂O₃ + Nd₂O₃ + Ta₂O₅ + Nb₂O₅ | 9.5 | 3.8 | 3.8 | 3.1 | 3.5 | 2.0 | 2.0 | 2.5 |
| Parameter A = (Al₂O₃ + RO)/(SiO₂ + Al₂O₃ + RO) | 0.38 | 0.39 | 0.39 | 0.40 | 0.41 | 0.42 | 0.42 | 0.42 |
| (Al₂O₃ + MgO)/(SiO₂ + Al₂O₃ + B₂O₃ + MgO) | 0.29 | 0.33 | 0.33 | 0.32 | 0.33 | 0.34 | 0.34 | 0.33 |
| MgO/ΣRO | 0.64 | 0.75 | 0.75 | 0.70 | 0.74 | 0.73 | 0.73 | 0.73 |
| N | 9 | 9 | 9 | 9 | 9 | 10 | 10 | 10 |
| Young's modulus E (GPa) | 110 | 104 | 102 | 104 | 103 | 100 | 100 | 101 |
| Coefficient of thermal expansion α (ppm/° C.) | 5.86 | 5.10 | 5.05 | 5.06 | 5.23 | 5.06 | 5.07 | 5.10 |
| Liquidus temperature TL (° C.) | 1245 | 1165 | 1185 | 1175 | 1155 | 1165 | 1165 | 1155 |
| Young's modulus parameter Y | 1.10 | 1.03 | 1.03 | 1.02 | 1.01 | 0.99 | 0.99 | 0.99 |
| Liquidus parameter L | 9.2 | 10.0 | 9.9 | 9.8 | 9.7 | 9.6 | 9.7 | 9.8 |
| Thermal expansion parameter C | 1.18 | 1.03 | 1.03 | 1.04 | 1.05 | 1.03 | 1.03 | 1.03 |
| Glass transition point (° C.) | | | | | | | | |
| Density (g/cm³) | 3.33 | 2.97 | 2.97 | 2.96 | 2.95 | 2.90 | 2.89 | 2.91 |
| Liquidus viscosity log η_{L}(dPa · s) | 2< | 2.5< | 2.5< | 2.5< | 2.5< | 2.5< | 2.5< | 2.5< |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 5≤ | 0< | 0< | 0< | 0< | 0< | 0< | 0< |
| Transmittance (%) @350 nm, 0.7 mmt | 85≤ | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ | 88≤ |
| Transmittance (%) @1064 nm, 0.7 mmt | 88≤ | 88≤ | 88≤ | 88≤ | 88≤ | 88≤ | 88≤ | 88≤ |
| T₂ (° C.) | <1300 | 1304 | <1350 | <1350 | <1350 | <1350 | <1350 | 1280 |
| T₃ (° C.) | <1200 | 1170 | <1200 | <1200 | <1200 | <1200 | <1200 | 1144 |
| T₄ (° C.) | <1100 | 1079 | <1100 | <1100 | <1100 | <1100 | <1100 | 1054 |
| Sulfuric acid resistance (amount of weight loss (mg/cm²)) | 0.05 | 0.003 | 0.003 | 0.004 | 0.008 | 0.007 | 0.007 | 0.007 |
| Sulfuric acid resistance (transmission ability) | ∘ | ∘ | ∘ | ∘ | ∘ | ∘ | ∘ | ∘ |
| Sulfuric acid resistance parameter S | −4.88 | −9.46 | −9.46 | −8.99 | −7.86 | −7.58 | −7.58 | −7.58 |
| Acid resistance parameter T | 0.68 | 1.20 | 1.20 | 1.14 | 1.06 | 1.04 | 1.04 | 1.03 |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 115

| | Example | Example | Example | Example | Example | Example | Example | Example |
|---|---|---|---|---|---|---|---|---|
| (mol %) | 802 | 803 | 804 | 805 | 806 | 807 | 808 | 809 |
| SiO₂ | 50 | 49.5 | 49.5 | 50 | 50 | 50 | 50 | 50 |
| Al₂O₃ | 7.8 | 8 | 8 | 8 | 8 | 8 | 8 | 8.5 |
| B₂O₃ | 5.2 | 6 | 6 | 5.5 | 5.5 | 6 | 6 | 5.5 |
| MgO | 20.5 | 20 | 20 | 20 | 20 | 19.5 | 19.5 | 20 |
| CaO | 4.5 | 3.5 | 3 | 3.5 | 3 | 3.5 | 3 | 3 |
| SrO | 3.2 | 4 | 4.5 | 4 | 4.5 | 4 | 4.5 | 4 |
| BaO | 0.5 | 0.5 | 0.5 | 0.5 | 0.5 | 0.5 | 0.5 | 0.5 |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 4.7 | 5 | 5 | 5 | 5 | 5 | 5 | 5 |
| Y₂O₃ | 2.6 | 2.5 | 2.5 | 2.5 | 2.5 | 2.5 | 2.5 | 2.5 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 10.4 | 10.5 | 10.5 | 10.5 | 10.5 | 10.5 | 10.5 | 11.0 |
| Y₂O₃ + Gd₂O₃ + La₂O₃ + Nd₂O₃ + | 2.6 | 2.5 | 2.5 | 2.5 | 2.5 | 2.5 | 2.5 | 2.5 |
| Ta₂O₅ + Nb₂O₅ | | | | | | | | |
| Parameter A = (Al₂O₃ + RO)/(SiO₂ + | 0.42 | 0.42 | 0.42 | 0.42 | 0.42 | 0.42 | 0.42 | 0.42 |
| Al₂O₃ + RO) | | | | | | | | |
| (Al₂O₃ + MgO)/(SiO₂ + Al₂O₃ + B₂O₃ + MgO) | 0.34 | 0.34 | 0.34 | 0.34 | 0.34 | 0.33 | 0.33 | 0.34 |
| MgO/ΣRO | 0.71 | 0.71 | 0.71 | 0.71 | 0.71 | 0.71 | 0.71 | 0.73 |
| N | 10 | 10 | 10 | 10 | 10 | 10 | 10 | 10 |
| Young's modulus E (GPa) | 102 | 101 | 101 | 101 | 101 | 100 | 100 | 101 |
| Coefficient of thermal expansion α (ppm/° C.) | 5.24 | 5.19 | 5.20 | 5.18 | 5.18 | 5.14 | 5.14 | 5.10 |
| Liquidus temperature TL (° C.) | 1165 | <1200 | <1200 | <1200 | <1200 | <1200 | <1200 | <1200 |
| Young's modulus parameter Y | 1.00 | 0.99 | 1.00 | 1.00 | 1.00 | 0.99 | 0.99 | 1.00 |
| Liquidus parameter L | 9.8 | 9.8 | 9.7 | 9.8 | 9.8 | 9.8 | 9.7 | 9.9 |
| Thermal expansion parameter C | 1.05 | 1.04 | 1.05 | 1.04 | 1.05 | 1.04 | 1.04 | 1.03 |
| Glass transition point (° C.) | | | | | | | | |
| Density (g/cm³) | 2.92 | 2.91 | 2.91 | 2.91 | 2.92 | 2.90 | 2.91 | 2.90 |
| Liquidus viscosity log η_{L}(dPa · s) | 2.5< | 2.5< | 2.5< | 2.5< | 2.5< | 2.5< | 2.5< | 2.5< |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 0< | 0< | 0< | 0< | 0< | 0< | 0< | 0< |
| Transmittance (%) @350 nm, 0.7 mmt | 75≤ | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ | 88≤ |
| Transmittance (%) @1064 nm, 0.7 mmt | 88≤ | 88≤ | 88≤ | 88≤ | 88≤ | 88≤ | 88≤ | 88≤ |
| T₂ (° C.) | <1350 | <1300 | <1300 | <1300 | <1300 | <1300 | <1300 | <1300 |
| T₃ (° C.) | <1200 | <1200 | <1200 | <1200 | <1200 | <1200 | <1200 | <1200 |
| T₄ (° C.) | <1100 | <1100 | <1100 | <1100 | <1100 | <1100 | <1100 | <1100 |
| Sulfuric acid resistance (amount of weight | 0.008 | <0.010 | <0.010 | <0.010 | <0.010 | <0.010 | <0.010 | <0.010 |
| loss (mg/cm²)) | | | | | | | | |
| Sulfuric acid resistance (transmission ability) | ∘ | ∘ | ∘ | ∘ | ∘ | ∘ | ∘ | ∘ |
| Sulfuric acid resistance parameter S | −7.36 | | | | | | | |
| Acid resistance parameter T | 1.00 | | | | | | | |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 116

| | Example | Example | Example | Example | Example | Example | Example | Example |
|---|---|---|---|---|---|---|---|---|
| (mol %) | 810 | 811 | 812 | 813 | 814 | 815 | 816 | 817 |
| SiO₂ | 50 | 50 | 50 | 50 | 50 | 50 | 50 | 50 |
| Al₂O₃ | 8 | 8 | 8 | 8 | 8 | 8 | 8 | 8 |
| B₂O₃ | 5.8 | 5.8 | 5.9 | 5.9 | 6 | 6 | 6 | 6 |
| MgO | 20 | 18.2 | 20 | 20 | 19.8 | 19.9 | 19.6 | 19.5 |
| CaO | 3 | 4 | 3.5 | 3 | 3.2 | 3.1 | 4.1 | 4.2 |
| SrO | 4 | 4 | 4 | 4.5 | 4.2 | 4.3 | 4.2 | 4 |
| BaO | 0.5 | 0.5 | 0.5 | 0.5 | 0.3 | 0.2 | | |
| Li₂O | | | | | | | | |
| Na₂O | | | | | | | | |
| K₂O | | | | | | | | |
| ZnO | | | | | | | | |
| P₂O₅ | | | | | | | | |
| ZrO₂ | 1 | 1 | 1 | 1 | 1 | 1 | 1 | 1 |
| TiO₂ | 5 | 5 | 5 | 5 | 5 | 5 | 5 | 5 |
| Y₂O₃ | 2.7 | 2.5 | 2.1 | 2.1 | 2.5 | 2.5 | 2.1 | 2.3 |
| Gd₂O₃ | | | | | | | | |
| La₂O₃ | | | | | | | | |
| WO₃ | | | | | | | | |
| Ta₂O₅ | | | | | | | | |
| Al₂O₃ + rare earth oxide | 10.7 | 10.5 | 10.1 | 10.1 | 10.5 | 10.5 | 10.1 | 10.3 |
| Y₂O₃ + Gd₂O₃ + La₂O₃ + Nd₂O₃ + | 2.7 | 2.5 | 2.1 | 2.1 | 2.5 | 2.5 | 2.1 | 2.3 |
| Ta₂O₅ + Nb₂O₅ | | | | | | | | |
| Parameter A = (Al₂O₃ + RO)/(SiO₂ + | 0.42 | 0.40 | 0.42 | 0.42 | 0.42 | 0.42 | 0.42 | 0.42 |
| Al₂O₃ + RO) | | | | | | | | |
| (Al₂O₃ + MgO)/(SiO₂ + Al₂O₃ + B₂O₃ + MgO) | 0.33 | 0.32 | 0.33 | 0.33 | 0.33 | 0.33 | 0.33 | 0.33 |
| MgO/ΣRO | 0.73 | 0.68 | 0.71 | 0.71 | 0.72 | 0.72 | 0.70 | 0.70 |
| N | 10 | 10 | 10 | 10 | 9 | 9 | 9 | 9 |
| Young's modulus E (GPa) | 101 | 99 | 100 | 100 | 100 | 101 | 100 | 100 |
| Coefficient of thermal expansion α (ppm/° C.) | 5.14 | 5.10 | 5.10 | 5.11 | 5.11 | 5.10 | 5.11 | 5.12 |
| Liquidus temperature TL (° C.) | <1200 | <1200 | <1200 | <1200 | <1200 | <1200 | <1200 | <1200 |
| Young's modulus parameter Y | 1.00 | 0.98 | 0.99 | 0.99 | 0.99 | 1.00 | 0.99 | 0.99 |
| Liquidus parameter L | 9.8 | 9.9 | 9.8 | 9.7 | 9.7 | 9.7 | 9.7 | 9.7 |
| Thermal expansion parameter C | 1.04 | 1.03 | 1.03 | 1.04 | 1.03 | 1.03 | 1.04 | 1.04 |
| Glass transition point (° C.) | | | | | | | | |
| Density (g/cm³) | 2.91 | 2.90 | 2.88 | 2.89 | 2.90 | 2.89 | 2.87 | 2.88 |
| Liquidus viscosity log η_{L}(dPa · s) | 2.5< | 2.5< | 2.5< | 2.5< | 2.5< | 2.5< | 2.5< | 2.5< |
| K_{IC} (MPa · m^{0.5}) | 0.8< | 0.8< | 0.8< | 0.8< | 0.8< | 0.8< | 0.8< | 0.8< |
| Transmittance (%) @308 nm, 0.7 mmt | 0< | 0< | 0< | 0< | 0< | 0< | 0< | 0< |
| Transmittance (%) @350 nm, 0.7 mmt | 75≤ | 75≤ | 75≤ | 75≤ | 75≤ | 75≤ | 75≤ | 75≤ |
| Transmittance (%) @550 nm, 0.7 mmt | 88≤ | 88≤ | 88≤ | 88≤ | 88≤ | 88≤ | 88≤ | 88≤ |
| Transmittance (%) @1064 nm, 0.7 mmt | 88≤ | 88≤ | 88≤ | 88≤ | 88≤ | 88≤ | 88≤ | 88≤ |
| T₂ (° C.) | <1300 | <1310 | <1300 | <1300 | <1300 | <1300 | <1300 | <1300 |
| T₃ (° C.) | <1200 | <1200 | <1200 | <1200 | <1200 | <1200 | <1200 | <1200 |
| T₄ (° C.) | <1100 | <1100 | <1100 | <1100 | <1100 | <1100 | <1100 | <1100 |
| Sulfuric acid resistance (amount of weight | <0.010 | <0.010 | <0.010 | <0.010 | <0.010 | <0.010 | <0.010 | <0.010 |
| loss (mg/cm²)) | | | | | | | | |
| Sulfuric acid resistance (transmission ability) | ∘ | ∘ | ∘ | ∘ | ∘ | ∘ | ∘ | ∘ |
| Sulfuric acid resistance parameter S | | | | | | | | |
| Acid resistance parameter T | | | | | | | | |
| Deflection determination | ∘ | ∘ | ∘ | ∘ | ∘ | ∘ | ∘ | ∘ |
| Manufacturability determination | ∘ | ∘ | ∘ | ∘ | ∘ | ∘ | ∘ | ∘ |
| Transmission ability determination | ∘ | ∘ | ∘ | ∘ | ∘ | ∘ | ∘ | ∘ |

TABLE 117

| | Example | Example | Example | Example |
|---|---|---|---|---|
| (mol %) | 818 | 819 | 820 | 821 |
| SiO₂ | 52.1 | 52.1 | 52.3 | 52.3 |
| Al₂O₃ | 7.7 | 7.7 | 7.7 | 7.7 |
| B₂O₃ | 3.8 | 3.8 | 3.8 | 3.8 |
| MgO | 19.6 | 19.6 | 19.6 | 19.6 |
| CaO | 3.4 | 2.9 | 3.8 | 2.9 |
| SrO | 3.8 | 4.3 | 3.8 | 4.7 |
| BaO | | | | |
| Li₂O | | | | |
| Na₂O | | | | |
| K [symbol] O | | | | |
| ZnO | | | | |
| P₂O [symbol] | | | | |
| ZrO₂ | 1 | 1 | 1 | 1 |
| TiO₂ | 4.8 | 4.8 | 5 | 5 |
| Y₂O₃ | 3.8 | 3.8 | 3 | 3 |
| Gd₂O₃ | | | | |
| La₂O₃ | | | | |
| WO₃ | | | | |
| Ta₂O₅ | | | | |
| Al₂O₃ + rare earth oxide | 11.5 | 11.5 | 10.7 | 10.7 |
| Y₂O₃ + Gd₂O₃ + La₂O₃ + Nd₂O₃ + Ta₂O₅ + Nb₂O₅ | 3.8 | 3.8 | 3.0 | 3.0 |
| Parameter A = (Al₂O₃ + RO)/(SiO₂ + Al₂O₃ + RO) | 0.40 | 0.40 | 0.40 | 0.40 |
| (Al₂O₃ + MgO)/(SiO₂ + Al₂O₃ + B₂O₃ + MgO) | 0.33 | 0.33 | 0.33 | 0.33 |
| MgO/ΣRO | 0.73 | 0.73 | 0.72 | 0.72 |
| N | 9 | 9 | 9 | 9 |
| Young's modulus E (GPa) | 104 | 104 | 102 | 102 |
| Coefficient of thermal expansion α (ppm/° C.) | 5.18 | 5.19 | 5.10 | 6.11 |
| Liquidus temperature TL (° C.) | <1200 | <1200 | <1200 | <1200 |
| Young's modulus parameter Y | 1.03 | 1.03 | 1.02 | 1.02 |
| Liquidus parameter L | 9.9 | 9.9 | 10.0 | 9.9 |
| Thermal expansion parameter C. | 1.04 | 1.05 | 1.03 | 1.04 |
| Glass transition point (° C.) | | | | |
| Density (g/cm [symbol] ) | 2.96 | 2.96 | 2.92 | 2.93 |
| Liquidus viscosity log η_{L} (dPa · s) | 2.5< | 2.5< | 2.5< | 2.5< |
| K_{IC} (Mpa · m^{0.5}) | 0.8< | 0.8< | 0.8< | 0.8< |
| Transmittance (%) @308 nm, 0.7 mmt | 0< | 0< | 0< | 0< |
| Transmittance (%) @350 nm, 0.7 mmt | 75≤ | 75≤ | 75≤ | 75≤ |
| Transmittance (%) @550 nm, 0.7 mmt | 88≤ | 88≤ | 88≤ | 88≤ |
| Transmittance (%) @1064 nm, 0.7 mmt | 88≤ | 88≤ | 88≤ | 88≤ |
| T₂ (° C.) | <1300 | <1300 | <1320 | <1320 |
| T₃ (° C.) | <1200 | <1200 | <1200 | <1200 |
| T₄ (° C.) | <1100 | <1100 | <1100 | <1100 |
| Sulfuric acid resistance (amount of weight loss (mg/cm²)) | <0.010 | <0.010 | <0.010 | <0.010 |
| Sulfuric acid resistance (transmission ability) | ∘ | ∘ | ∘ | ∘ |
| Sulfuric acid resistance parameter S | | | | |
| Acid resistance parameter T | | | | |
| Deflection determination | ∘ | ∘ | ∘ | ∘ |
| Manufacturability determination | ∘ | ∘ | ∘ | ∘ |
| Transmission ability determination | ∘ | ∘ | ∘ | ∘ |

[symbol]

indicates data missing or illegible when filed

### Example 1

In Example 1, a glass having the composition shown in Table 1 was produced. In Example 1, a base plate having a diameter of 320 mm and a thickness of 6 mm was manufactured using a melt casting method. Next, a plurality of plates having a diameter of 300 mm and a thickness of 3 mm were cut out from the center of the base plate. Both surfaces of these plates were polished using cerium oxide as a polishing material to obtain a glass having a thickness of 0.7 mm.

For the glass of Example 1, the Young's modulus E (GPa) was measured. The Young's modulus was measured by an ultrasonic pulse method defined in JIS R 1602:1995 “Testing methods for elastic modulus of fine ceramics”. The bulk density of the sample was measured by the Archimedes method, the longitudinal wave velocity and the transverse wave velocity were measured using an ultrasonic thickness gage 38DL PLUS manufactured by Olympus Corporation, and the value of Young's modulus was determined.

For the glass of Example 1, the coefficient of linear thermal expansion α (ppm/° C.) was measured. Measurement was performed in the range of 30° C. to 300° C. using a dilatometer (DIL 402 Expedis Supreme) manufactured by NETZSCH as a measuring apparatus, and an average coefficient of thermal expansion in the range of 50° C. to 200° C. was defined as the coefficient of linear thermal expansion α.

For the glass of Example 1, the liquidus temperature T_{L} (° C.) was measured. The liquidus temperature T_{L} was measured by placing glass particles, which passed through a sieve with a mesh width of 4.0 mm and did not pass through a sieve with a mesh width of 2.3 mm, on a platinum dish, then holding the glass particles for 1 hour in an electric furnace set at a predetermined temperature, and measuring the temperature at which crystals were precipitated.

For the glass of Example 1, the melting temperature T₂ (° C.), the working temperature T₃ (° C.), and the molding temperature T₄ (° C.) were measured as high temperature viscosity values. The melting temperature T₂, the working temperature T₃, and the molding temperature T₄ were measured by an inner cylinder rotation method. For the glass of Example 1, the Young's modulus parameter Y was calculated using Formula (3).

For the glass of Example 1, the thermal expansion parameter C was calculated using Formula (2).

For the glass of Example 1, the liquidus parameter L was calculated using Formula (3).

For the glass of Example 1, the glass transition temperature (° C.) was measured. The glass transition temperature was measured by obtaining an expansion curve until the glass was softened using a thermal expansion measuring apparatus.

For the glass of Example 1, the density (g/cm³) was measured. The density was measured by the Archimedes method.

For the glass of Example 1, the liquidus viscosity was measured. The liquidus viscosity was measured by measuring a temperature-viscosity curve according to an inner cylinder rotation method and calculating the viscosity at the liquidus temperature.

For the glass of Example 1, the fracture toughness value K_{IC} (MPa·m^{0.5}) was measured. The fracture toughness value K_{IC} was measured using a single-edge-precracked-beam method (SEPB method) as defined in JIS R1607:2015 “Testing methods for fracture toughness of fine ceramics at room temperature”.

For the glass of Example 1, the transmittance for light with a wavelength of 308 nm, the transmittance for light with a wavelength of 350 nm, the transmittance for light with a wavelength of 550 nm, and the transmittance for light with a wavelength of 1064 nm were measured. The transmittance was measured by measuring a spectral transmittance curve using an ultraviolet-visible spectrophotometer (UH4150 type, manufactured by Hitachi High-Tech Corporation).

For the glass of Example 1, the weight (mg) before the acid immersion test and the weight (mg) after the acid immersion test were measured, and the amount of weight loss (amount of weight change) was calculated by the method described in the above embodiment. As the acid immersion test, the glass was immersed in sulfuric acid (H₂SO₄) having a pH of 2 and a temperature of 40° C. for 2 hours. The weight of the states before and after the acid immersion test was accurately measured using an electronic balance.

For the glass of Example 1, the sulfuric acid resistance parameter S was calculated using Formula (4).

For the glass of Example 1, the acid resistance parameter T was calculated using Formula (5).

The measurement results and the calculation results are shown in Table 1.

### Examples 2 to 821

In Examples 2 to 821, a glass was manufactured in the same manner as in Example 1 except that each composition of the glass was as shown in Table 1. The measurement results and calculation results of each example are shown in Tables 1 to 117.

### Evaluation

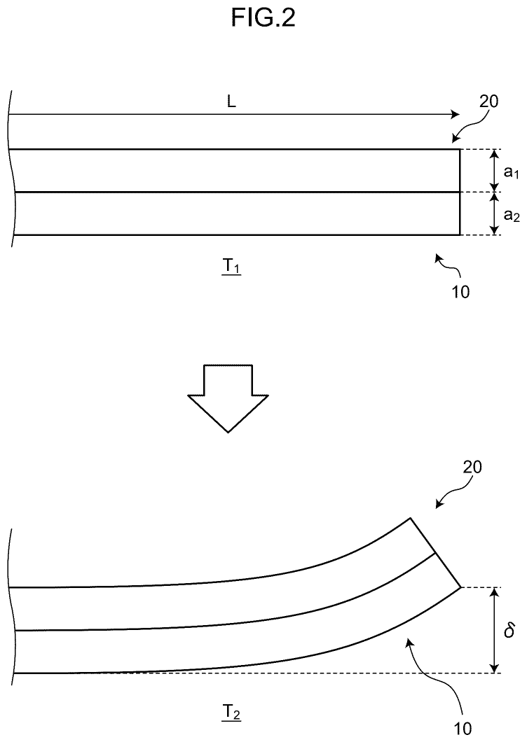

For the glass of each example, deflection and manufacturability were determined. The deflection evaluation was carried out on the basis of the Bi-Metal warpage calculation defined in the document S. Timoshenko, “Analysis of Bi-Metal Thermostats” J. Opt. Soc. Am. 11 (1925) 233. FIG. 2 is a schematic diagram for explaining the deflection evaluation. Here, as illustrated in FIG. 2, the amount of warpage δ is defined as an amount of displacement of the end portion of the glass 10 in either of the vertical up direction or the vertical down direction with the center of the second surface 14 as a height reference, in a process of molding and bonding a semiconductor substrate with a resin to the first surface 12 side of the glass 10 processed into the shape of FIG. 1, the displacement being caused when cooling from a high temperature state of 200° C. to a low temperature of 20° C. is performed. Specifically, the amount of warpage δ is calculated by Formula (4).

$$δ = \frac{6 {L}^{2} ( {α}_{2} - {α}_{1} ) ( {T}_{2} - {T}_{1} ) {( 1 + m )}^{2}}{8 h [ 3 {( 1 + m )}^{2} + ( 1 - mn ) \{ {m}^{2} + {( mn )}^{- 1} \} ]} \qquad ( 1 )$$

Here, as illustrated in FIG. 2, L is a length in a warpage direction (lateral direction in FIG. 2) of the glass 10, α₁ is a coefficient of linear thermal expansion of the resin substrate 20, α₂ is a coefficient of linear thermal expansion of the glass 10, T₂ is a temperature after cooling (here, 20° C.), and T₁ is a temperature before cooling (here, 200° C.). In addition, m is a₁/a₂, h is a₁+a₂, and n is E₁/E₂. Here, a₁ is the thickness of the resin substrate 20, a₂ is the thickness of the glass 10, E₁ is the Young's modulus of the resin substrate 20, and E₂ is the Young's modulus of the glass 10. In the deflection evaluation, the thickness of the resin substrate 20 to be bonded to the glass 10 was assumed to be 0.3 mm and the Young's modulus thereof was assumed to be 31.5 GPa, in consideration of semiconductor mounting. Since application to various manufacturing processes was anticipated, assuming two patterns: {coefficient of linear thermal expansion of glass (ppm/° C.)}+0.5 ppm/° C. and {coefficient of linear thermal expansion of glass (ppm/° C.)}−0.5 ppm/° C., for the coefficient of linear thermal expansion, each amount of warpage δ was calculated in a case where the thickness of the glass 10 was 0.7 mm and length L=300 mm. In the determination of deflection, a case where the total value of the absolute values of the respective calculated values δ was 1.732 mm or less was evaluated as “◯”, and a case where the total value was higher than 1.732 mm was evaluated as “×”. The manufacturability refers to ease of manufacturing, and a case where the liquidus temperature was less than 1300° C. and the melting temperature was less than 1400° C. was evaluated as “◯”, and a case where at least one of a liquidus temperature of 1300° C. or higher or a melting temperature of 1400° C. or higher was satisfied was evaluated as “×”. In the evaluation of the transmission ability, a case where the glass 10 having a thickness D of 0.7 mm had an internal transmittance for light with a wavelength of 350 nm of 70% or more, an internal transmittance for light with a wavelength of 550 nm of 85% or more, and an internal transmittance for light with a wavelength of 1064 nm of 80% or more was evaluated as “◯” and a case where the glass had an internal transmittance for light with a wavelength of 350 nm of less than 70%, an internal transmittance for light with a wavelength of 550 nm of less than 85%, or an internal transmittance for light with a wavelength of 1064 nm of less than 80% was evaluated as “×”

As shown in Tables 1 to 117, in Examples 1 to 759 and 770 to 821 in which the content of SiO₂ is 40% to 60%, the content of B₂O₃ is 0.01% to 15%, the total content of Al₂O₃ and the rare earth oxide is 0% to 20%, and the parameter A is 0.38 or more, the deflection determination, the manufacturability determination, and the transmission ability determination are “◯”, and it can be seen that it is possible to easily manufacture while suppressing deflection and to increase the transmission ability. On the other hand, in Examples 760 to 769, which are comparative examples, at least one of the manufacturability determination, the deflection determination, or the transmission ability is “×”, and it can be seen that it cannot be easily manufactured or it is not suitable as a substrate.

In addition, for some examples, the sulfuric acid resistance (transmission ability) was confirmed as an optional evaluation. It is preferable that there is no change in the transmission ability when the method for determining a change in the transmission ability after exposure to acid described in the above-described embodiment is used as an evaluation method. In the determination of a change in the transmission ability after exposure to acid, at the time of visual observation, a case where no cloudy portion was observed on the surface was evaluated as “◯”, and a case where a cloudy portion was observed was evaluated as “×”.

According to the present invention, it is possible to facilitate manufacturing while suppressing deflection and to enhance the transmission ability.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A glass comprising:
SiO₂: 40% to 60%,
B₂O₃: 0.01% to 15%, and
Al₂O₃+rare earth oxide: 0% to 20%,
as expressed in mol % on an oxide basis,
wherein a ratio of a total content of Al₂O₃ and ΣRO to a total content of SiO₂, Al₂O₃, and ΣRO, which is a total content of divalent oxides, (that is, (Al₂O₃+ΣRO)/(SiO₂+Al₂O₃+ΣRO)) is 0.38 or more.

2. The glass according to claim 1, comprising:
SiO₂: 41% to 59%,
B₂O₃: 1% to 12%,
Al₂O₃: 5% to 20%, and
(Y₂O₃+Gd₂O₃+Ta₂O₅+La₂O₃+Nd₂O₃+Nb₂O₅): 0.5% or more,
as expressed in mol % on an oxide basis.

3. The glass according to claim 1, wherein a transmittance of light with a wavelength of 308 nm at a thickness of 0.7 mm is 30% or more.

4. The glass according to claim 1, wherein
$$0.1 \leq \{ ( {Al}_{2} {O}_{3} + MgO ) / ( {SiO}_{2} + {Al}_{2} {O}_{3} + {B}_{2} {O}_{3} + MgO ) \} \leq 1 ,$$
$$0.3 \leq ( MgO / {Σ}_{RO} ) \leq 1 , and$$
$$0 \% \leq {Al}_{2} {O}_{3} + rare earth oxide \leq 20 \% ,$$
as expressed in mol % on an oxide basis,
wherein ΣRO refers to a total content of divalent oxides contained in the glass.

5. The glass according to claim 1, wherein when a content of an oxide RₓO_{y} contained in the glass in terms of mol % on an oxide basis is represented by [RₓO_{y}],
a Young's modulus parameter Y calculated by Formula (1) is 0.8 or more, a thermal expansion parameter C calculated by Formula (2) is 1.2 or less, and a liquidus parameter L calculated by Formula (3) is 10.5 or less,
$$Y = ( 123 - 0.54 [ {SiO}_{2} ] + 0.3 [ {Al}_{2} {O}_{3} ] - 1.15 [ {B}_{2} {O}_{3} ] + 0.21 [ MgO ] - 0.2 [ CaO ] - 0.1 [ SrO ] - 1.2 [ BaO ] + [ {Li}_{2} O ] - 2.8 [ {K}_{2} O ] + 0.05 [ ZnO ] + 1.46 [ {ZrO}_{2} ] - 0.05 [ {TiO}_{2} ] - 1.6 [ {Y}_{2} {O}_{3} ] + 1.35 [ {Gd}_{2} {O}_{3} ] + 1.37 [ {La}_{2} {O}_{3} ] + [ {Ta}_{2} {O}_{5} ] ) / 100 , \qquad ( 1 )$$
$$C = ( 14.098 - 0.1245 [ {SiO}_{2} ] - 0.131 [ {Al}_{2} {O}_{3} ] - 0.101 [ {B}_{2} {O}_{3} ] - 0.051 [ MgO ] + 0.013 [ CaO ] + 0.053 [ SrO ] + 0.018 [ BaO ] + 0.041 [ {Li}_{2} O ] + 0.395 [ {Na}_{2} O ] - 0.066 [ ZnO ] - 0.033 ] {ZrO}_{2} ] - 0.072 [ {TiO}_{2} ] + 0.035 [ {Y}_{2} {O}_{3} ] + 0.074 [ {Gd}_{2} {O}_{3} ] + 0.074 [ {La}_{2} {O}_{3} ] - 0.091 [ {Ta}_{2} {O}_{5} ] ) / 5 , and \qquad ( 2 )$$
$$L = ( - 642.5 + 20.6 [ {SiO}_{2} ] + 31.9 [ {Al}_{2} {O}_{3} ] + 2.85 [ {B}_{2} {O}_{3} ] + 11.24 [ MgO ] + 17.3 [ CaO ] + 1.75 [ SrO ] + 31.41 [ BaO ] - 6.86 [ {Li}_{2} O ] + 37.96 [ {K}_{2} O ] + 11.47 [ ZnO ] + 25.83 [ {ZrO}_{2} ] + 41. [ {TiO}_{2} ] + 12.32 [ {Y}_{2} {O}_{3} ] - 1.18 [ {Gd}_{2} {O}_{3} ] - 1.18 [ {La}_{2} {O}_{3} ] + 24.46 [ {Ta}_{2} {O}_{5} ] ) / 125. \qquad ( 3 )$$

6. The glass according to claim 1, which is used as a substrate.

7. The glass according to claim 6, which is used in manufacture of at least one of a fan out wafer level package or a fan out panel level package.
